(19) United States
(12) Patent Application Publication
(10) Pub. No.: US 2022/0069239 A1
(43) Pub. Date: Mar. 3, 2022

(54) ORGANOMETALLIC COMPOUND, LIGHT-EMITTING DEVICE INCLUDING THE SAME, AND ELECTRONIC APPARATUS INCLUDING THE LIGHT-EMITTING DEVICE

(71) Applicant: Samsung Display Co., Ltd., Yongin-si (KR)

(72) Inventors: Eunyoung LEE, Yongin-si (KR); Jaesung LEE, Yongin-si (KR); Soobyung KO, Yongin-si (KR); Sungbum KIM, Yongin-si (KR); Sujin SHIN, Yongin-si (KR); Junghoon HAN, Yongin-si (KR)

(21) Appl. No.: 17/307,826

(22) Filed: May 4, 2021

(30) Foreign Application Priority Data
Aug. 28, 2020 (KR) 10-2020-0109468

(51) Int. Cl. H01L 51/00; C07F 15/00; C09K 11/06

(52) U.S. Cl. CPC H01L 51/0087; C07F 15/0086; H01L 51/5012; H01L 51/0094; C09K 11/06

(57) ABSTRACT

An electronic apparatus includes a light-emitting device including an organometallic compound represented by Formula 1-1 or 1-2:

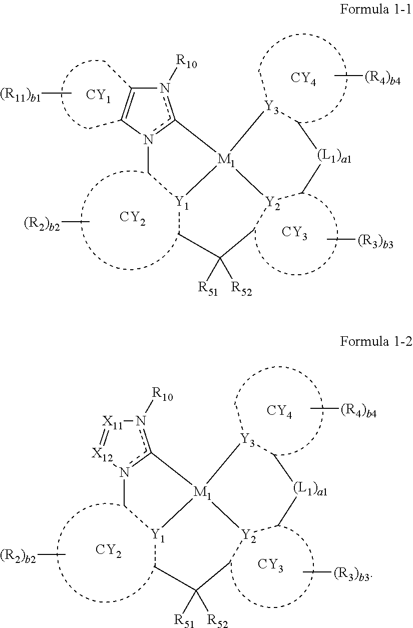

In Formulae 1-1 and 1-2, M₁ may be platinum (Pt), palladium (Pd), copper (Cu), silver (Ag), gold (Au), rhodium (Rh), iridium (Ir), ruthenium (Ru), osmium (Os), titanium (Ti), zirconium (Zr), hafnium (Hf), europium (Eu), terbium (Tb), or thulium (Tm).

### CROSS-REFERENCE TO RELATED APPLICATION

This application claims priority to and benefit of Korean Patent Application No. 10-2020-0109468, filed on Aug. 28, 2020, in the Korean Intellectual Property Office, the entire content of which is incorporated herein by reference.

### BACKGROUND

### 1. Field

One or more aspects of embodiments of the present disclosure relate to an organometallic compound, a light-emitting device including the same, and an electronic apparatus including the light-emitting device.

### 2. Description of Related Art

Self-emissive devices are light-emitting devices that may have wide viewing angles, high contrast ratios, short response times, and/or excellent characteristics in terms of luminance, driving voltage, and/or response speed.

In a light-emitting device, a first electrode is placed on a substrate, and a hole transport region, an emission layer, an electron transport region, and a second electrode are sequentially stacked on the first electrode. Holes provided from the first electrode may move toward the emission layer through the hole transport region, and electrons provided from the second electrode may move toward the emission layer through the electron transport region. Carriers (such as the holes and electrons) may recombine in the emission layer to produce excitons. These excitons may transition from an excited state to a ground state to thereby generate light.

### SUMMARY

One or more aspects of embodiments of the present disclosure are directed toward a novel organometallic compound, a light-emitting device including the same, and an electronic apparatus including the light-emitting device.

Additional aspects will be set forth in part in the description which follows and, in part, will be apparent from the description, or may be learned by practice of the presented embodiments of the disclosure.

One or more embodiments of the present disclosure provide an organometallic compound represented by Formula 1-1 or 1-2:

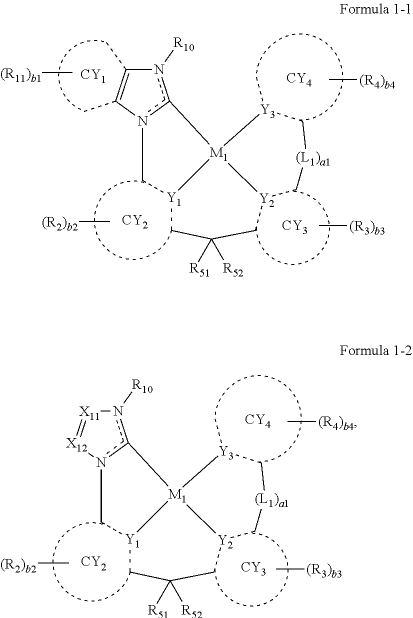

wherein, in Formulae 1-1 and 1-2,

M₁ may be platinum (Pt), palladium (Pd), copper (Cu), silver (Ag), gold (Au), rhodium (Rh), iridium (Ir), ruthenium (Ru), osmium (Os), titanium (Ti), zirconium (Zr), hafnium (Hf), europium (Eu), terbium (Tb), or thulium (Tm),

Y₁ to Y₃ may each independently be N or C,

CY₁ to CY₄ may each independently be a C₃-C₆₀ carbocyclic group or a C₁-C₆₀ heterocyclic group,

X₁₁ may be N or C(R₁₂) and X₁₂ may be N or C(R₁₃),

L₁ may be a single bond, *—O—*′, *—S—*′, *—Se—*′, *—S(═O)₂—*′, *—C(R₆₁)(R₆₂)—*′, *—C(R₆₁)═*′, *═C(R₆₁)*′, *—C(R₆₁)═C(R₆₂)*′, *—C(═O)—*′, *—C(═S)—*′, *—C≡C—*′, *—B(R₆₁)—*′, *—N(R₆₁)—*′, *—P(R₆₁)—*′, *—Si(R₆₁)(R₆₂)—*′, *—P(═O)(R₆₁)—*′, or *—Ge(R₆₁)(R₆₂)—*′,

a1 may be an integer from 1 to 3,

R₁₀ may be a C₃-C₆₀ carbocyclic group unsubstituted or substituted with at least one R₁₀ₐ, or a C₁-C₆₀ heterocyclic group unsubstituted or substituted with at least one R₁₀ₐ,

R₂ to R₄, R₁₁ to R₁₃, R₅₁, R₅₂, R₆₁, and R₆₂ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

b1 to b4 may each independently be an integer from 0 to 10,

two or more groups selected from the b1 R₁₁(s), R₁₂, R₁₃, the b2 R₂(s), the b3 R₃(s), the b4 R₄(s), R₅₁, R₅₂, R₆₁, and R₆₂ are optionally linked together to form a C₃-C₆₀ carbocyclic group unsubstituted or substituted with at least one R₁₀ₐ or a C₁-C₆₀ heterocyclic group unsubstituted or substituted with at least one R₁₀ₐ, and

R₁₀ₐ may be:

deuterium, —F, —Cl, —Br, —I, a hydroxyl group, a cyano group, or a nitro group,

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,

a C₃-C₆₀ carbocyclic group, a C₁-C₆ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁ to Q₃, Q₁₁ to Q₁₃, Q₂₁ to Q₂₃, and Q₃₁ to Q₃₃ may each independently be hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

One or more embodiments of the present disclosure provide a light-emitting device including:

a first electrode, a second electrode facing the first electrode, an interlayer between the first electrode and the second electrode and including an emission layer, and the organometallic compound.

One or more embodiments of the present disclosure provide an electronic apparatus including the light-emitting device.

### BRIEF DESCRIPTION OF THE DRAWING

The above and other aspects, features, and advantages of selected embodiments of the disclosure will be more apparent from the following description taken in conjunction with the accompanying drawings, in which:

FIG. 1 is a schematic view of a light-emitting device according to an embodiment;

FIG. 2 is a schematic view of an electronic apparatus according to an embodiment; and

FIG. 3 is a schematic view of an electronic apparatus according to another embodiment.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, expressions such as “at least one of,” “one of,” and “selected from,” when preceding a list of elements, modify the entire list of elements and do not modify the individual elements of the list. Further, the use of “may” when describing embodiments of the present disclosure refers to “one or more embodiments of the present disclosure”.

One or more embodiments of the present disclosure provide an organometallic compound represented by Formula 1-1 or 1-2:

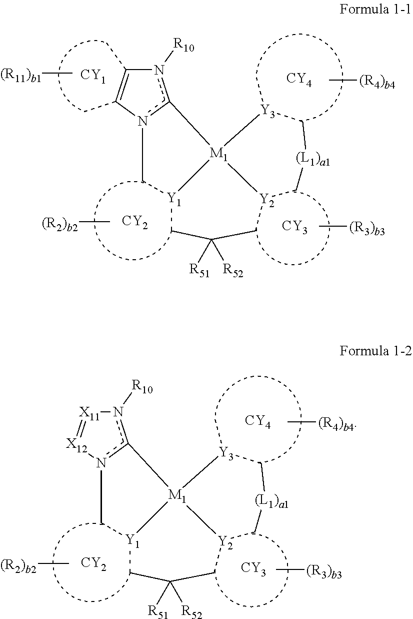

In an embodiment, in Formulae 1-1 and 1-2, M₁ may be platinum (Pt), palladium (Pd), copper (Cu), silver (Ag), gold (Au), rhodium (Rh), iridium (Ir), ruthenium (Ru), osmium (Os), titanium (Ti), zirconium (Zr), hafnium (Hf), europium (Eu), terbium (Tb), or thulium (Tm).

In one or more embodiments, in Formulae 1-1 and 1-2, M₁ may be Pt, Pd, Cu, Ag, Au, Rh, Ir, Ru, or Os.

In one or more embodiments, in Formulae 1-1 and 1-2, M₁ may be Pt.

In an embodiment, in Formulae 1-1 and 1-2, Y₁ to Y₃ may each independently be N or C.

In one or more embodiments, in Formulae 1-1 and 1-2, Y₁ and Y₂ may each independently be C, and Y₃ may be N.

In Formulae 1-1 and 1-2, a bond between M₁ and the carbon atom of a carbene moiety in

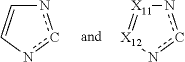

(e.g., the carbene group connected to M₁) may be a coordination bond (e.g., dative bond).

In Formulae 1-1 and 1-2, a bond between Y₁ and M₁ may be a covalent bond, a bond between Y₂ and M₁ may be a covalent bond, and a bond between Y₃ and M₁ may be a coordination bond.

In an embodiment, in Formulae 1-1 and 1-2, Y₁ and Y₂ may each independently be C, and Y₃ may be N, wherein the bond between Y₁ and M₁ may be a covalent bond, the bond between Y₂ and M₁ may be a covalent bond, and the bond between Y₃ and M₁ may be a coordination bond.

In Formulae 1-1 and 1-2, CY₁ to CY₄ may each independently be a C₃-C₆₀ carbocyclic group or a C₁-C₆₀ heterocyclic group.

In an embodiment, in Formula 1-1, CY₁ may be a benzene group, a pyridine group, or a pyrimidine group.

In an embodiment, in Formulae 1-1 and 1-2, CY₂ to CY₄ may each independently be a benzene group, a naphthalene group, a 1,2,3,4-tetrahydronaphthalene group, a pyridine group, a pyrimidine group, a triazine group, a fluorene group, a carbazole group, a dibenzofuran group, a dibenzothiophene group, or a dibenzosilole group.

In one or more embodiments,

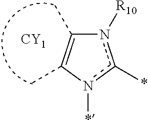

in Formula 1-1 may be a group represented by Formula CY1-1;

CY₂ in Formulae 1-1 and 1-2 may be a group represented by one of Formulae CY2-1 to CY2-9;

CY₃ in Formulae 1-1 and 1-2 may be a group represented by one of Formulae CY3-1 to CY₃₋₉; and/or

CY₄ in Formulae 1-1 and 1-2 may be a group represented by one of Formulae CY4-1 to CY4-9:

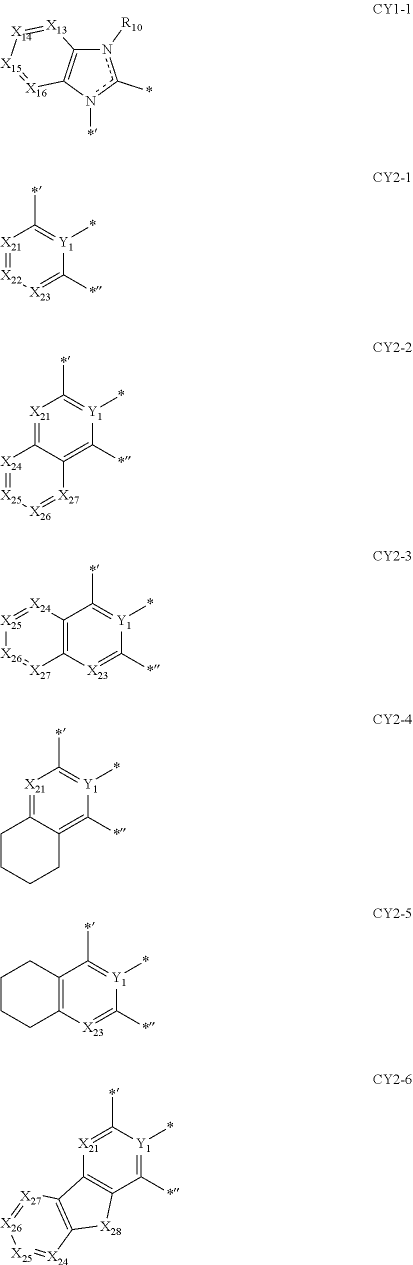

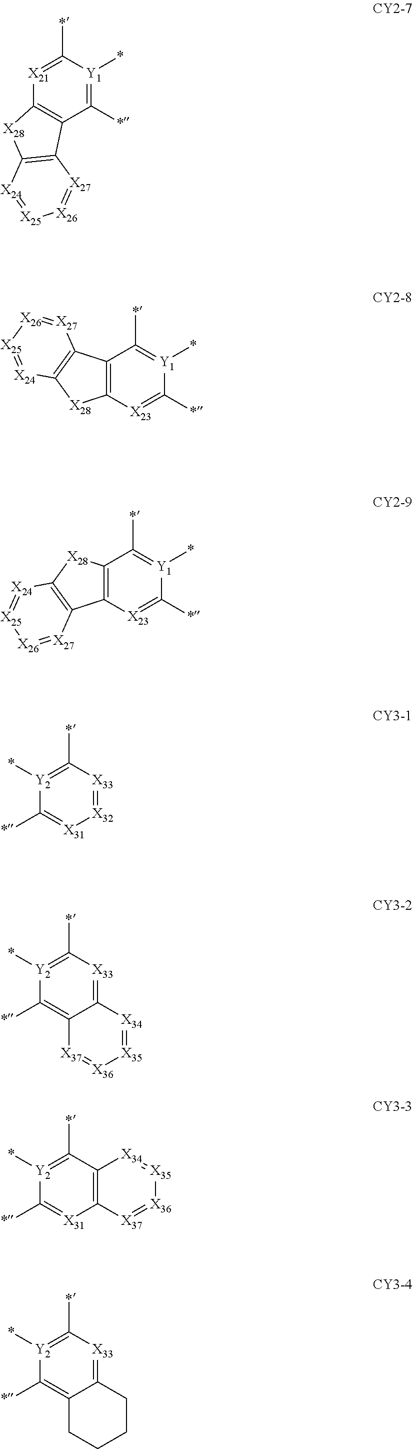

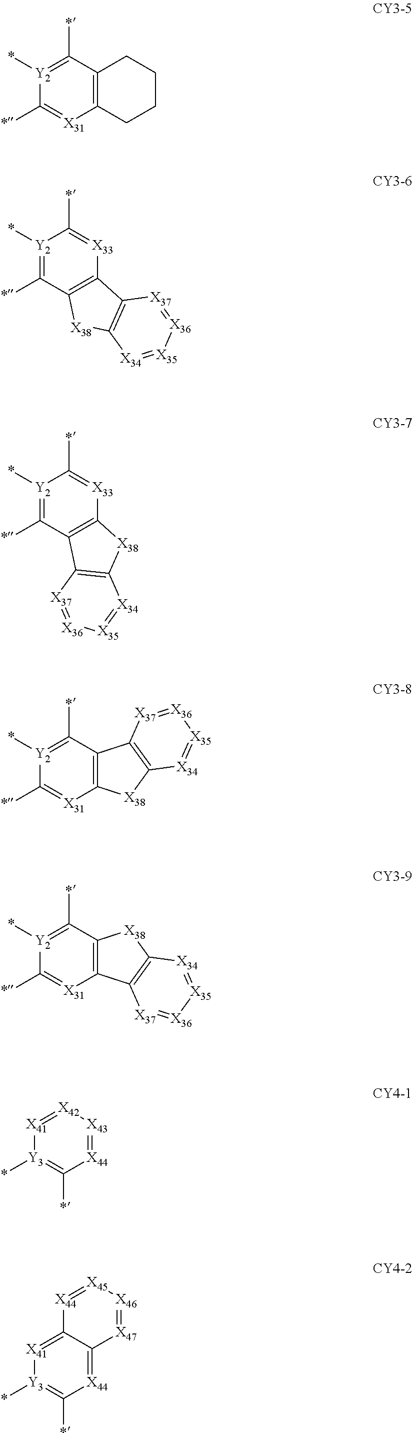

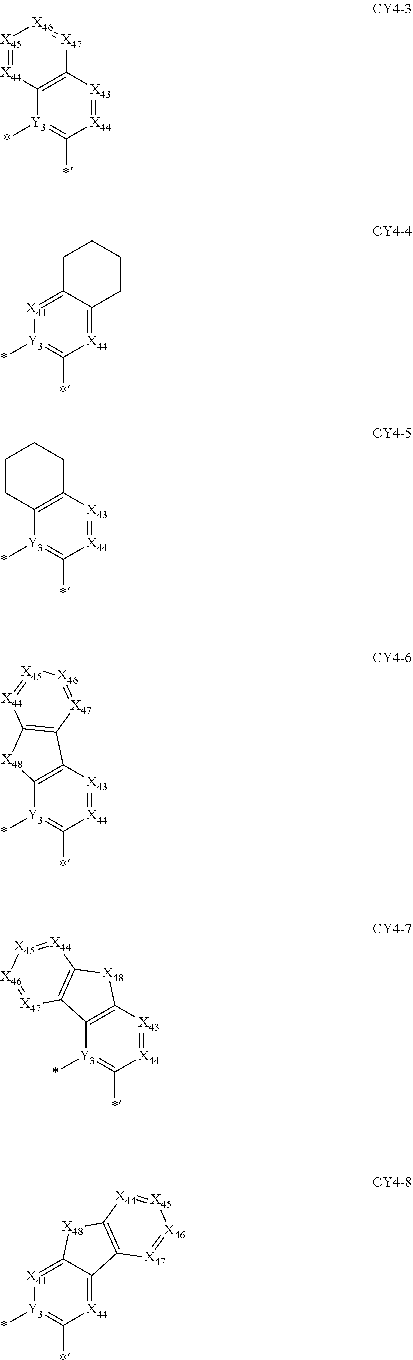

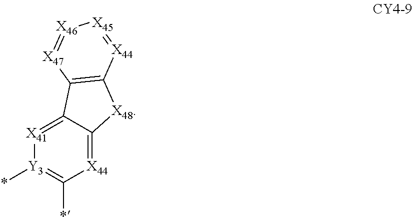

In Formulae CY1-1, CY2-1 to CY2-9, CY3-1 to CY3-9, and CY4-1 to CY4-9,

X₁₃ to X₁₆, X₂₁ to X₂₇, X₃₁ to X₃₇, and X₄₁ to X₄₇ may each independently be N or C,

X₂₈, X₃₈, and X₄₈ may each independently be O, S, N, C, or Si,

R₁₀ and Y₁ to Y₃ may each independently be the same as described above,

* indicates a binding site to M, and

*′ and *″ each indicate a binding site to a neighboring atom.

In one or more embodiments,

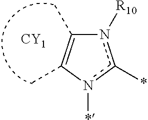

in Formula 1-1 may be a group represented by Formula CY1-11;

CY₂ in Formulae 1-1 and 1-2 may be a group represented by one of Formulae CY2-11 to CY2-14;

CY₃ in Formulae 1-1 and 1-2 may be a group represented by one of Formulae CY3-11 to CY3-14; and/or

CY₄ in Formulae 1-1 and 1-2 may be a group represented by one of Formulae CY4-11 to CY4-14:

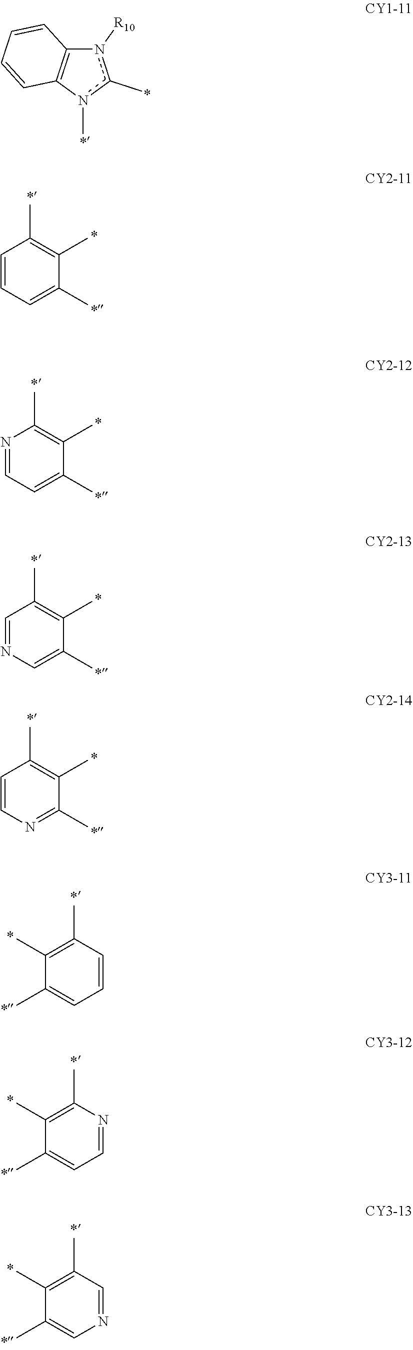

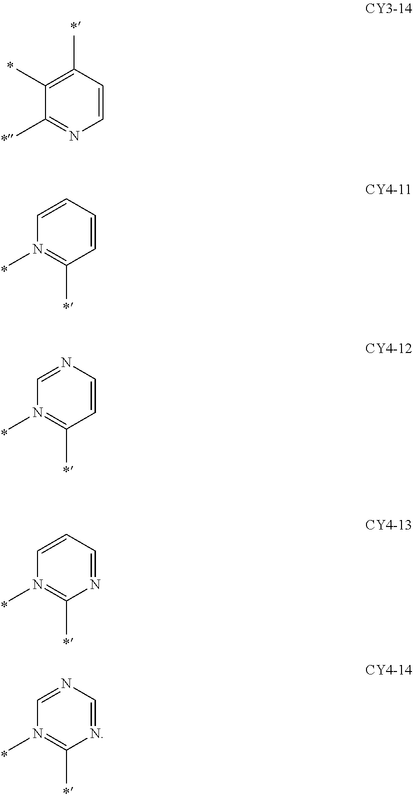

In Formulae CY1-11, CY2-11 to CY2-14, CY3-11 to CY3-14, and CY4-11 to CY4-14,

* indicates a binding site to M, and

*′ and *″ each indicate a binding site to a neighboring atom.

In Formulae 1-1 and 1-2, X₁₁ may be N or C(R₁₂), and X₁₂ may be N or C(R₁₃).

In an embodiment, L1 in Formulae 1-1 and 1-2 may be a single bond, *—O—*′, *—S—*′, *—Se—*′, *—S(═O)₂—*′, *—C(R₆₁)(R₆₂)*′, *—C(R₆₁)═*′, *═C(R₆₁)—*′, *—C(R₆₁)═C(R₆₂)—*′, *—C(═O)—*′, *—C(═S)—*′, *—C≡C—*′, *—B(R₆₁)—*′, *—N(R₆₁)—*′, *—P(R₆₁)—*′, *—Si(R₆₁)(R₆₂)—*′, *—P(═O)(R₆₁)—*′, or *—Ge(R₆₁)(R₆₂)*′.

In one or more embodiments, L1 in Formulae 1-1 and 1-2 may be a single bond, *—O—*′, *—S—*′, *—C(R₆₁)(R₆₂)—*′, *—B(R₆₁)—*′, *—N(R₆₁)—*′, *—P(R₆₁)—*′, *—Si(R₆₁)(R₆₂)—*′, or *—Ge(R₆₁)(R₆₂)—*′.

In Formulae 1-1 and 1-2, a1 indicates the number of L1(s), and may be an integer from 1 to 3. When a1 is 2 or more, the two or more L1(s) may be identical to or different from each other.

In an embodiment, in Formulae 1-1 and 1-2, R₁₀ may be a C₃-C₆₀ carbocyclic group unsubstituted or substituted with at least one R₁₀ₐ, or a C₁-C₆₀ heterocyclic group unsubstituted or substituted with at least one R₁₀ₐ.

In one or more embodiments, in Formulae 1-1 and 1-2, R₁₀ may be a phenyl group unsubstituted or substituted with at least one R_{10b},

In one or more embodiments, R_{10b} may be deuterium, —F, —Cl, —Br, —I, a hydroxyl group, a cyano group, a C₁-C₂₀ alkyl group, a C₁-C₂₀ alkyl group substituted with at least one deuterium, a C₁-C₂₀ alkyl group substituted with at least one phenyl group, a C₁-C₂₀ alkoxy group, a phenyl group, a biphenyl group, a naphthyl group, a fluorenyl group, a spiro-bifluorenyl group, a pyridinyl group, a pyrazinyl group, a pyrimidinyl group, a pyridazinyl group, or a triazinyl group; or

a phenyl group, a biphenyl group, a naphthyl group, a fluorenyl group, a spiro-bifluorenyl group, a pyridinyl group, a pyrazinyl group, a pyrimidinyl group, a pyridazinyl group, or a triazinyl group, each substituted with at least one deuterium.

In one or more embodiments, in Formulae 1-1 and 1-2, R₁₀ may be a group represented by one of Formulae 10-1 to 10-64:

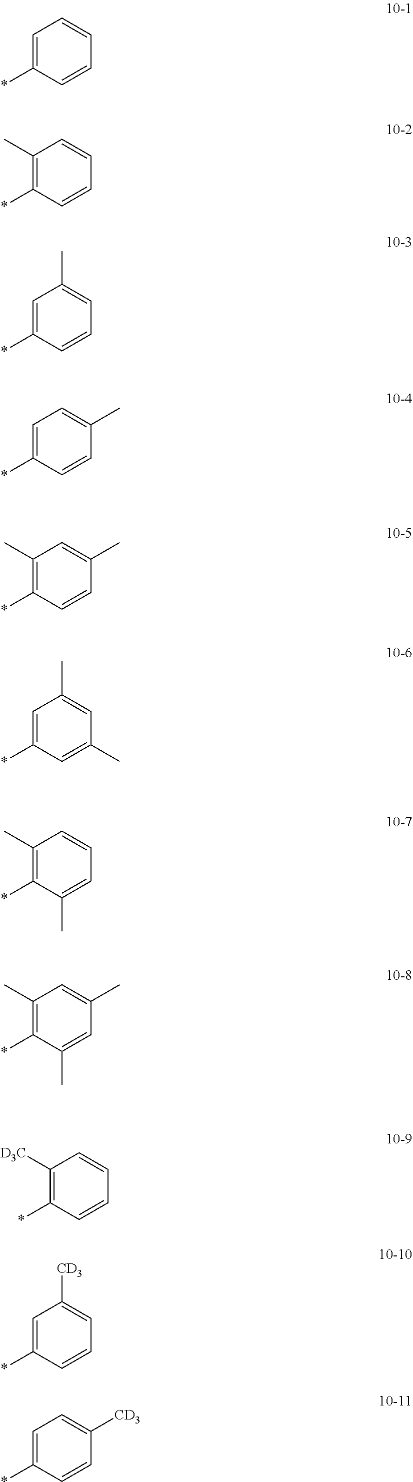

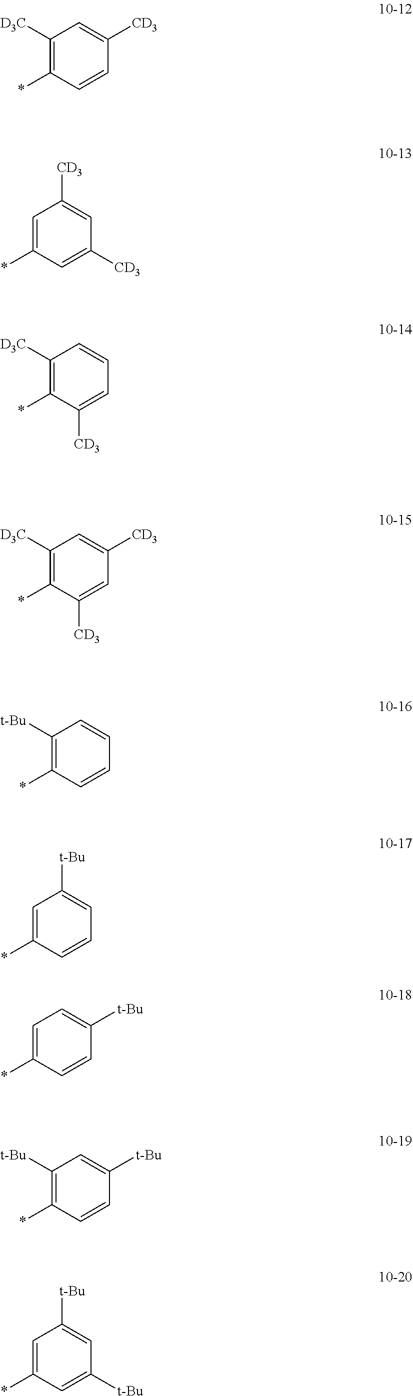

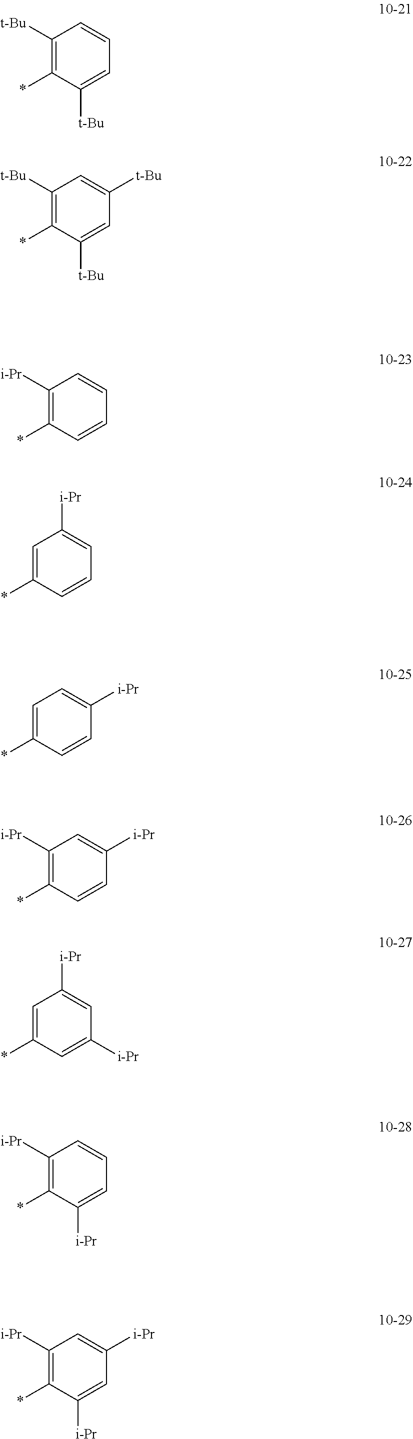

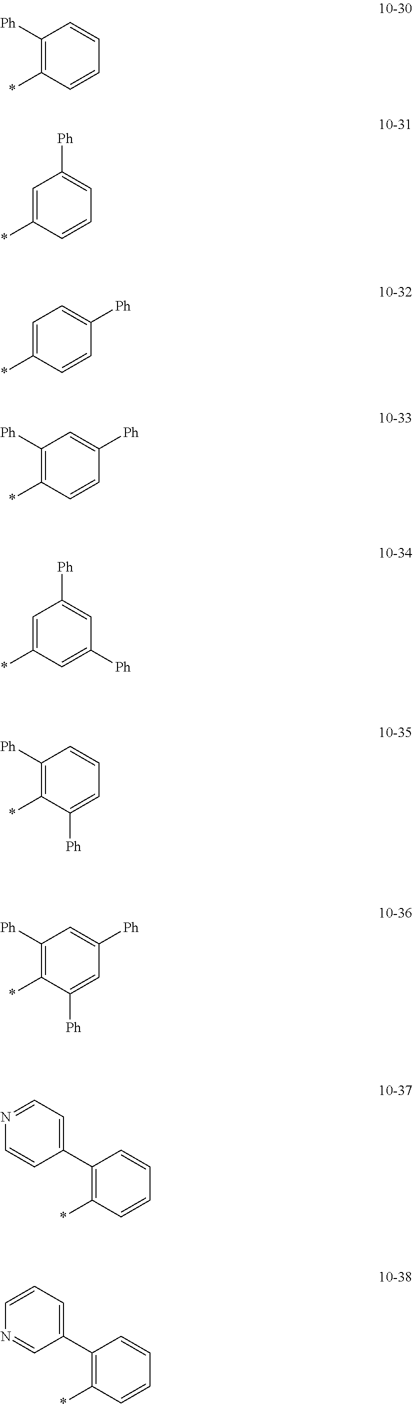

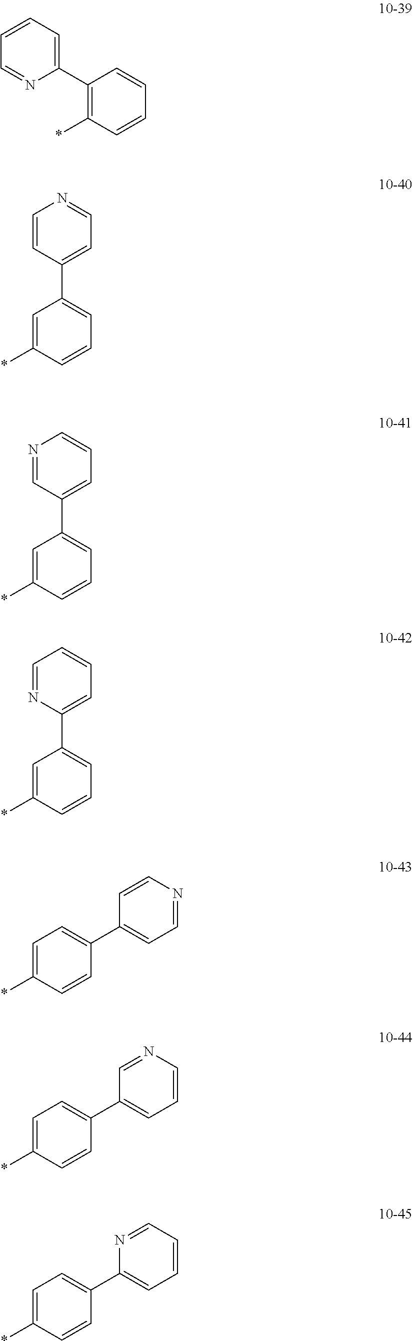

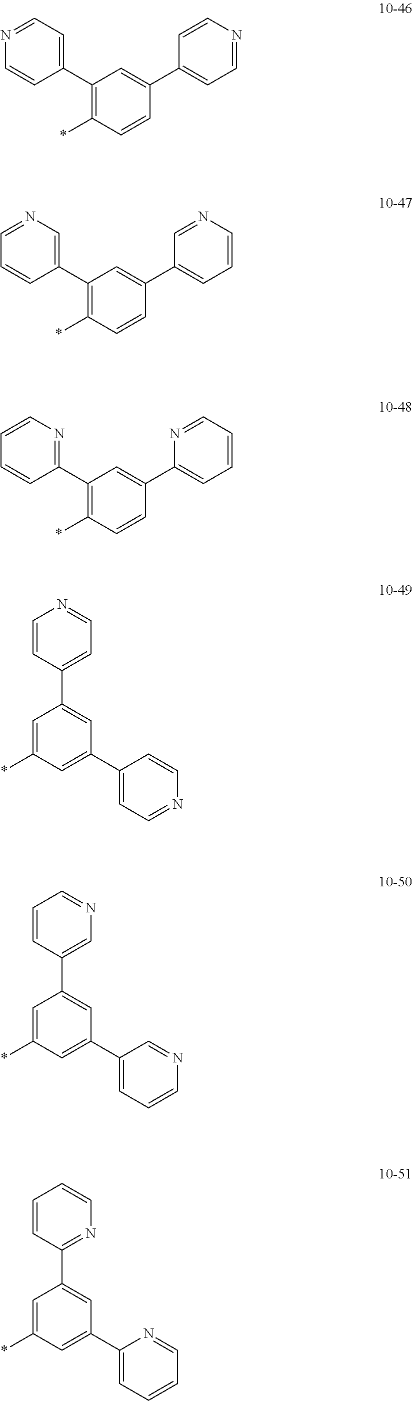

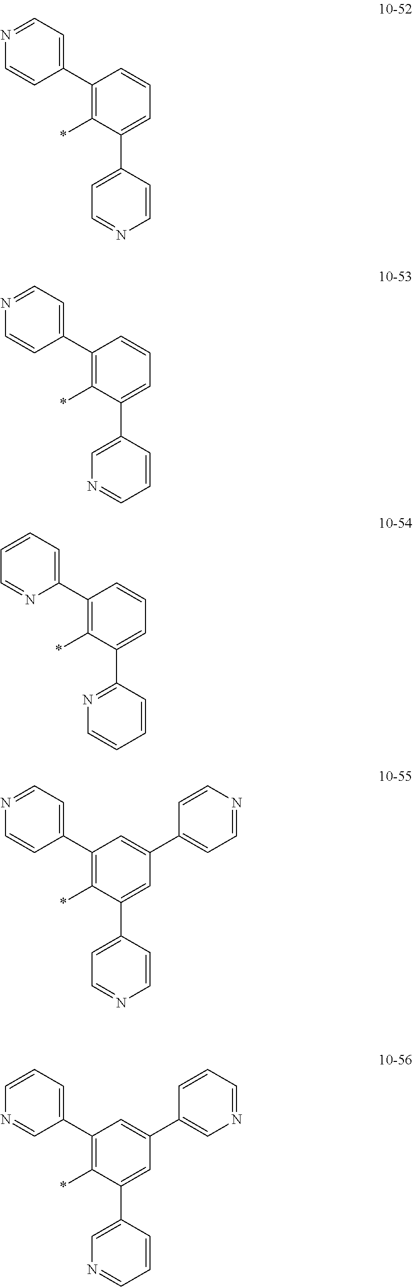

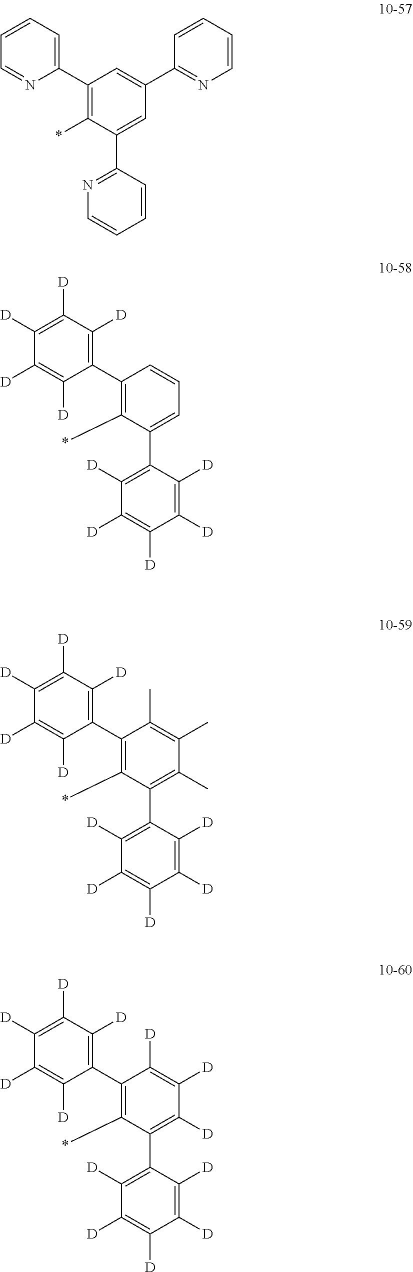

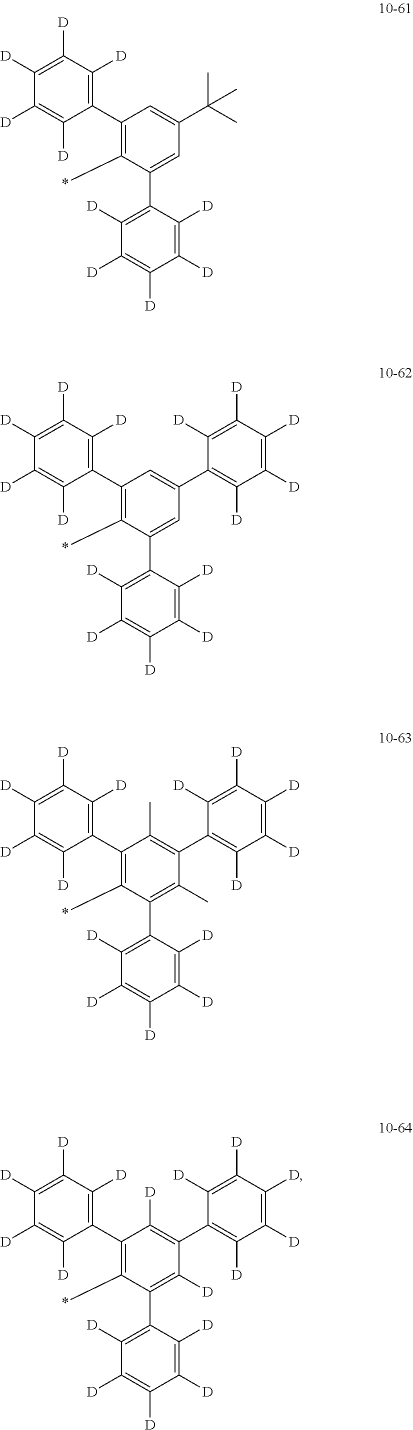

wherein, in Formulae 10-1 to 10-64,

t-Bu may be a tert-butyl group,

Pr may be an isopropyl group,

Ph may be a phenyl group, and

* indicates a binding site to a neighboring atom.

In Formulae 1-1 and 1-2, R₂ to R₄, R₁₁ to R₁₃, R₅₁, R₅₂, R₆₁, and R₆₂ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

b1 to b4 may each independently be an integer from 0 to 10.

In Formulae 1-1 and 1-2, b1, b2, b3, and b4 respectively indicate the number of R₁₁, the number of R₂, the number of R₃, and the number of R₄, wherein when b1 is 2 or more, the two or more R₁₁(s) may be identical to or different from each other, when b2 is 2 or more, the two or more R₂ (s) may be identical to or different from each other, when b3 is 2 or more, the two or more R₃(s) may be identical to or different from each other, and when b4 is 2 or more, the two or more R₄(s) may be identical to or different from each other.

In Formulae 1-1 and 1-2, two or more groups selected from the b1 R₁₁(s), R₁₂, R₁₃, the b2 R₂(s), the b3 R₃(s), the b4 R₄(s), R₅₁, R₅₂, R₆₁, and R₆₂ may optionally be linked together to form a C₃-C₆₀ carbocyclic group unsubstituted or substituted with at least one R₁₀ₐ or a C₁-C₆₀ heterocyclic group unsubstituted or substituted with at least one R₁₀ₐ.

In an embodiment, in Formulae 1-1 and 1-2, R₂ to R₄, R₁₁ to R₁₃, R₆₁, and R₆₂ may each independently be hydrogen, deuterium, —F, —Cl, —Br, —I, a hydroxyl group, a cyano group, a nitro group, CH₃, —CD₃, —CD₂H, —CDH₂, —CF₃, —CF₂H or —CFH₂;

a C₁-C₂₀ alkyl group and a C₁-C₂₀ alkoxy group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a naphthyl group, a pyridinyl group, a pyrimidinyl group, or any combination thereof;

a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or

—Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

wherein Q₁ to Q₃ may each independently be: hydrogen; deuterium; —F; —Cl; —Br; —I; a hydroxyl group; a cyano group; a nitro group; a C₁-C₂₀ alkyl group; a C₁-C₂₀ alkoxy group; or a C₃-C₂₀ carbocyclic group or a C₁-C₂₀ heterocyclic group, each unsubstituted or substituted with deuterium, —F, a cyano group, a C₁-C₂₀ alkyl group, a C₁-C₂₀ alkoxy group, a phenyl group, a biphenyl group, or any combination thereof.

In one or more embodiments, in Formulae 1-1 and 1-2, R₂ to R₄, R₁₁ to R₁₃, R₆₁, and R₆₂ may each independently be hydrogen, deuterium, —F, —Cl, —Br, —I, a hydroxyl group, a cyano group, a nitro group, —CH₃, —CD₃, —CD₂H, —CDH₂, —CF₃, —CF₂H, —CFH₂, an ethyl group, a propyl group, an isopropyl group, a butyl group, an isobutyl group, a sec-butyl group, a tert-butyl group, a group represented by one of Formulae 10-1 to 10-36, a group represented by one of Formulae 11-1 to 11-6, —Si(Q₁)(Q₂)(Q₃), —N(Q₁)(Q₂) or —B(Q₁)(Q₂):

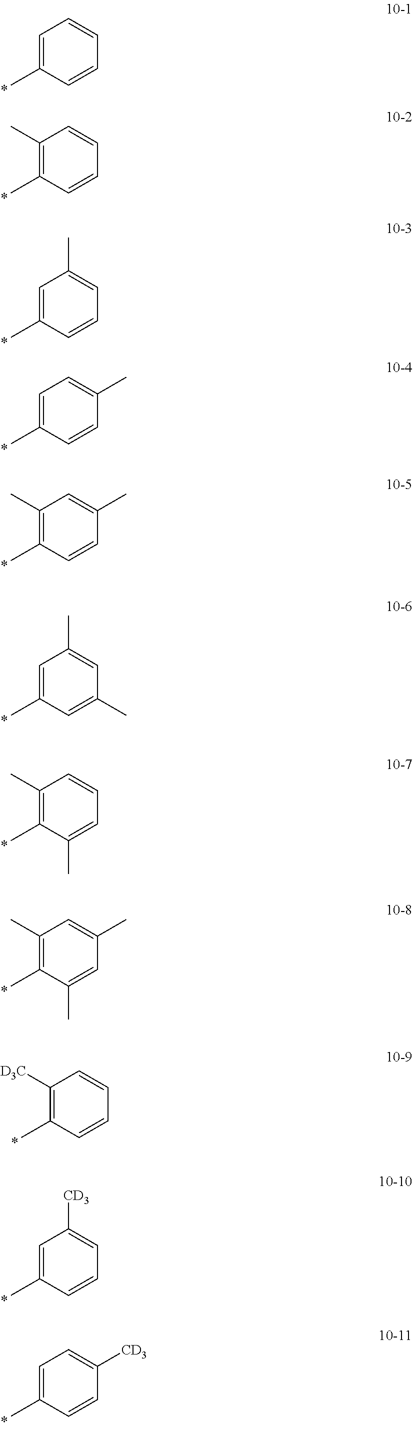

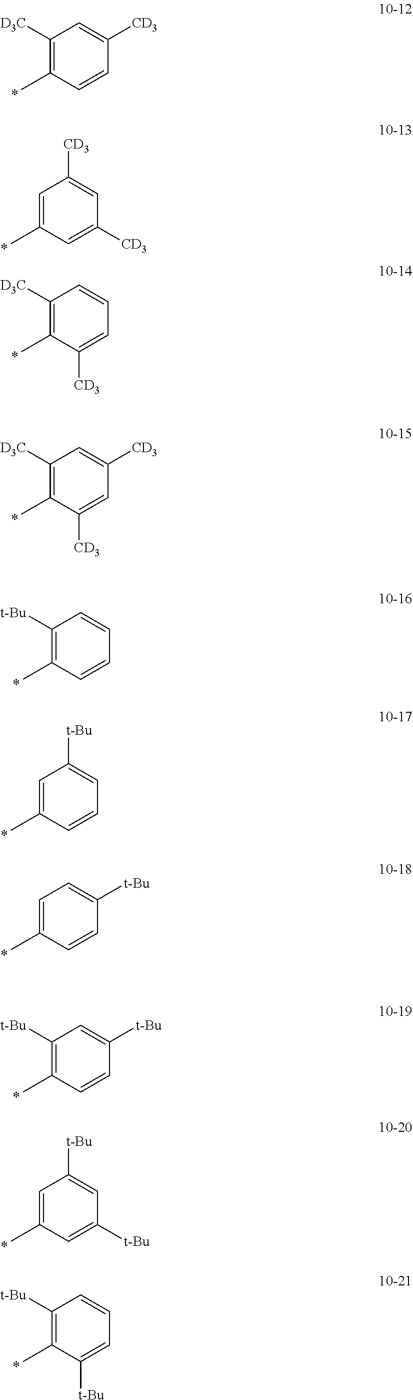

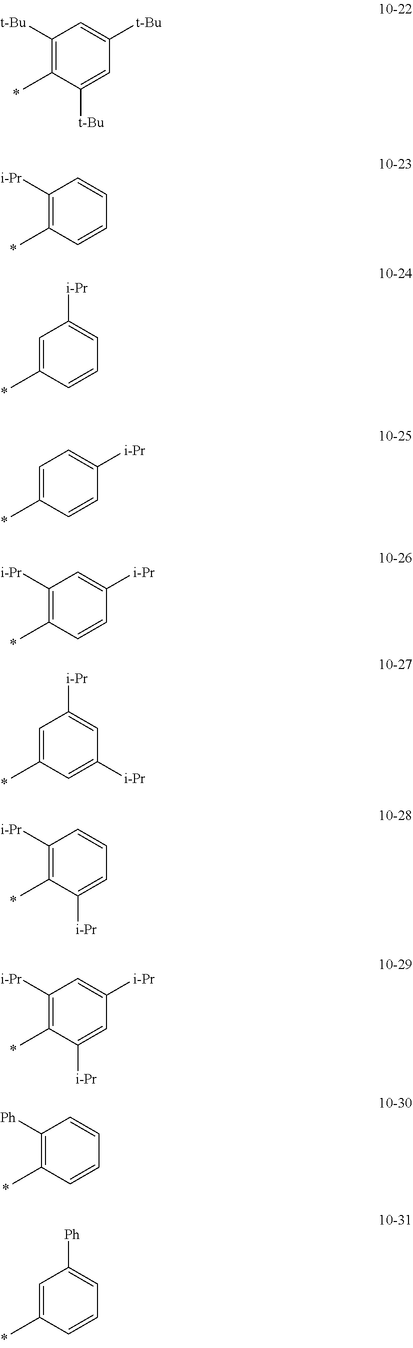

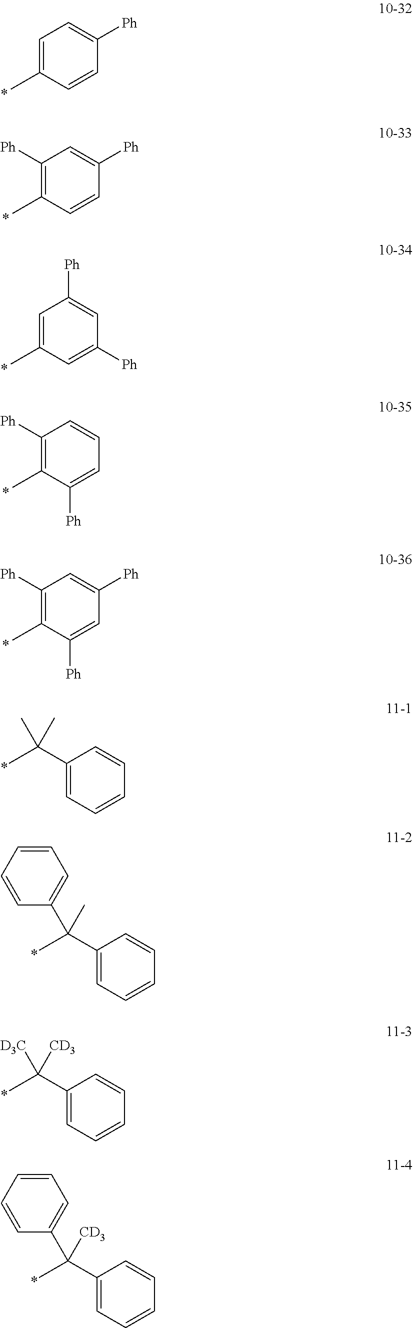

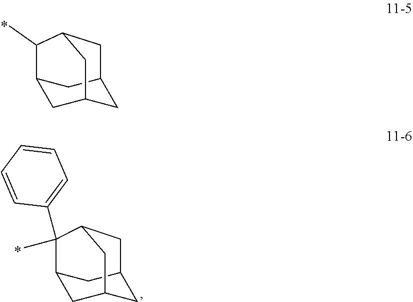

wherein Q₁ to Q₃ may each independently be: a C₁-C₁₀ alkyl group; a C₁-C₁₀ alkyl group substituted with at least one deuterium; or a phenyl group or a naphthyl group, each unsubstituted or substituted with deuterium, a C₁-C₁₀ alkyl group, a phenyl group, or any combination thereof.

In Formulae 10-1 to 10-36 and 11-1 to 11-6,

t-Bu may be a tert-butyl group,

Pr may be an isopropyl group,

Ph may be a phenyl group, and

* indicates a binding site to a neighboring atom.

In an embodiment, R₅₁ and R₅₂ in Formulae 1-1 and 1-2 may each independently be: hydrogen; deuterium; or a C₁-C₁₀ alkyl group unsubstituted or substituted with deuterium, —F, —Cl, —Br, —I, or any combination thereof.

In one or more embodiments, R₅₁ and R₅₂ may each independently be hydrogen, deuterium, a methyl group, or —CD₃.

In an embodiment, a moiety represented by

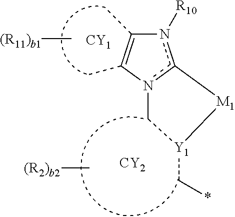

in Formula 1-1 may be a group represented by Formula L-1:

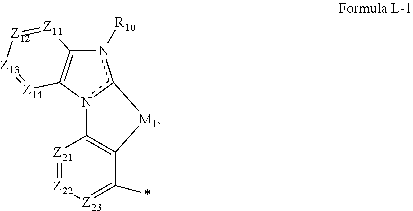

wherein, in Formula L-1,

Z₁₁ may be N or C(R₁₄), Z₁₂ may be N or C(R₁₅), Z₁₃ may be N or C(R₁₆), and Z₁₄ may be N or C(R₁₇),

Z₂₁ may be N or C(R₂₁), Z₂₂ may be N or C(R₂₂), and Z₂₃ may be N or C(R₂₃),

R₁₄ to R₁₇ may each independently be the same as described in connection with R₁₁,

R₂₁ to R₂₃ may each independently be the same as described in connection with R₂,

M₁ and R₁₀ may each independently be the same as described above, and

* indicates a binding site to a neighboring atom.

In an embodiment, a moiety represented by

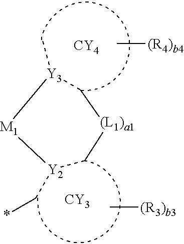

in Formulae 1-1 and 1-2 may be a group represented by Formula L-2:

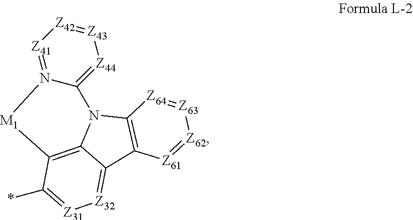

wherein, in Formula L-2,

Z₃₁ may be N or C(R₃₁), and Z₃₂ may be N or C(R₃₂),

Z₄₁ may be N or C(R₄₁), Z₄₂ may be N or C(R₄₂), Z₄₃ may be N or C(R₄₃), and Z₄₄ may be N or C(R₄₄),

Z₆₁ may be N or C(R₆₁₁), Z₆₂ may be N or C(R₆₁₂), Z₆₃ may be N or C(R₆₁₃), and Z₆₄ may be N or C(R₆₁₄),

R₃₁ and R₃₂ may each independently be the same as described in connection with R₃,

R₄₁ to R₄₄ may each independently be the same as described in connection with R₄, and

R₆₁₁ to R₆₁₄ may each independently be the same as described in connection with R₁₀ₐ.

In an embodiment, the organometallic compound may be a compound represented by Formula 1-1A:

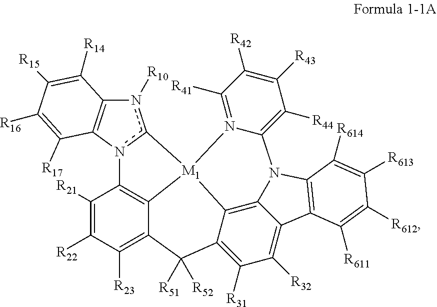

wherein, in Formula 1-1A,

R₁₄ to R₁₇ may each independently be the same as described in connection with R₁₁,

R₂₁ to R₂₃ may each independently be the same as described in connection with R₂,

R₃₁ and R₃₂ may each independently be the same as described in connection with R₃,

R₄₁ to R₄₄ may each independently be the same as described in connection with R₄,

R₆₁₁ to R₆₁₄ may each independently be the same as described in connection with R₁₀ₐ, and

M₁, R₁₀, R₅₁, and R₅₂ may each independently be the same as described above.

For example, the organometallic compound may be one of Compounds 1 to 188:

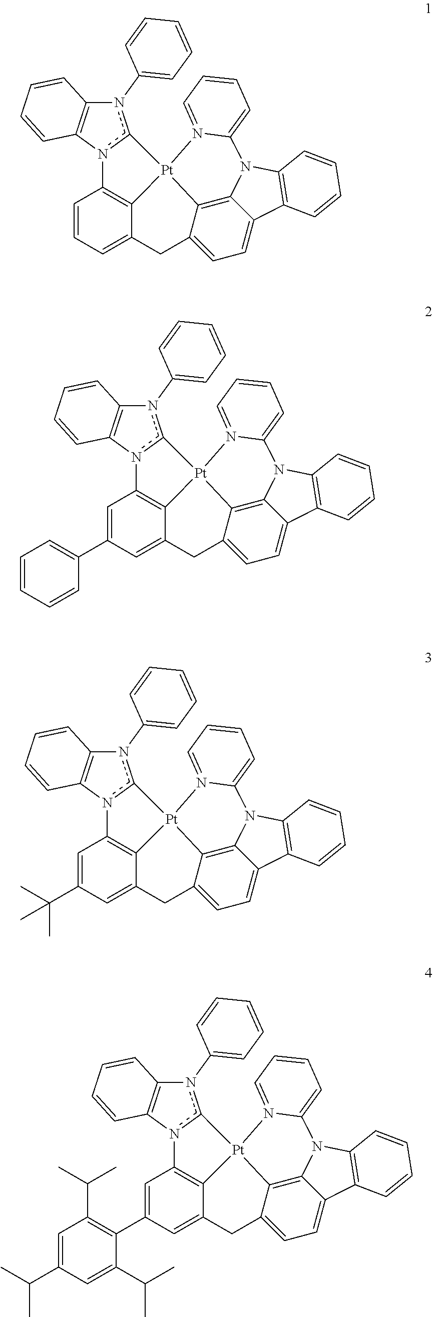

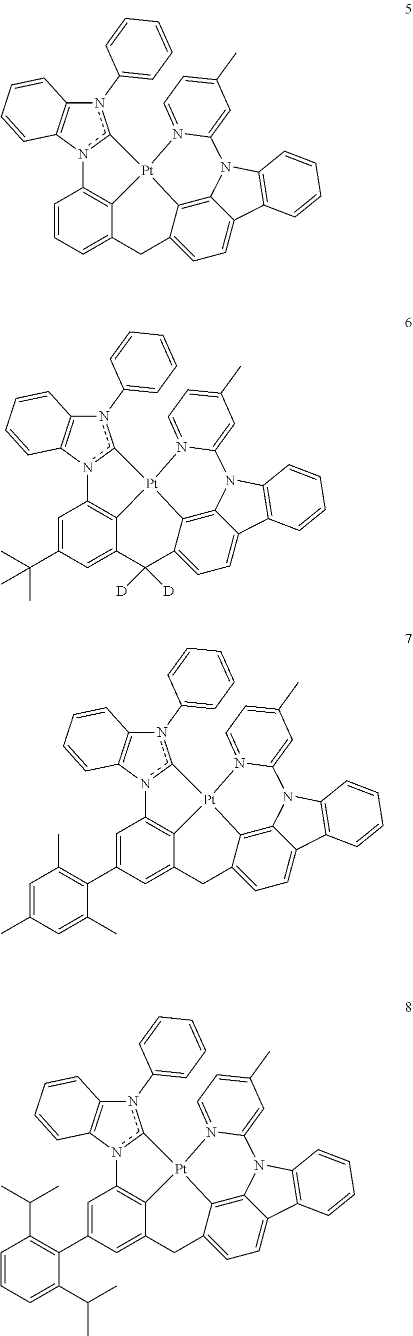

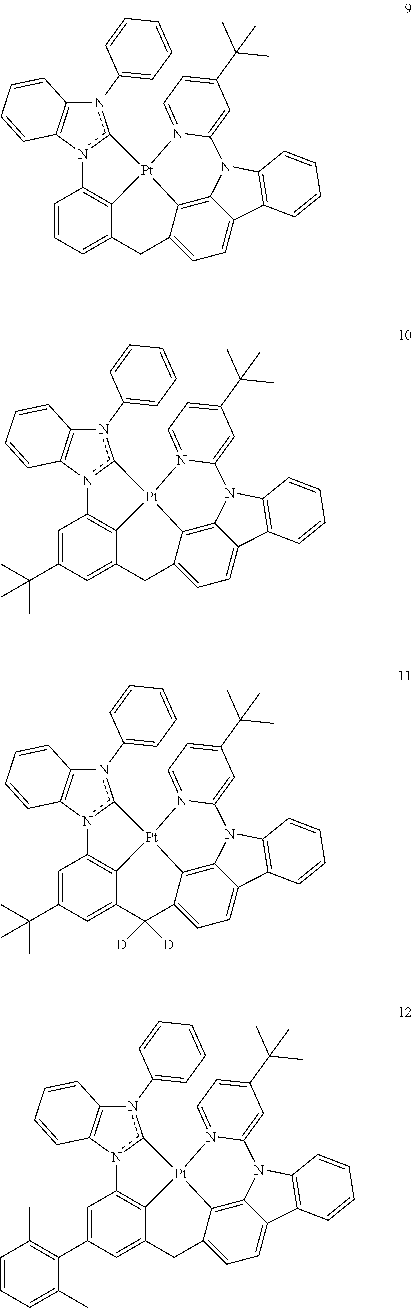

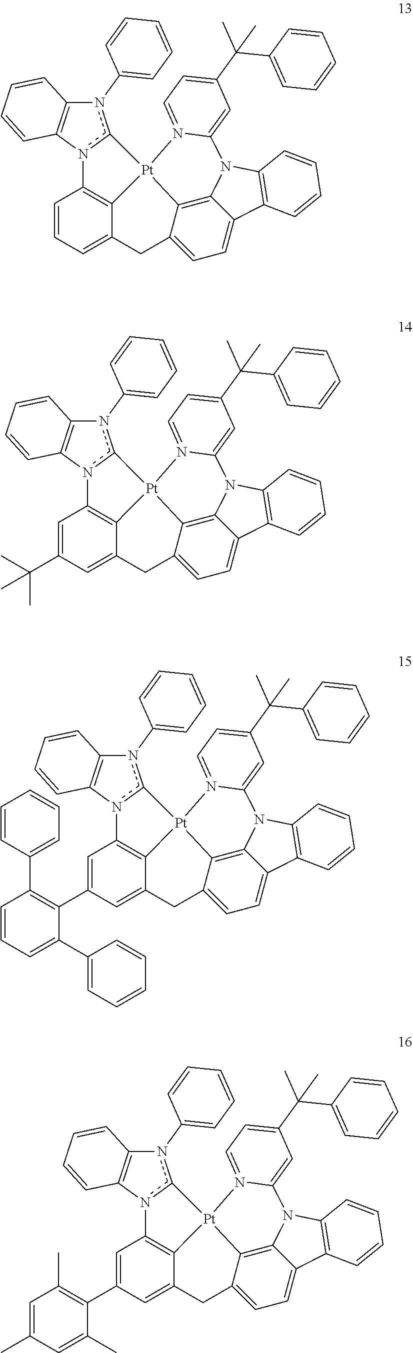

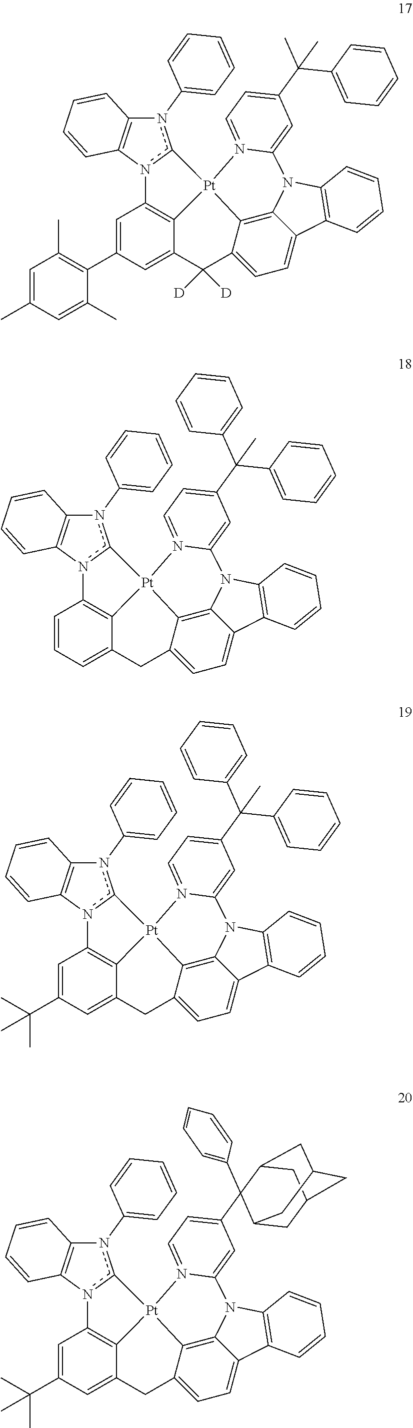

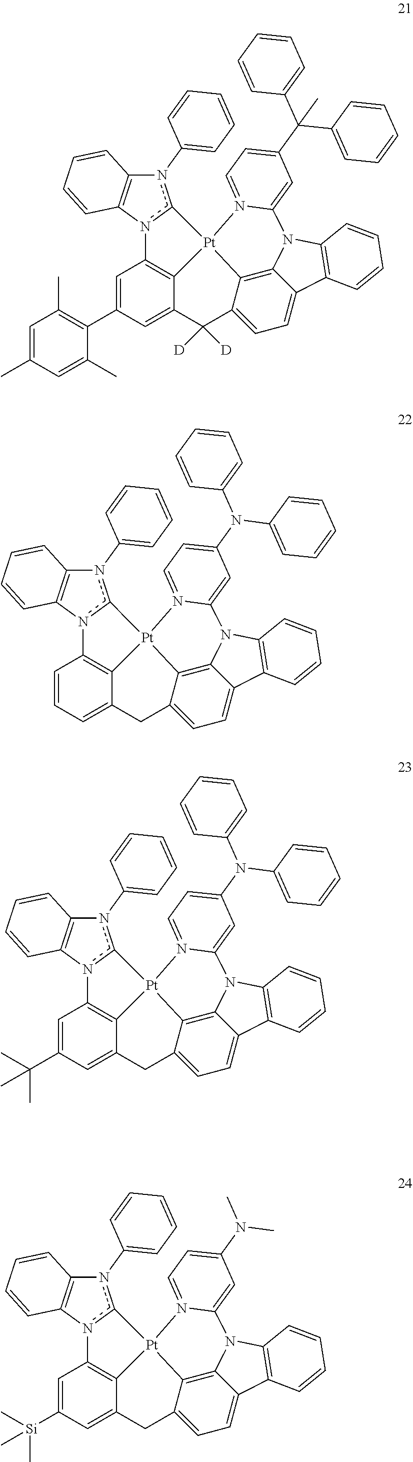

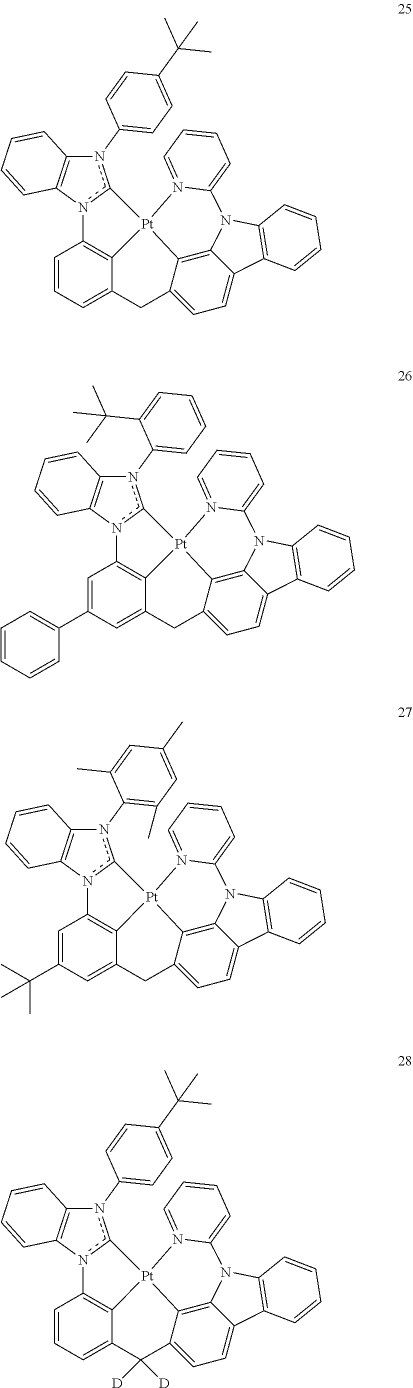

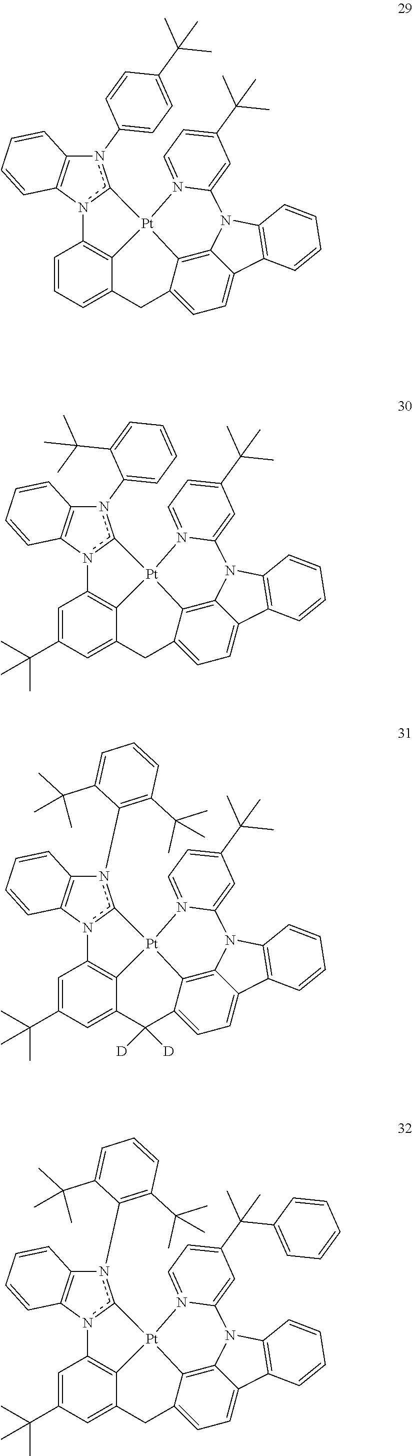

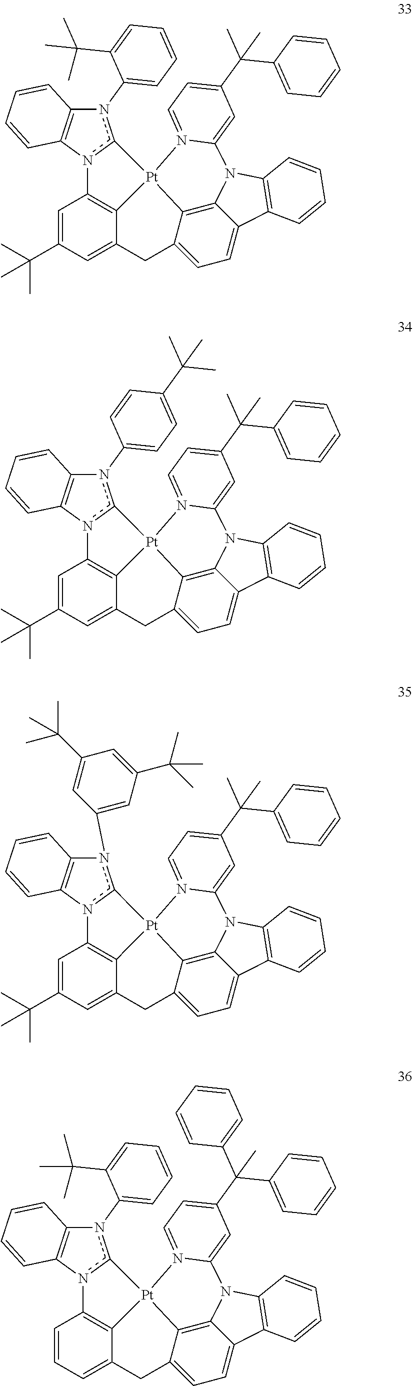

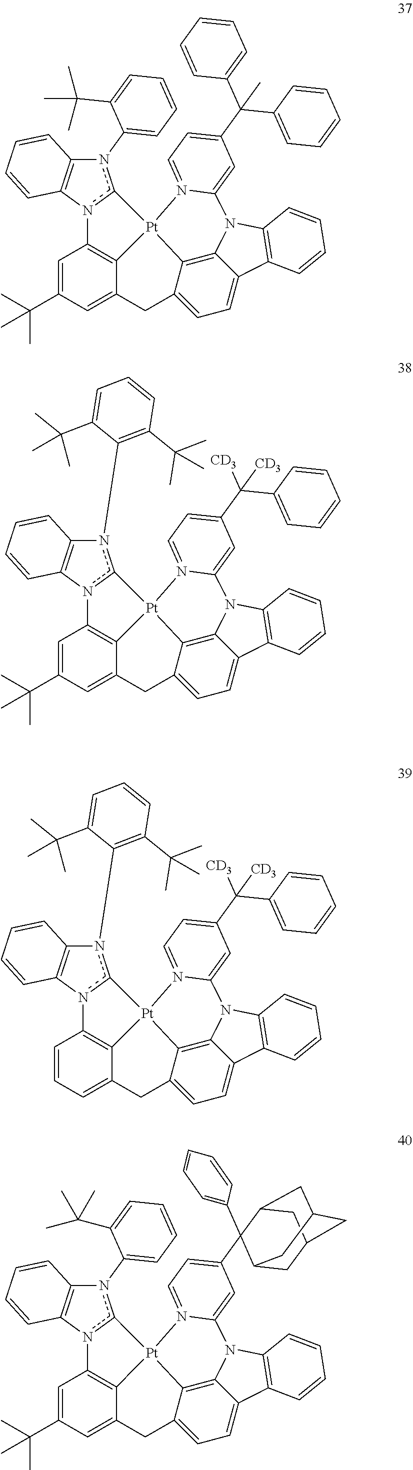

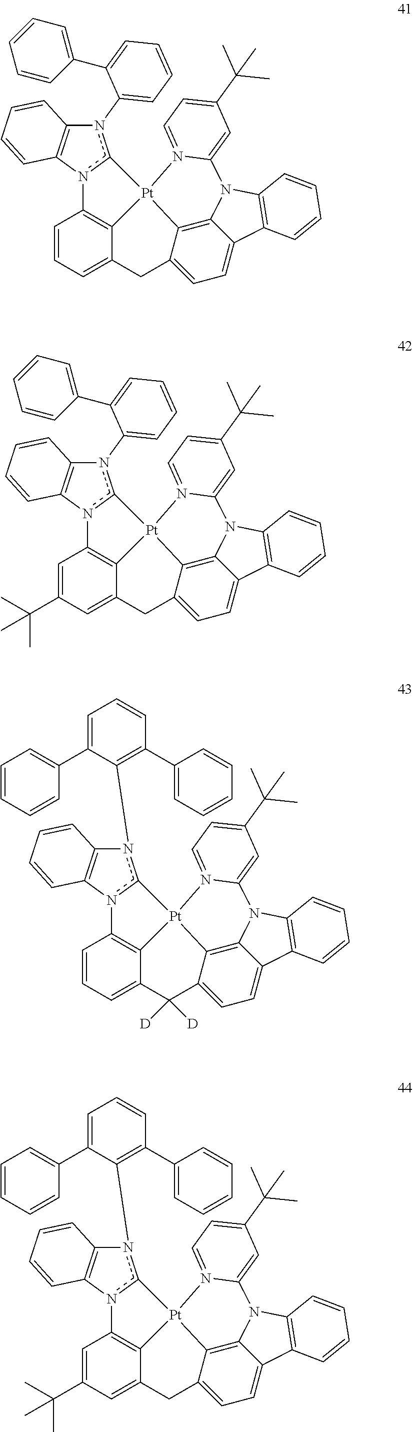

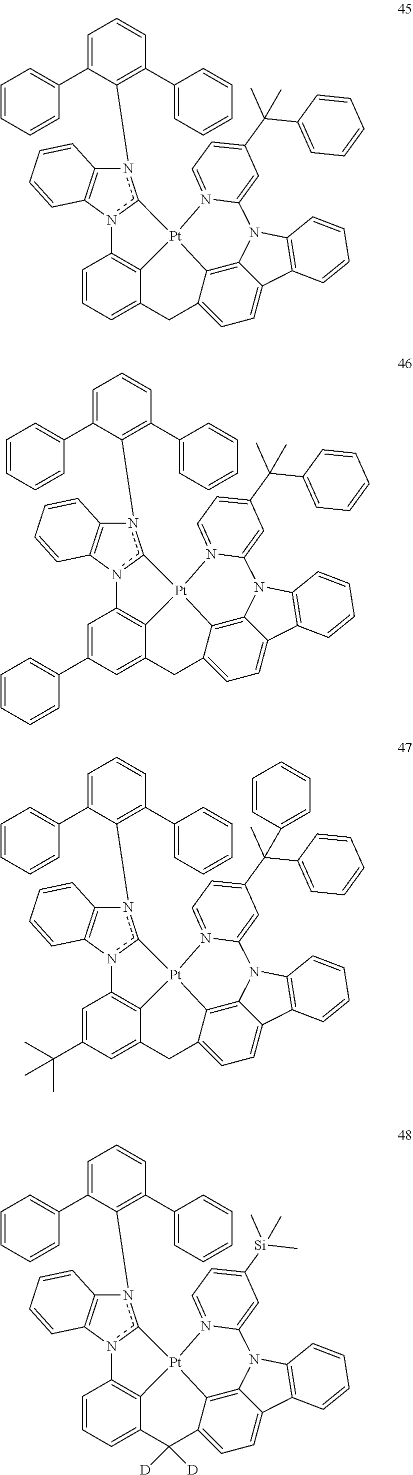

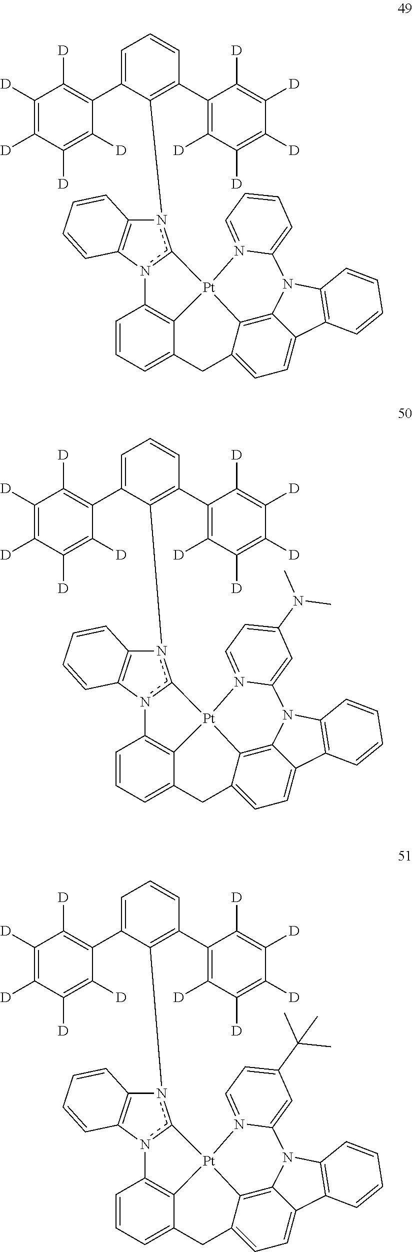

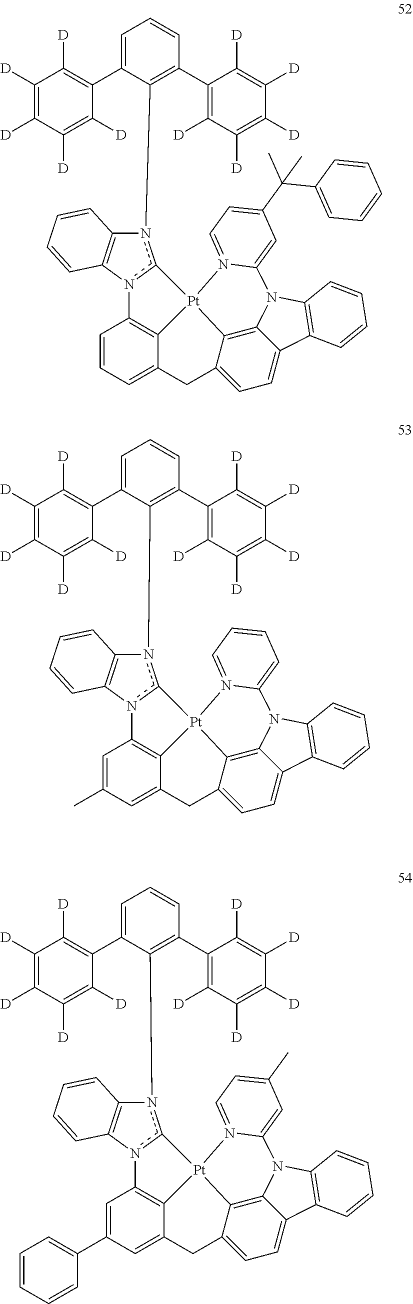

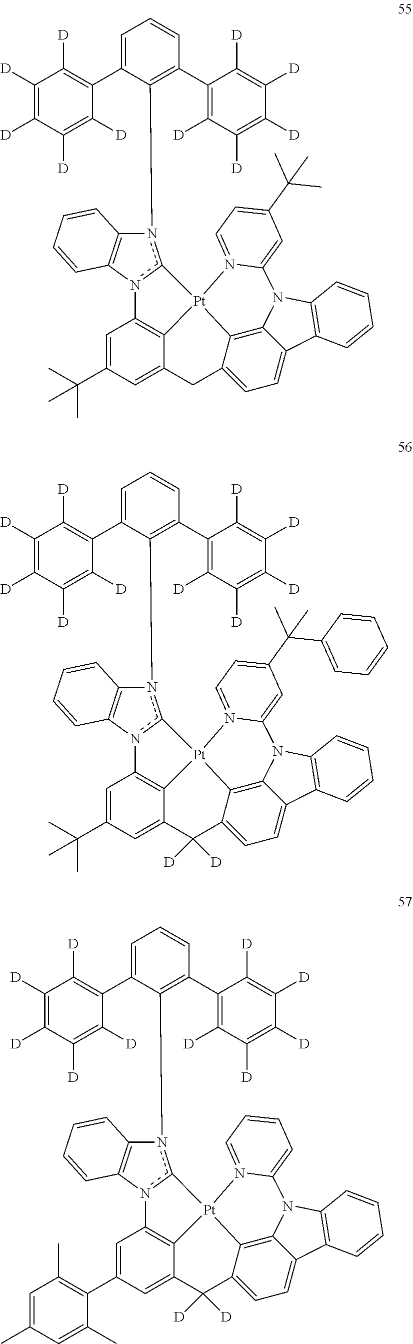

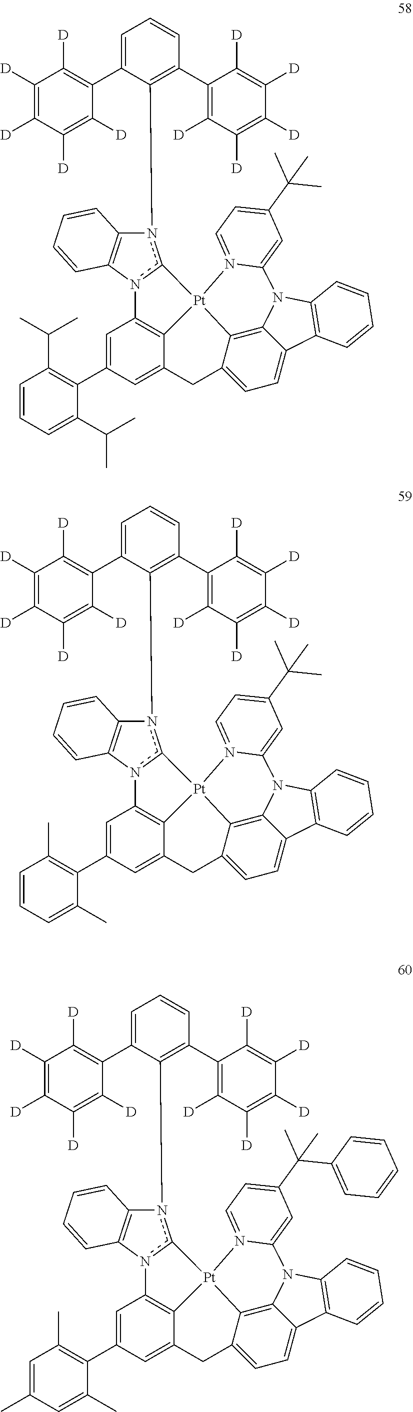

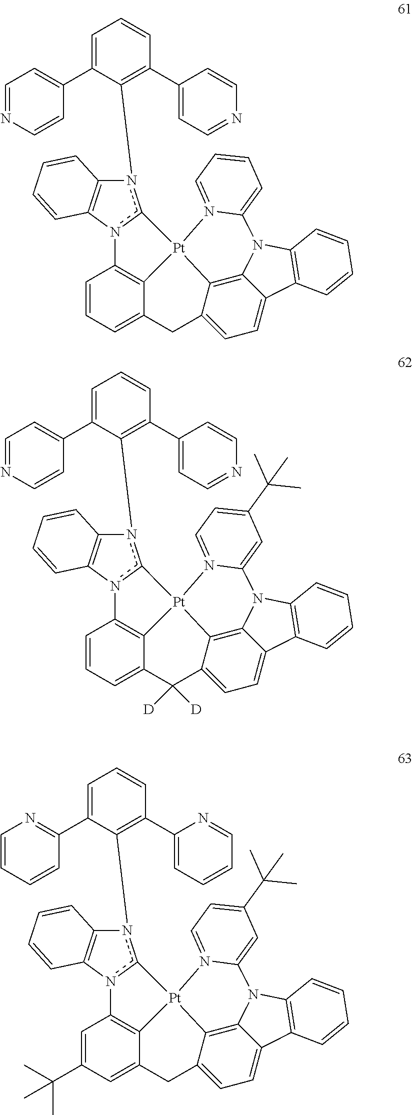

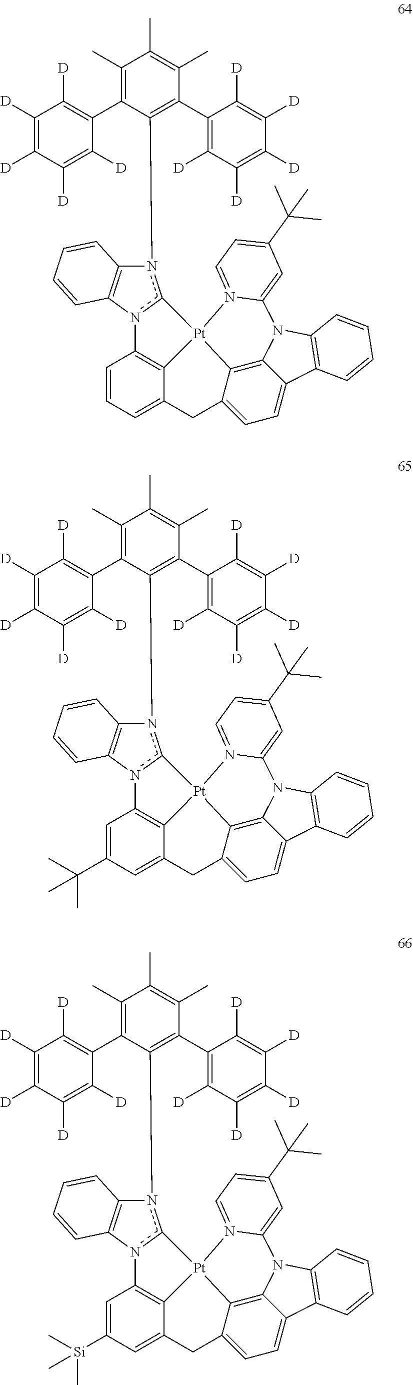

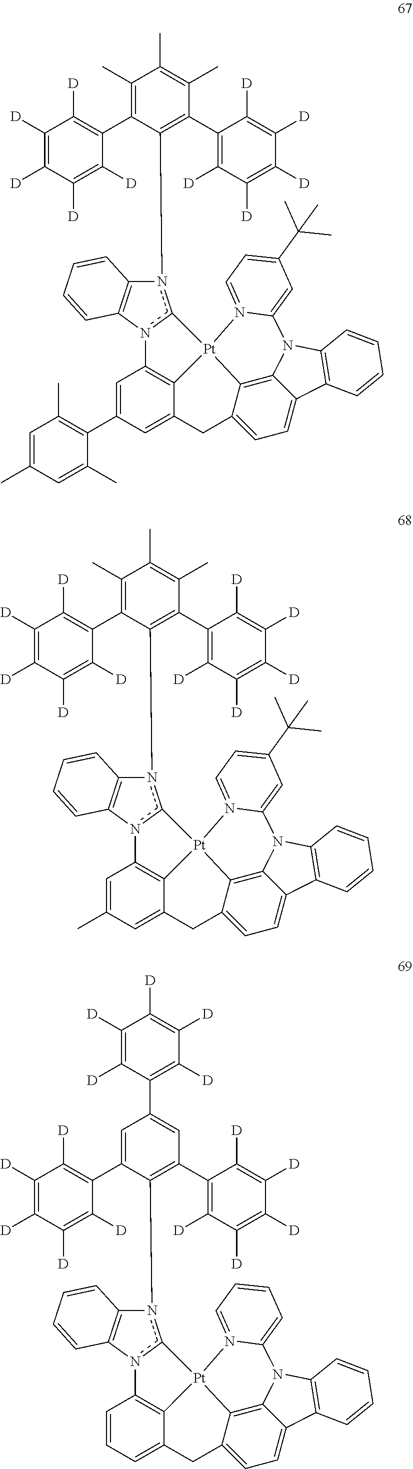

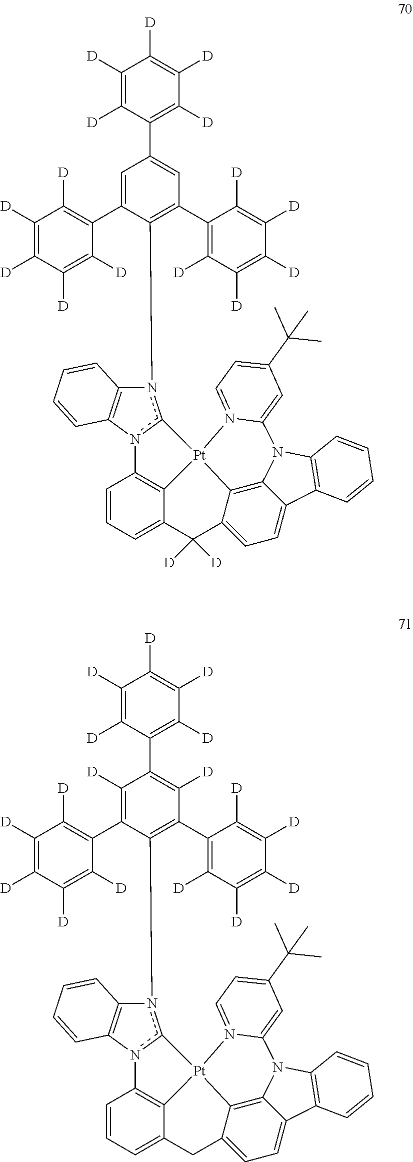

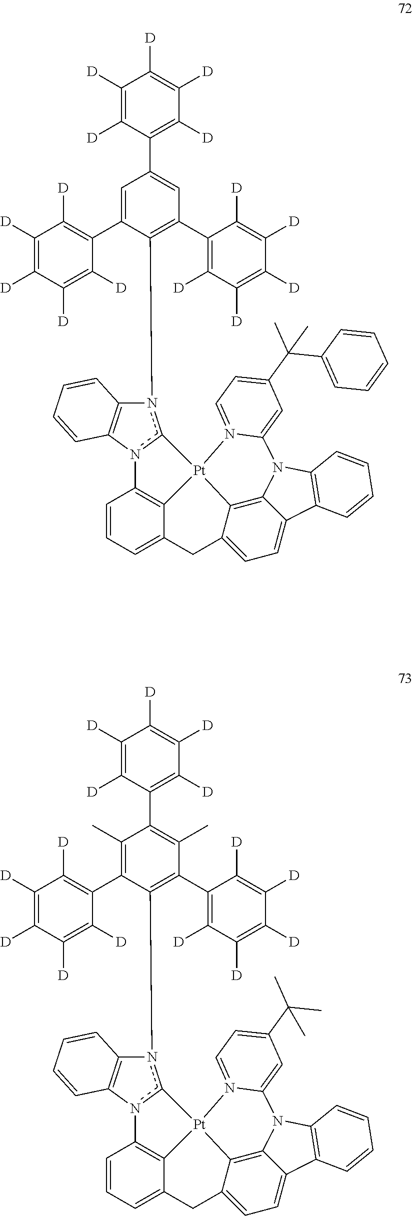

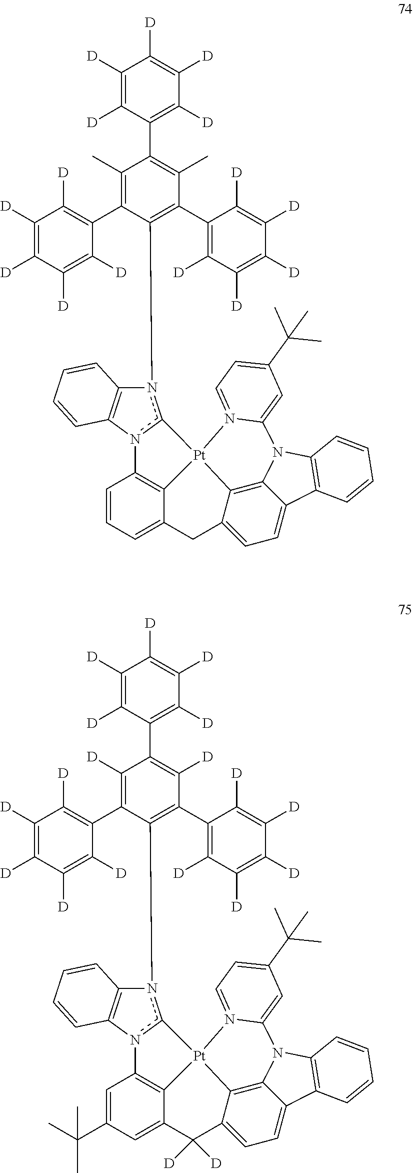

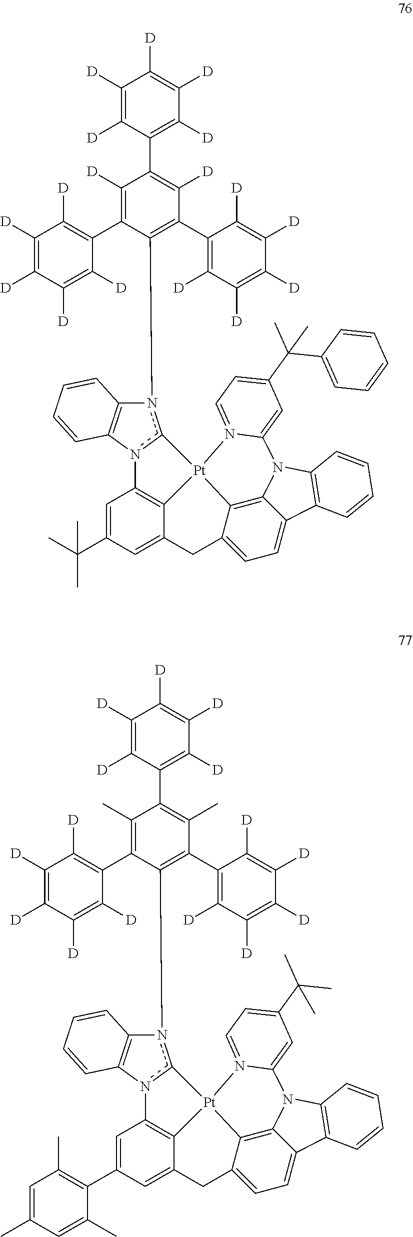

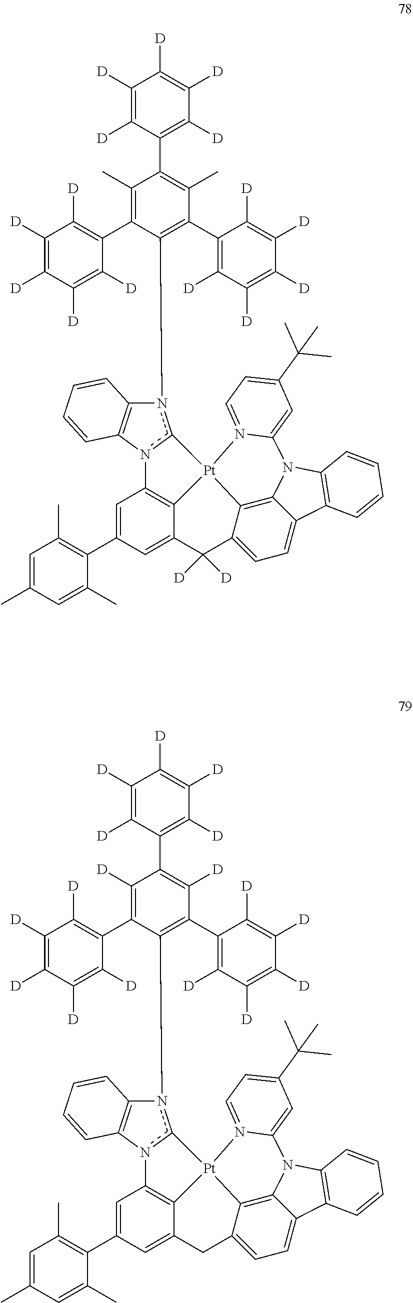

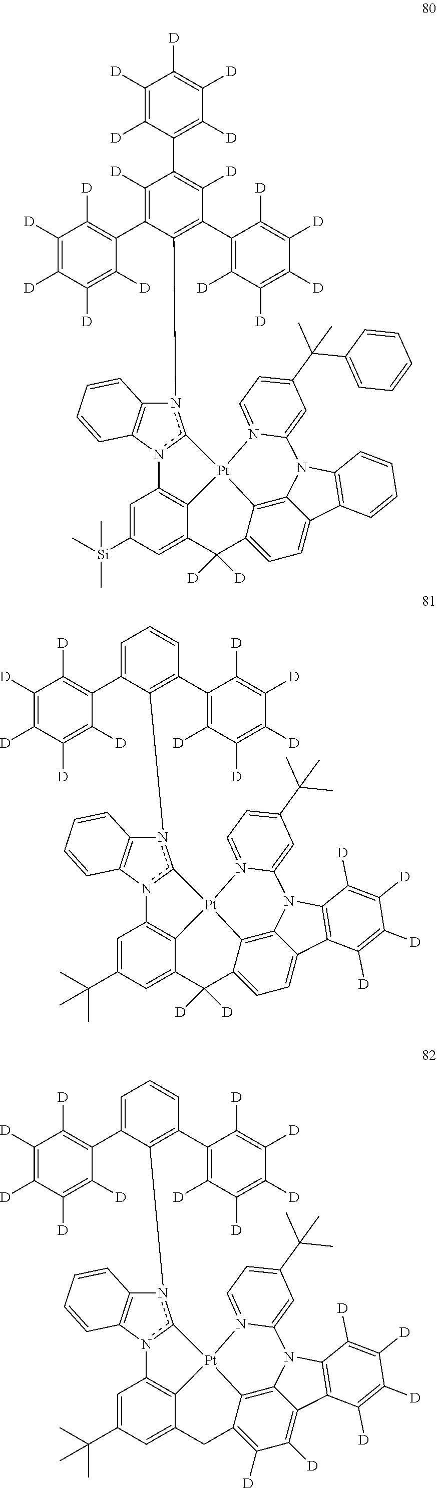

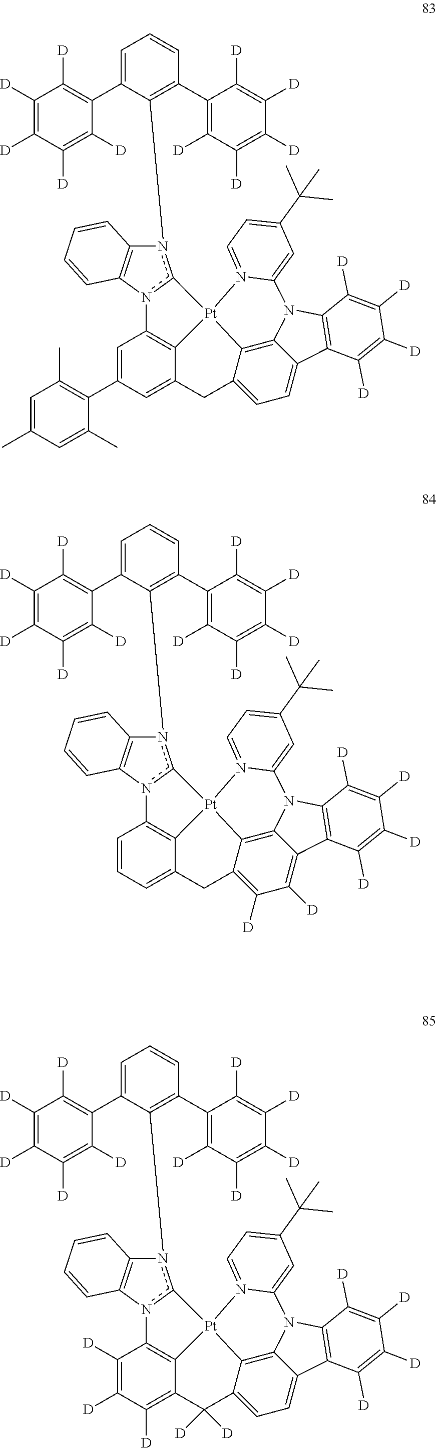

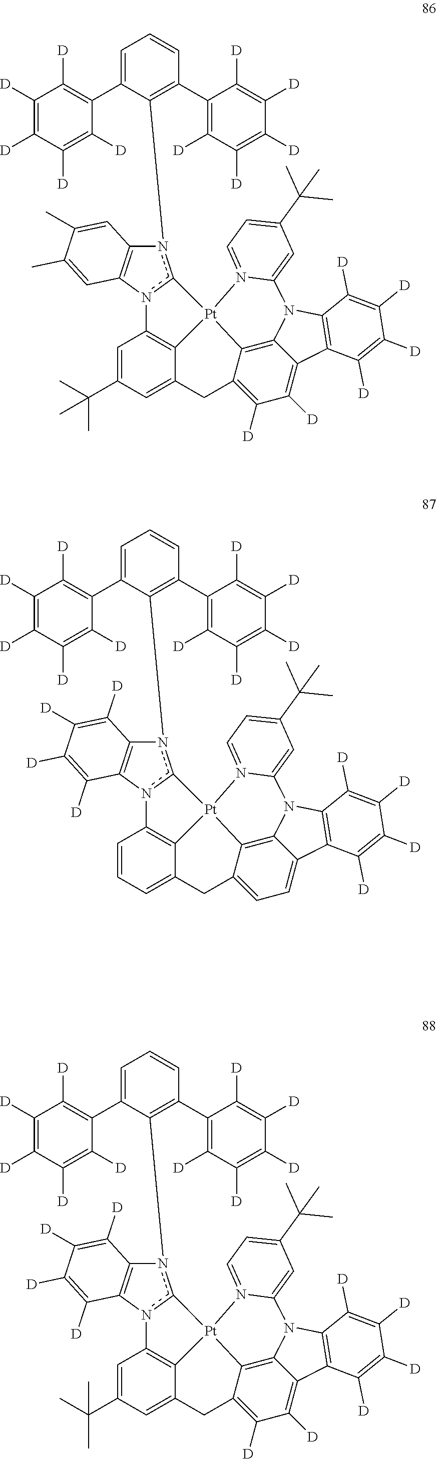

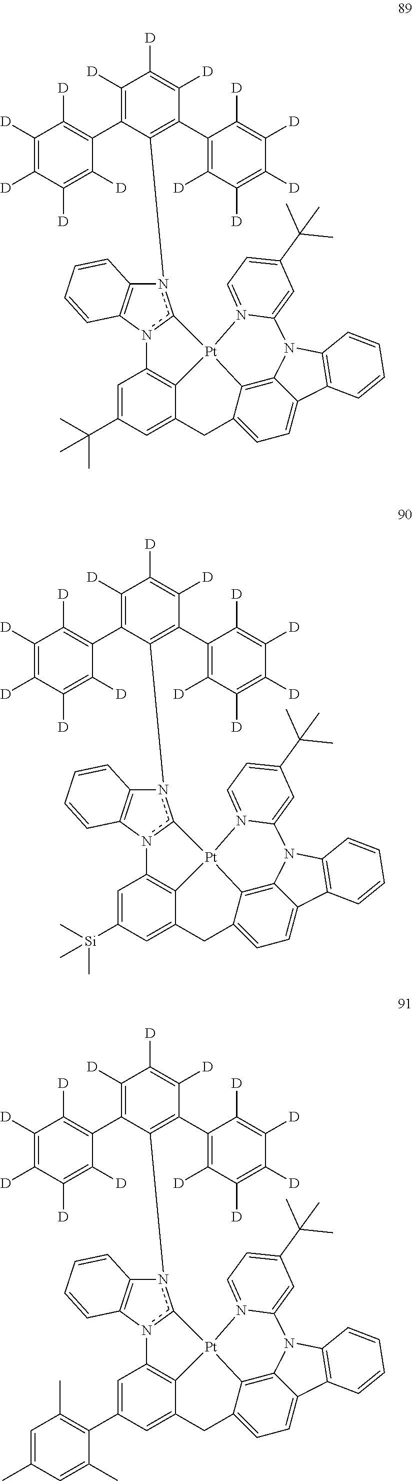

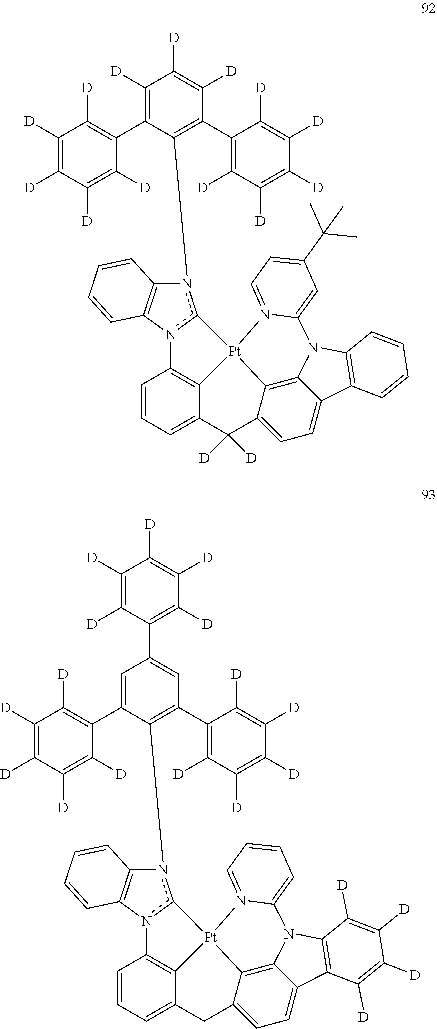

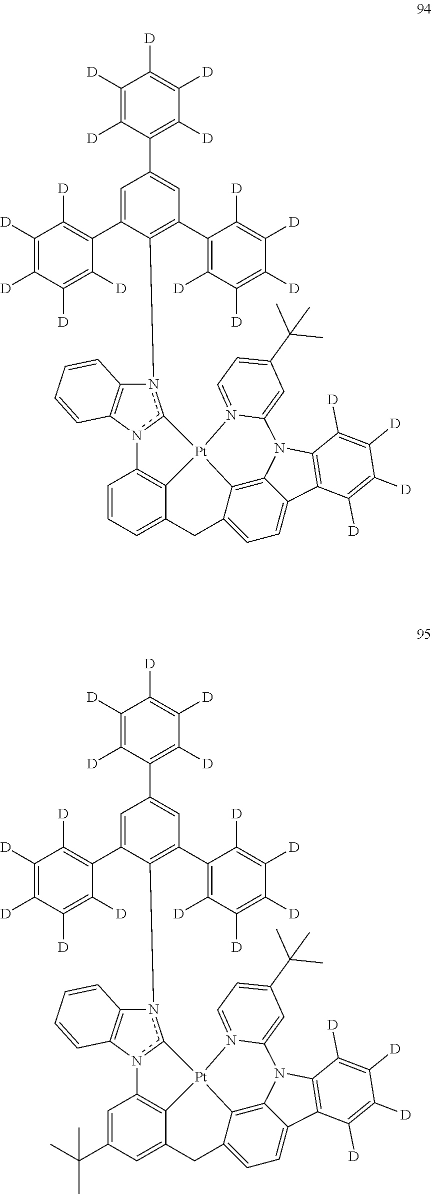

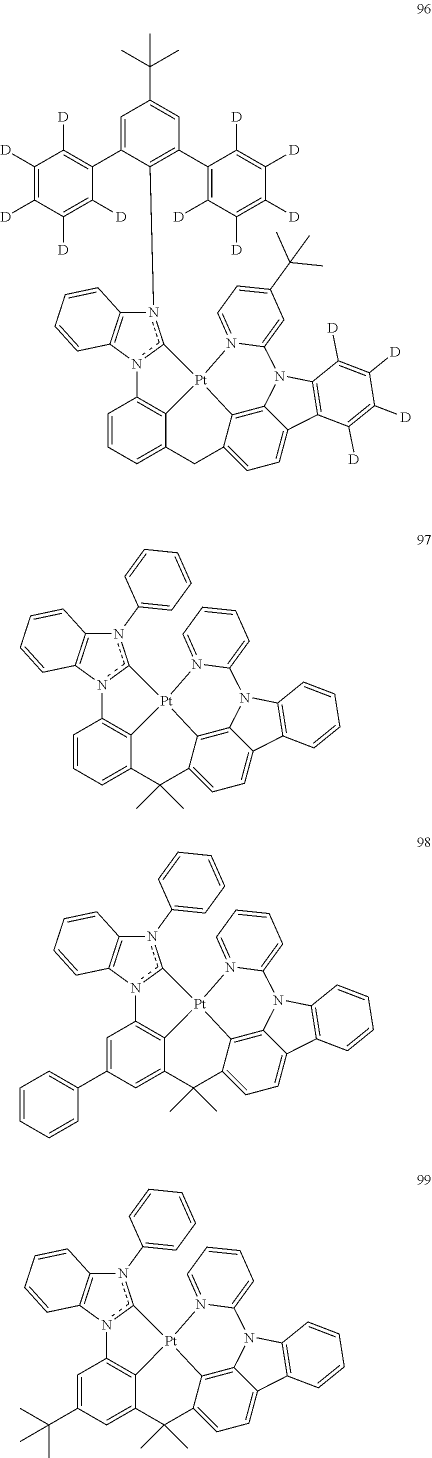

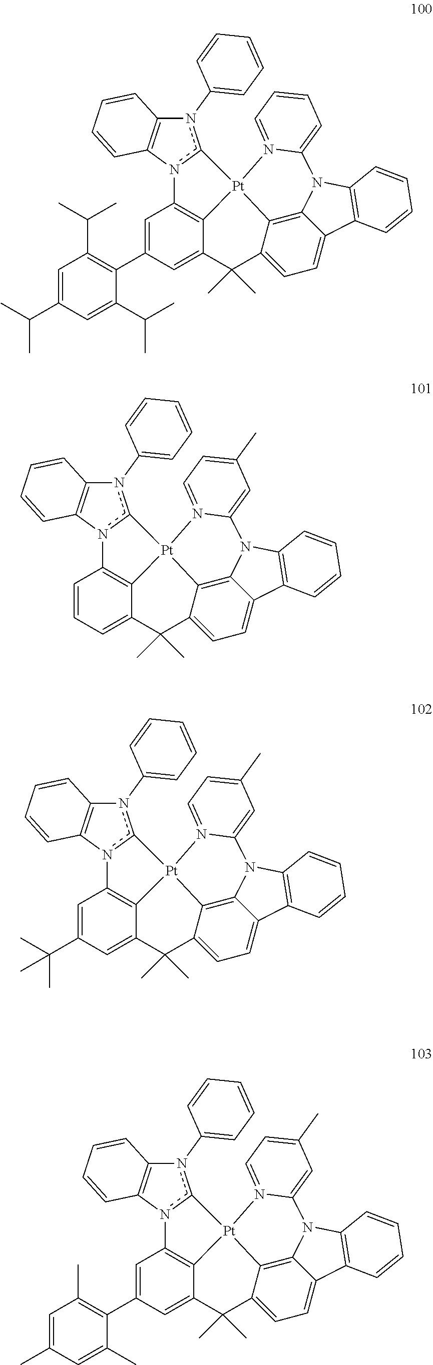

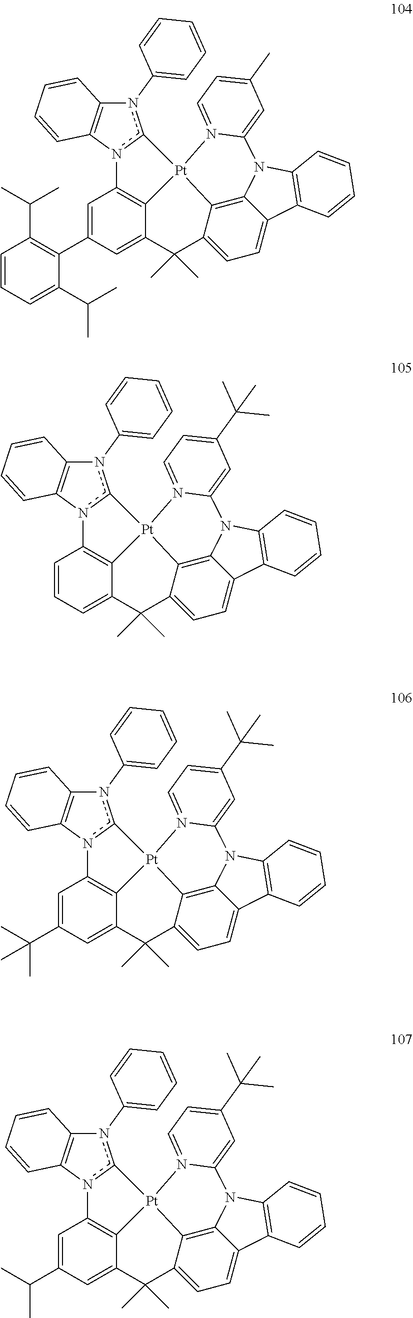

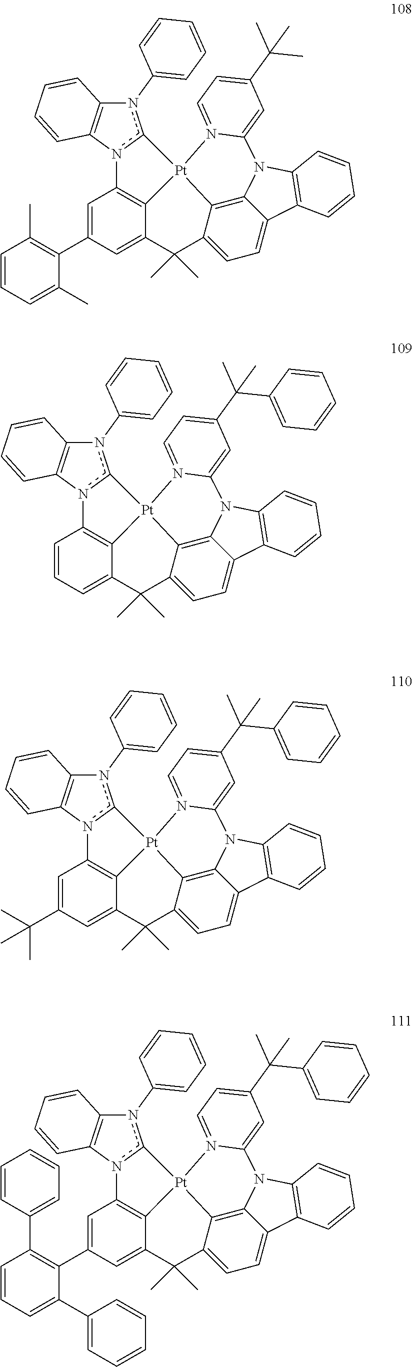

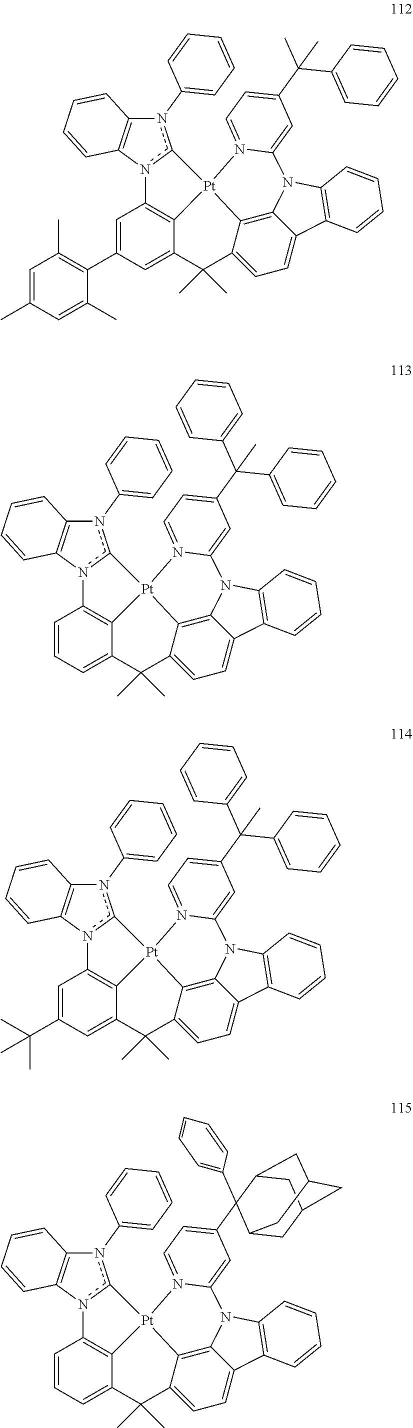

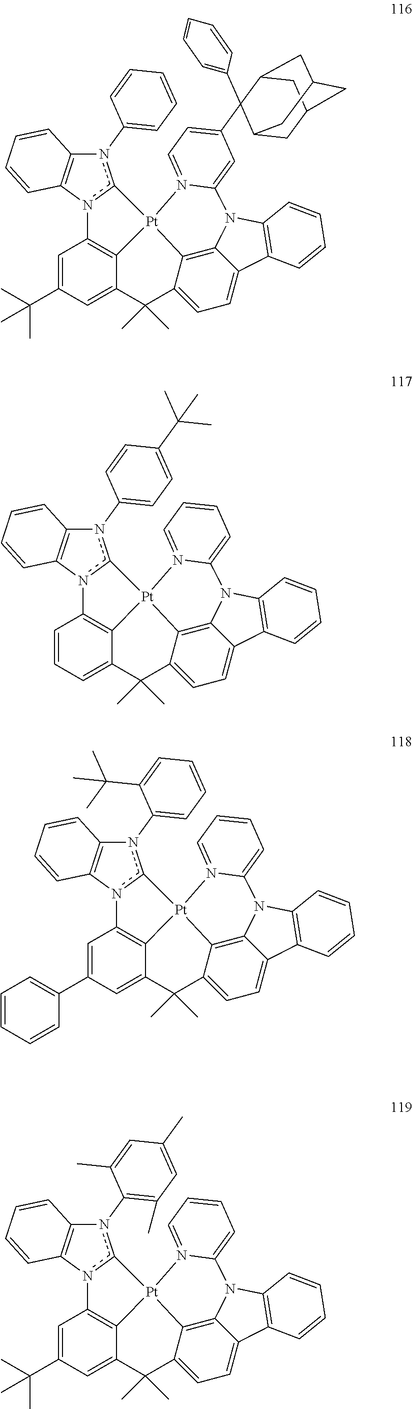

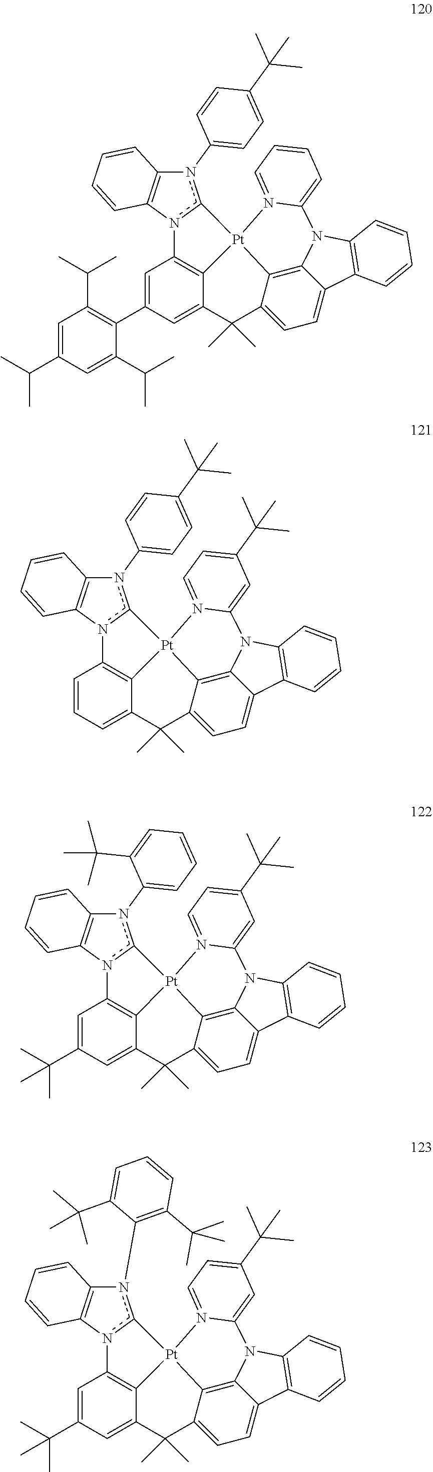

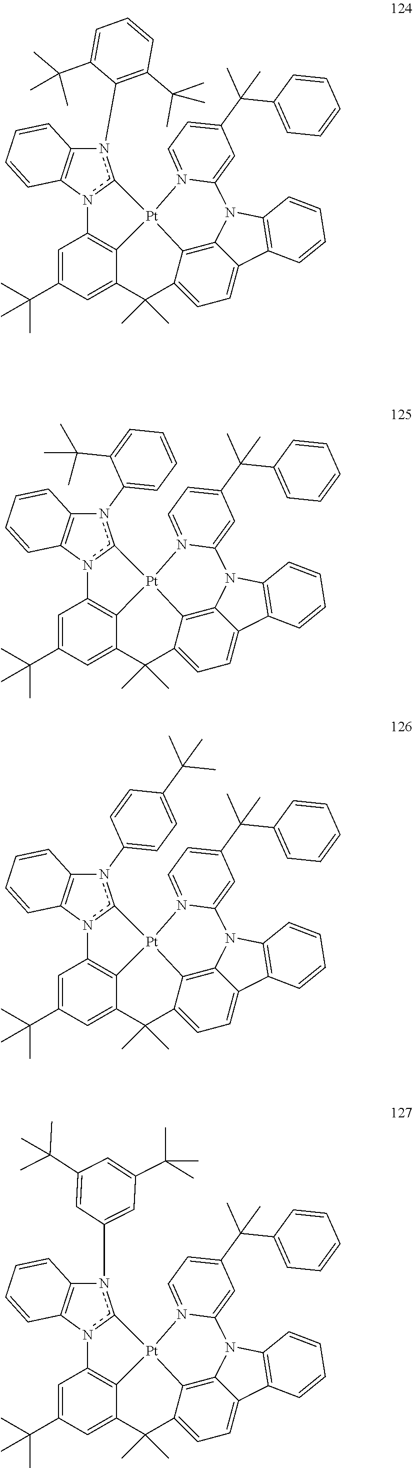

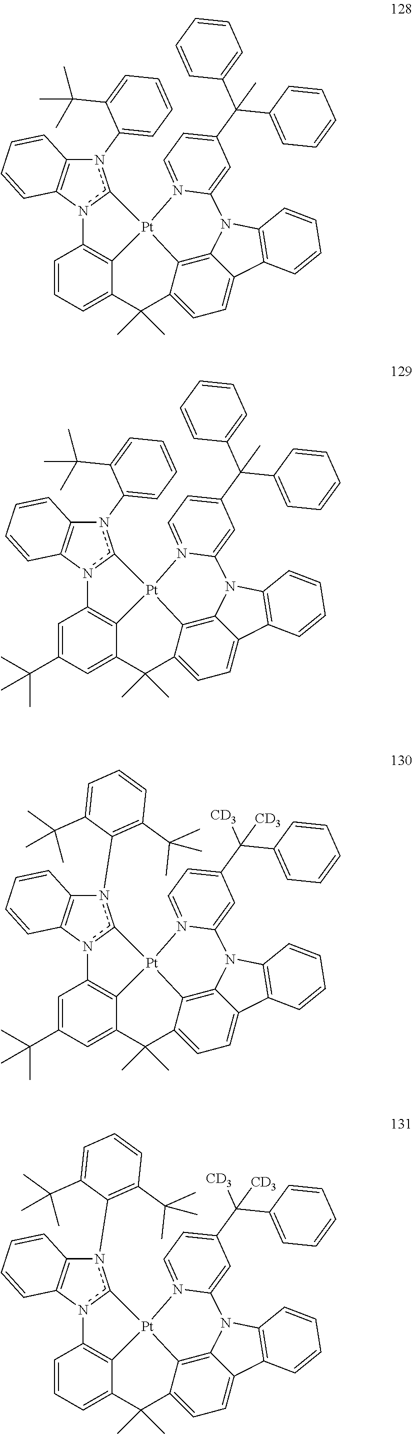

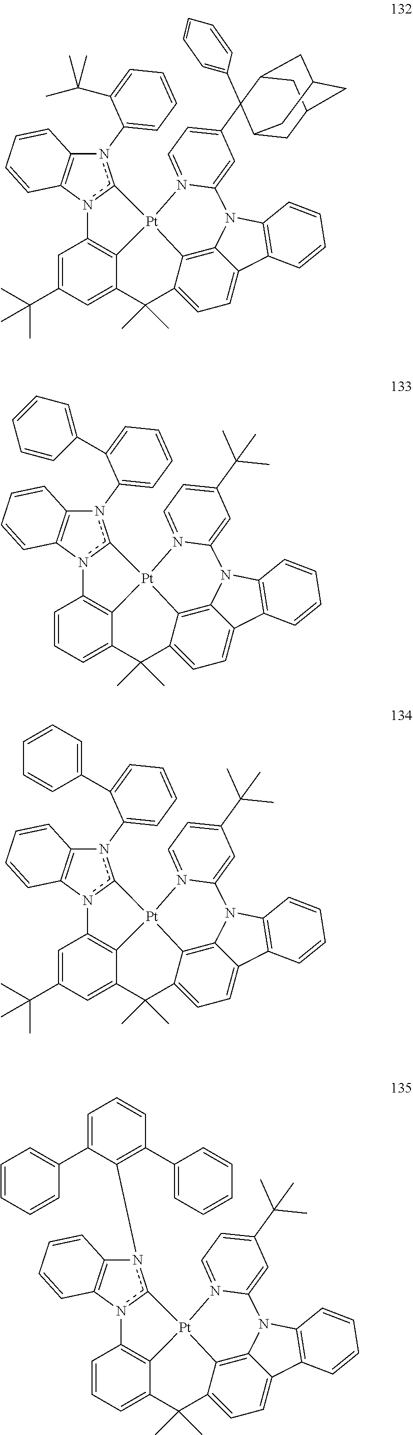

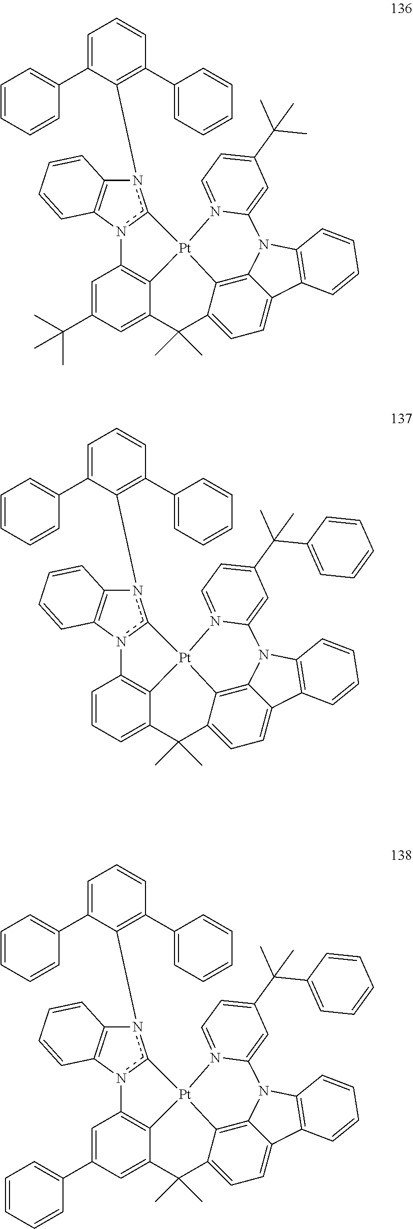

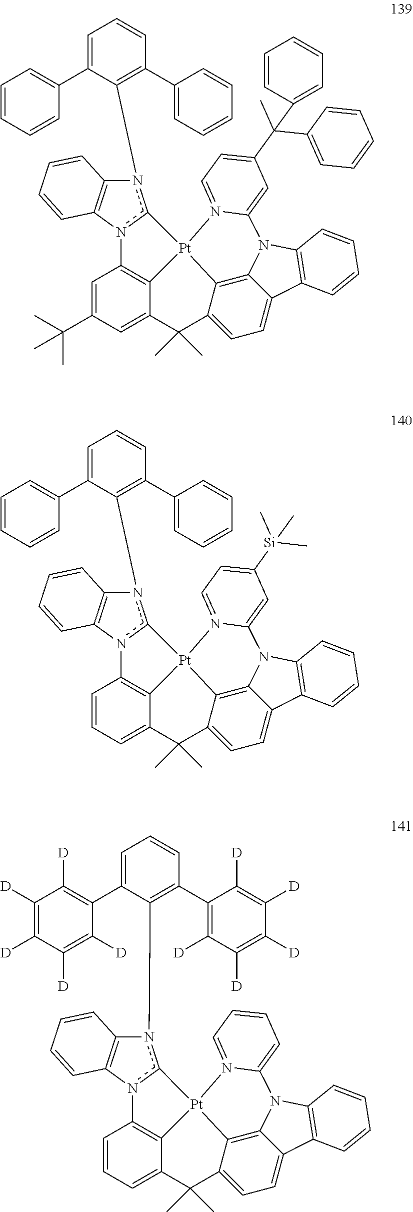

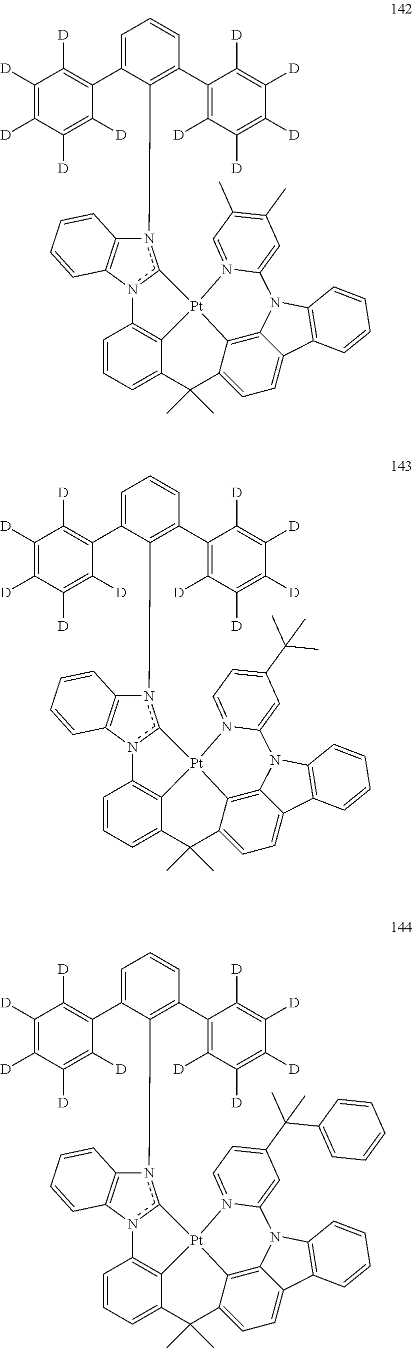

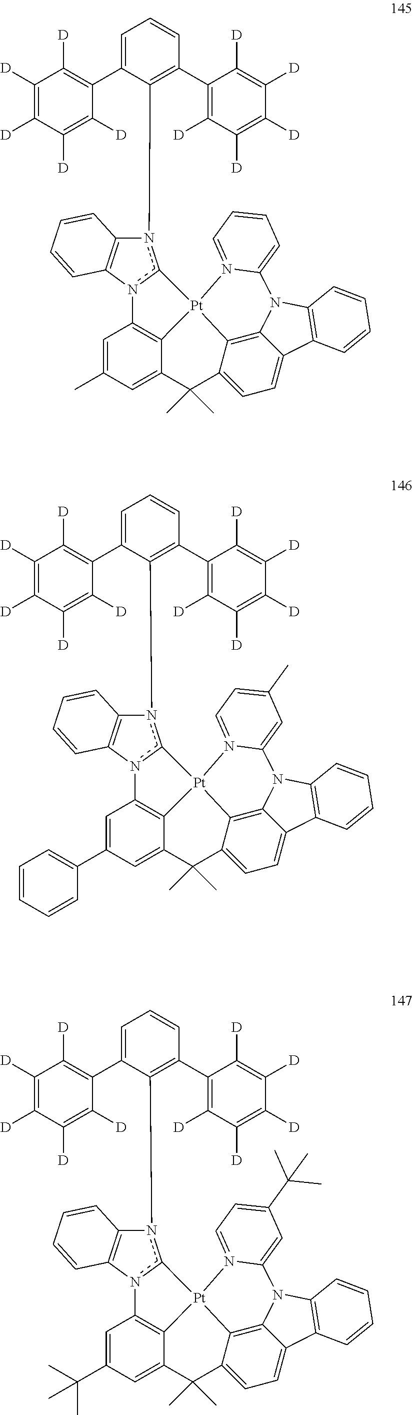

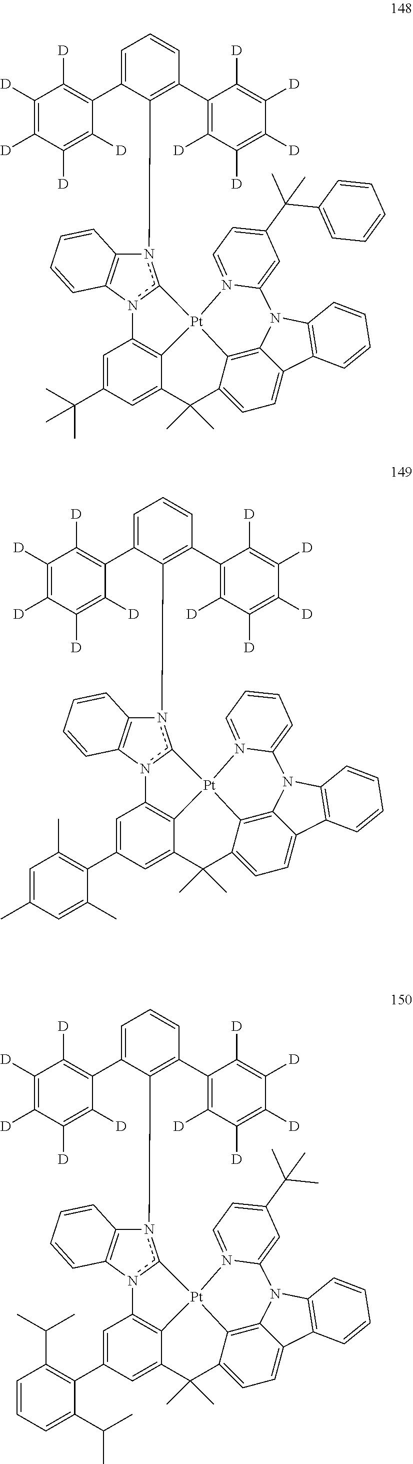

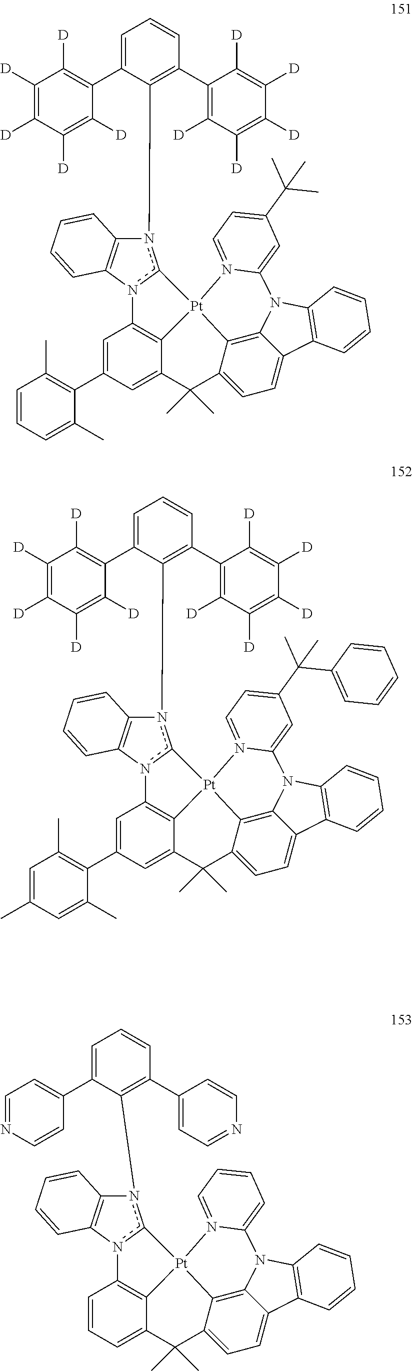

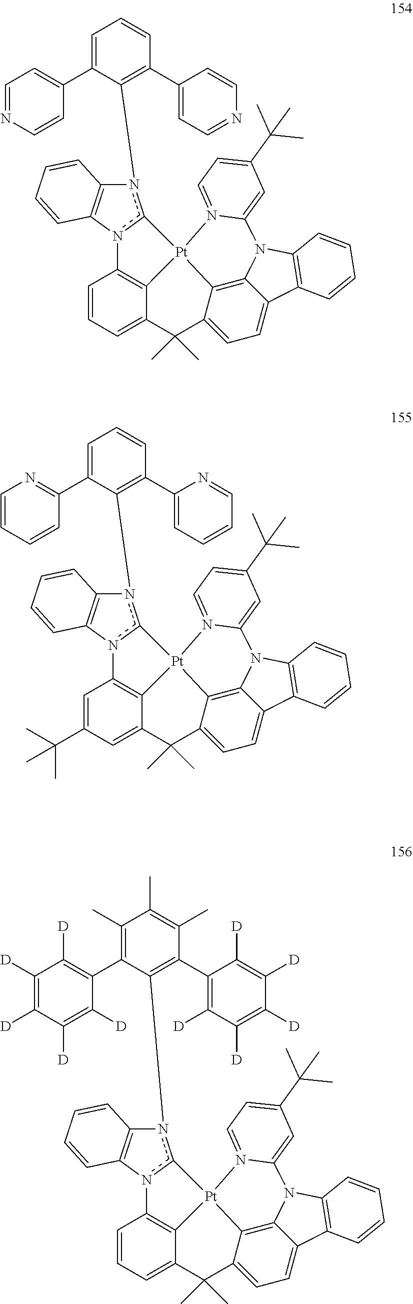

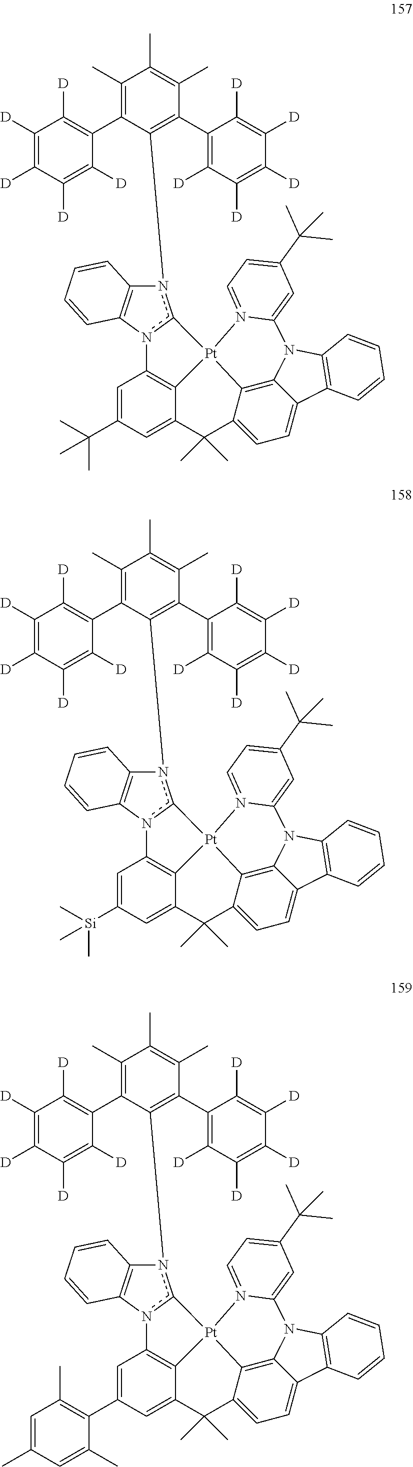

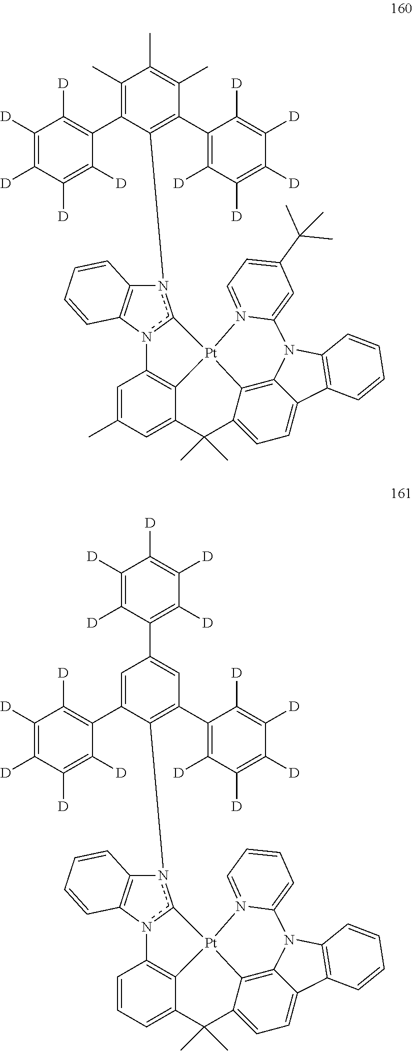

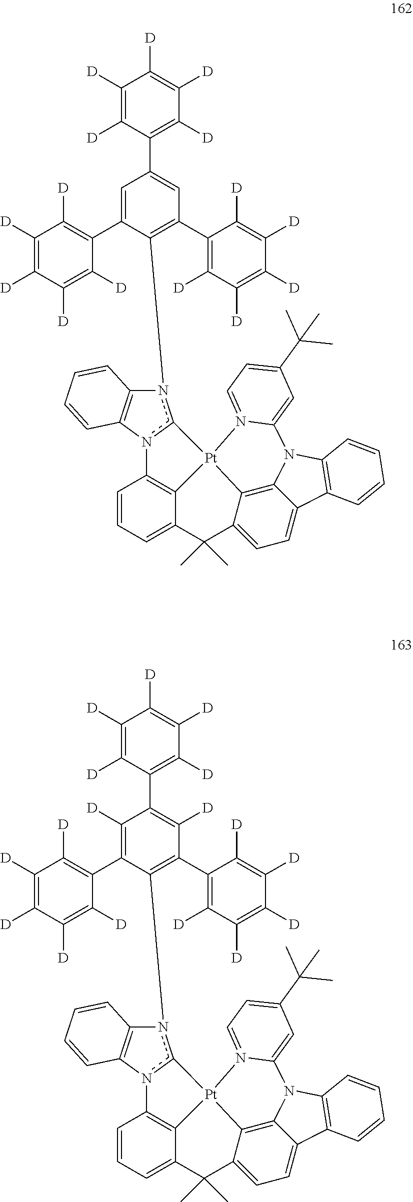

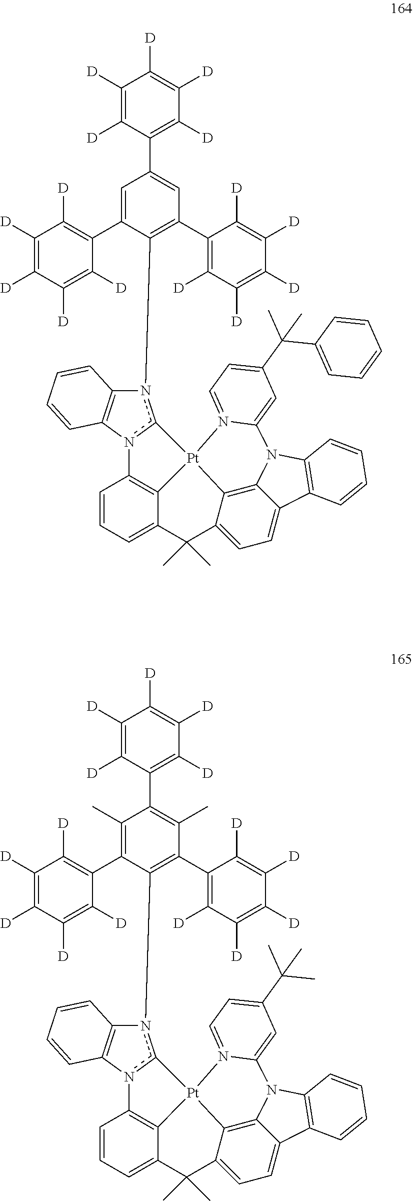

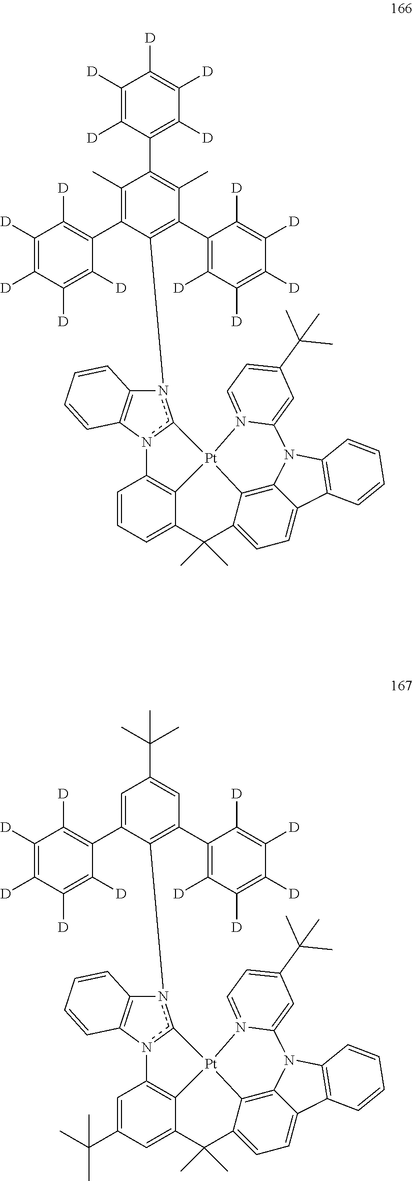

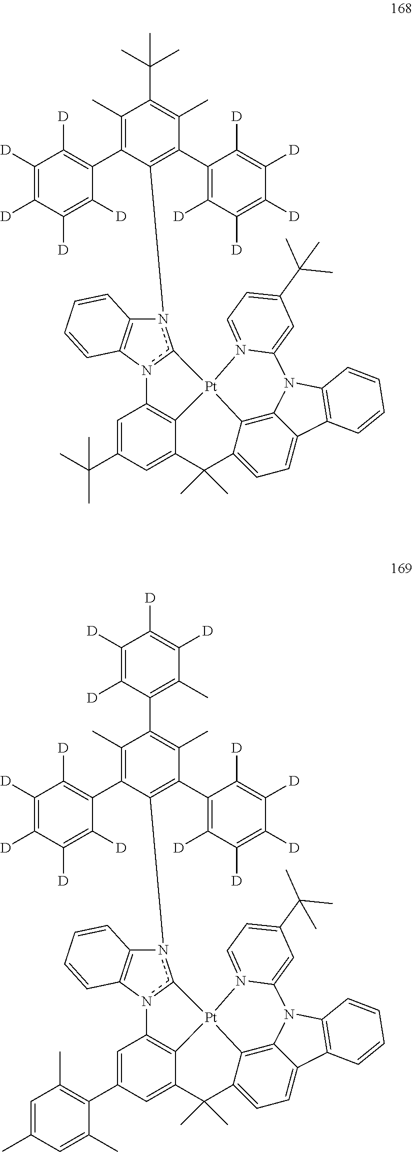

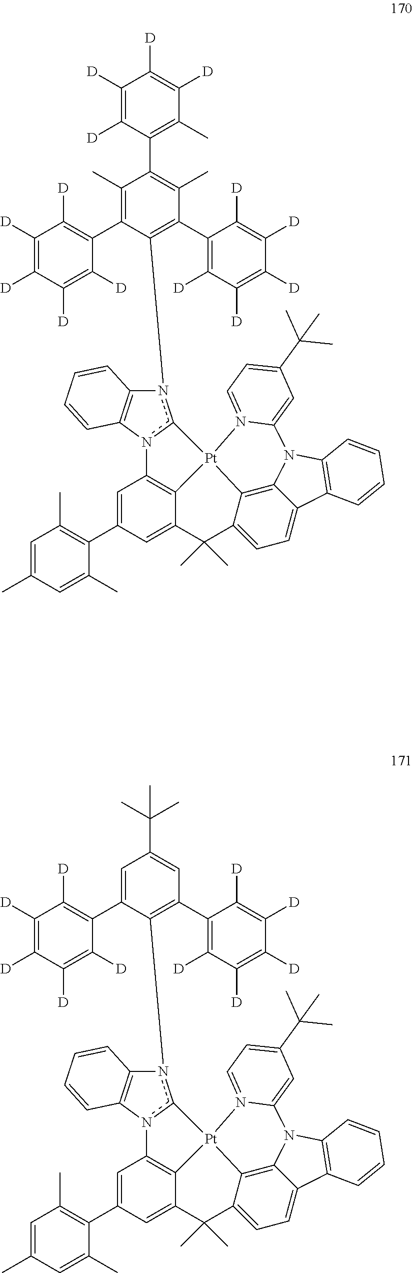

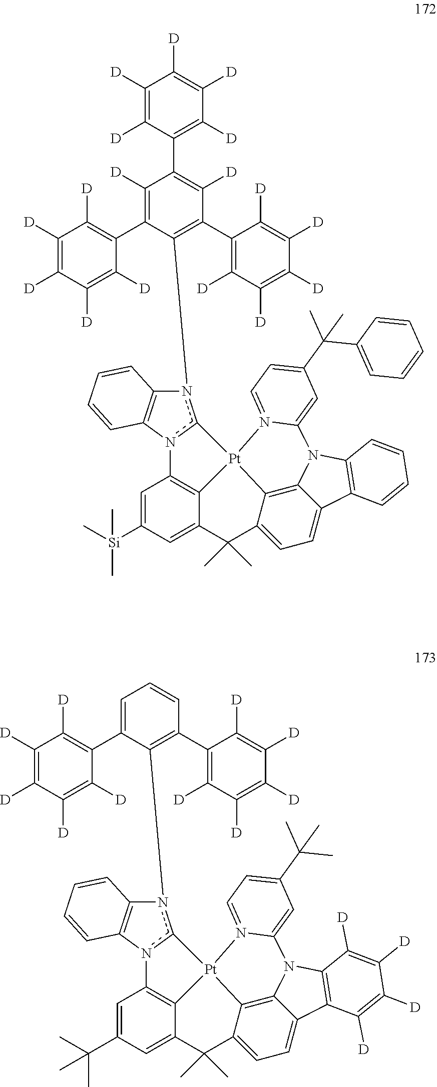

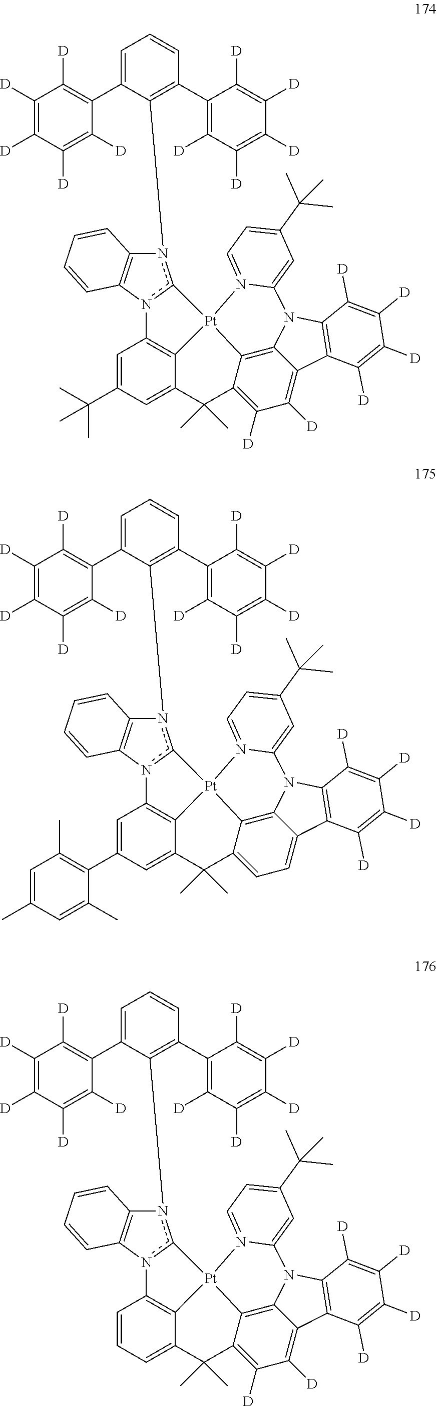

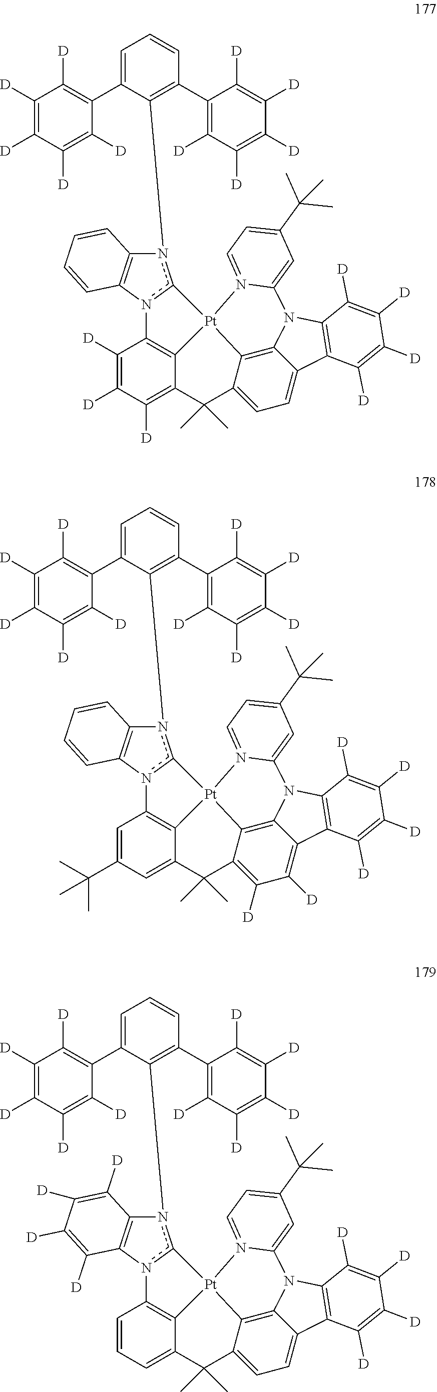

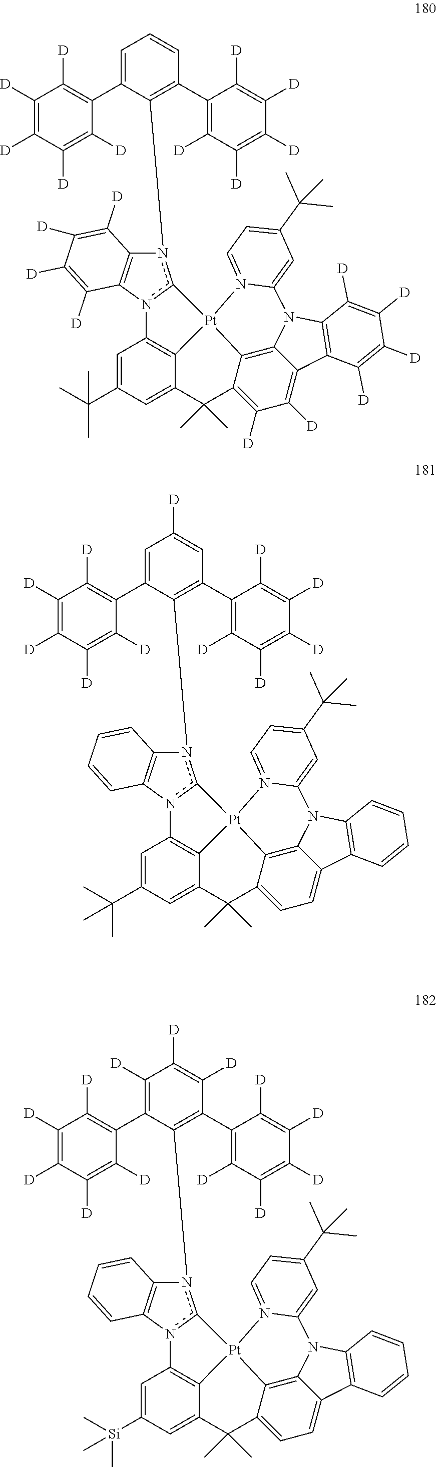

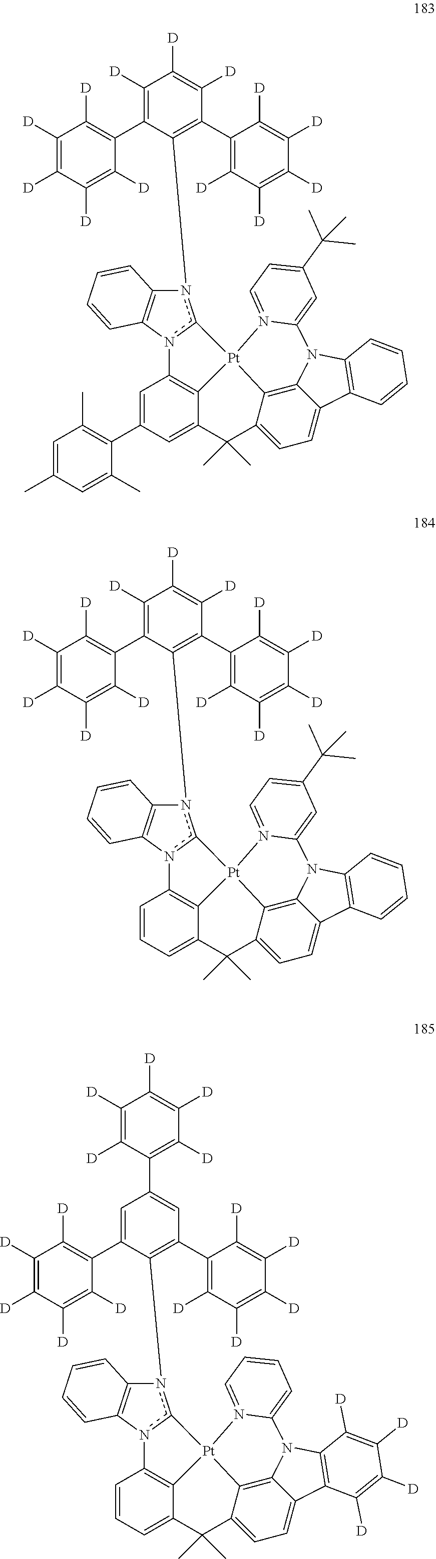

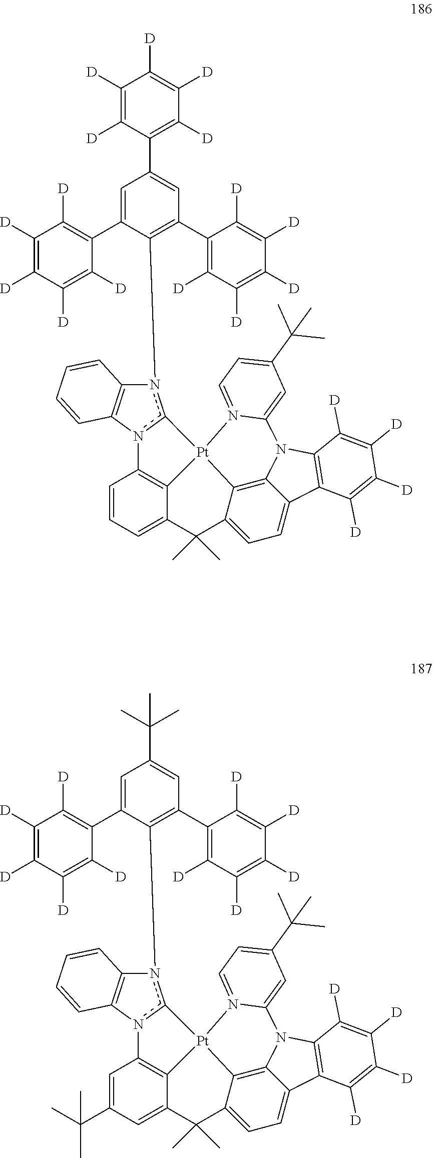

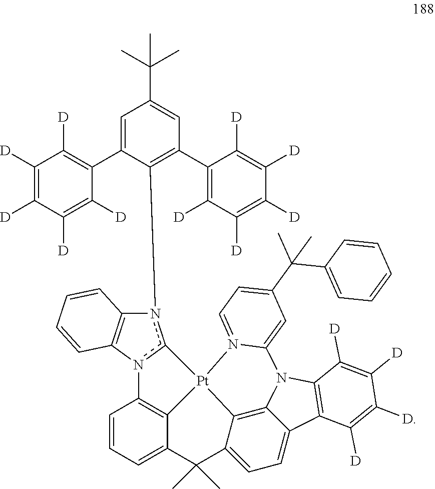

The organometallic compound represented by Formula 1-1 or 1-2, in which a linker connecting ring CY₂ and ring CY₃ is a carbon atom (e.g., includes a quaternary carbon atom), has a shorter luminescence wavelength than a compound in which the linker connecting ring CY₂ and ring CY₃ is a non-carbon atom (such as an oxygen atom), and may thus be able to emit deep blue light. Thus, the light-emitting device including the organometallic compound may be able to exhibit high color purity and/or color reproducibility.

Furthermore, the organometallic compound may include a bulky group R₁₀ substituent on a nitrogen atom of a carbene moiety, and thus may increase the stability of the compound by increasing the rigidity of the molecule. Accordingly, triplet excitons in the organometallic compound may have a short lifespan, such that the probability that the triplet excitons are used for luminescence may increase. Thus, the light-emitting device including the organometallic compound may have a high efficiency and/or an increased lifespan.

Accordingly, an electronic device including the organometallic compound (such as a light-emitting device) may have a low driving voltage, high efficiency, and/or a long lifetime.

Synthesis methods of the organometallic compound represented by Formula 1-1 or 1-2 may be recognizable by one of ordinary skill in the art by referring to the Synthesis Examples and/or Examples provided below.

At least one organometallic compound represented by Formula 1-1 or 1-2 may be used in a light-emitting device (for example, an organic light-emitting device). Accordingly, another aspect of the present disclosure provides a light-emitting device including: a first electrode; a second electrode facing the first electrode; an interlayer between the first electrode and the second electrode and including an emission layer; and the organometallic compound represented by Formula 1-1 or 1-2.

In an embodiment,

the first electrode of the light-emitting device may be an anode,

the second electrode of the light-emitting device may be a cathode,

the interlayer may further include a hole transport region between the first electrode and the emission layer and an electron transport region between the emission layer and the second electrode,

the hole transport region may include a hole injection layer, a hole transport layer, an emission auxiliary layer, an electron blocking layer, or any combination thereof, and

the electron transport region may include a buffer layer, a hole blocking layer, an electron control layer, an electron transport layer, an electron injection layer, or any combination thereof.

In one or more embodiments, the organometallic compound may be included between a pair of electrodes of the light-emitting device. Accordingly, the organometallic compound may be included in the interlayer of the light-emitting device, for example, in the emission layer of the interlayer.

In one or more embodiments, the emission layer in the interlayer of the light-emitting device may include a dopant and a host, and the organometallic compound may be included in the dopant. In one or more embodiments, the organometallic compound may act as a dopant. An amount of the dopant in the emission layer may be in a range of about 0.1 parts by weight to about 49.99 parts by weight based on 100 parts by weight of the emission layer.

The emission layer may be to emit red light, green light, blue light, and/or white light. For example, the emission layer may be to emit blue light. The emission layer may be to emit blue light having a maximum luminescence wavelength in a range of about 440 nm to about 475 nm. Based on the bottom emission, the blue light may have a CIEₓ color coordinate in a range of about 0.13 to about 0.14 and a CIE_{y} color coordinate in a range of about 0.06 to about 0.25.

In an embodiment, the host may include two different types (kinds) of hosts. For example, the host may include a hole transport host and an electron transport host.

In one or more embodiments, the light-emitting device may further include at least one of a first capping layer disposed outside the first electrode or a second capping layer disposed outside the second electrode. For example, at least one of the first capping layer or the second capping layer may include the organometallic compound represented by Formula 1-1 or 1-2.

In an embodiment, at least one of the first capping layer or the second capping layer may have a refractive index of equal to or greater than 1.6 at a wavelength of about 589 nm.

Additional details for the first capping layer and/or the second capping layer may be the same as described in the present specification.

The phrase “(interlayer and/or capping layer) includes an organometallic compound” as used herein may be understood as “the (interlayer and/or capping layer) may include one kind of organometallic compound represented by Formula 1-1 or 1-2 or two different kinds of organometallic compounds, each represented by Formula 1-1 or 1-2.”

In an embodiment, for example, the interlayer and/or the capping layer may include, as the organometallic compound, only Compound 1. In this embodiment, Compound 1 may be included in the emission layer of the light-emitting device. In one or more embodiments, the interlayer may include, as the organometallic compound, Compound 1 and Compound 2 (e.g., simultaneously). In this embodiment, Compound 1 and Compound 2 may exist (e.g., co-exist) in the same layer (for example, Compound 1 and Compound 2 may all exist in an emission layer), or may exist in different layers (for example, Compound 1 may exist in an emission layer and Compound 2 may exist in an electron transport region).

The term “interlayer” as used herein may refer to a single layer and/or all of a plurality of layers located between a first electrode and a second electrode of a light-emitting device.

Another aspect of the present disclosure provides an electronic apparatus including the light-emitting device. The electronic apparatus may further include a thin-film transistor. For example, the electronic apparatus may further include a thin-film transistor including a source electrode and a drain electrode, and the first electrode of the light-emitting device may be electrically connected to one or the source electrode or the drain electrode. In an embodiment, the electronic apparatus may further include a color filter, a color conversion layer, a touch screen layer, a polarizing layer, or any combination thereof. More details on the electronic apparatus may be the same as described in the present specification.

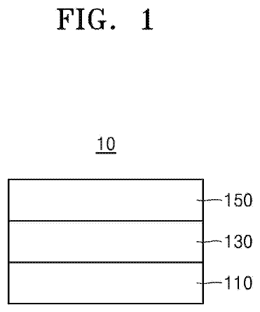

### Description of FIG. 1

FIG. 1 is a schematic cross-sectional view of a light-emitting device 10 according to an embodiment. The light-emitting device 10 includes a first electrode 110, an interlayer 130, and a second electrode 150.

Hereinafter, the structure of the light-emitting device 10 according to an embodiment and a method of manufacturing the light-emitting device 10 will be described in connection with FIG. 1.

### First Electrode 110

In FIG. 1, a substrate may be additionally located under the first electrode 110 and/or above the second electrode 150. The substrate may be a glass substrate and/or a plastic substrate. The substrate may be a flexible substrate. In one or more embodiments, the substrate may include plastics with excellent heat resistance and/or durability (such as polyimide, polyethylene terephthalate (PET), polycarbonate, polyethylene naphthalate, polyarylate (PAR), polyetherimide, and/or a combination thereof).

The first electrode 110 may be formed by, for example, depositing or sputtering a material for forming the first electrode 110 on the substrate. When the first electrode 110 is an anode, a high work function material that can easily inject holes may be used as the material for forming the first electrode 110.

The first electrode 110 may be a reflective electrode, a semi-transmissive electrode, or a transmissive electrode. In an embodiment, when the first electrode 110 is a transmissive electrode, the material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, the material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layered structure including (e.g., consisting of) a single layer or a multi-layered structure including a plurality of layers. For example, the first electrode 110 may have a three-layered structure of ITO/Ag/ITO.

### Interlayer 130

The interlayer 130 may be on the first electrode 110. The interlayer 130 may include an emission layer.

In some embodiments, the interlayer 130 may further include a hole transport region between the first electrode 110 and the emission layer, and/or an electron transport region between the emission layer and the second electrode 150.

The interlayer 130 may further include metal-containing compounds (such as an organometallic compound), inorganic materials (such as quantum dots), and/or the like, in addition to various suitable organic materials.

In an embodiment, the interlayer 130 may include: i) two or more emitting units sequentially stacked between the first electrode 110 and the second electrode 150, and ii) a charge generation layer between the two emitting units. When the interlayer 130 includes the emitting unit and the charge generation layer as described above, the light-emitting device 10 may be a tandem light-emitting device.

### Hole Transport Region in Interlayer 130

The hole transport region may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the constituting layer of each structure are stacked sequentially on the first electrode 110.

The hole transport region may include a compound represented by Formula 201, a compound represented by Formula 202, or any combination thereof:

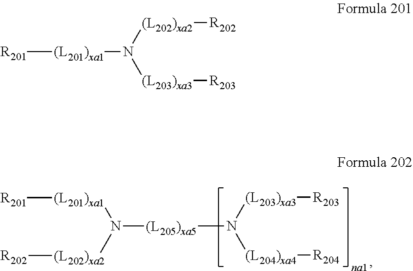

wherein, in Formulae 201 and 202,

L₂₀₁ to L₂₀₄ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,

L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,

R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, for example to form a C₈-C₆₀ polycyclic group unsubstituted or substituted with at least one R₁₀ₐ (for example, a carbazole group and/or the like) (for example, see Compound HT16),

R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, for example to form a C₈-C₆₀ polycyclic group unsubstituted or substituted with at least one R₁₀ₐ, and

na1 may be an integer from 1 to 4.

In some embodiments, Formulae 201 and 202 may each include at least one of the groups represented by Formulae CY201 to CY217:

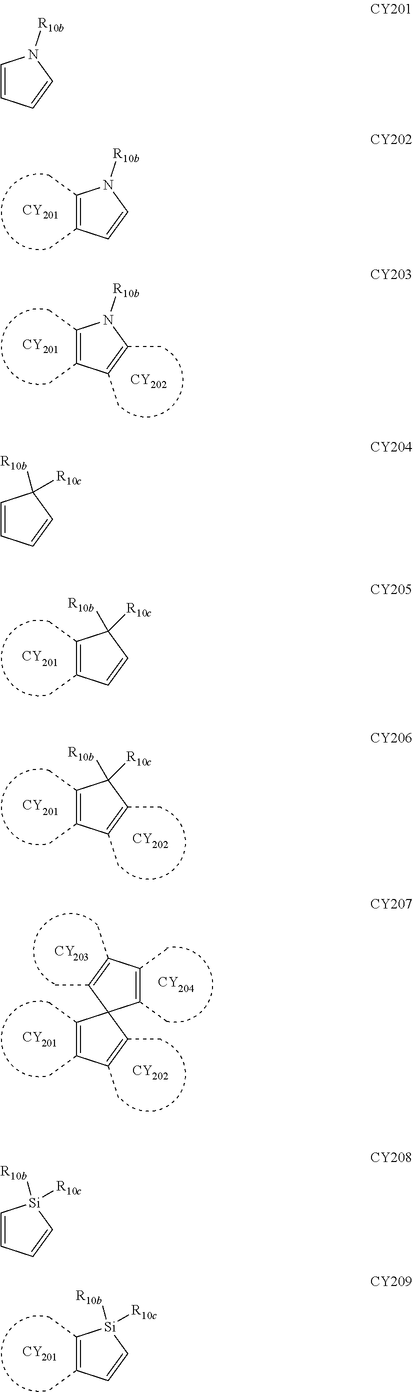

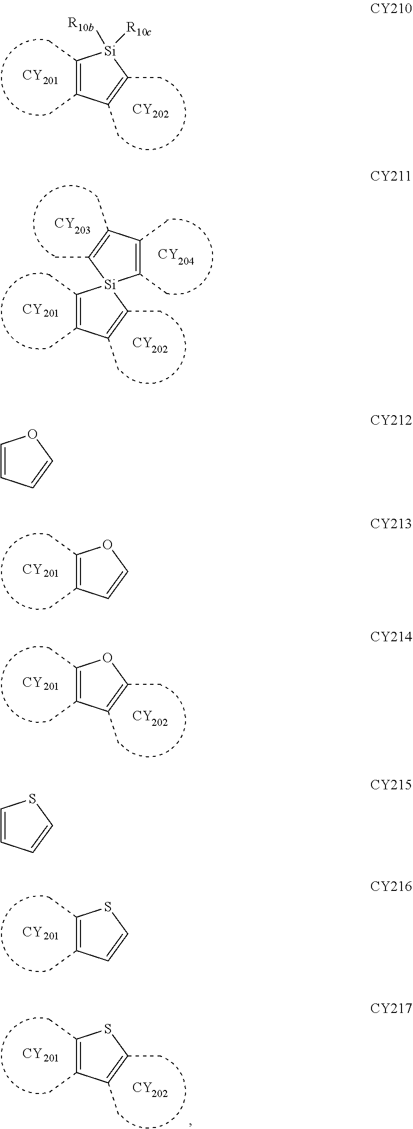

wherein, in Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with at least one R₁₀ₐ.

In an embodiment, ring CY₂₀₁ to ring CY₂₀₄ in Formulae CY201 to CY217 may each independently be a benzene group, a naphthalene group, a phenanthrene group, or an anthracene group.

In one or more embodiments, Formulae 201 and 202 may each include at least one of the groups represented by Formulae CY201 to CY203.

In one or more embodiments, Formula 201 may include at least one of the groups represented by Formulae CY201 to CY203 and at least one of the groups represented by Formulae CY204 to CY217.

In one or more embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

In one or more embodiments, each of Formulae 201 and 202 may not include (e.g., may not be) the groups represented by Formulae CY201 to CY203 (e.g., may be groups other than those represented by Formulae CY201 to CY203).

In one or more embodiments, each of Formulae 201 and 202 may not include the groups represented by Formulae CY201 to CY203, and may include at least one of the groups represented by Formulae CY204 to CY217.

In one or more embodiments, each of Formulae 201 and 202 may not include the groups represented by Formulae CY201 to CY217.

For example, the hole transport region may include one of Compounds HT1 to HT44, m-MTDATA, TDATA, 2-TNATA, NPB(NPD), β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), or any combination thereof:

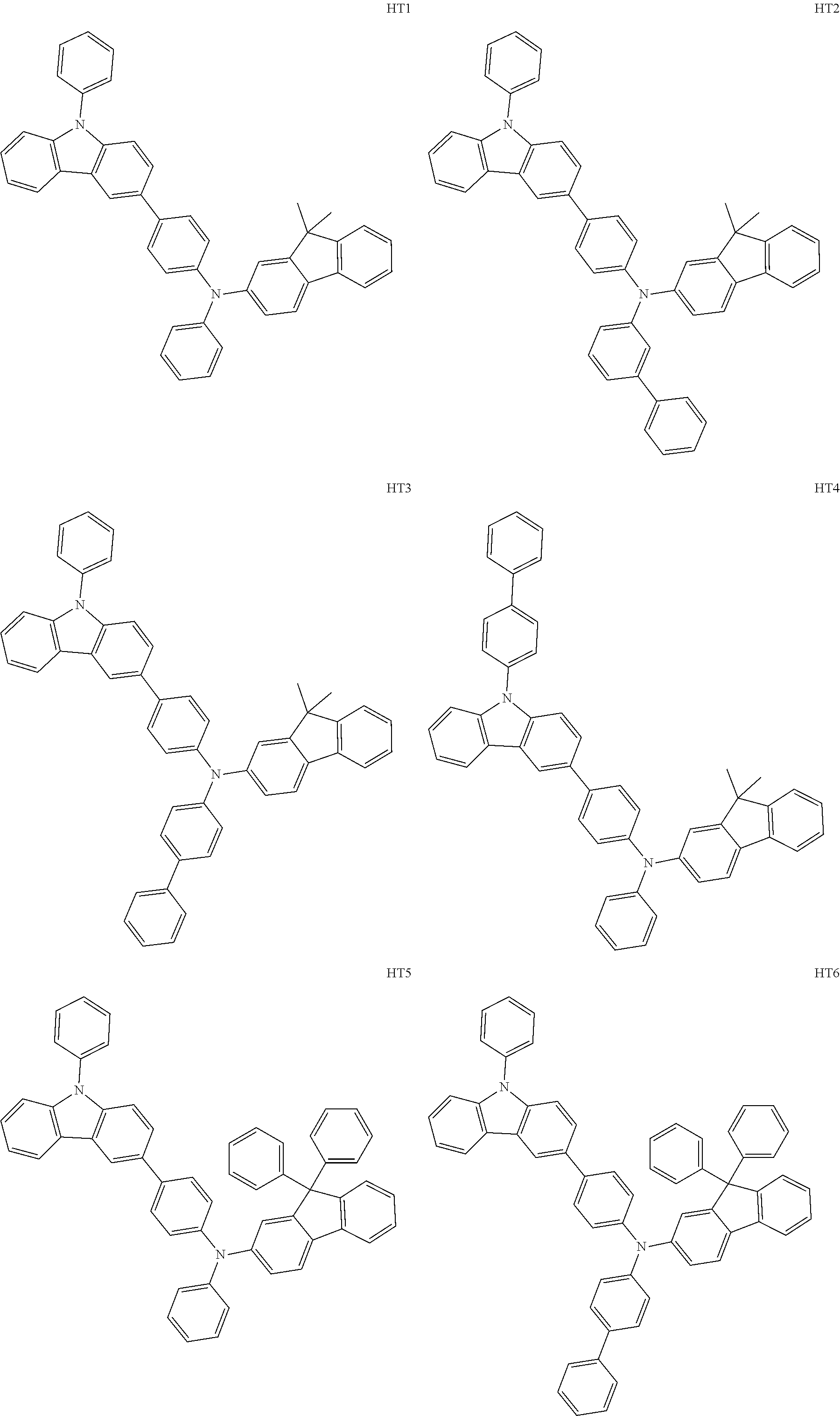

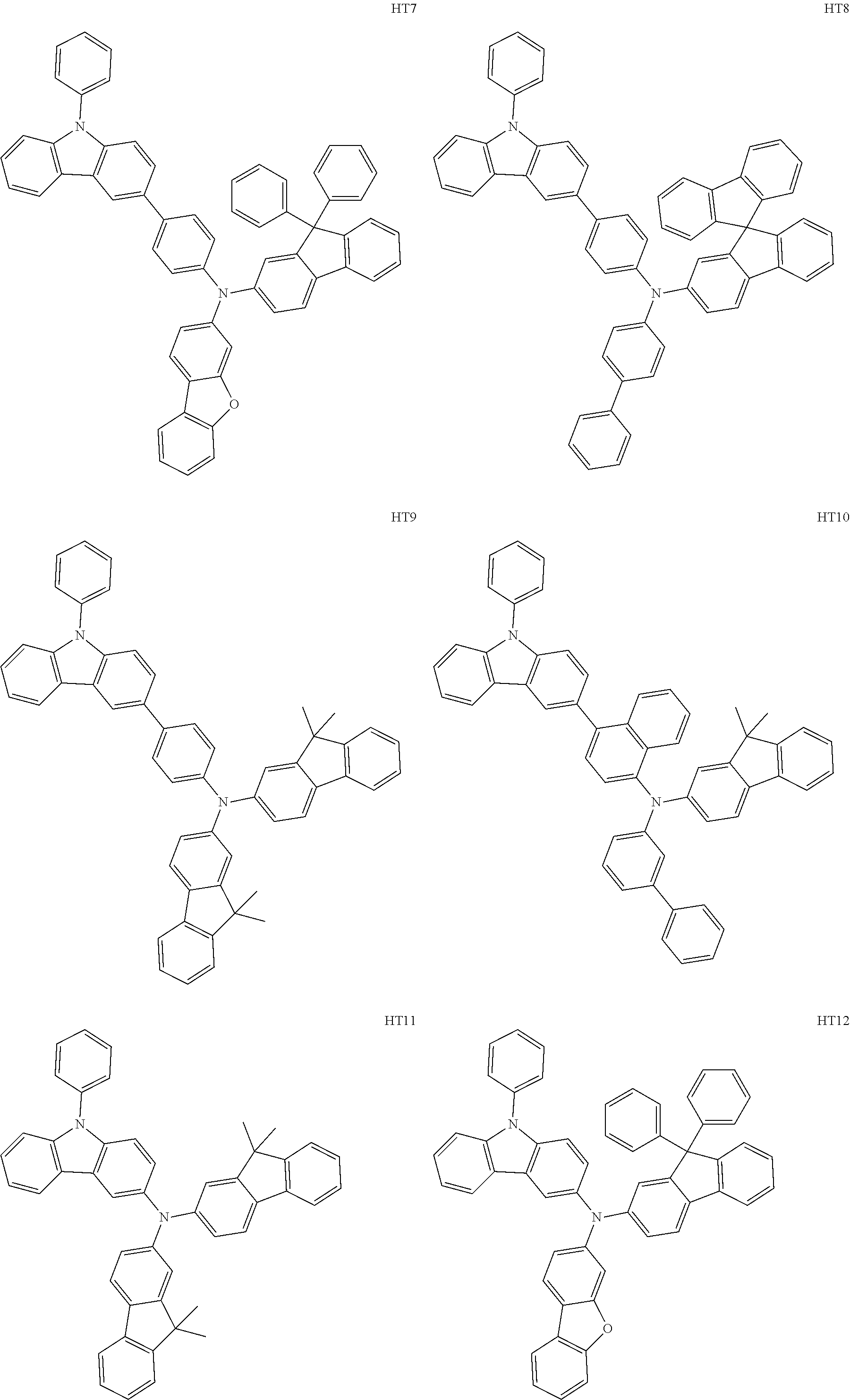

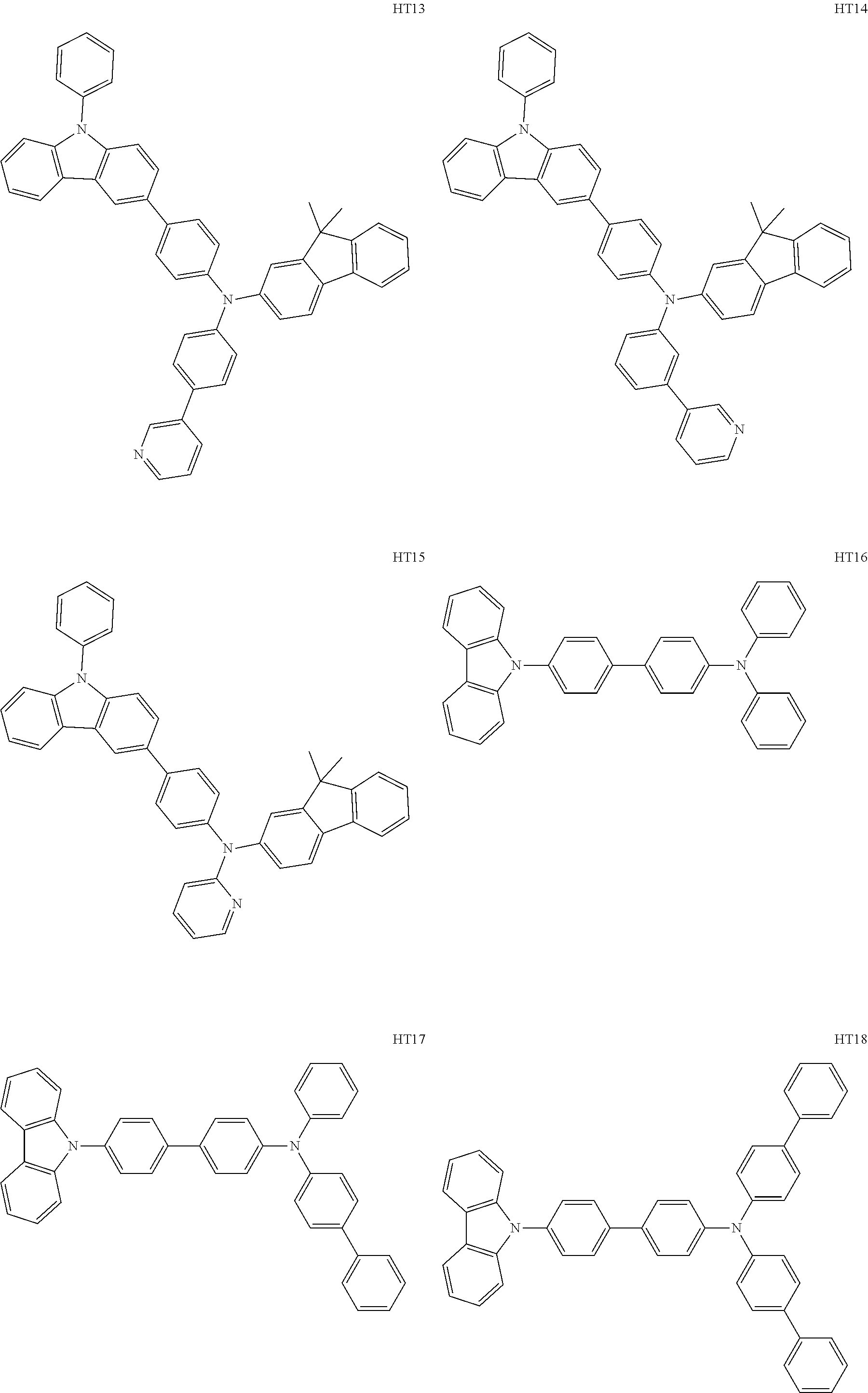

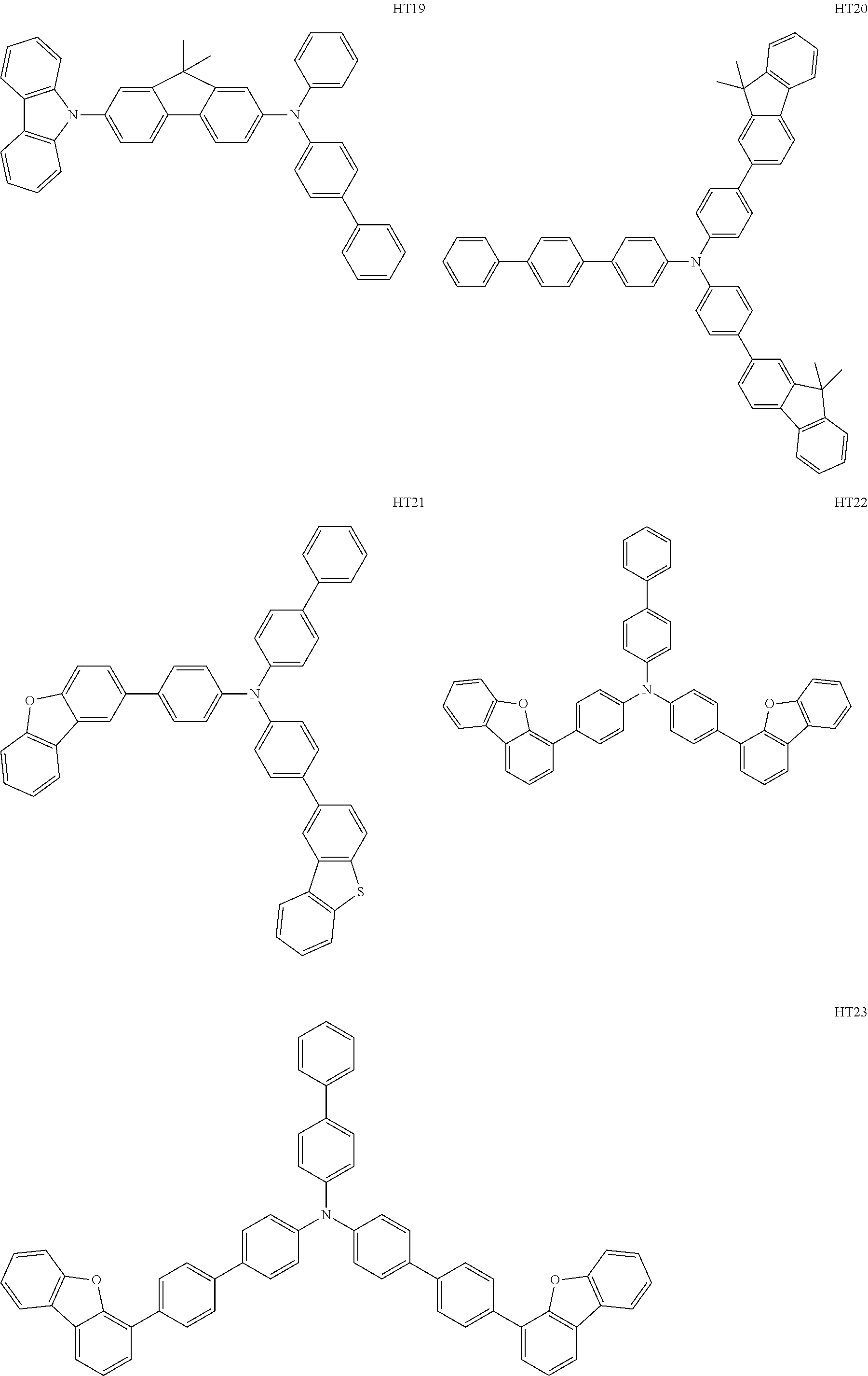

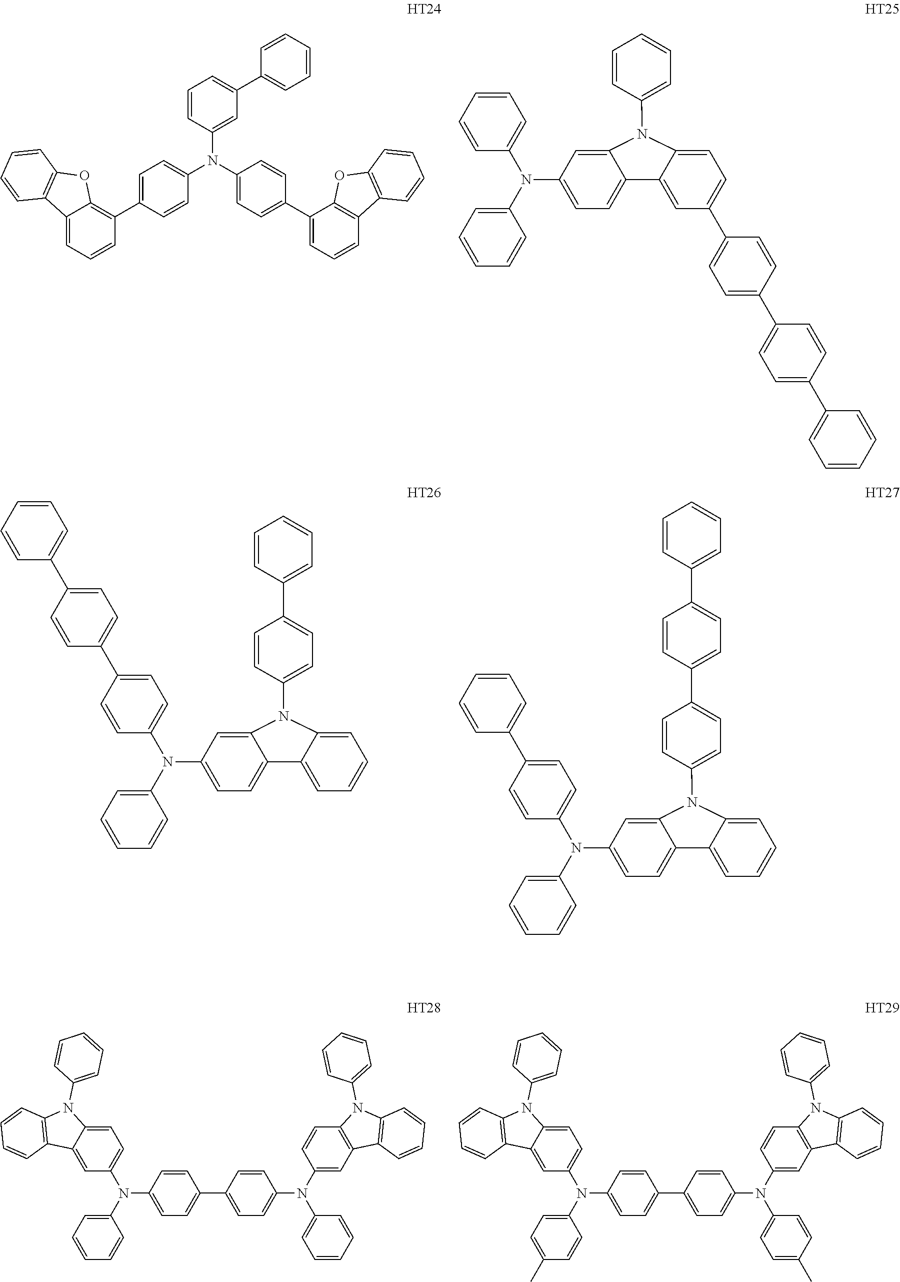

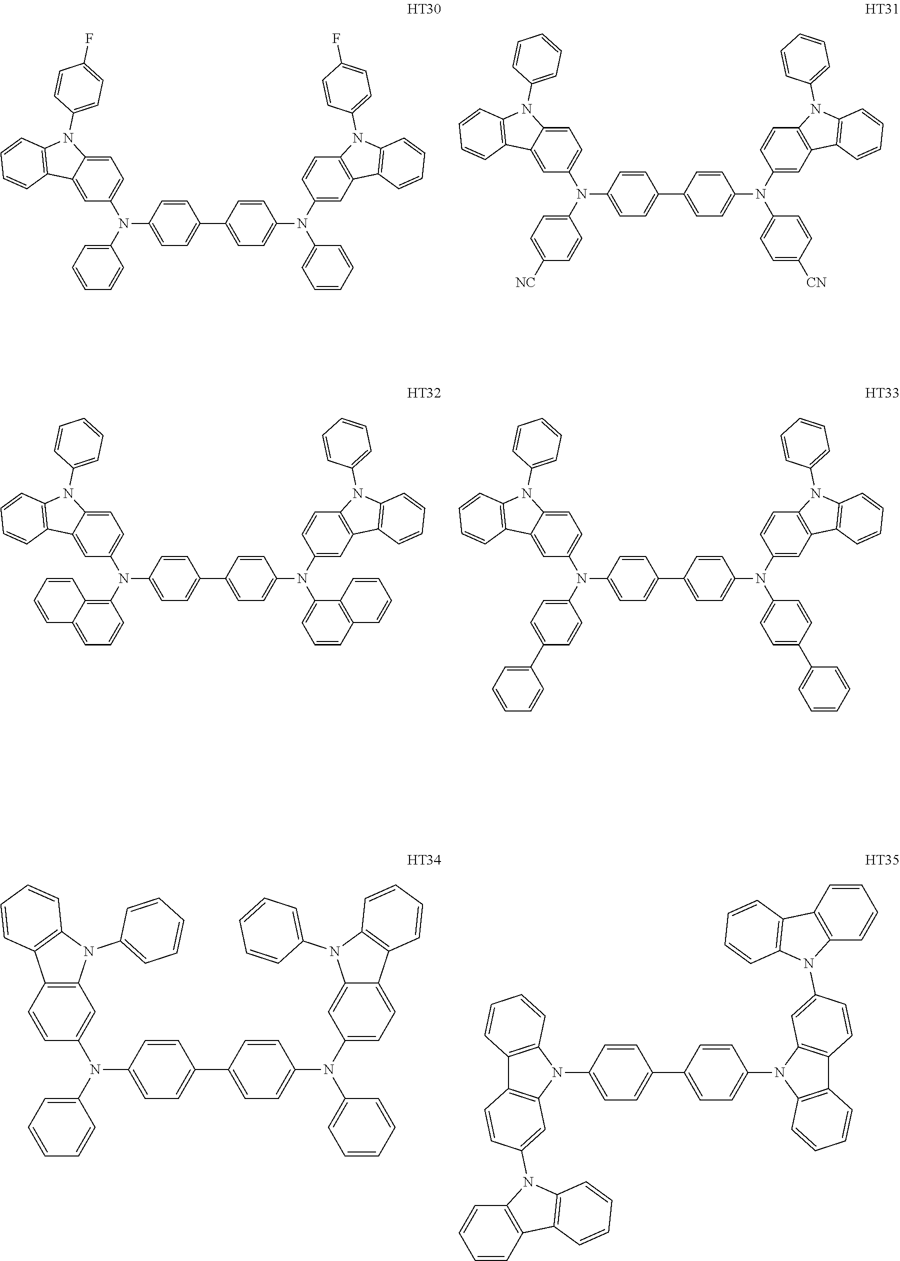

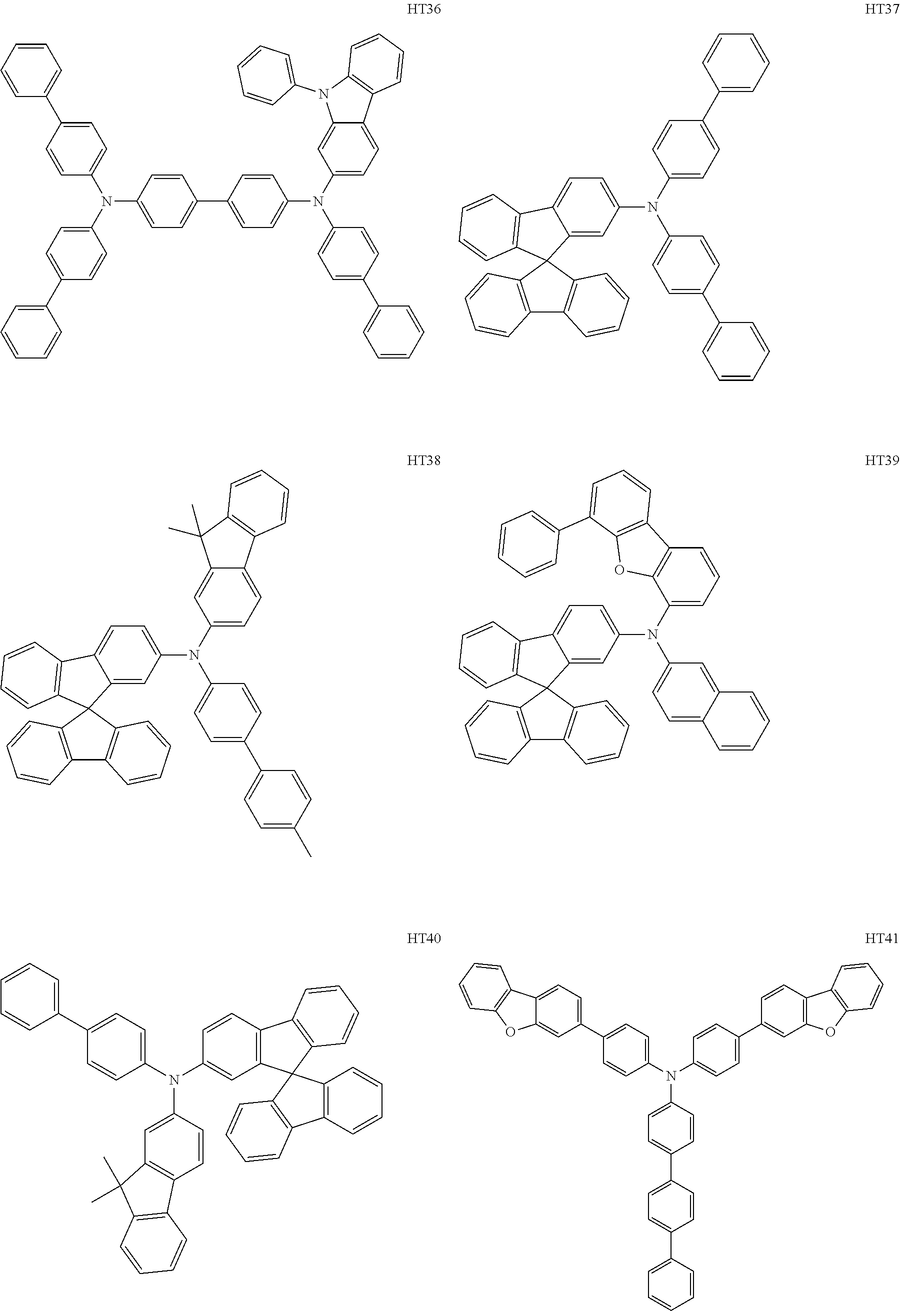

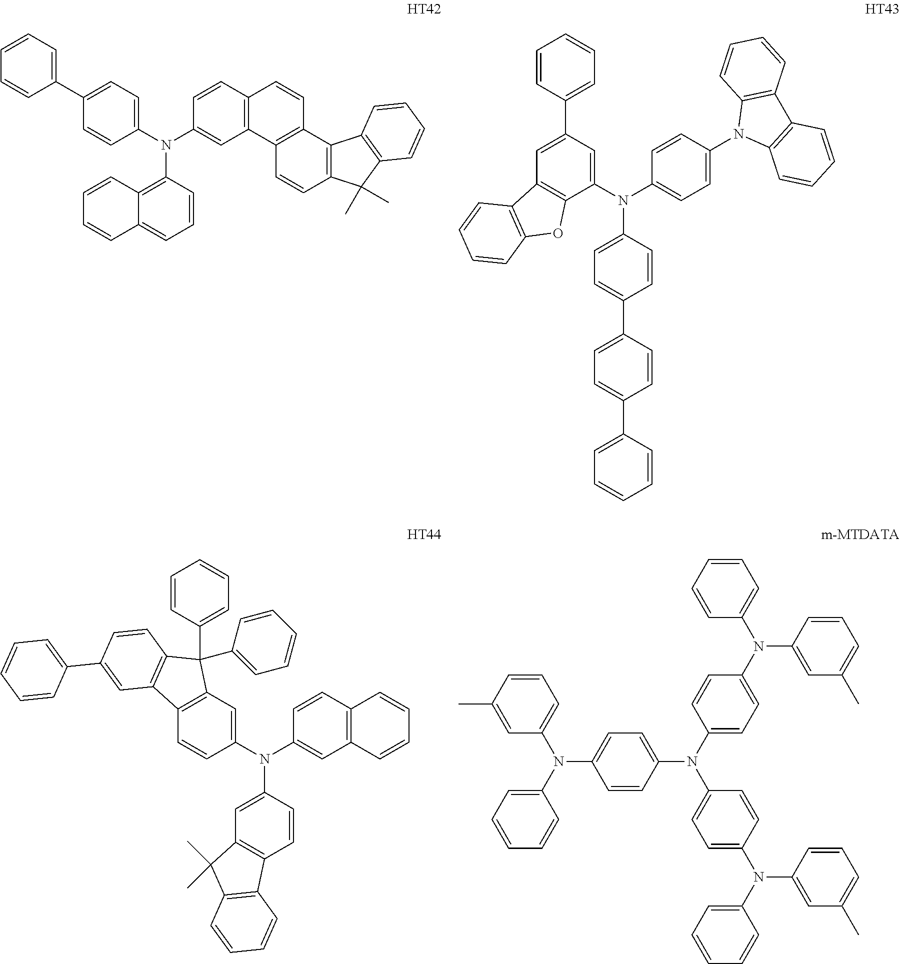

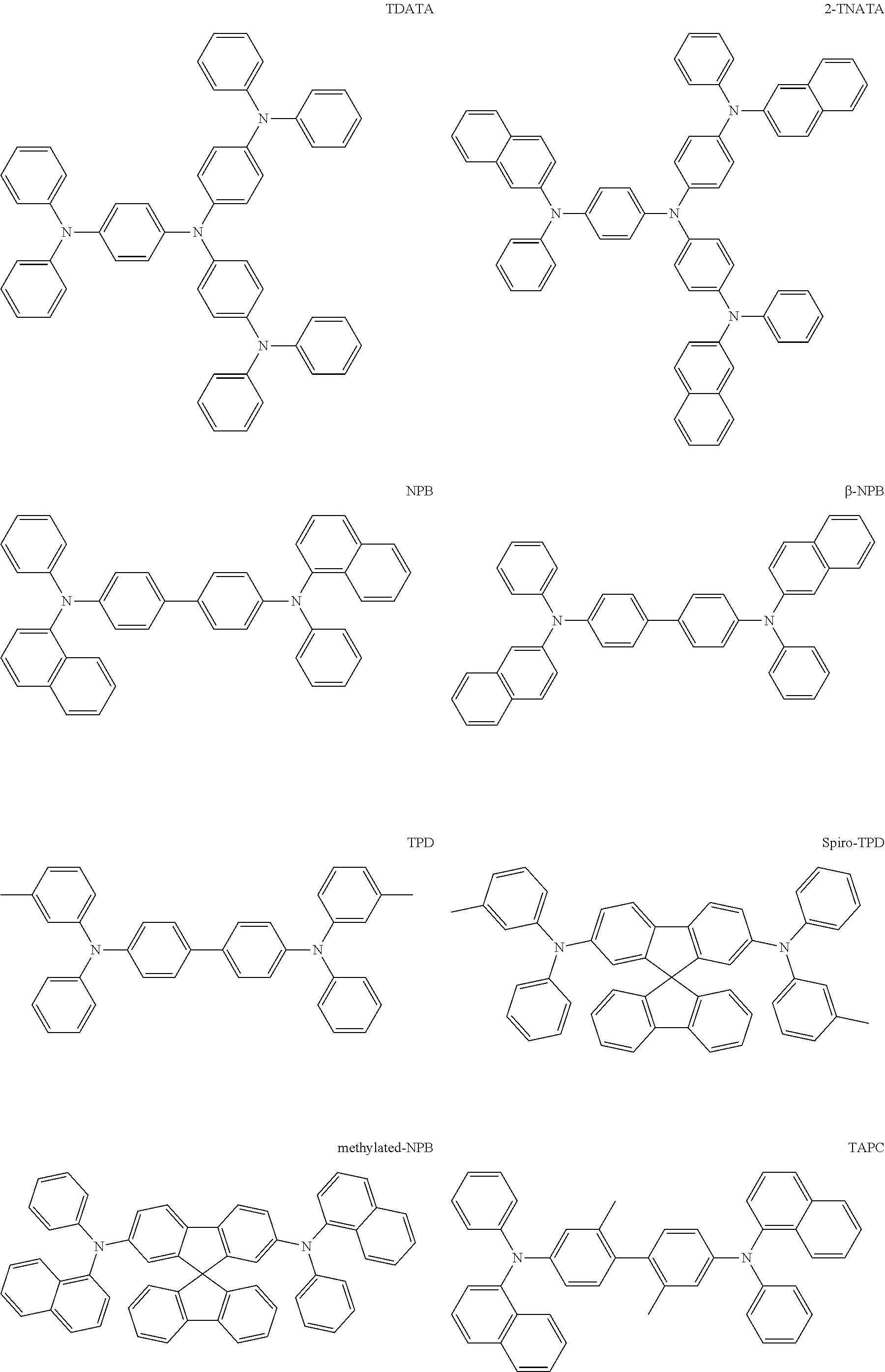

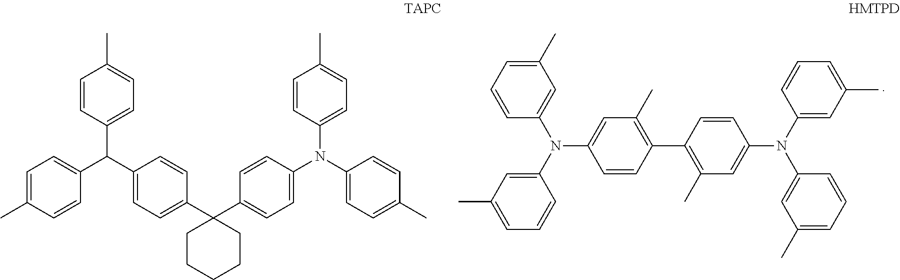

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase the light-emission efficiency of the device by compensating for an optical resonance distance of the wavelength of light emitted by the emission layer, and the electron blocking layer may block or reduce the flow of electrons from the electron transport region. The emission auxiliary layer and the electron blocking layer may include the materials as described above.

### P-Dopant

The hole transport region may further include, in addition to these materials, a charge-generation material for the improvement of conductive properties. The charge-generation material may be substantially uniformly or non-uniformly dispersed in the hole transport region (for example, in the form of a single layer consisting of a charge-generation material).

The charge-generation material may be, for example, a p-dopant.

In an embodiment, a lowest unoccupied molecular orbital (LUMO) energy level of the p-dopant may be equal to or less than −3.5 eV.

In an embodiment, the p-dopant may include a quinone derivative, a cyano group-containing compound, a compound containing an element EL1 and an element EL2, or any combination thereof.

Non-limiting examples of the quinone derivative include TCNQ and/or F4-TCNQ.

Non-limiting examples of the cyano group-containing compound include HAT-CN and/or a compound represented by Formula 221:

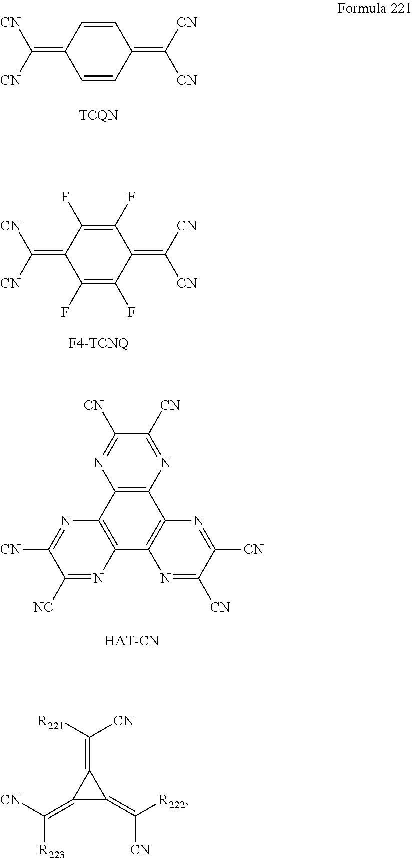

wherein, in Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and

at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

Regarding the compound containing element EL1 and element EL2, element EL1 may be a metal, a metalloid, or a combination thereof, and element EL2 may be a non-metal, a metalloid, or a combination thereof.

Non-limiting examples of the metal include an alkali metal (for example, lithium (Li), sodium (Na), potassium (K), rubidium (Rb), cesium (Cs), and/or the like); alkaline earth metal (for example, beryllium (Be), magnesium (Mg), calcium (Ca), strontium (Sr), barium (Ba), and/or the like); transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metals (for example, zinc (Zn), indium (In), tin (Sn), and/or the like); and/or lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Non-limiting examples of the metalloid include silicon (Si), antimony (Sb), and/or tellurium (Te).

Non-limiting examples of the non-metal include oxygen (O) and/or halogen (for example, F, Cl, Br, I, etc.).

Non-limiting examples of the compound containing element EL1 and element EL2 include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), and/or a metal telluride.

Non-limiting examples of the metal oxide include a tungsten oxide (for example, WO, W₂O₃, WO₂, WO₃, and/or W₂O₅), a vanadium oxide (for example, VO, V₂O₃, VO₂, and/or V₂O₅), a molybdenum oxide (MoO, Mo₂O₃, MoO₂, MoO₃, and/or Mo₂O₅), and/or a rhenium oxide (for example, ReO₃).

Non-limiting examples of the metal halide include an alkali metal halide, an alkaline earth metal halide, a transition metal halide, a post-transition metal halide, and/or a lanthanide metal halide.

Non-limiting examples of the alkali metal halide include LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Non-limiting examples of the alkaline earth metal halide include BeF₂, MgF₂, CaF₂, SrF₂, BaF₂, BeCl₂, MgCl₂, CaCl₂), SrCl₂, BaCI₂, BeBr₂, MgBr₂, CaBr₂, SrBr₂, BaBr₂, BeI₂, MgI₂, CaI₂, SrI₂, and/or BaI₂.

Non-limiting examples of the transition metal halide include a titanium halide (for example, TiF₄, TiCl₄, TiBr₄, and/or TiI₄), a zirconium halide (for example, ZrF₄, ZrCl₄, ZrBr₄, and/or ZrI₄), a hafnium halide (for example, HfF₄, HfCl₄, HfBr₄, and/or Hfl₄), a vanadium halide (for example, VF₃, VCl₃, VBr₃, and/or VI₃), a niobium halide (for example, NbF₃, NbCl₃, NbBr₃, and/or NbI₃), a tantalum halide (for example, TaF₃, TaCl₃, TaBr₃, and/or TaI₃), a chromium halide (for example, CrF₃, CrCl₃, CrBr₃, and/or CrI₃), a molybdenum halide (for example, MoF₃, MoCl₃, MoBr₃, and/or MoI₃), a tungsten halide (for example, WF₃, WCl₃, WBr₃, and/or WI₃), a manganese halide (for example, MnF₂, MnCl₂, MnBr₂, and/or MnI₂), a technetium halide (for example, TcF₂, TcCl₂, TcBr₂, and/or TcI₂), a rhenium halide (for example, ReF₂, ReCl₂, ReBr₂, and/or ReI₂), an iron halide (for example, FeF₂, FeCl₂, FeBr₂, and/or FeI₂), a ruthenium halide (for example, RuF₂, RuCl₂, RuBr₂, and/or RuI₂), an osmium halide (for example, OsF₂, OsCl₂, OsBr₂, and/or OsI₂), a cobalt halide (for example, CoF₂, CoCl₂, CoBr₂, and/or CoI₂), a rhodium halide (for example, RhF₂, RhCl₂, RhBr₂, and/or RhI₂), an iridium halide (for example, IrF₂, IrCl₂, IrBr₂, and/or IrI₂), a nickel halide (for example, NiF₂, NiCl₂, NiBr₂, and/or NiI₂), a palladium halide (for example, PdF₂, PdCl₂, PdBr₂, and/or PdI₂), a platinum halide (for example, PtF₂, PtCl₂, PtBr₂, and/or PtI₂), a copper halide (for example, CuF, CuCl, CuBr, and/or CuI), a silver halide (for example, AgF, AgCl, AgBr, and/or AgI), and/or a gold halide (for example, AuF, AuCl, AuBr, and/or AuI).

Non-limiting examples of the post-transition metal halide include a zinc halide (for example, ZnF₂, ZnCl₂, ZnBr₂, and/or ZnI₂), an indium halide (for example, InI₃), and/or a tin halide (for example, SnI₂).

Non-limiting examples of the lanthanide metal halide include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, and/or SmI₃.

Non-limiting examples of the metalloid halide include an antimony halide (for example, SbCl₅).

Non-limiting examples of the metal telluride include an alkali metal telluride (for example, Li₂Te, Na₂Te, K₂Te, Rb₂Te, and/or Cs₂Te), an alkaline earth metal telluride (for example, BeTe, MgTe, CaTe, SrTe, and/or BaTe), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, and/or Au₂Te), a post-transition metal telluride (for example, ZnTe), and/or a lanthanide metal telluride (for example, LaTe, CeTe, PrTe, NdTe, PmTe, EuTe, GdTe, TbTe, DyTe, HoTe, ErTe, TmTe, YbTe, and/or LuTe).

### Emission Layer in Interlayer 130

In an embodiment, when the light-emitting device 10 is a full-color light-emitting device, the emission layer may be patterned into a red emission layer, a green emission layer, and/or a blue emission layer, according to a subpixel. In one or more embodiments, the emission layer may have a stacked structure of two or more layers selected from a red emission layer, a green emission layer, and a blue emission layer, where the two or more layers may contact each other or may be separated from each other. In one or more embodiments, the emission layer may include two or more materials selected from a red light-emitting material, a green light-emitting material, and a blue light-emitting material, in which the two or more materials may be mixed with each other in a single (e.g., the same) layer to emit white light.

The emission layer may include a host and a dopant. The dopant may include a phosphorescent dopant, a fluorescent dopant, or any combination thereof.

An amount of the dopant in the emission layer may be in a range of about 0.01 parts by weight to about 15 parts by weight based on 100 parts by weight of the host.

In one or more embodiments, the emission layer may include a quantum dot.

In some embodiments, the emission layer may include a delayed fluorescence material. The delayed fluorescence material may act as a host or a dopant in the emission layer.

A thickness of the emission layer may be in the range of about 100 Å to about 1,000 Å, for example, about 200 Å to about 600 Å. When the thickness of the emission layer is within the ranges described above, excellent luminescence characteristics may be exhibited without a substantial increase in driving voltage.

### Host

In an embodiment, the host may include a compound represented by Formula 301:

[Ar₃₀₁]_{xb11}-[(L₃₀₁)_{xb1}-R₃₀₁]_{xb21}, Formula 301

wherein, in Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb11 may be 1, 2, or 3,

xb1 may be an integer from 0 to 5,

R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer from 1 to 5, and

Q₃₀₁ to Q₃₀₃ may each independently be the same as described in connection with Q₁.

In one or more embodiments, when xb11 in Formula 301 is 2 or more, two or more of Ar₃₀₁(s) may be linked to each other via a single bond.

In one or more embodiments, the host may include a compound represented by Formula 301-1, a compound represented by Formula 301-2, or any combination thereof:

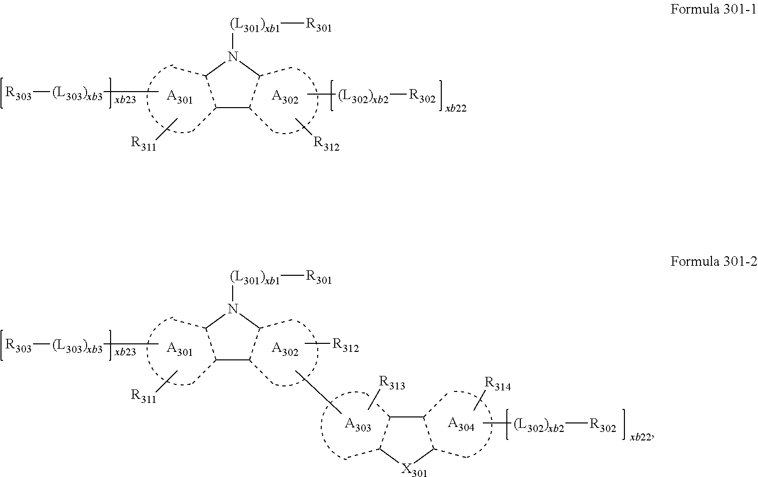

wherein, in Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N-[(L₃₀₄)_{xb4}-R₃₀₄], C(R₃₀₄)(R₃₀₅), or Si(R₃₀₄)(R₃₀₅),

xb22 and xb23 may each independently be 0, 1, or 2,

L₃₀₁, xb1, and R₃₀₁ may each independently be the same as described above,

L₃₀₂ to L₃₀₄ may each independently be the same as described in connection with L₃₀₁,

xb2 to xb4 may each independently be the same as described in connection with xb1, and

R₃₀₂ to R₃₀₅ and R₃₁₁ to R₃₁₄ may each independently be the same as described in connection with R₃₀₁.

In one or more embodiments, the host may include an alkaline earth metal complex, a post-transition metal complex, or any combination thereof. In one or more embodiments, the host may include a Be complex (for example, Compound H55) or a Mg complex. In some embodiments, the host may include a Zn complex, or any combination of the above.

In one or more embodiments, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

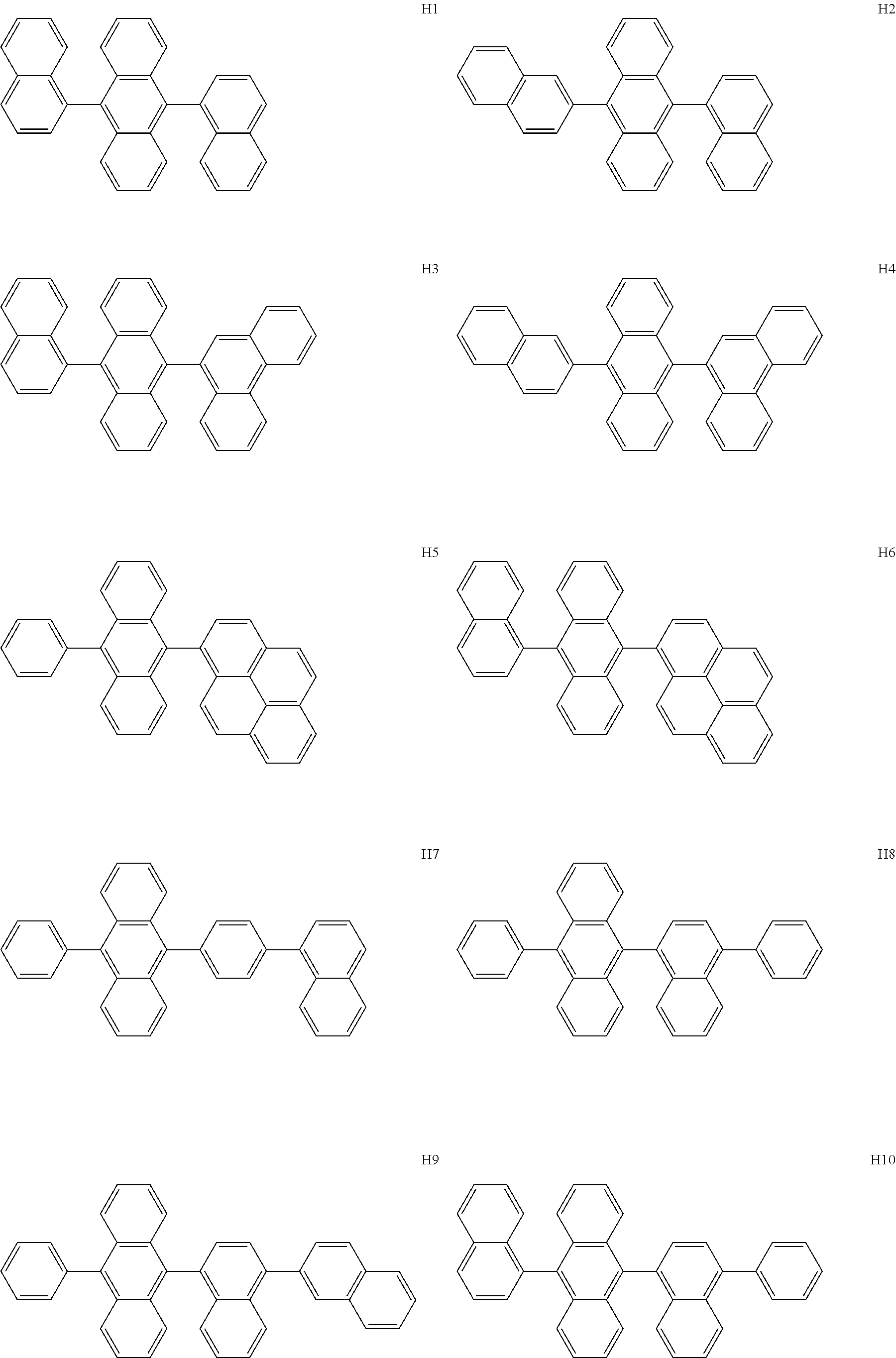

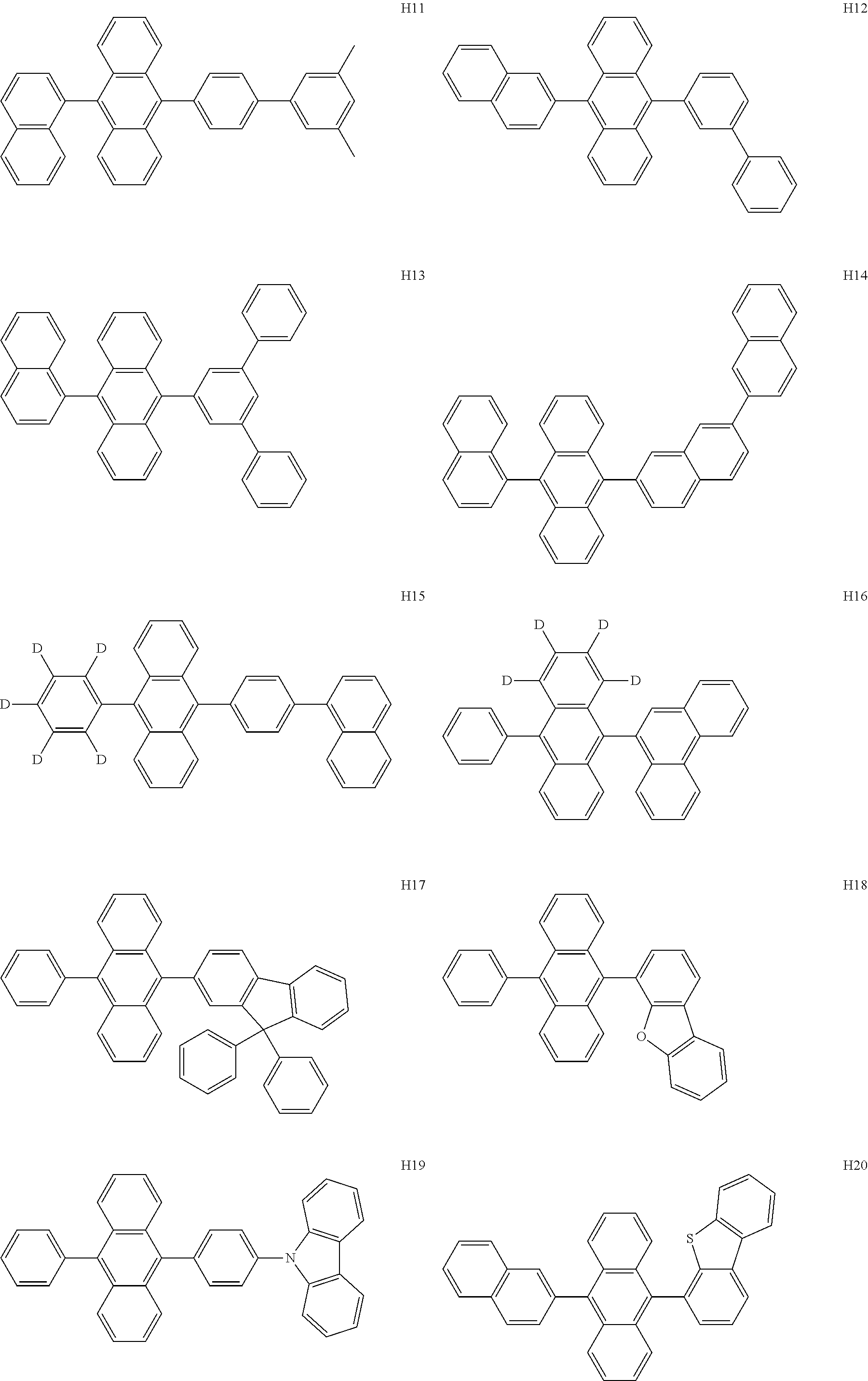

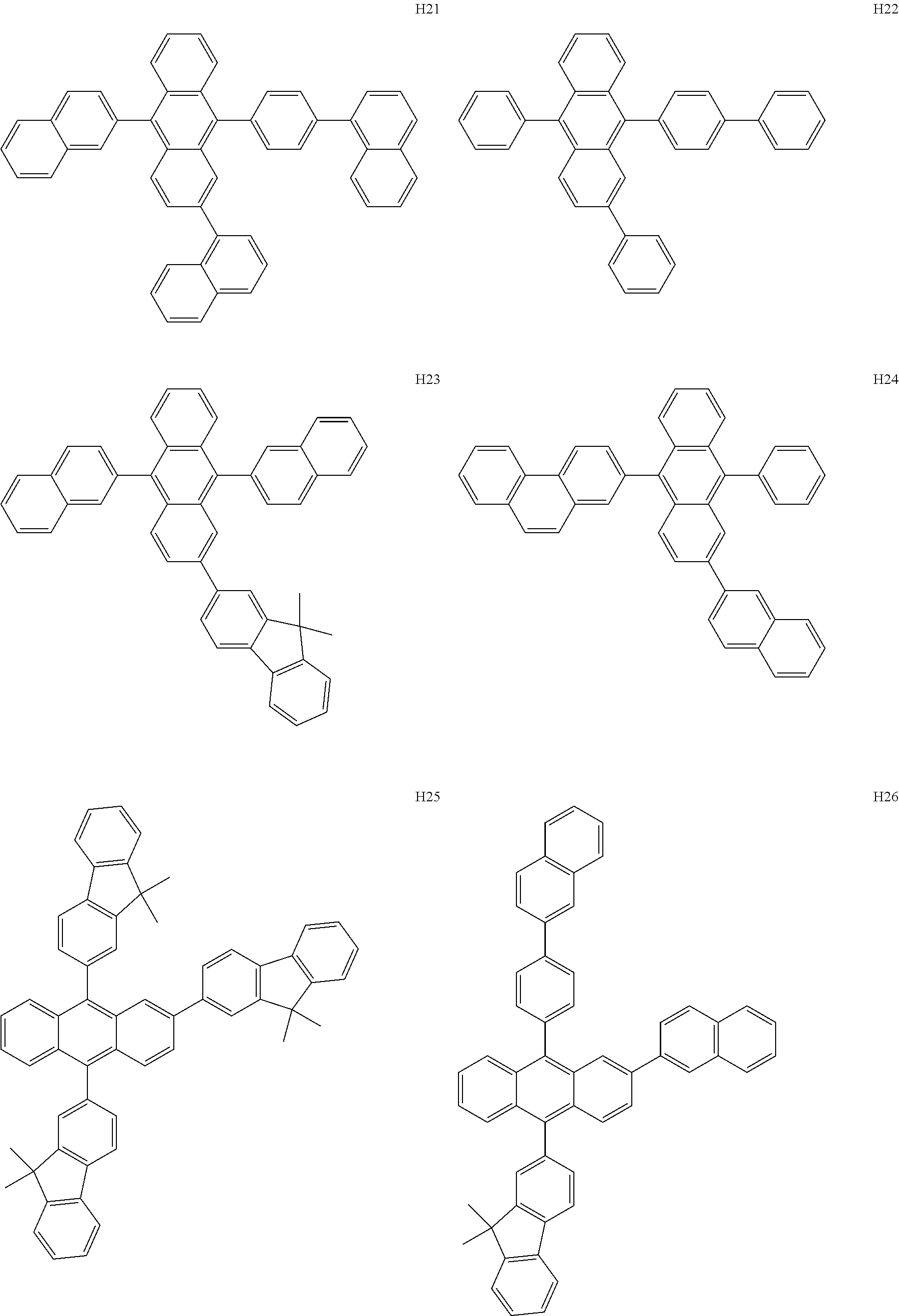

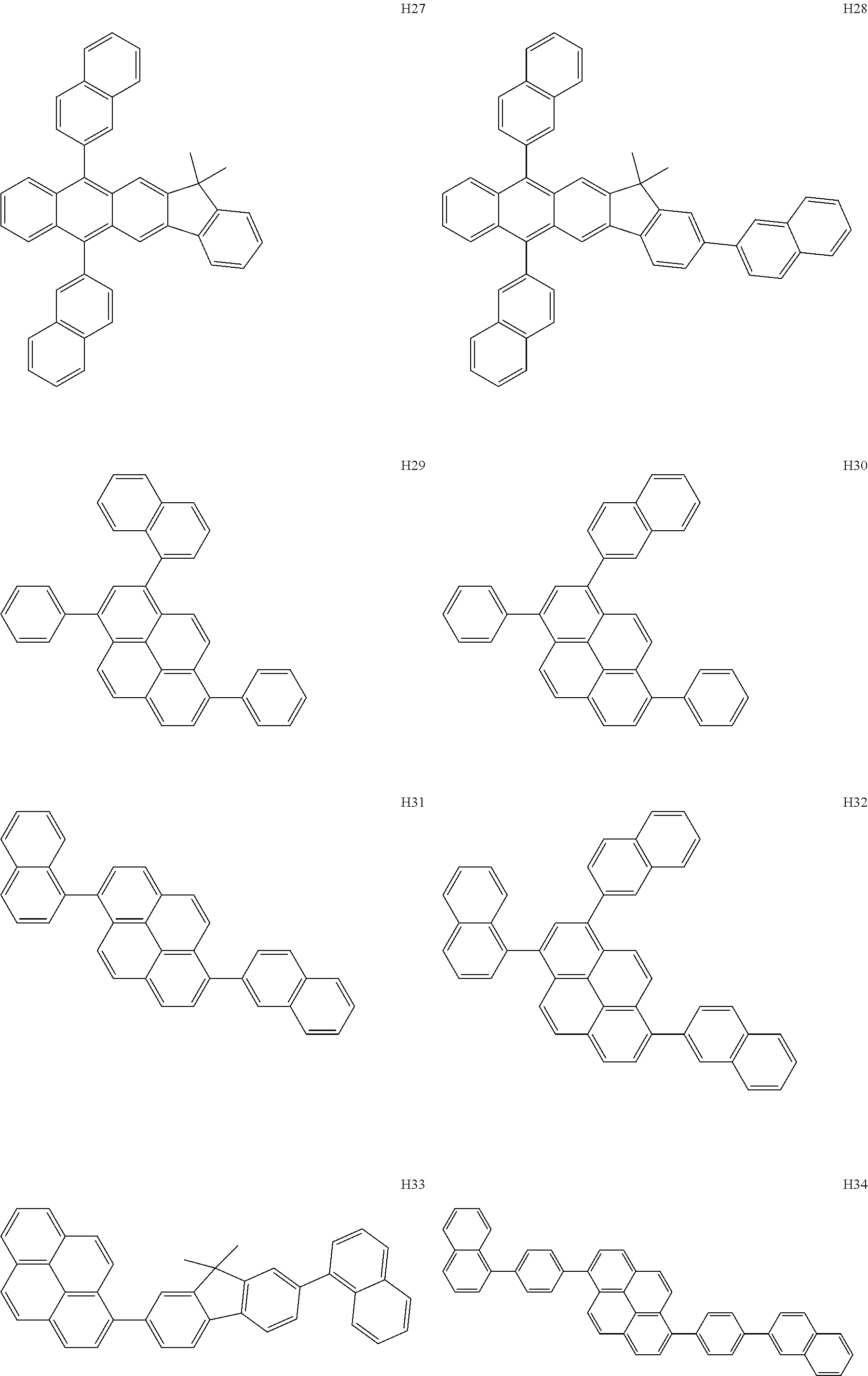

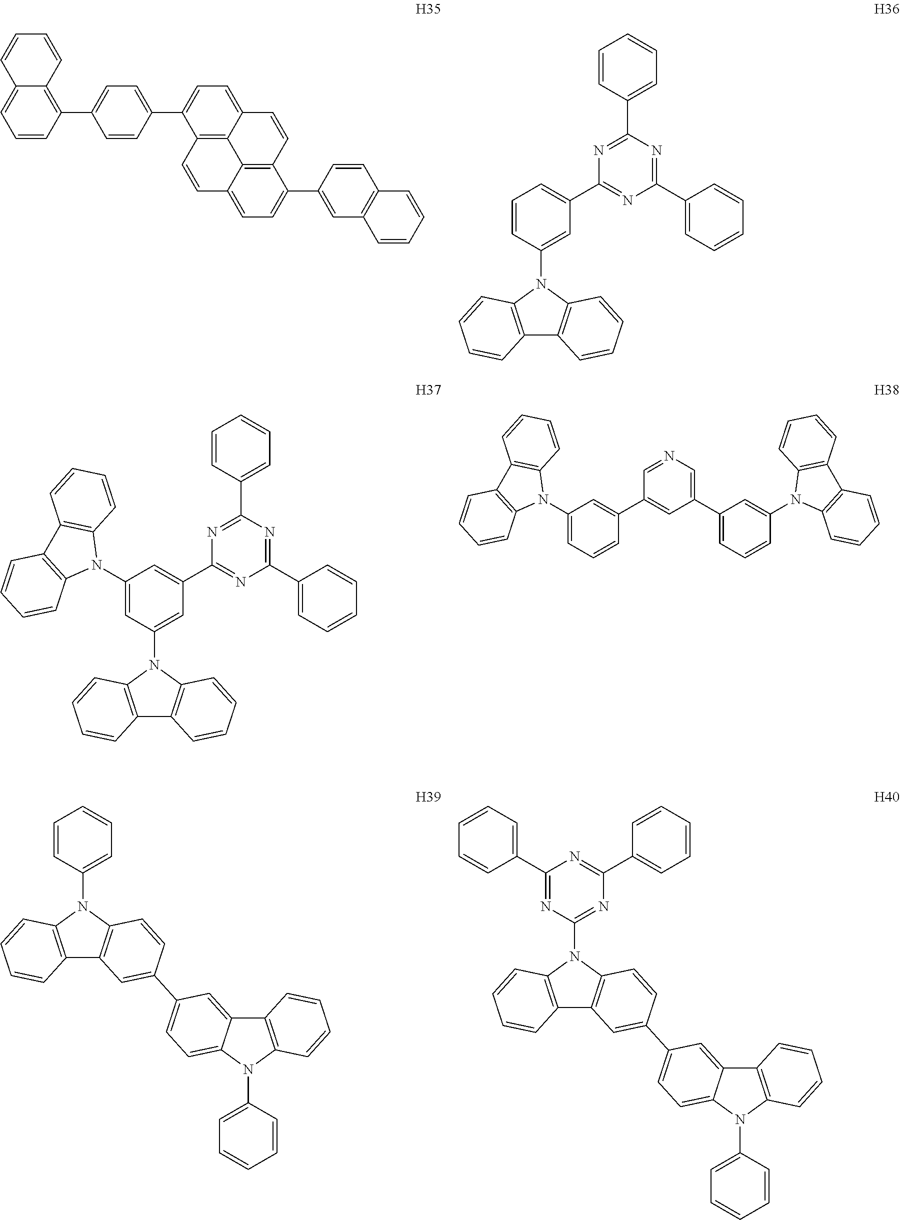

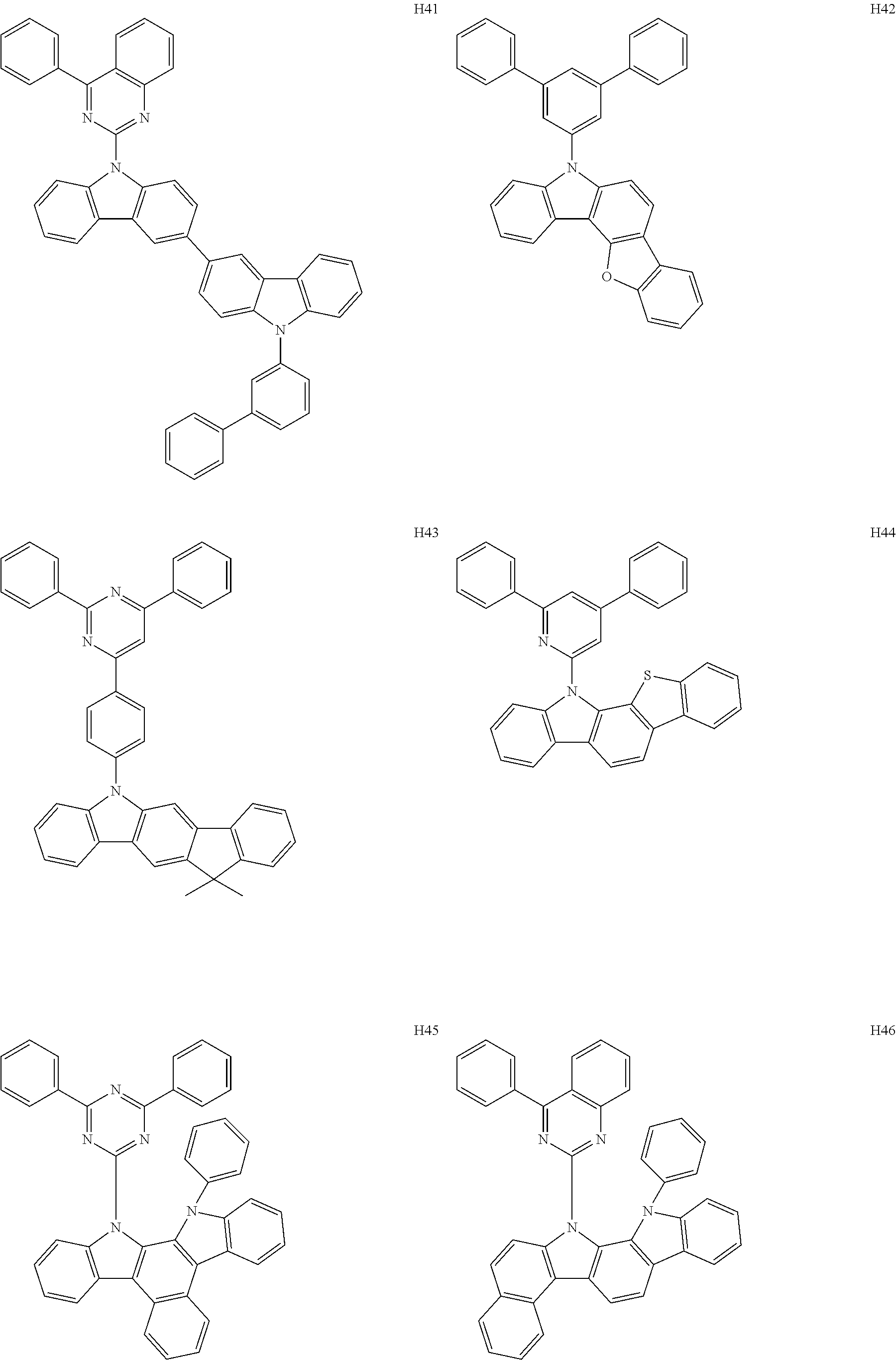 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

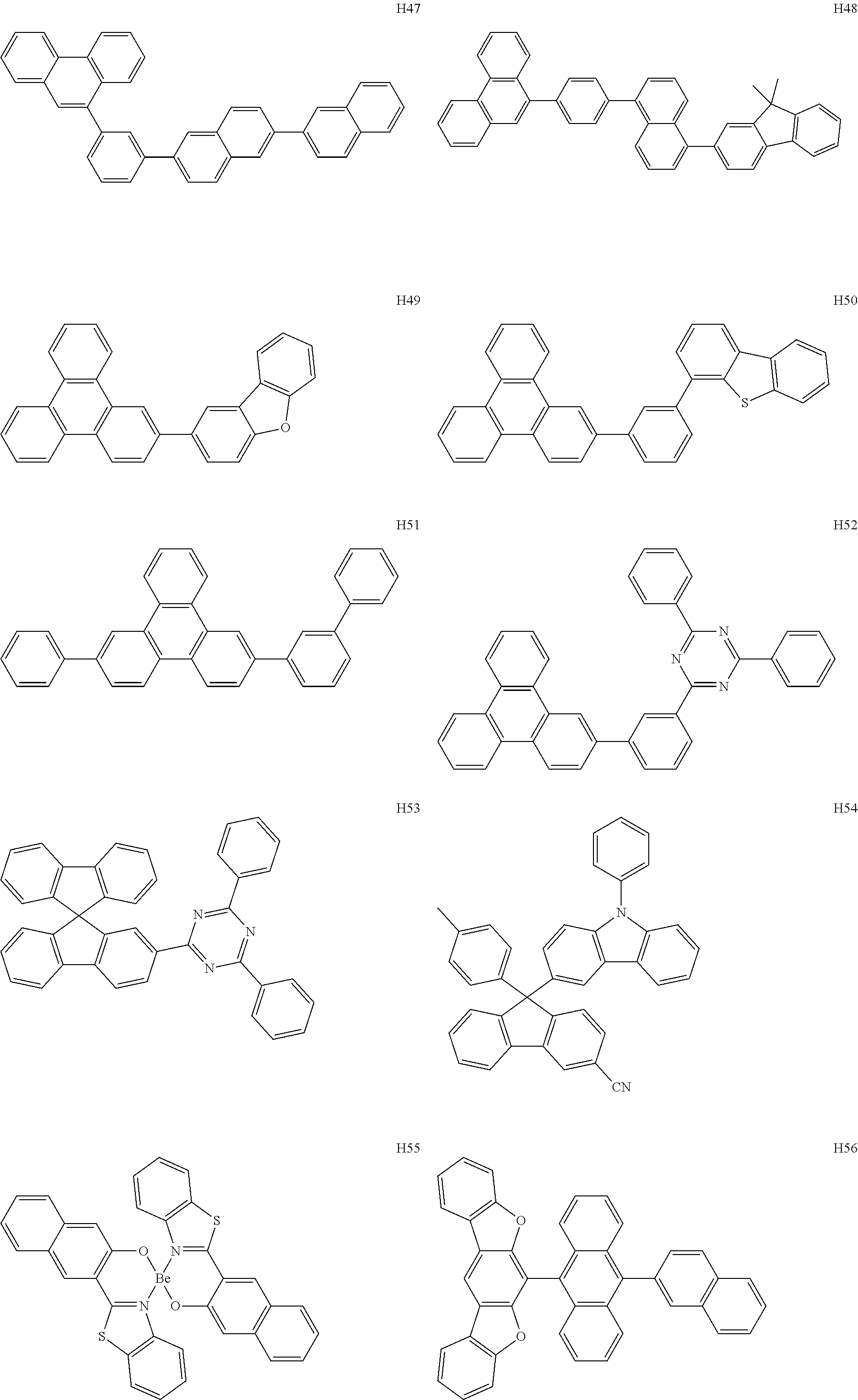

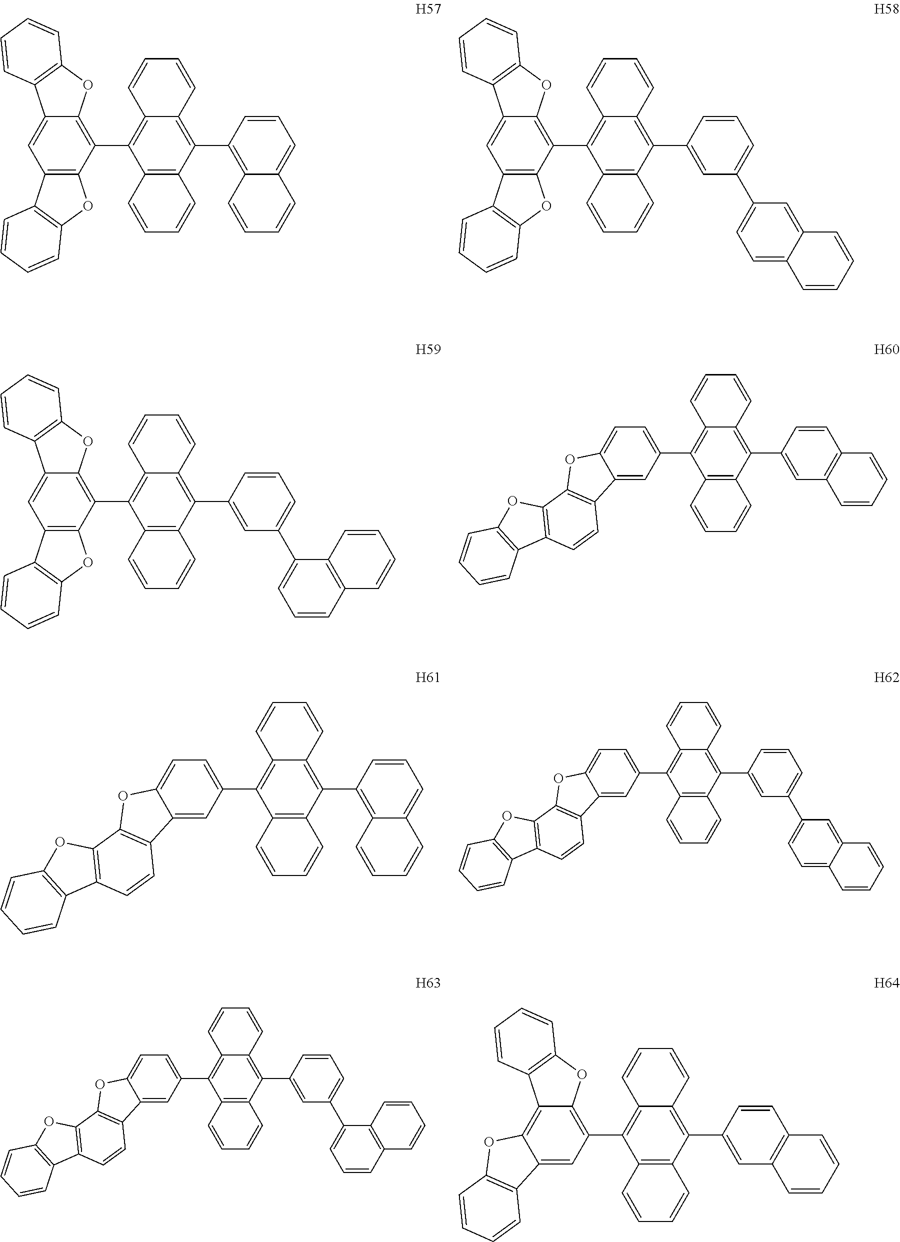

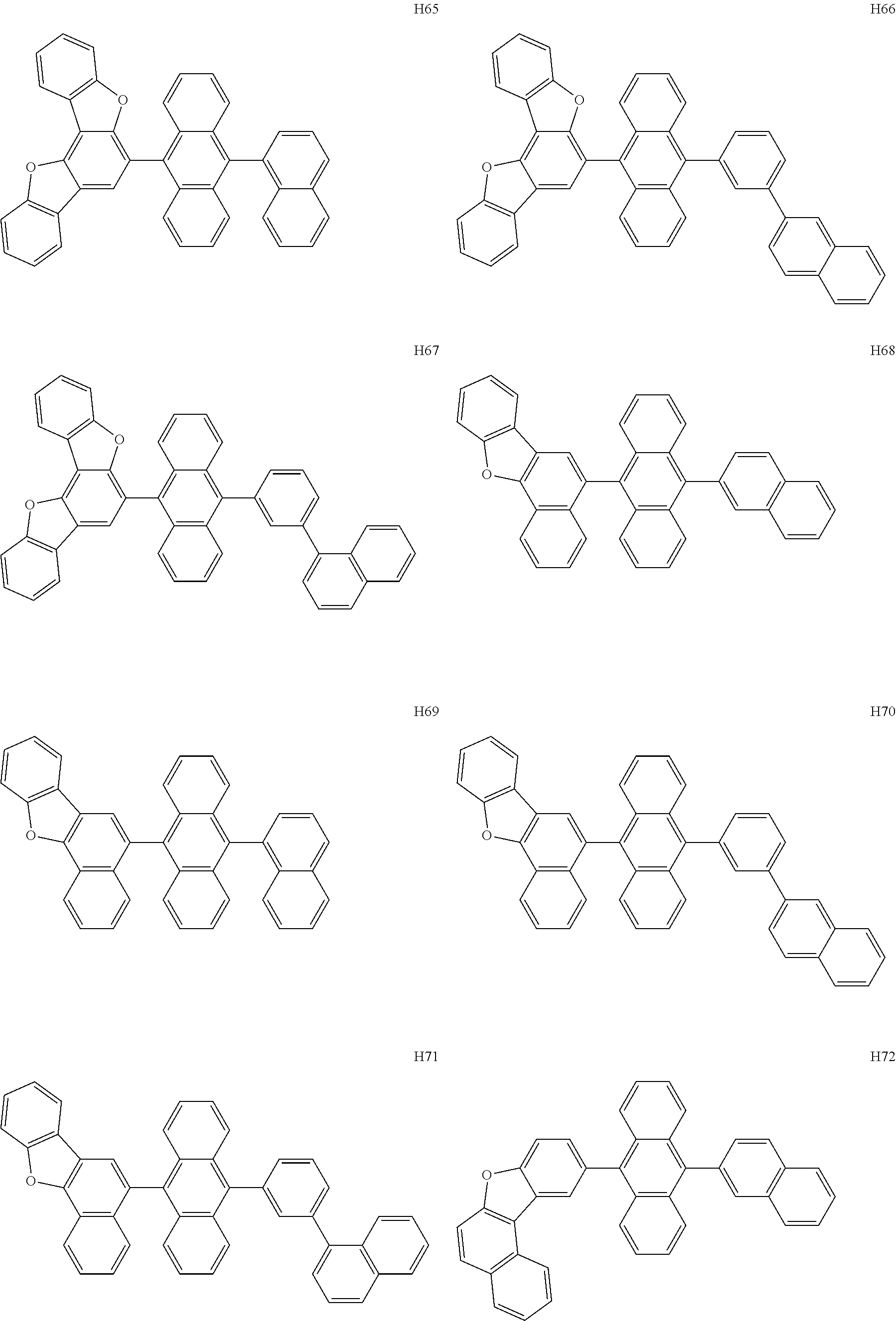

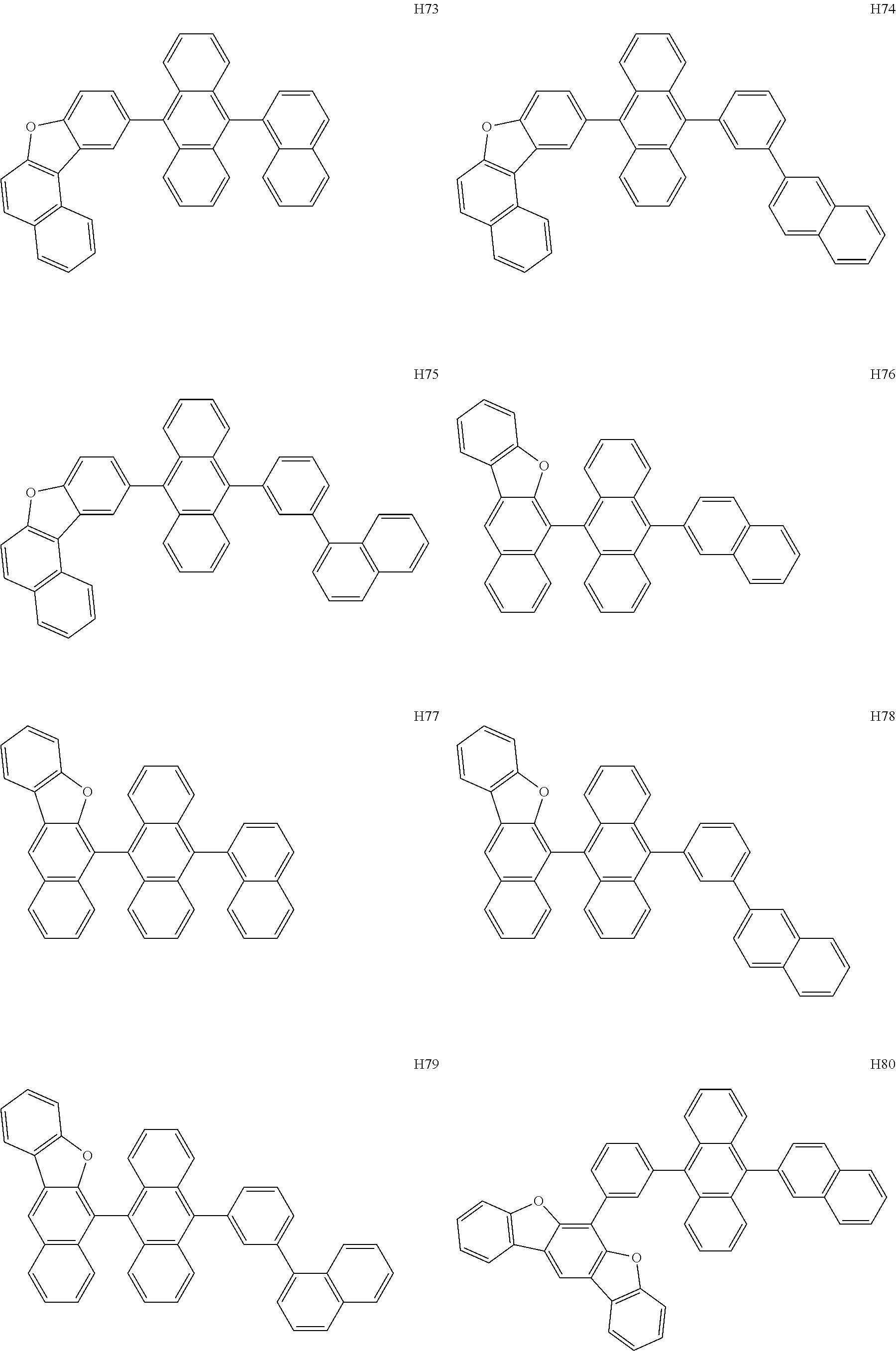

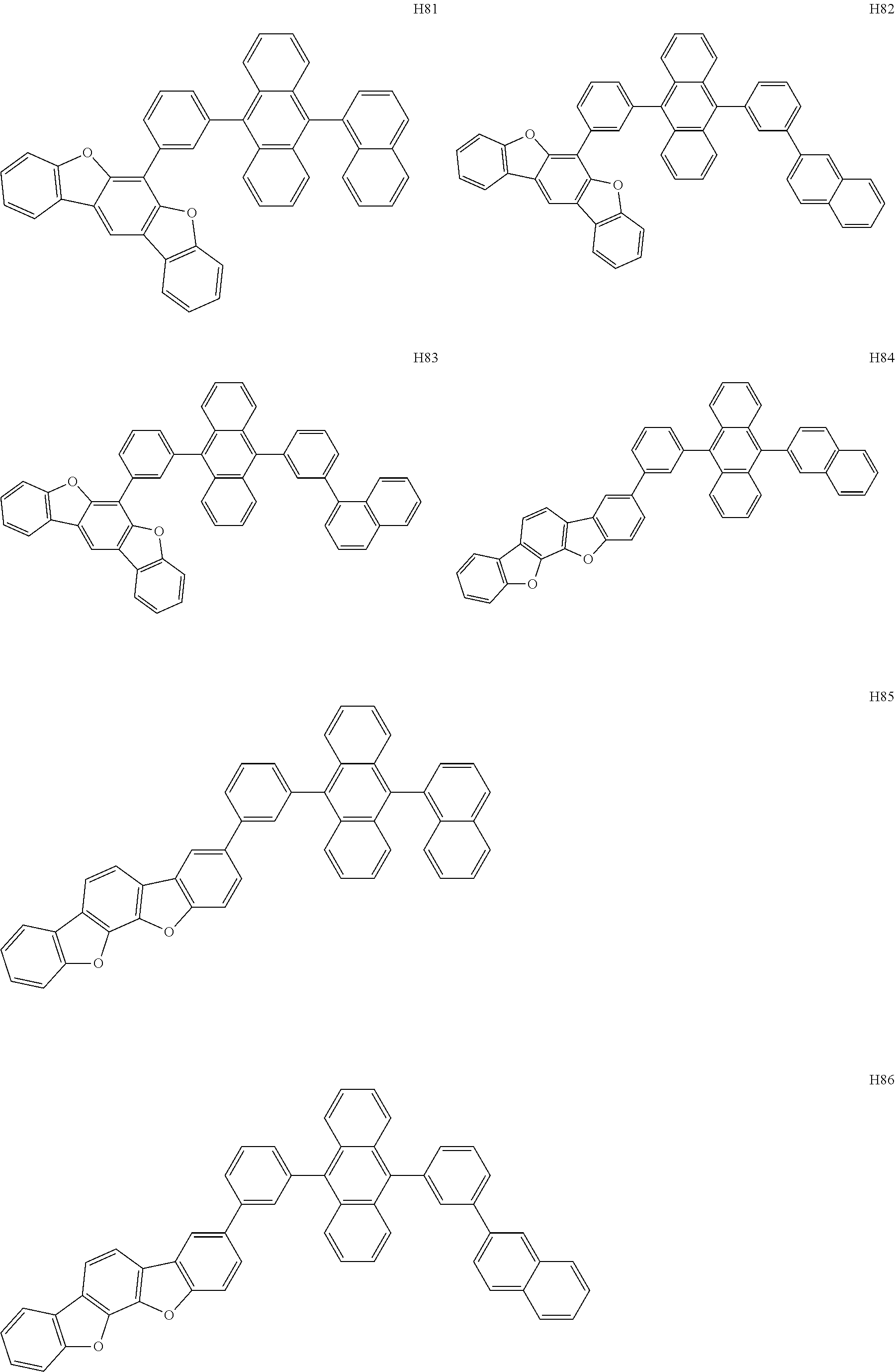

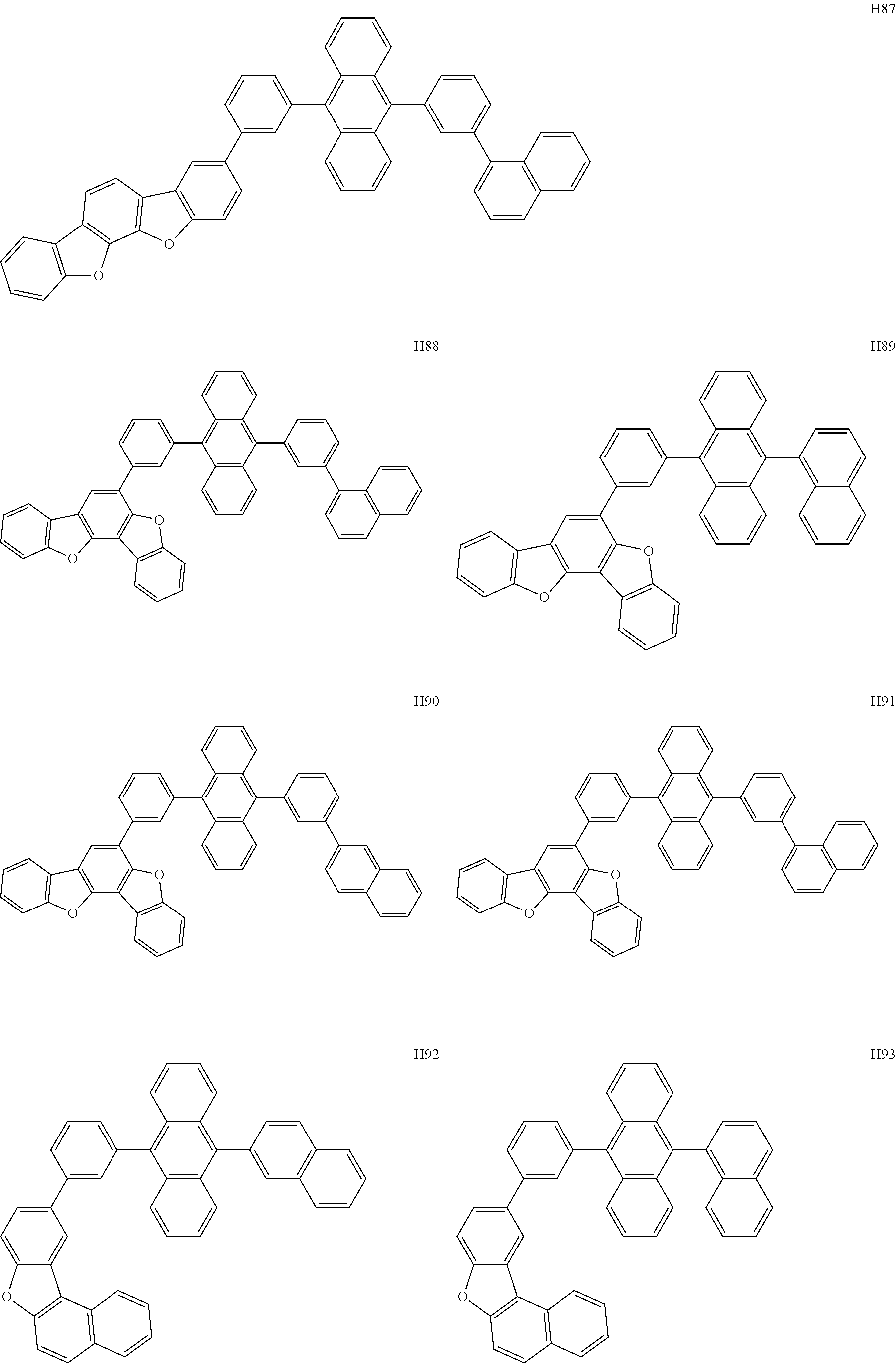

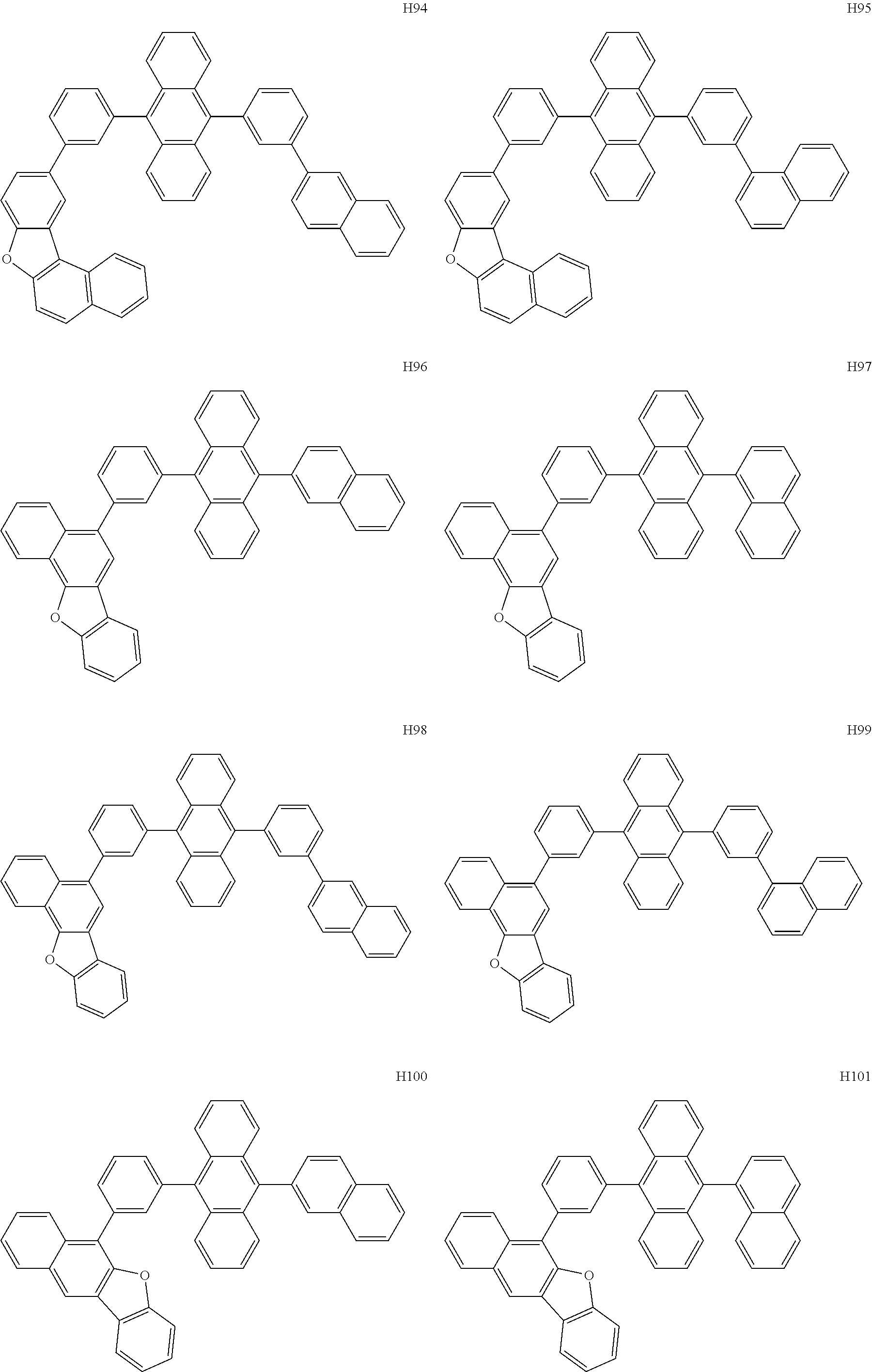

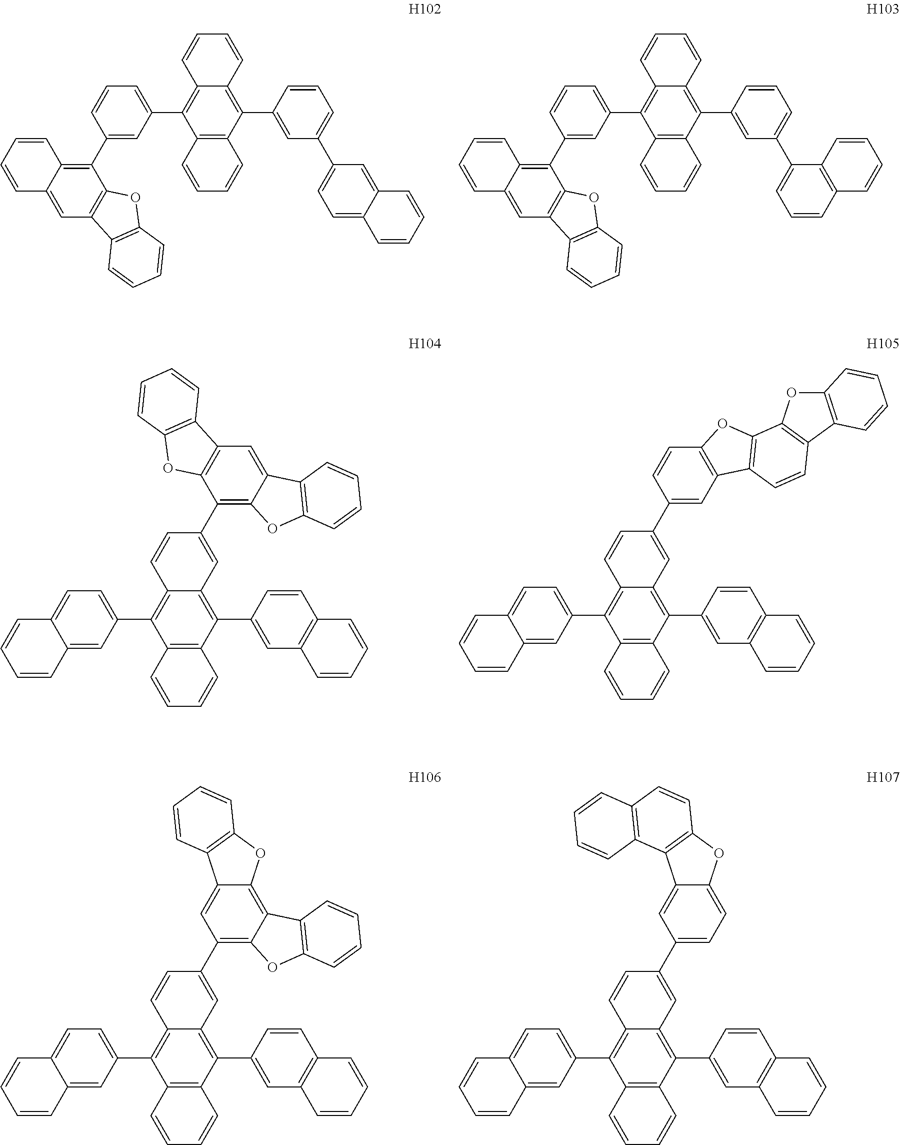

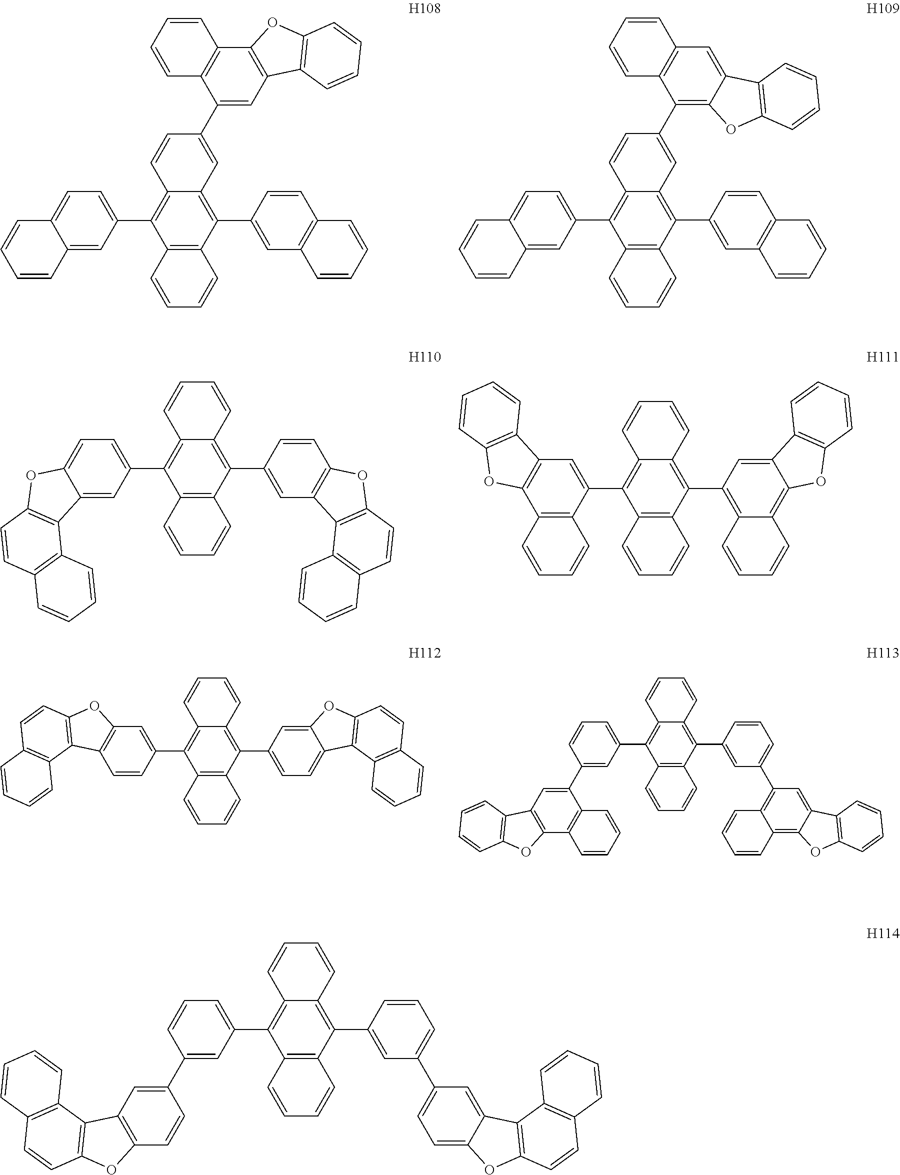

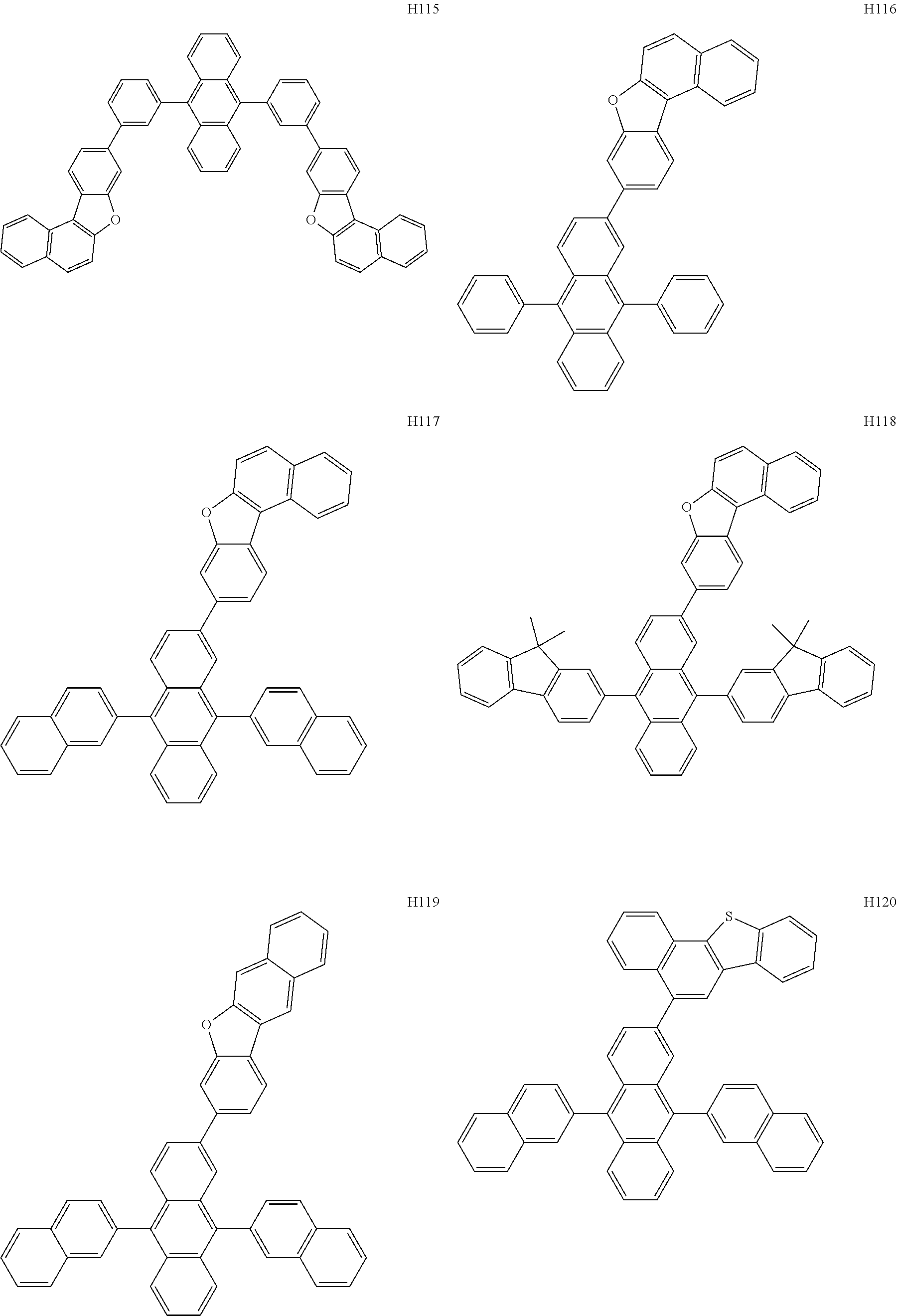

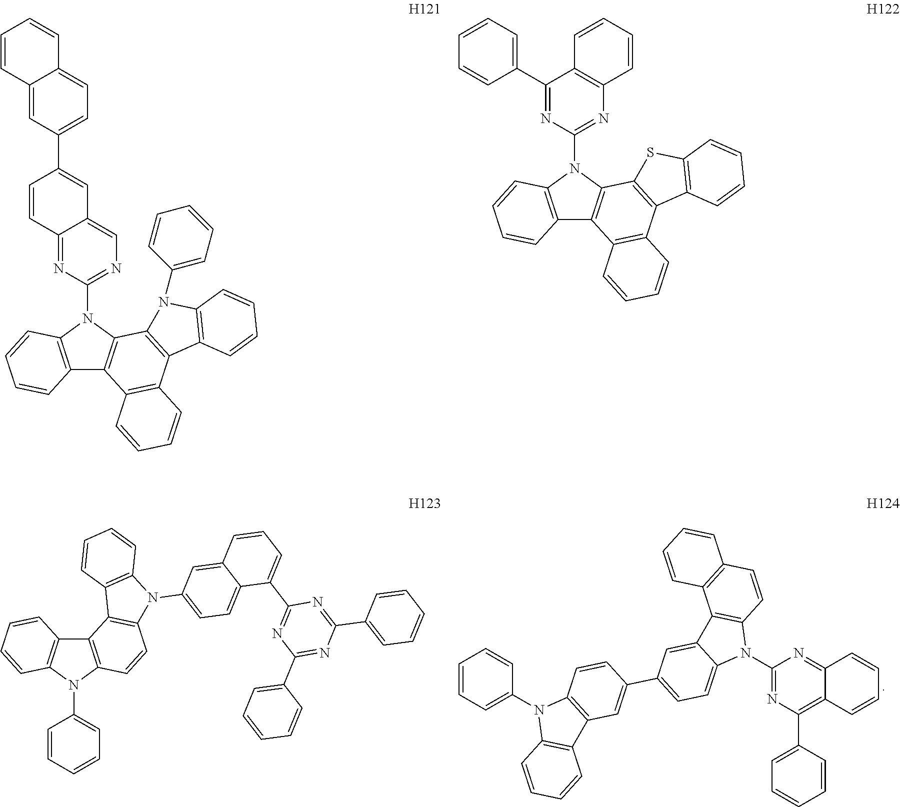 [SMILES: c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

### Phosphorescent Dopant

The emission layer may include, as a phosphorescent dopant, the organometallic compound represented by Formula 1-1 or 1-2.

### Fluorescent Dopant

The fluorescent dopant may include an amine group-containing compound, a styryl group-containing compound, or any combination thereof.

In an embodiment, the fluorescent dopant may include a compound represented by Formula 501:

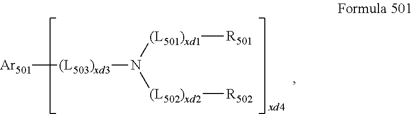

wherein, in Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

In an embodiment, Ar₅₀₁ in Formula 501 may be a condensed cyclic group (for example, an anthracene group, a chrysene group, or a pyrene group) in which three or more monocyclic groups are condensed together.

In one or more embodiments, xd4 in Formula 501 may be 2.

For example, the fluorescent dopant may include: one of Compounds FD1 to FD36; DPVBi; DPAVBi; or any combination thereof:

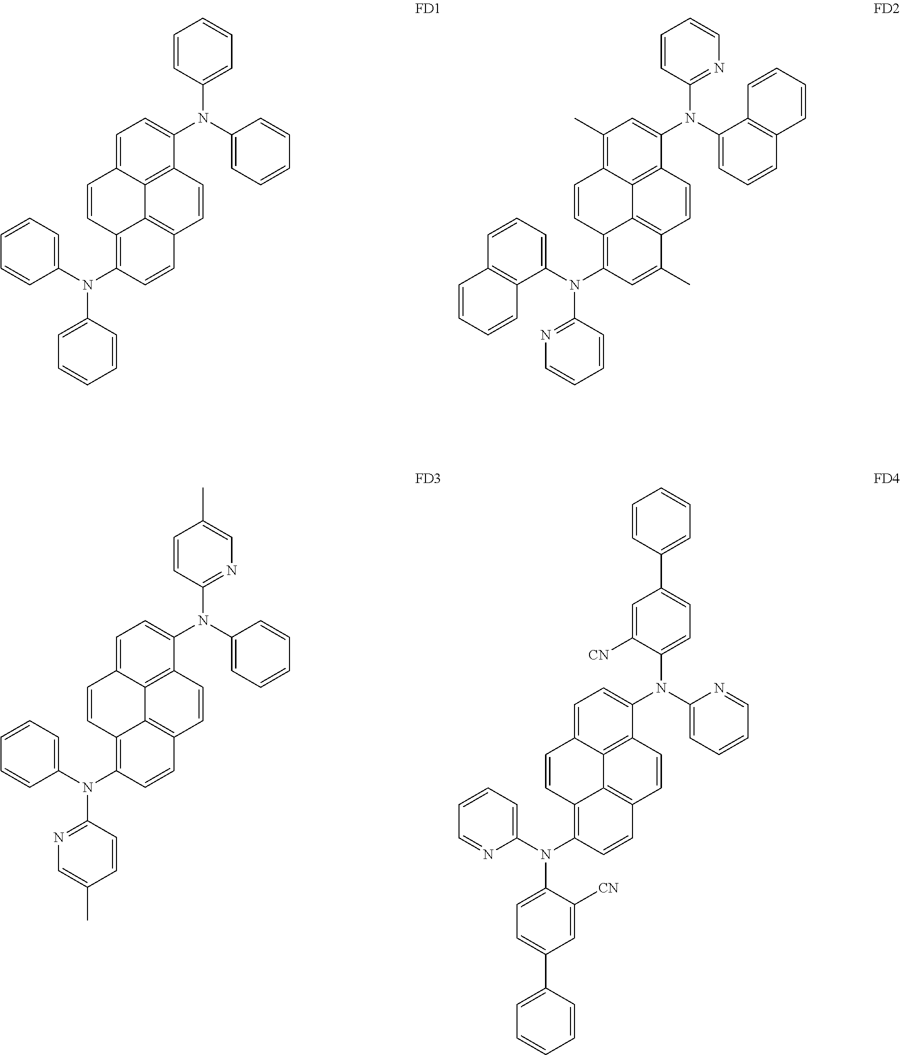

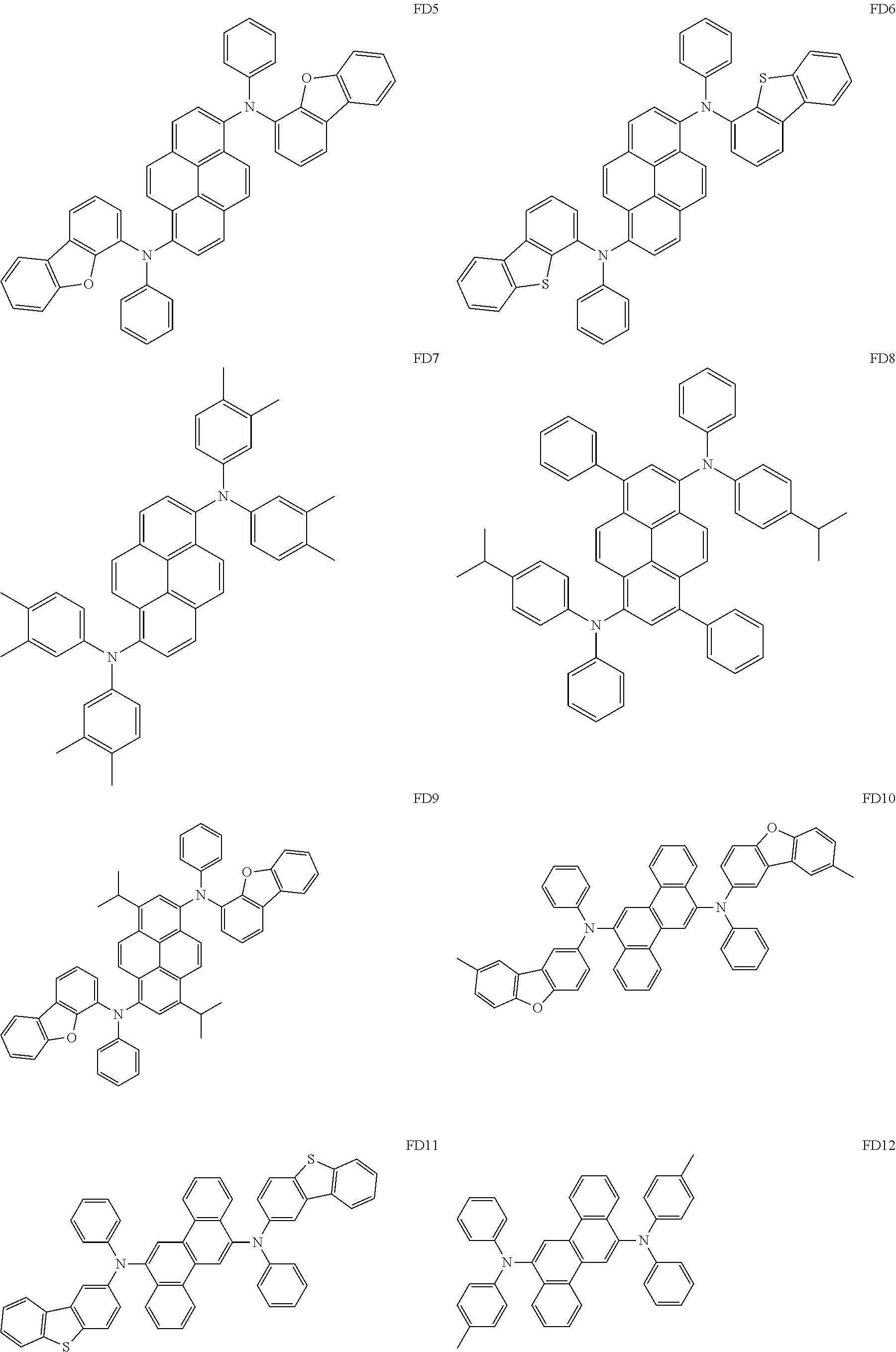

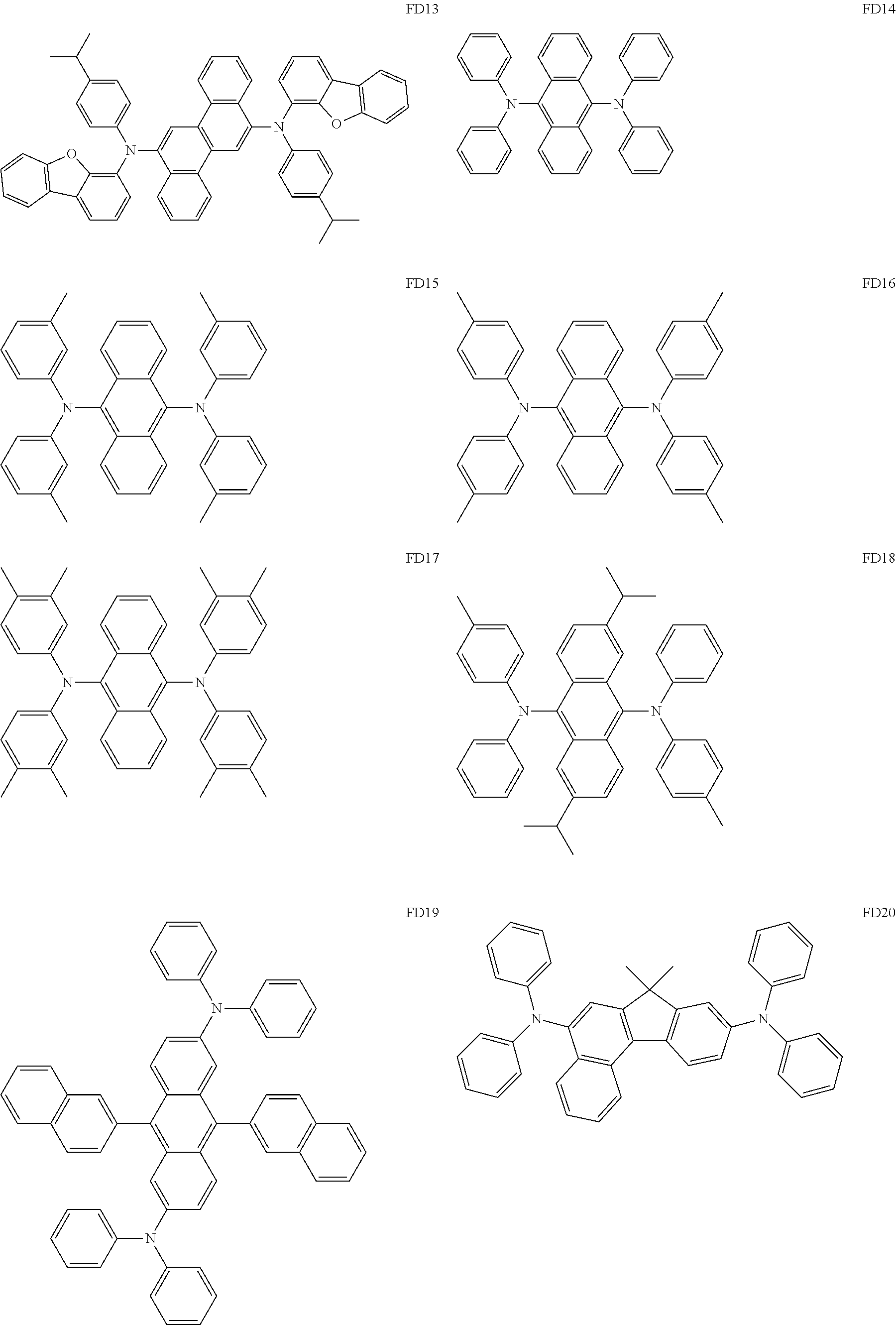

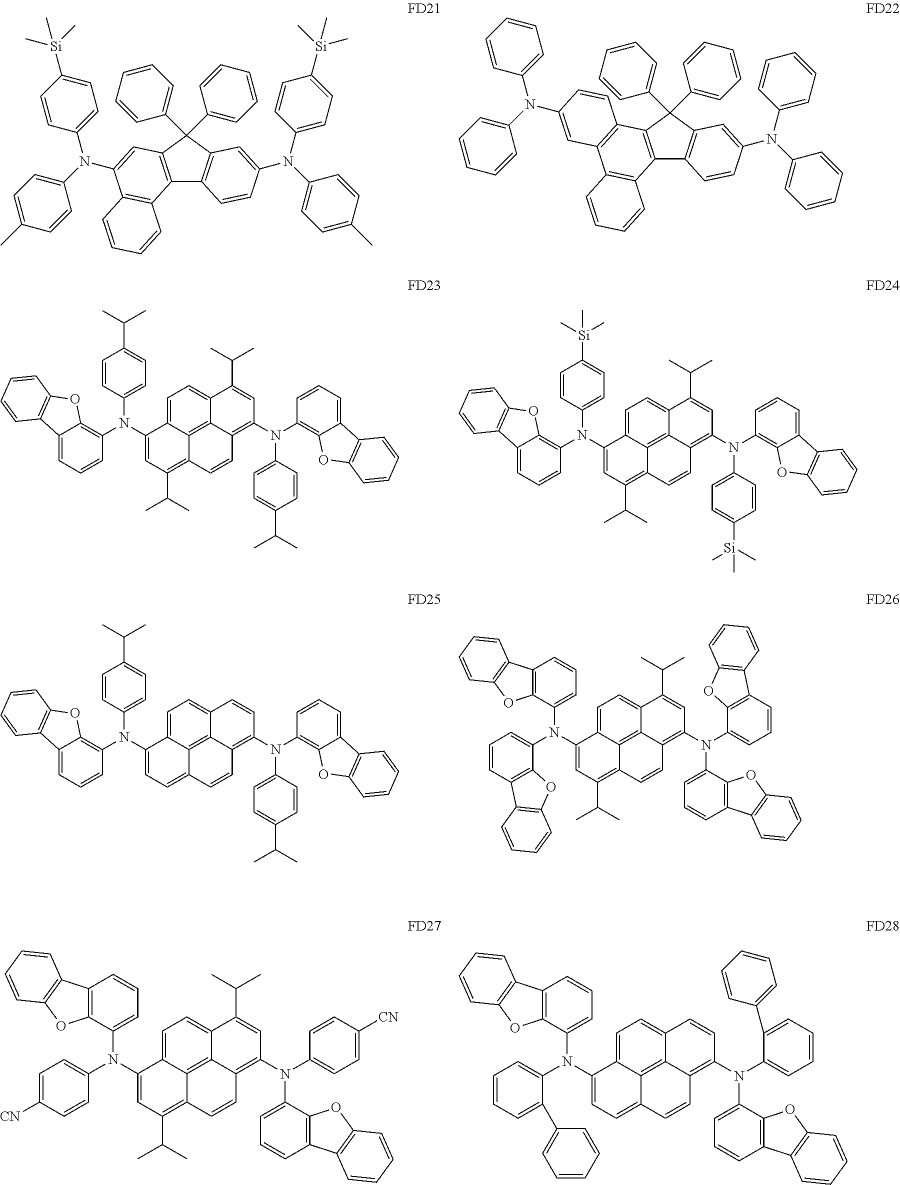

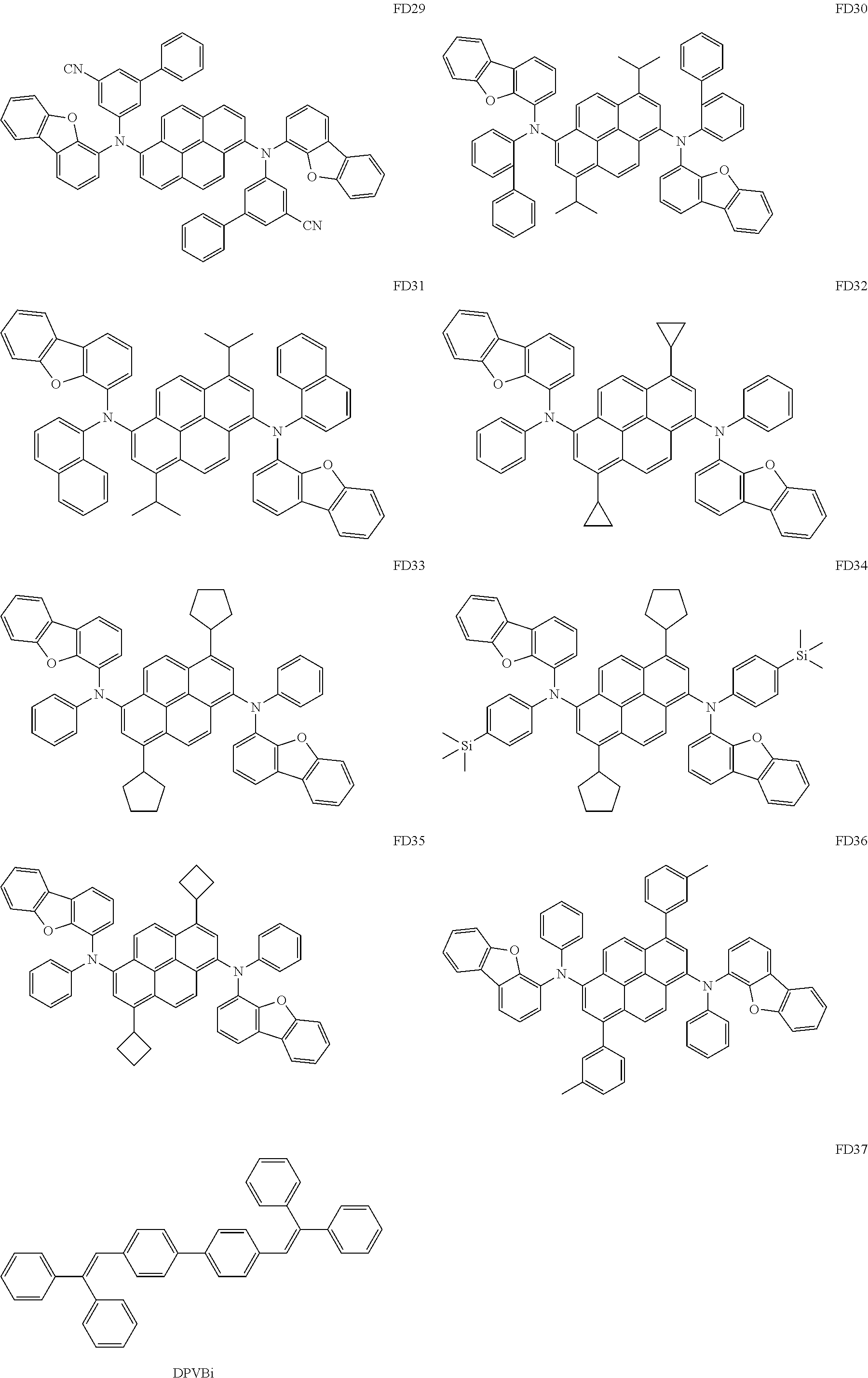

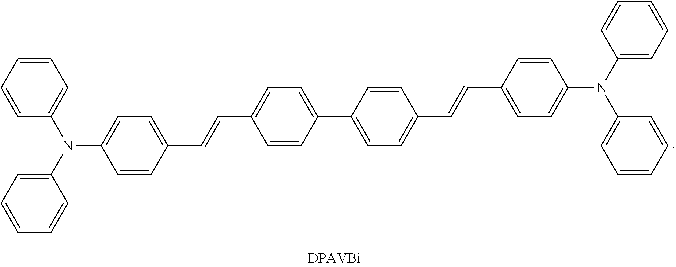 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1]

### Delayed Fluorescence Material

The emission layer may include a delayed fluorescence material.

The delayed fluorescent material may be any compound that is capable of emitting delayed fluorescence based on a delayed fluorescence emission mechanism (e.g., thermally activated delayed fluorescence (TADF)).

The delayed fluorescence material included in the emission layer may act as a host or a dopant depending on the type (kind) of other materials included in the emission layer.

In an embodiment, a difference between a triplet energy level (eV) of the delayed fluorescence material and a singlet energy level (eV) of the delayed fluorescence material may be equal to or greater than 0 eV, and equal to or less than 0.5 eV. When the difference between the triplet energy level (eV) of the delayed fluorescence material and the singlet energy level (eV) of the delayed fluorescence material is within the ranges above, exciton up-conversion from the triplet state to the singlet state of the delayed fluorescence materials may effectively occur, and thus, the luminescence efficiency of the light-emitting device 10 may be improved.

For example, the delayed fluorescence material may include: i) a material that includes at least one electron donor (for example, a π electron-rich C₃-C₆₀ cyclic group, such as a carbazole group) and at least one electron acceptor (for example, a sulfoxide group, a cyano group, and/or a π electron-deficient nitrogen-containing C₁-C₆₀ cyclic group), or ii) a material including a C₈-C₆₀ polycyclic group in which two or more cyclic groups share a boron (B) atom and are condensed with each other.

The delayed fluorescence material may include, for example, at least one of Compounds DF1 to DF9:

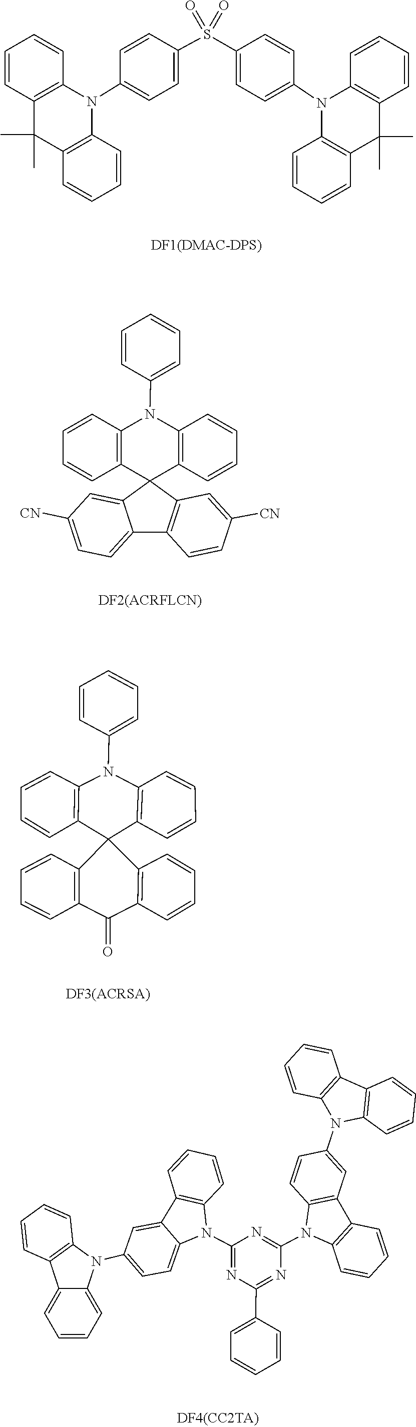

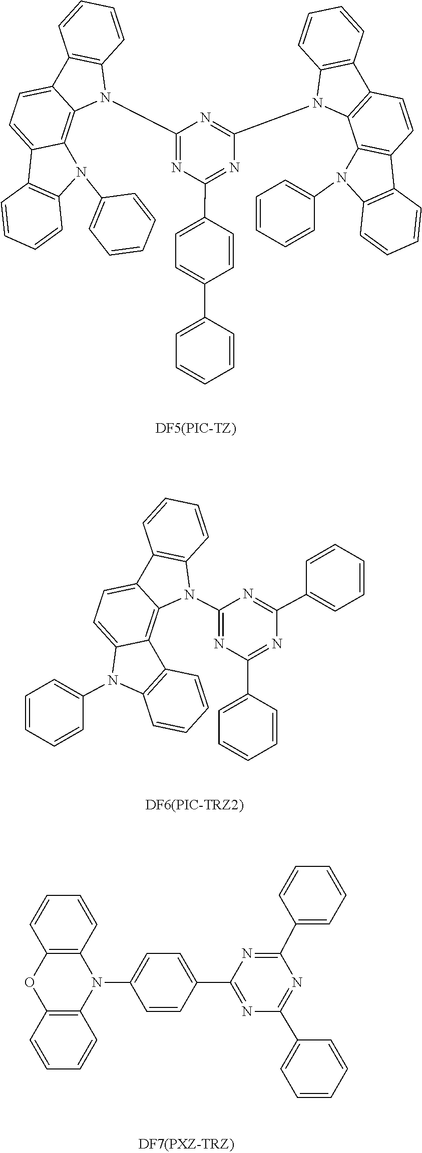 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

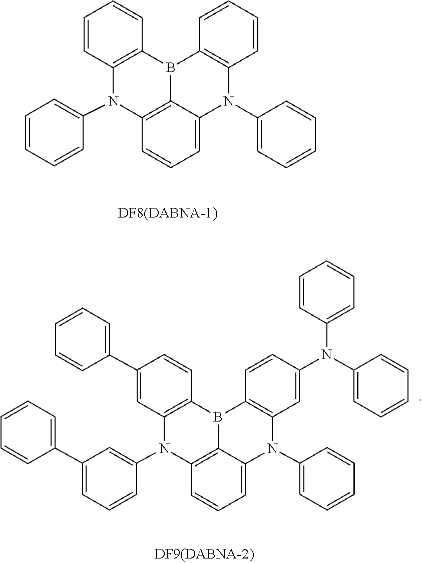 [SMILES: c1ccc(N2c3ccccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

### Quantum Dot

The emission layer may include a quantum dot.

The term “quantum dot” as used herein refers to a crystal of a semiconductor compound, and may include any suitable material that is capable of emitting light of various emission wavelengths depending on the size of the crystal.

A diameter of the quantum dot may be, for example, in a range of about 1 nm to about 10 nm.

The quantum dot may be synthesized by a wet chemical process, an organometallic chemical vapor deposition process, a molecular beam epitaxy process, or any suitable process that is similar to these processes.

The term “wet chemical process” refers to a method in which an organic solvent and a precursor material are mixed, and then, a quantum dot particle crystal is grown. When the crystal grows, the organic solvent acts as a dispersant naturally coordinated on the surface of the quantum dot crystal, and thereby controls the growth of the crystal. Accordingly, by using a process that is easily performed at low costs compared to a vapor deposition process (such as a metal organic chemical vapor deposition (MOCVD) process and/or a molecular beam epitaxy (MBE) process), the growth of quantum dot particles may be controlled.

The quantum dot may include: a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Non-limiting examples of the Group II-VI semiconductor compound include a binary compound (such as CdSe, CdTe, ZnS, ZnSe, ZnTe, ZnO, HgS, HgSe, HgTe, MgSe, and/or MgS); a ternary compound (such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS); and/or a quaternary compound (such as CdZnSeS, CdZnSeTe, CdZnSTe, CdHgSeS, CdHgSeTe, CdHgSTe, HgZnSeS, HgZnSeTe, and/or HgZnSTe).

Non-limiting examples of the Group III-V semiconductor compound include a binary compound (such as GaN, GaP, GaAs, GaSb, AlN, AlP, AlAs, AlSb, InN, InP, InAs, and/or InSb); a ternary compound (such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and/or GaAlNP); and/or a quaternary compound (such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb). In some embodiments, the Group III-V semiconductor compound may further include a Group II element. Non-limiting examples of the Group III-V semiconductor compound further including a Group II element include InZnP, InGaZnP, and/or InAlZnP.

Non-limiting examples of the Group III-VI semiconductor compound include a binary compound (such as GaS, GaSe, Ga₂Se₃, GaTe, InS, InSe, In₂S₃, In₂Se₃, and/or InTe); and/or a ternary compound (such as InGaS₃, and/or InGaSe₃).

Non-limiting examples of the Group I-III-VI semiconductor compound include a ternary compound (such as AgInS, AgInS₂, CuInS, CuInS₂, CuGaO₂, AgGaO₂, and/or AgAlO₂).

Non-limiting examples of the Group IV-VI semiconductor compound include a binary compound (such as SnS, SnSe, SnTe, PbS, PbSe, and/or PbTe); a ternary compound (such as SnSeS, SnSeTe, SnSTe, PbSeS, PbSeTe, PbSTe, SnPbS, SnPbSe, and/or SnPbTe); and/or a quaternary compound (such as SnPbSSe, SnPbSeTe, and/or SnPbSTe).

Non-limiting examples of the Group IV element or compound include a single element compound (such as Si and/or Ge); and/or a binary compound (such as SiC and/or SiGe).

Each element included in the multi-element compound (e.g., the binary compound, the ternary compound, or the quaternary compound) may be present at a substantially uniform concentration or a non-uniform concentration in the quantum dot particle.

In some embodiments, the quantum dot may have a single structure having a substantially uniform concentration of each element throughout the quantum dot, or a dual structure of a core-shell. For example, the material included in the core may be different from the material included in the shell.

In some embodiments, the shell of the quantum dot may function as a protective layer for maintaining semiconductor characteristics by preventing or reducing chemical degeneration of the core, and/or may function as a charging layer for imparting electrophoretic characteristics to the quantum dot. The shell may be a single layer or a multilayer structure. An interface between the core and the shell may have (e.g., include) a concentration gradient, in which the concentration of elements existing in the shell decreases toward the center.

Non-limiting examples of material in the shell of the quantum dot include a metal oxide, a metalloid oxide, a non-metal oxide, and/or a semiconductor compound. Non-limiting examples of the oxide of metal or non-metal include a binary compound (such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO); and/or a ternary compound (such as MgAl₂O₄, CoFe₂O₄, NiFe₂O₄, and/or CoMn₂O₄). Non-limiting examples of the semiconductor compound include, as described herein, a Group II-VI semiconductor compound, a Group III-V semiconductor compound, a Group III-VI semiconductor compound, a Group I-III-VI semiconductor compound, and/or a Group IV-VI semiconductor compound. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of an emission wavelength spectrum of the quantum dot may be about 45 nm or less, for example, about 40 nm or less, for example, about 30 nm or less. When the FWHM of the emission wavelength spectrum of the quantum dot is within this range, color purity and/or color reproduction may be improved. In addition, light emitted through such quantum dots may be irradiated omnidirectionally. Accordingly, a display device including the organic light-emitting device may have a wide (increased) viewing angle.

In some embodiments, the quantum dot may be a spherical, pyramidal, multi-arm, and/or cubic nanoparticle, a nanotube, a nanowire, a nanofiber, and/or nanoplate particle.

The size (diameter) of the quantum dot may be adjusted so that the energy band gap is also adjusted, thereby providing light of various suitable wavelengths in the quantum dot emission layer. Therefore, a light-emitting device that emits light of various wavelengths may be implemented by using quantum dots of different sizes. For example, the size of the quantum dot may be selected to emit red, green, and/or blue light. In some embodiments, the size of the quantum dot may be adjusted such that light of various colors are combined to emit white light.

### Electron Transport Region in Interlayer 130

The electron transport region may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the constituting layers of each structure are sequentially stacked on the emission layer.

The electron transport region (for example, the buffer layer, the hole blocking layer, the electron control layer, and/or the electron transport layer in the electron transport region) may include a metal-free compound including at least one π electron-deficient nitrogen-containing C₁-C₆₀ cyclic group.

In an embodiment, the electron transport region may include a compound represented by Formula 601:

[Ar₆₀₁]ₓₑ₁₁-[(L₆₀₁)ₓₑ₁-R₆₀₁]ₓₑ₂₁, Formula 601

wherein, in Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each independently be the same as described in connection with Q₁,

xe21 may be 1, 2, 3, 4, or 5, and

at least one of Ar₆₀₁, L₆₀₁, or R₆₀₁ may each independently be a π electron-deficient nitrogen-containing C₁-C₆₀ cyclic group unsubstituted or substituted with at least one R₁₀ₐ.

In one or more embodiments, when xe11 in Formula 601 is 2 or more, the two or more Ar₆₀₁(s) may be linked to each other via a single bond.

In one or more embodiments, Ar₆₀₁ in Formula 601 may be a substituted or unsubstituted anthracene group.

In one or more embodiments, the electron transport region may include a compound represented by Formula 601-1:

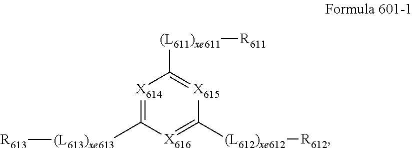

wherein, in Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may each independently be the same as described in connection with L₆₀₁,

xe611 to xe613 may each independently be the same as described in connection with xe1,

R₆₁₁ to R₆₁₃ may each independently be the same as described in connection with R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

For example, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

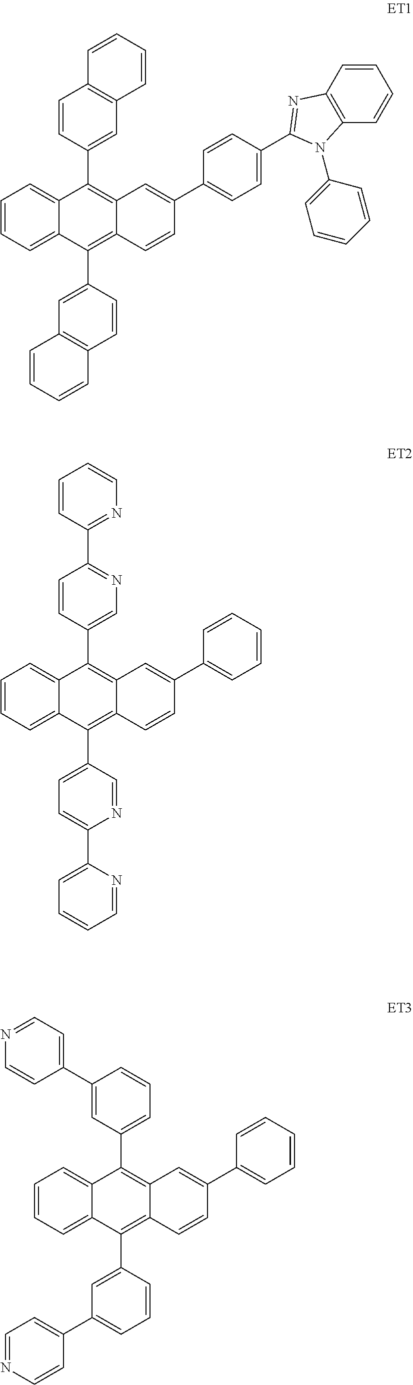 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

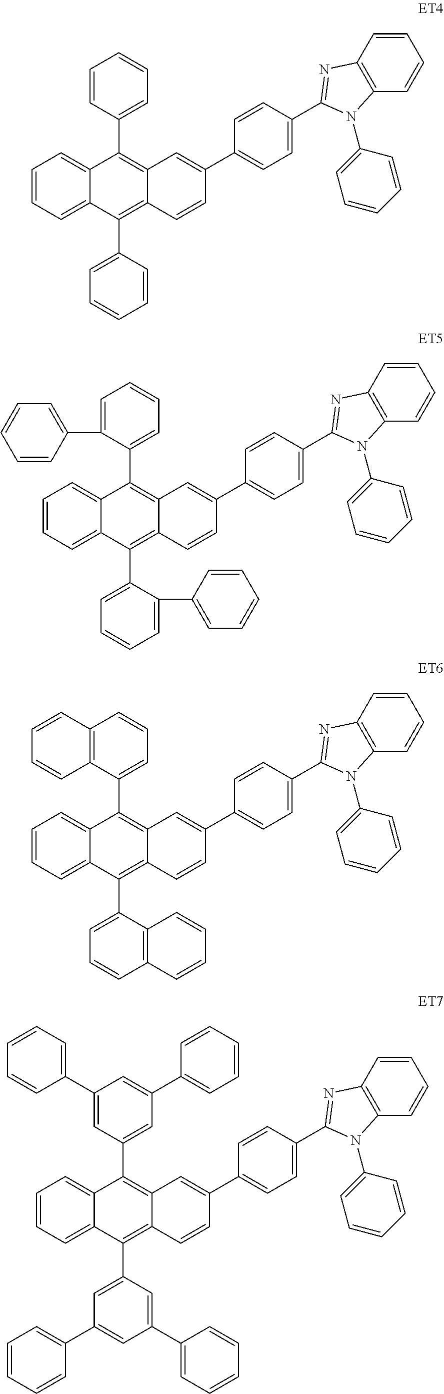 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

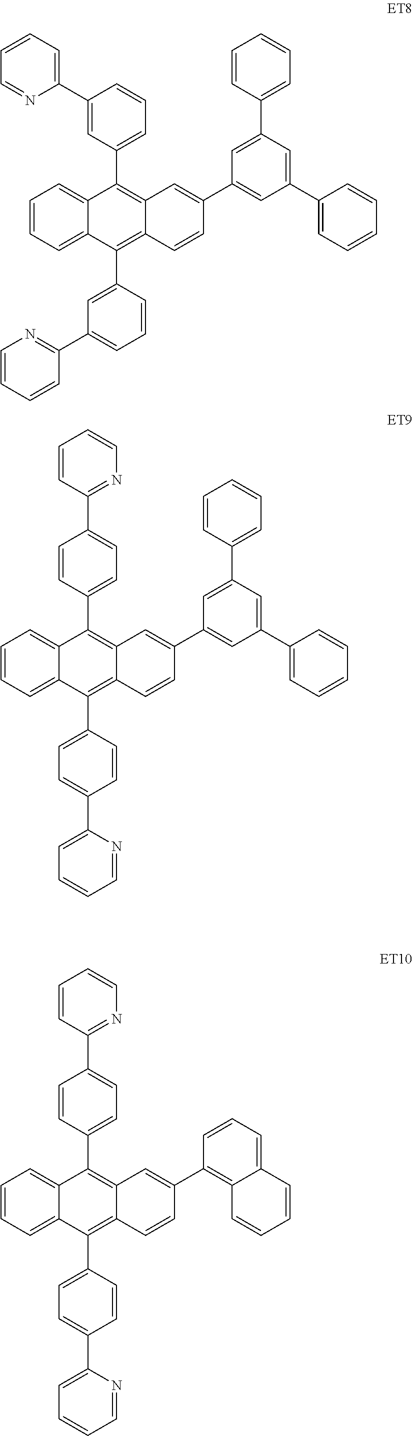 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

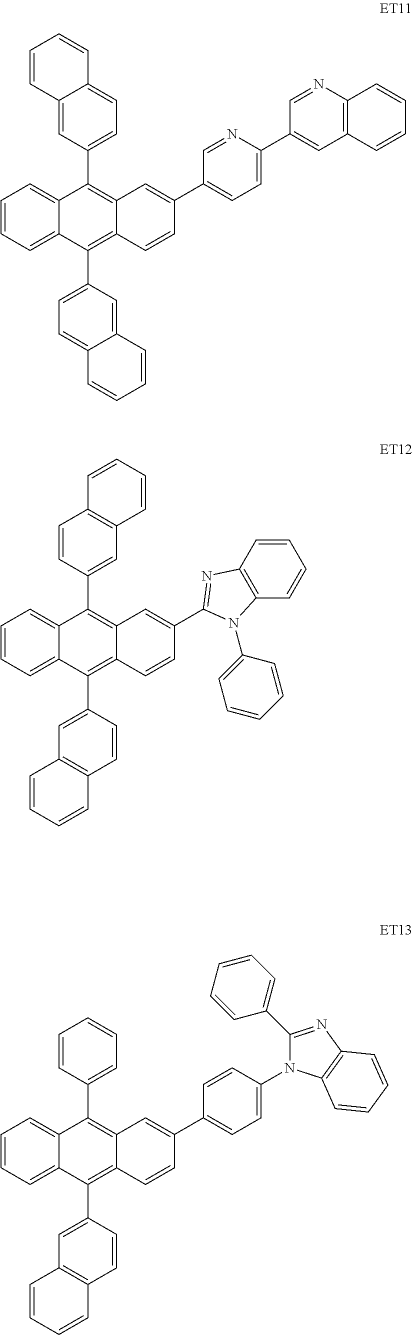 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

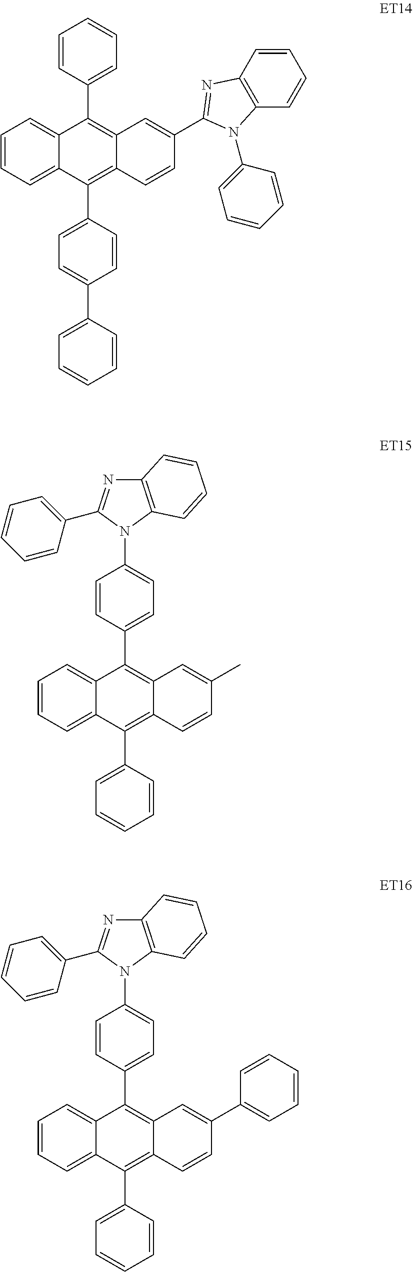 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

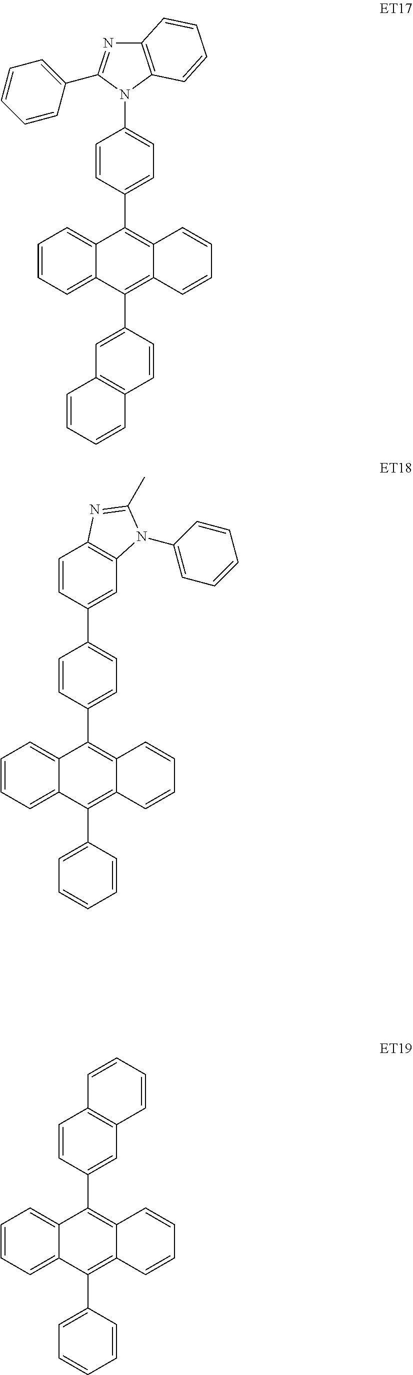

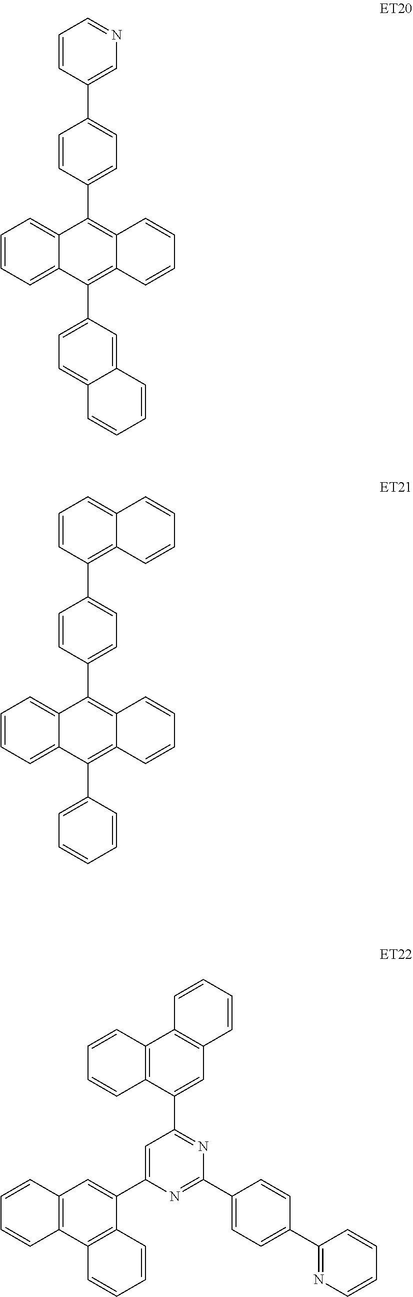

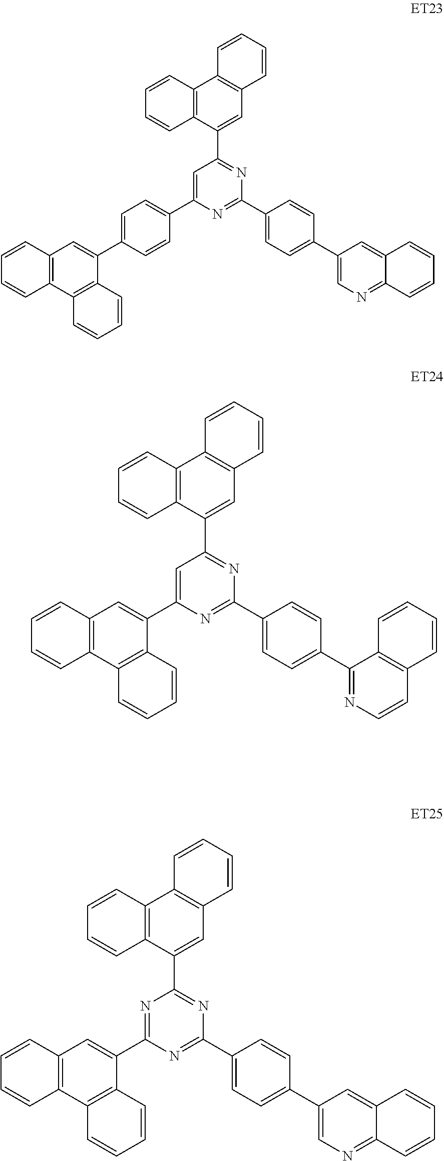 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

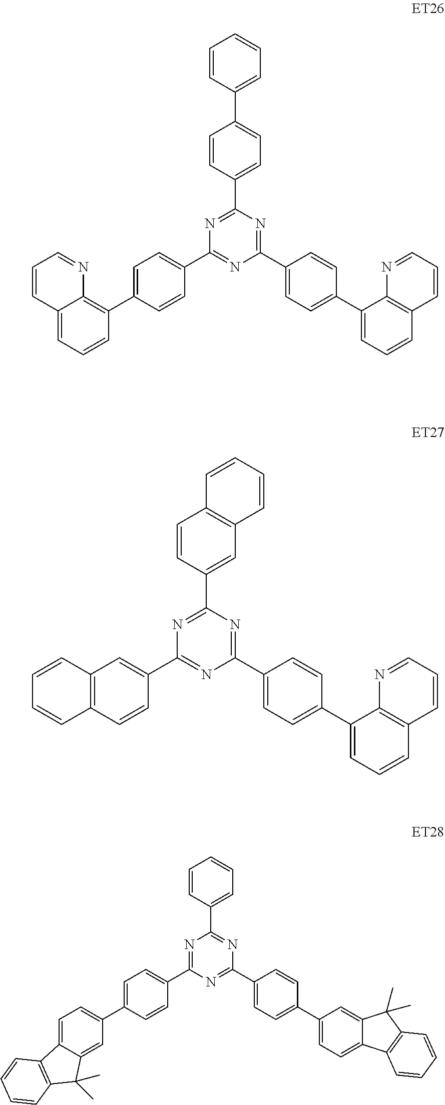 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

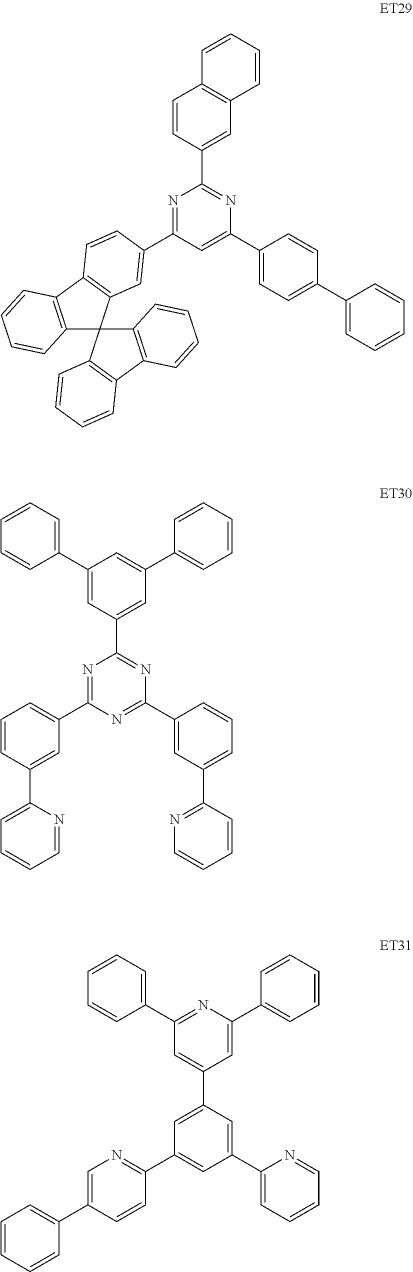 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

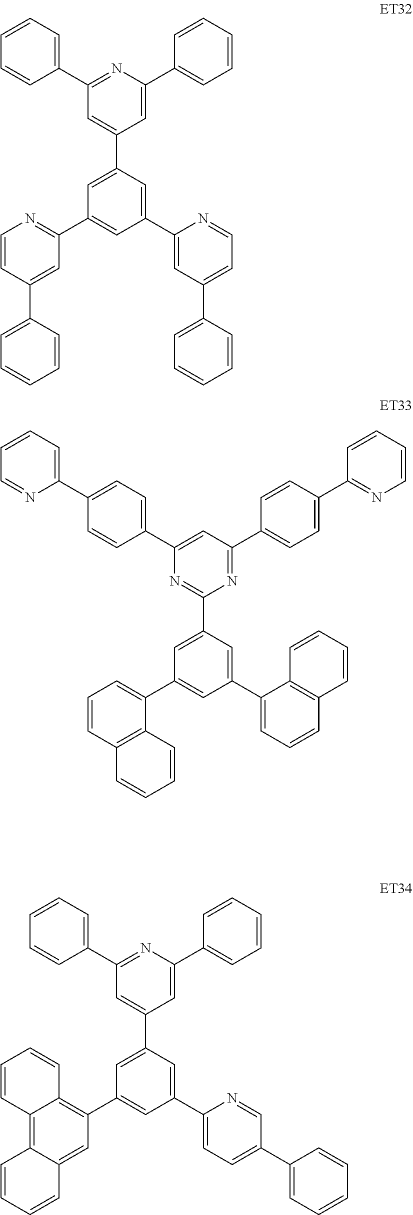

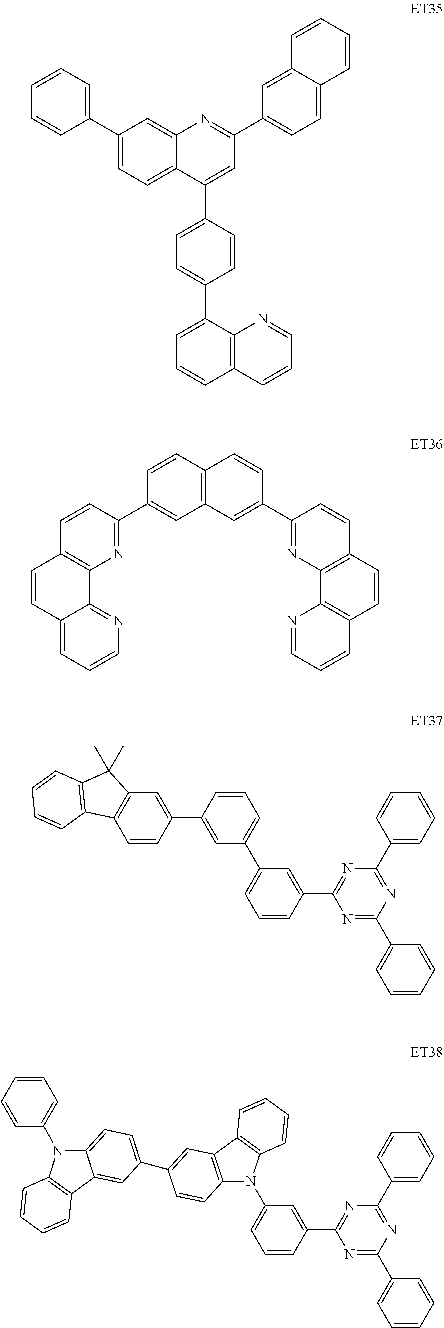 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

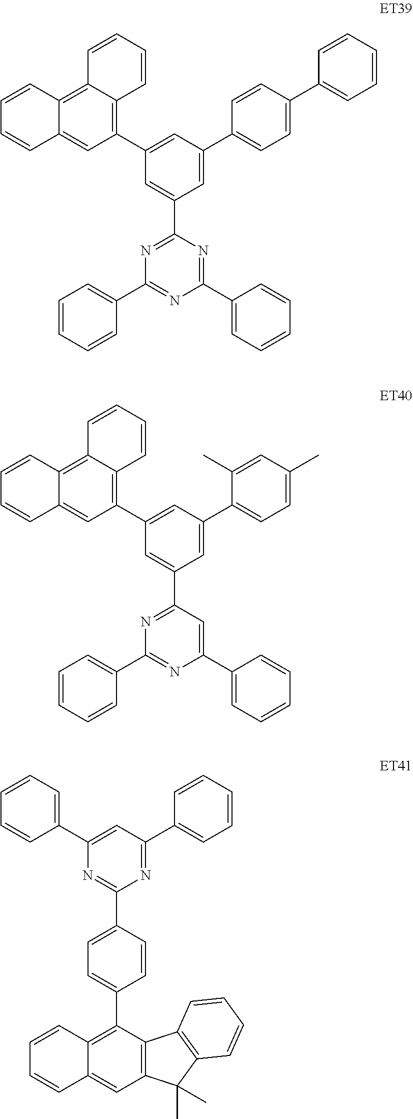 [SMILES: c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1]

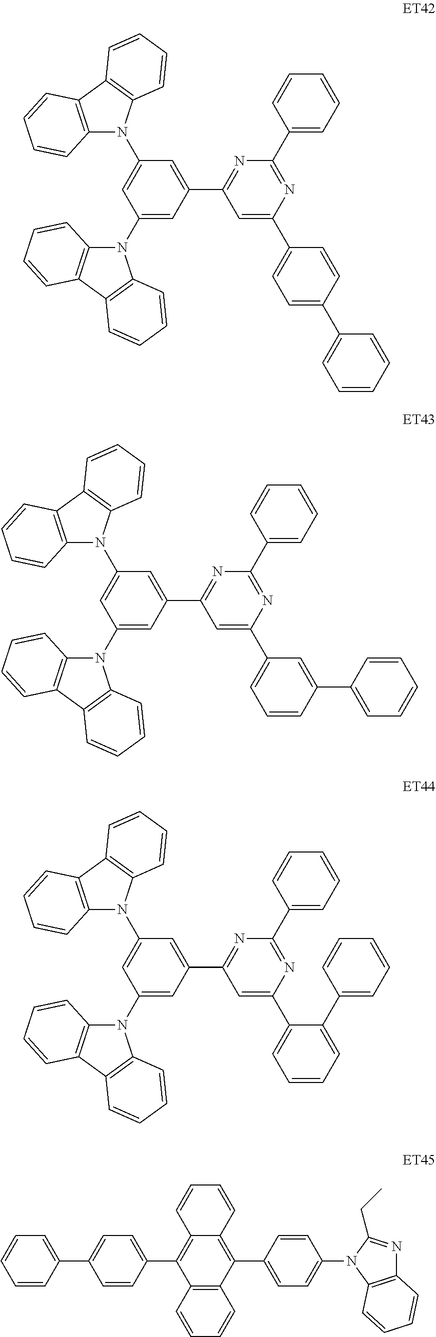 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

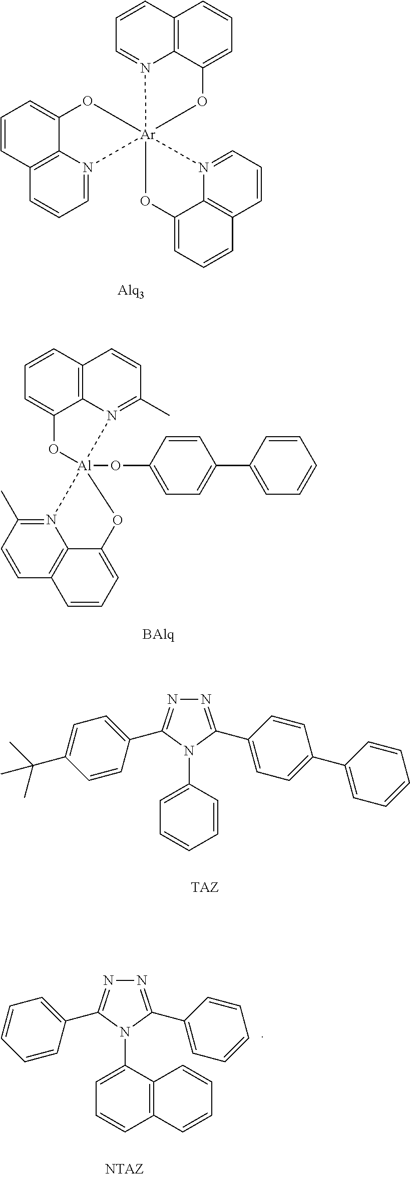

A thickness of the electron transport region may be in a range of about 160 Å to about 5,000 Å, for example, about 100 Å to about 4,000 Å. When the electron transport region includes a buffer layer, a hole blocking layer, an electron control layer, an electron transport layer, or any combination thereof, a thickness of the buffer layer, the hole blocking layer, and/or the electron control layer may each independently be in a range of about 20 Å to about 1,000 Å, for example, about 30 Å to about 300 Å, and a thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport layer are within these ranges, satisfactory hole transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth-metal complex, or any combination thereof. A metal ion of the alkali metal complex may be a Li ion, a Na ion, a K ion, a Rb ion, or a Cs ion, and a metal ion of the alkaline earth-metal complex may be a Be ion, a Mg ion, a Ca ion, a Sr ion, or a Ba ion. A ligand coordinated with the metal ion of the alkali metal complex or the alkaline earth-metal complex may be a hydroxy quinoline, a hydroxy isoquinoline, a hydroxy benzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

For example, the metal-containing material may include a Li complex. The Li complex may include, for example, Compound ET-D1 (LiQ) and/or ET-D2:

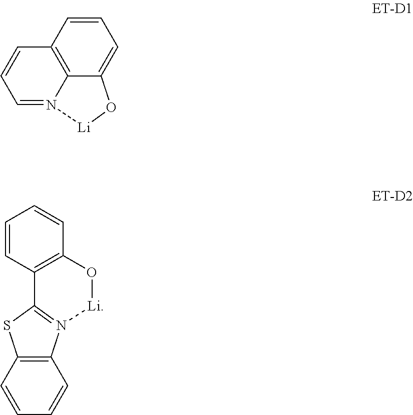

The electron transport region may include an electron injection layer that facilitates the injection of electrons from the second electrode 150. In some embodiments, the electron injection layer may directly contact the second electrode 150.

The electron injection layer may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, tellurides, halides (for example, fluorides, chlorides, bromides, or iodides), or any combination thereof of the alkali metal, the alkaline earth metal, and the rare earth metal, respectively.

The alkali metal-containing compound may be an alkali metal oxide (such as Li₂O, Cs₂O, and/or K₂O), an alkali metal halide (such as LiF, NaF, CsF, KF, LiI, NaI, CsI, and/or KI), or any combination thereof. The alkaline earth metal-containing compound may include an alkaline earth metal compound (such as BaO, SrO, CaO, BaₓSr₁₋ₓO (x is a real number that satisfies the condition of 0<x<1), and/or BaₓCa₁₋ₓO (x is a real number that satisfies the condition of 0<x<1)). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. For example, the rare earth metal-containing compound may include a lanthanide metal telluride. Non-limiting examples of the lanthanide metal telluride include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth-metal complex, and the rare earth metal complex may include: i) an alkali metal ion, an alkaline earth metal ion, or an rare earth metal ion, respectively, and ii) a ligand linked to the metal ion, for example, hydroxyquinoline, hydroxy isoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof, or may further include an organic material (for example, a compound represented by Formula 601).

In an embodiment, the electron injection layer may include (e.g., consist of) i) an alkali metal-containing compound (for example, an alkali metal halide), or ii) a) an alkali metal-containing compound (for example, an alkali metal halide); and b) an alkali metal, an alkaline earth metal, a rare earth metal, or any combination thereof. In one or more embodiments, the electron injection layer may be a KI:Yb co-deposited layer or a RbI:Yb co-deposited layer.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or combination thereof may be substantially homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within these ranges, satisfactory electron injection characteristics may be obtained without a substantial increase in driving voltage.

### Second Electrode 150

The second electrode 150 may be on the interlayer 130 having such a structure. The second electrode 150 may be a cathode, which is an electron injection electrode, and a metal, an alloy, an electrically conductive compound, or any combination thereof, each having a low work function, may be used as a material for forming the second electrode 150.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure, or a multi-layered structure including two or more layers.

### Capping Layer

A first capping layer may be disposed outside the first electrode 110, and/or a second capping layer may be disposed outside the second electrode 150. For example, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in the emission layer of the interlayer 130 of the light-emitting device 10 may be extracted toward the outside through the first electrode 110 (which may be a semi-transmissive electrode or a transmissive electrode) and the first capping layer, and/or light generated in the emission layer of the interlayer 130 of the light-emitting device 10 may be transmitted or extracted toward the outside through the second electrode 150 (which is a semi-transmissive electrode or a transmissive electrode) and the second capping layer.

The first capping layer and the second capping layer may increase the external luminescence efficiency of the device according to the principle of constructive interference. Accordingly, the light extraction efficiency of the light-emitting device 10 may be increased, so that the luminescence efficiency of the light-emitting device 10 may be improved.

Each of the first capping layer and the second capping layer may include a material having a refractive index of equal to or greater than 1.6 (e.g., at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer or the second capping layer may each independently include a carbocyclic compound, a heterocyclic compound, an amine group-containing compound, a porphyrin derivative, a phthalocyanine derivative, a naphthalocyanine derivative, an alkali metal complex, an alkaline earth-metal complex, or any combination thereof. The carbocyclic compound, the heterocyclic compound, and the amine group-containing compound may be optionally substituted with a substituent containing O, N, S, Se, Si, F, Cl, Br, I, or any combination thereof. In an embodiment, at least one of the first capping layer or the second capping layer may each independently include an amine group-containing compound.

In one or more embodiments, at least one of the first capping layer or the second capping layer may each independently include a compound represented by Formula 201, a compound represented by Formula 202, or any combination thereof.

In one or more embodiments, at least one of the first capping layer or the second capping layer may each independently include one of Compounds HT28 to HT33, one of Compounds CP1 to CP6, p-NPB, or any combination thereof:

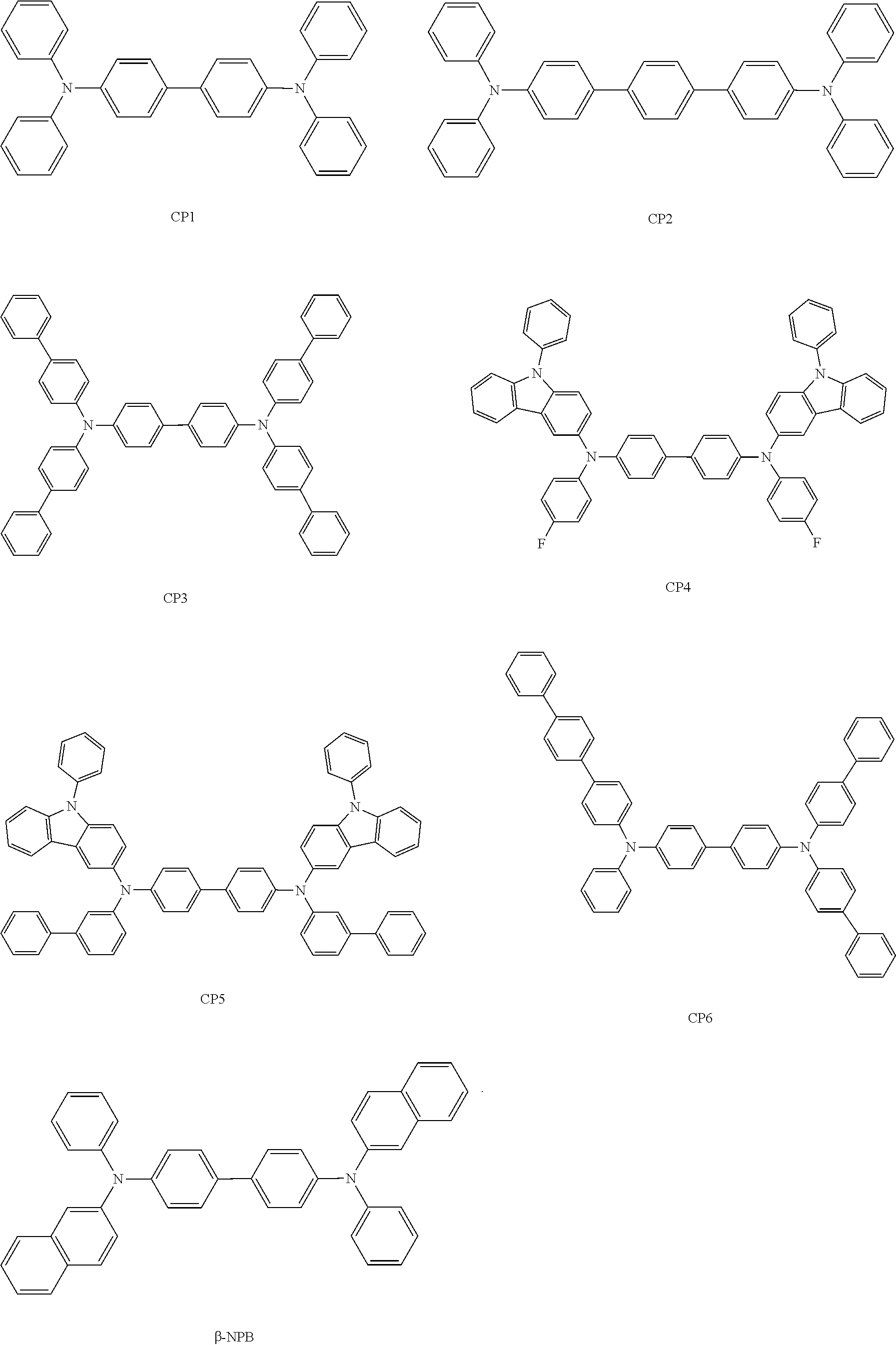

### Electronic Apparatus

The light-emitting device may be included in various suitable electronic apparatuses. For example, the electronic apparatus including the light-emitting device may be a light-emitting apparatus, an authentication apparatus, and/or the like.

The electronic apparatus (for example, light-emitting apparatus) may further include, in addition to the light-emitting device, i) a color filter, ii) a color conversion layer, or iii) a color filter and a color conversion layer. The color filter and/or the color conversion layer may be disposed in at least one traveling direction of light emitted from the light-emitting device. For example, light emitted from the light-emitting device may be blue light and/or white light. The light-emitting device may be the same as described above. In an embodiment, the color conversion layer may include quantum dots. The quantum dots may be the same as described in the present specification.

The electronic apparatus may include a first substrate. The first substrate may include a plurality of subpixel areas, the color filter may include a plurality of color filter areas respectively corresponding to the plurality of subpixel areas, and the color conversion layer may include a plurality of color conversion areas respectively corresponding to the subpixel areas.

A pixel-defining film may be arranged between the plurality of subpixel areas to define each of the subpixel areas.

The color filter may further include the color filter areas and a light-blocking pattern arranged between adjacent color filter areas of the color filter areas, and the color conversion layer may further include the color conversion areas and a light-blocking pattern arranged between adjacent color conversion areas of the color conversion areas.

The color filter areas (and/or the plurality of color conversion areas) may each independently include: a first area to emit first-color light; a second area to emit second-color light; and/or a third area to emit third-color light, and the first-color light, the second-color light, and/or the third-color light may have different maximum luminescence wavelengths from one another. For example, the first color light may be red light, the second color light may be green light, and the third color light may be blue light. For example, the color filter areas (or the color conversion areas) may include quantum dots. For example, the first area may include red quantum dots, the second area may include green quantum dots, and the third area may not include (e.g., may exclude) quantum dots. The quantum dots may be the same as described in the present specification. Each of the first area, the second area, and/or the third area may further include a scatterer.

For example, the light-emitting device may be to emit first light, the first area may be to absorb the first light to emit first first-color light, the second area may be to absorb the first light to emit second first-color light, and the third area may be to absorb the first light to emit third first-color light. In this regard, the first first-color light, the second first-color light, and the third first-color light may have different maximum emission wavelengths from one another. For example, the first light may be blue light, the first first-color light may be red light, the second first-color light may be green light, and the third first-color light may be blue light.

The electronic apparatus may further include a thin-film transistor in addition to the light-emitting device as described above. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulation layer, and/or the like.

The active layer may include crystalline silicon, amorphous silicon, organic semiconductor, oxide semiconductor, and/or the like.

The electronic apparatus may further include an encapsulation unit for sealing the light-emitting device. The encapsulation unit may be arranged between the color filter and the light-emitting device and/or between the color conversion layer and the light-emitting device. The encapsulation unit may allow light from the light-emitting device 10 to be extracted to the outside, while also preventing or reducing ambient air and/or moisture from penetrating into the light-emitting device 10. The encapsulation unit may be a sealing substrate including a transparent glass substrate or a plastic substrate. The encapsulation unit may be a thin-film encapsulation layer including an organic layer and/or an inorganic layer. When the encapsulation unit is a thin-film encapsulation layer, the electronic apparatus may be flexible.

In addition to the color filter and/or the color conversion layer, various functional layers may be further arranged on the encapsulation unit according to the use of the electronic device. The functional layers may include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus for authenticating an individual by using biometric information of a biometric body (for example, a fingertip, a pupil, and/or the like).

The authentication apparatus may further include, in addition to the light-emitting device, a biometric information collector.

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement apparatuses, pulse wave measurement apparatuses, electrocardiogram displays, ultrasonic diagnostic apparatuses, or endoscope displays), fish finders, various measuring instruments, meters (for example, meters for a vehicle, an aircraft, and a vessel), projectors, and/or the like.

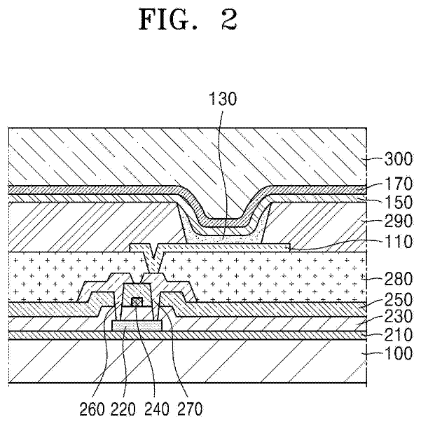

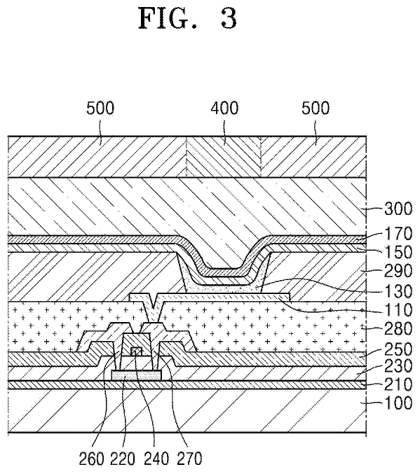

### Description of FIGS. 2 and 3

FIG. 2 is a cross-sectional view showing a light-emitting apparatus according to an embodiment of the present disclosure.

The light-emitting apparatus of FIG. 2 includes a substrate 100, a thin-film transistor, a light-emitting device, and an encapsulation unit 300 that seals light-emitting device.

The substrate 100 may be a flexible substrate, and may be a glass substrate or a metal substrate. A buffer layer 210 may be on the substrate 100. The buffer layer 210 may prevent or reduce the penetration of impurities through the substrate 100 and may provide a flat surface on (e.g., planarize) the substrate 100.

A thin-film transistor may be on the buffer layer 210. The thin-film transistor may include an active layer 220, a gate electrode 240, a source electrode 260, and a drain electrode 270.

The active layer 220 may include an inorganic semiconductor (such as silicon or polysilicon, an organic semiconductor, and/or an oxide semiconductor), and may include a source region, a drain region, and a channel region.

A gate insulating film 230 for insulating the active layer 220 from the gate electrode 240 may be on the active layer 220, and the gate electrode 240 may be on the gate insulating film 230.

An interlayer insulating film 250 may be on the gate electrode 240. The interlayer insulating film 250 may be between the gate electrode 240 and the source electrode 260 to insulate the gate electrode 240 from the source electrode 260, and between the gate electrode 240 and the drain electrode 270 to insulate the gate electrode 240 from the drain electrode 270.

The source electrode 260 and the drain electrode 270 may be on the interlayer insulating film 250. The interlayer insulating film 250 and the gate insulating film 230 may be formed to expose the source region and the drain region of the active layer 220, and the source electrode 260 and the drain electrode 270 may be arranged to be in contact with the exposed portions of the source region and the drain region of the active layer 220.

The thin-film transistor may be electrically connected to the light-emitting device to drive the light-emitting device, and may be covered by a passivation layer 280. The passivation layer 280 may include an inorganic insulating film, an organic insulating film, or a combination thereof. The light-emitting device may be provided on the passivation layer 280. The light-emitting device includes the first electrode 110, the interlayer 130, and the second electrode 150.

The first electrode 110 may be on the passivation layer 280. The passivation layer 280 does not (e.g., may not) completely cover the drain electrode 270 and may expose a portion of the drain electrode 270, and the first electrode 110 may be connected to the exposed portion of the drain electrode 270.

A pixel defining layer 290 including an insulating material may be on the first electrode 110. The pixel defining layer 290 may expose a set or predetermined region of the first electrode 110, and the interlayer 130 may be formed in the exposed region of the first electrode 110. The pixel defining layer 290 may be a polyimide or polyacryl-based organic film. In some embodiments, at least some layers of the interlayer 130 may extend beyond the upper portion of the pixel defining layer 290, and may thus be disposed in the form of a common layer.

The second electrode 150 may be on the interlayer 130, and a capping layer 170 may be additionally formed on the second electrode 150. The capping layer 170 may be formed to cover the second electrode 150.

The encapsulation unit 300 may be on the capping layer 170. The encapsulation unit 300 may be on the light-emitting device and may protect the light-emitting device from moisture and/or oxygen. The encapsulation unit 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate and/or polyacrylic acid), an epoxy-based resin (for example, aliphatic glycidyl ether (AGE), or a combination thereof; or a combination of the inorganic film and the organic film.

FIG. 3 is a cross-sectional view showing a light-emitting apparatus according to another embodiment of the present disclosure.

The light-emitting apparatus of FIG. 3 is the same as the light-emitting apparatus of FIG. 2, except that a light-blocking pattern 500 and a functional region 400 are additionally disposed on the encapsulation unit 300. The functional region 400 may be i) a color filter area, ii) a color conversion area, or iii) a combination of the color filter area and the color conversion area. In an embodiment, the light-emitting device included in the light-emitting apparatus of FIG. 3 may be a tandem light-emitting device.

### Preparation Method

The layers constituting the hole transport region, the emission layer, and the layers constituting the electron transport region may be formed in a set or predetermined region by using one or more suitable methods selected from vacuum deposition, spin coating, casting, Langmuir-Blodgett (LB) deposition, ink-jet printing, laser-printing, and laser-induced thermal imaging.

When the layers constituting the hole transport region, the emission layer, and the layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec depending on the material to be included in a layer to be formed, and the structure of a layer to be formed.

### DEFINITION OF TERMS

The term “C₃-C₆₀ carbocyclic group” as used herein refers to a cyclic group consisting of three to sixty carbon atoms, and the term “C₁-C₆₀ heterocyclic group” as used herein refers to a cyclic group that has one to sixty carbon atoms and further includes, in addition to carbon, a heteroatom. The C₃-C₆₀ carbocyclic group and the C₁-C₆₀ heterocyclic group may each be a monocyclic group that includes (e.g., consists of) one ring, or a polycyclic group in which two or more rings are condensed with each other. For example, the number of ring-forming atoms of the C₁-C₆ heterocyclic group may be from 3 to 61.

The term “cyclic group” as used herein includes the C₃-C₆₀ carbocyclic group and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

For example, the C₃-C₆₀ carbocyclic group may be i) a group T1 (defined below) or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) a group T2 (defined below), ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothieno dibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group),

the π electron-rich C₃-C₆₀ cyclic group may be i) a group T1, ii) a condensed cyclic group in which two or more groups T1 are condensed with each other, iii) a group T3 (defined below), iv) a condensed cyclic group in which two or more groups T3 are condensed with each other, or v) a condensed cyclic group in which at least one group T3 and at least one group T1 are condensed with each other (for example, a C₃-C₆₀ carbocyclic group, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, or a benzothienodibenzothiophene group),

the π electron-deficient nitrogen-containing C₁-C₆₀ cyclic group may be i) a group T4 (defined below), ii) a condensed cyclic group in which two or more groups T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with each other (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group),

where the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane group (or, a bicyclo[2.2.1]heptane group), a norbornene group, a bicyclo[1.1.1]pentane group, a bicyclo[2.1.1]hexane group, a bicyclo[2.2.2]octane group, or a benzene group,

the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group,

the group T3 may be a furan group, a thiophene group, a 1H-pyrrole group, a silole group, or a borole group, and

the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The cyclic group, the C₃-C₆₀ carbocyclic group, the C₁-C₆₀ heterocyclic group, the π electron-rich C₃-C₆₀ cyclic group, and/or the π electron-deficient nitrogen-containing C₁-C₆₀ cyclic group may each independently be a group that is condensed with a cyclic group, a monovalent group, and/or a polyvalent group (for example, a divalent group, a trivalent group, a tetravalent group, and/or the like), according to the structure of the formula described with the corresponding terms. For example, “a benzene group” may be a benzene, a phenyl group, a phenylene group, and/or the like, which may be easily understand by one of ordinary skill in the art according to the structure of a formula including the “benzene group.”

Examples of the monovalent C₃-C₆₀ carbocyclic group and the monovalent C₁-C₆ heterocyclic group may each include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and/or a monovalent non-aromatic condensed heteropolycyclic group, and examples of the divalent C₃-C₆₀ carbocyclic group and the monovalent C₁-C₆₀ heterocyclic group may each include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and/or a divalent non-aromatic condensed heteropolycyclic.

The term “C₁-C₆₀ alkyl group” as used herein refers to a linear or branched aliphatic hydrocarbon monovalent group having 1 to 60 carbon atoms, and non-limiting examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and/or a tert-decyl group. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one carbon-carbon double bond in the middle or at the terminus of a C₂-C₆₀ alkyl group, and non-limiting examples thereof include an ethenyl group, a propenyl group, and/or a butenyl group. The term “C₂-C₆ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of a C₂-C₆₀ alkyl group, and non-limiting examples thereof include an ethynyl group and/or a propynyl group. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by —OA₁₀₁ (wherein A₁₀₁ is a C₁-C₆ alkyl group), and non-limiting examples thereof include a methoxy group, an ethoxy group, and/or an isopropyloxy group.

The term “C₃-C₁₀ cycloalkyl group” as used herein refers to a monovalent saturated hydrocarbon cyclic group having 3 to 10 carbon atoms, and non-limiting examples thereof include a cyclopropyl group, a cyclobutyl group, a cyclopentyl group, a cyclohexyl group, a cycloheptyl group, a cyclooctyl group, an adamantyl group, a norbornyl group (or a bicyclo[2.2.1]heptyl group), a bicyclo[1.1.1]pentyl group, a bicyclo[2.1.1]hexyl group, and/or a bicyclo[2.2.2]octyl group. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group that further includes, in addition to 1 to 10 carbon atoms, at least one heteroatom as a ring-forming atom, and non-limiting examples thereof include a 1,2,3,4-oxatriazolidinyl group, a tetrahydrofuranyl group, and/or a tetrahydrothiophenyl group. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has 3 to 10 carbon atoms, at least one carbon-carbon double bond in the ring thereof, and no aromaticity, and non-limiting examples thereof include a cyclopentenyl group, a cyclohexenyl group, and/or a cycloheptenyl group. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group that has, in addition to 1 to 10 carbon atoms, at least one heteroatom as a ring-forming atom, and at least one carbon-carbon double bond in the cyclic structure thereof. Non-limiting examples of the C₁-C₁₀ heterocycloalkenyl group include a 4,5-dihydro-1,2,3,4-oxatriazolyl group, a 2,3-dihydrofuranyl group, and/or a 2,3-dihydrothiophenyl group. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and/or an ovalenyl group. When the C₆-C₆₀ aryl group and the C₆-C₆₀ arylene group each include two or more rings, the two or more rings may be condensed to each other.

The term “C₁-C₆₀ heteroaryl group” as used herein refers to a monovalent group having a heterocyclic aromatic system that has, in addition to 1 to 60 carbon atoms, at least one heteroatom as a ring-forming atom. The term “C₁-C₆₀ heteroarylene group” as used herein refers to a divalent group having a heterocyclic aromatic system that has, in addition to 1 to 60 carbon atoms, at least one heteroatom as a ring-forming atom. Non-limiting examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and/or a naphthyridinyl group. When the C₁-C₆ heteroaryl group and the C₁-C₆₀ heteroarylene group each include two or more rings, the two or more rings may be condensed with each other.

The term “monovalent non-aromatic condensed polycyclic group” as used herein refers to a monovalent group having two or more rings condensed with each other, only carbon atoms (for example, 8 to 60 carbon atoms) as ring-forming atoms, and no aromaticity in its molecular structure when the structure of the group is considered as a whole. Non-limiting examples of the monovalent non-aromatic condensed polycyclic group include an adamantyl group, an indenyl group, a fluorenyl group, a spiro-bifluorenyl group, a benzofluorenyl group, an indenophenanthrenyl group, and/or an indenoanthracenyl group. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group having two or more rings condensed to each other, at least one heteroatom other than carbon atoms (for example, 1 to 60 carbon atoms) as a ring-forming atom, and no aromaticity in its molecular structure when the structure of the group is considered as a whole. Non-limiting examples of the monovalent non-aromatic condensed heteropolycyclic group include an azaadamantyl group and/or 9H-xanthenyl group. The term “divalent non-aromatic condensed heteropolycyclic group” as used herein refers to a divalent group having substantially the same structure as the monovalent non-aromatic condensed heteropolycyclic group.

The term “C₆-C₆₀ aryloxy group” as used herein refers to —OA₁₀₂ (wherein A₁₀₂ is a C₆-C₆₀ aryl group), and the term “C₆-C₆₀ arylthio group” as used herein refers to —SA₁₀₃ (wherein A₁₀₃ is a C₆-C₆₀ aryl group).

The term “R₁₀ₐ” as used herein may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the present specification, Q₁ to Q₃, Q₁₁ to Q₁₃, Q₂₁ to Q₂₃ and Q₃₁ to Q₃₃ may each independently be hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆ alkoxy group, a phenyl group, a biphenyl group, or any combination thereof.

The term “heteroatom” as used herein refers to any atom other than a carbon atom or a hydrogen atom. Non-limiting examples of the heteroatom include O, S, N, P, Si, B, Ge, and/or Se.

The term “Ph” as used herein refers to a phenyl group, the term “Me” as used herein refers to a methyl group, the term “Et” as used herein refers to an ethyl group, the term “ter-Bu” or “Bu^{t}” as used herein refers to a tert-butyl group, and the term “OMe” as used herein refers to a methoxy group.

The term “biphenyl group” as used herein refers to “a phenyl group substituted with a phenyl group.” In other words, a “biphenyl group” is a substituted phenyl group having a C₆-C₆₀ aryl group as a substituent.

The term “terphenyl group” as used herein refers to “a phenyl group substituted with a biphenyl group”. In other words, a “terphenyl group” is a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula.

Hereinafter, a compound according to embodiments and a light-emitting device according to embodiments will be described in more detail with reference to Synthesis Examples and Examples. The wording “B was used instead of A” used in describing Synthesis Examples indicates that an identical molar equivalent of B was used in place of A.

### EXAMPLES

### Synthesis Example 1: Synthesis of Compound 1

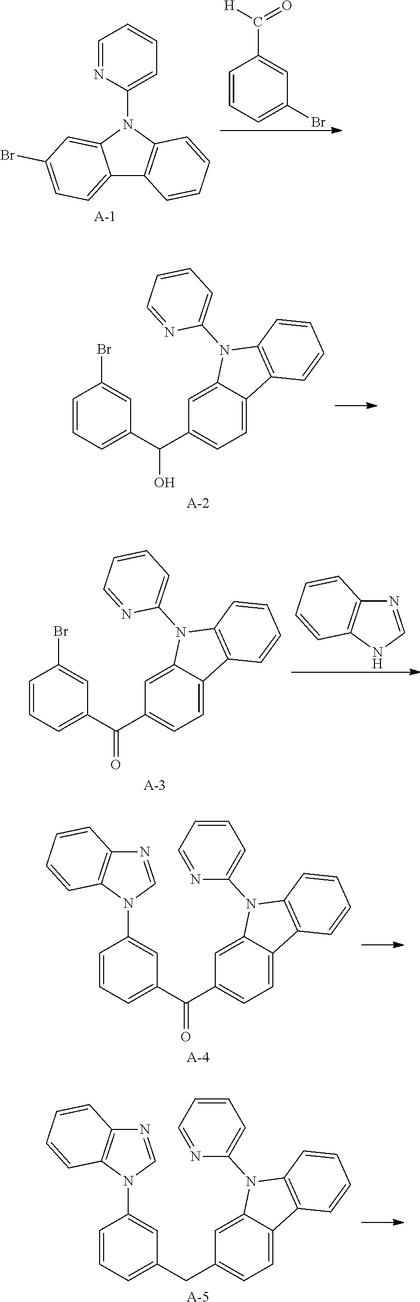

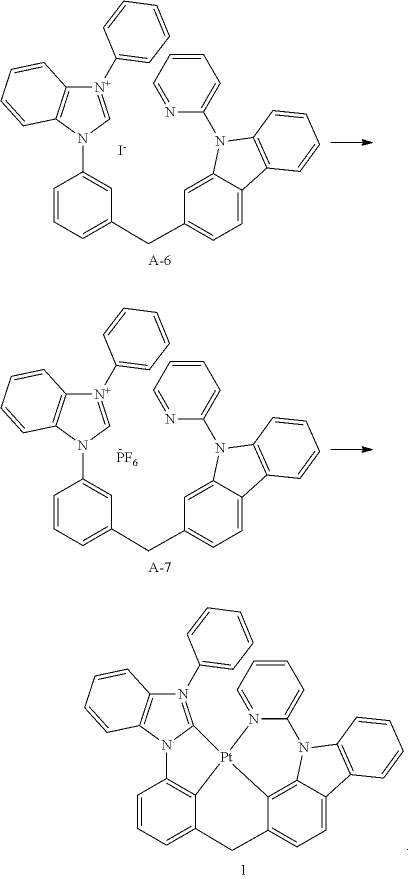

### Synthesis of Intermediate A-1

12.30 g (50 mmol) of bromo-9H-carbazole, 11.85 g (75 mmol) of 2-bromopyridine, 23 g (100 mmol) of potassium triphosphate, 1.83 g (10 mmol) of CuI, and 1.17 g (10 mmol) of picolinic acid were added to a reaction vessel and suspended in 150 mL of dimethyl sulfoxide. The reaction mixture was heated and stirred at a temperature of 160° C. for 24 hours. After completion of the reaction, the reaction result was cooled at room temperature, 300 mL of distilled water was added thereto, and an extraction process was performed thereon using ethyl acetate. The extracted organic layer was washed with a saturated aqueous sodium chloride solution and dried using sodium sulfate. A residue obtained by removing the solvent therefrom was separated by column chromatography to obtain 12.28 g (38 mmol) of Intermediate A-1 (2-bromo-9-(pyridin-2-yl)-9H-carbazole).

### 1-2. Synthesis of Intermediate A-2

12.28 g (38 mmol) of Intermediate [A-1] was dissolved in 500 mL of THF, and 41.8 mmol (2.5 M in hexane) of n-butyl lithium was slowly added thereto at a temperature of −78° C. After 1 hour, 10.5 g (57 mmol) of 3-bromobenzaldehyde was added thereto at a temperature of 0° C. After stirring the reaction result for 2 hours, ammonium chloride was added thereto and washed three times with 30 mL of diethyl ether. The washed diethyl ether layer was dried using sodium sulfate. A residue obtained by removing the solvent therefrom was separated by column chromatography to obtain 9.45 g (22 mmol) of Intermediate A-2.

### 1-3. Synthesis of Intermediate A-3

9.45 g (22 mmol) of Intermediate [A-2] was dissolved in dimethylchloride, 14.9 g (66 mmol) of 2,3-dichloro-5,6-dicyano-1,4-benzoquinone (DDQ) was added thereto, and the reaction mixture was stirred at room temperature for 12 hours. After completion of the reaction, a separation process was performed thereon using column chromatography to obtain 7.69 g (18 mmol) of Intermediate A-3.

### 1-4. Synthesis of Intermediate A-4

7.69 g (18 mmol) of Intermediate [A-3], 1.65 g (14 mmol) 1H-benz[d]imidazole, 6.44 g (28 mmol) of potassium triphosphate, 0.51 g (2.8 mmol) of CuI, and 0.32 g (2.8 mmol) of picolinic acid were added to a reaction vessel and suspended in 40 mL of dimethyl sulfoxide. The reaction mixture was heated and stirred at a temperature of 160° C. for 12 hours. After completion of the reaction, the reaction result was cooled to room temperature, 100 mL of distilled water was added thereto, and an extraction process was performed thereon using ethyl acetate. The extracted organic layer was washed with a saturated aqueous sodium chloride solution and dried using sodium sulfate. A residue obtained by removing the solvent therefrom was separated by column chromatography to obtain 5.57 g (12 mmol) of Intermediate A-4.

### 1-5. Synthesis of Intermediate A-5

5.57 g (12 mmol) of Intermediate [A-4] was dissolved in dimethylchloride under nitrogen, and 120 mmol of trifluoroacetic acid and 120 mmol of triflic acid (e.g., trifluoromethanesulfonic acid) were added thereto. 36 mmol of triethylsilane was slowly added dropwise to the reaction mixture and stirred at a temperature of 50° C. for 6 hours. After completion of the reaction, a washing process was performed thereon using 1 M sodium hydroxide. The washed diethyl ether layer was dried using sodium sulfate. A residue obtained by removing the solvent therefrom was separated by column chromatography to obtain 4.50 g (10 mmol) of Intermediate A-5.

### 1-6. Synthesis of Intermediate A-6

4.86 g (10 mmol) of Intermediate [A-5] and 15 mmol of diphenyl iodonium were suspended in toluene. The reaction mixture was heated and stirred at a temperature of 110° C. for 24 hours. After completion of the reaction, the reaction result was cooled to room temperature, 100 mL of distilled water was added thereto, and an extraction process was performed thereon using ethyl acetate. An extracted organic layer was washed with a saturated aqueous sodium chloride solution and dried using sodium sulfate. A residue obtained by removing the solvent therefrom was separated by column chromatography to obtain 5.30 g (8.1 mmol) of Intermediate A-6.

### 1-7. Synthesis of Intermediate A-7

5.30 g (8.1 mmol) of Intermediate [A-6] and 5.31 g (32 mmol) of ammonium hexafluorophosphate were added to a reaction vessel and suspended in a mixed solution including 100 mL of methyl alcohol and 25 mL of water. The reaction mixture was stirred at room temperature for 24 hours. After completion of the reaction, the resulting solid was filtered and washed with ether. The washed solid was dried to obtain 5.11 g (7.6 mmol) of Intermediate A-7.

### 1-8. Synthesis of Compound 1

5.11 g (7.6 mmol) of Intermediate [A-7], 2.96 g (8.08 mmol) of dichloro(1,5-cyclooctadiene)platinum, and 1.26 g (15.4 mmol) of sodium acetate were suspended in 80 mL of dioxane. The reaction mixture was heated and stirred at the temperature of 110° C. for 72 hours. After completion of the reaction, the reaction result was cooled to room temperature, 100 mL of distilled water was added thereto, and an extraction process was performed thereon using ethyl acetate. The extracted organic layer was washed with a saturated aqueous sodium chloride solution and dried using sodium sulfate. A residue obtained by removing the solvent therefrom was separated by column chromatography to obtain 1.37 g (1.9 mmol) of Compound 1.

### Synthesis Example 2: Synthesis of Compound 10

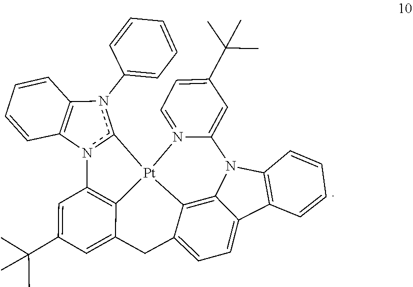

Compound 10 was obtained in substantially the same manner as in Synthesis Example 1, except that 2-bromo-9-(4-(t-butyl)pyridin-2-yl)-9H-carbazole was used instead of Intermediate [A-1], and 3-bromo-5-(t-butyl)benzaldehyde was used instead of 3-bromobenzaldehyde.

### Synthesis Example 3: Synthesis of Compound 22

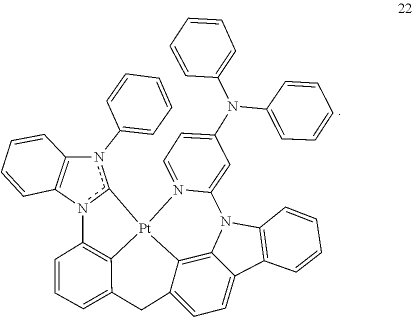

Compound 22 was obtained in substantially the same manner as in Synthesis Example 1, except that 2-(2-bromo-9H-carbazol-9-yl)-N,N-diphenylpyridine-4-amine was used instead of Intermediate [A-1].

### Synthesis Example 4: Synthesis of Compound 28

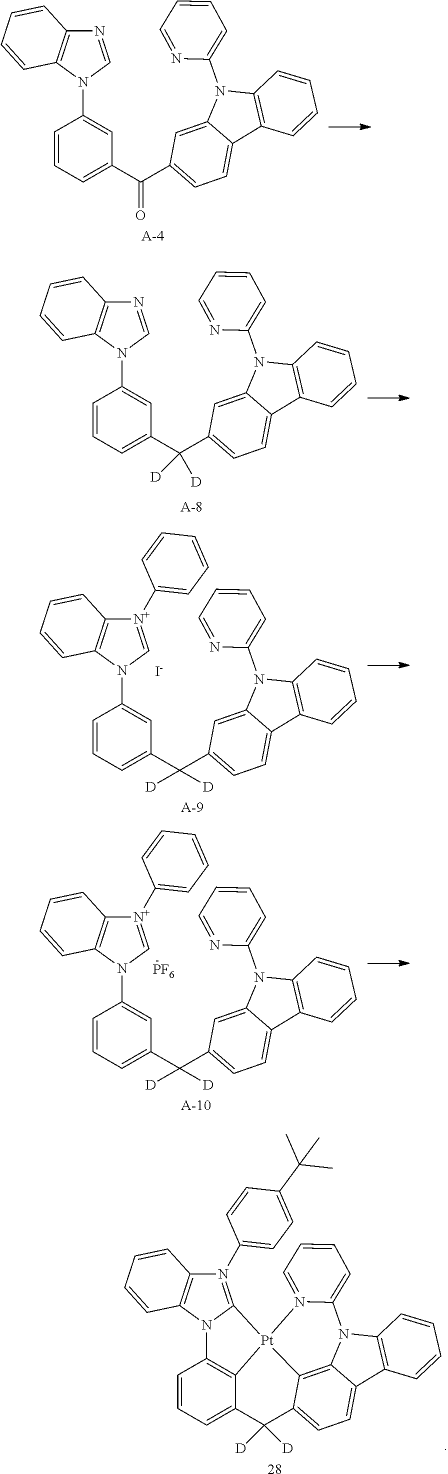

### 4-1. Synthesis of Intermediate A-8

4.64 g (10 mmol) of Intermediate [A-4] was dissolved in tetrahydrofuran under nitrogen, and 10 mmol of NaBD₄ was slowly added dropwise thereto. 10 mmol of aluminum chloride was slowly added dropwise to the reaction mixture and stirred at a temperature of 80° C. for 6 hours. After the reaction result was cooled to room temperature, 100 mL of NaBD₄ was slowly added dropwise thereto and stirred at a temperature of 80° C. for 12 hours. After completion of the reaction, 100 mL of distilled water was added thereto, and an extraction process was performed thereon using ethyl acetate. The washed ethyl acetate layer was by using sodium sulfate. A residue obtained by removing the solvent therefrom was separated by column chromatography to obtain 3.17 g (7 mmol) of Intermediate A-8.

### 4-2. Synthesis of Intermediate A-9

Intermediate A-9 was obtained in substantially the same manner as used to prepare Intermediate [A-6] of Synthesis Example 1, except that Intermediate [A-8] was used instead of Intermediate [A-5].

### 4-3. Synthesis of Intermediate A-10

Intermediate A-10 was obtained in substantially the same manner as used to prepare Intermediate [A-7] of Synthesis Example 1, except that Intermediate [A-9] was used instead of Intermediate [A-6].

### 4-4. Synthesis of Compound 28

Compound 28 was obtained in substantially the same manner as in Synthesis Example 1, except that Intermediate [A-10] was used instead of Intermediate [A-7].

### Synthesis Example 5: Synthesis of Compound 33

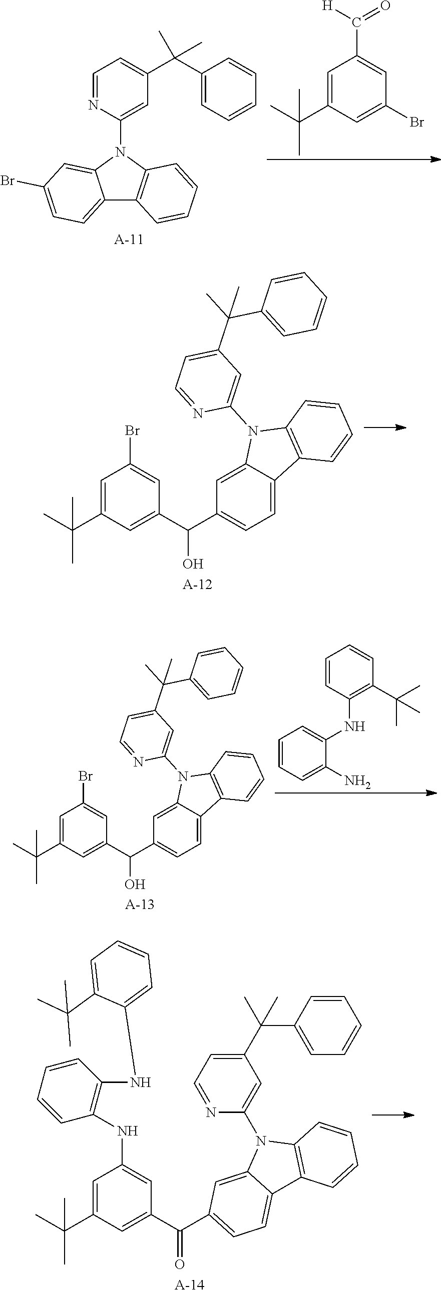

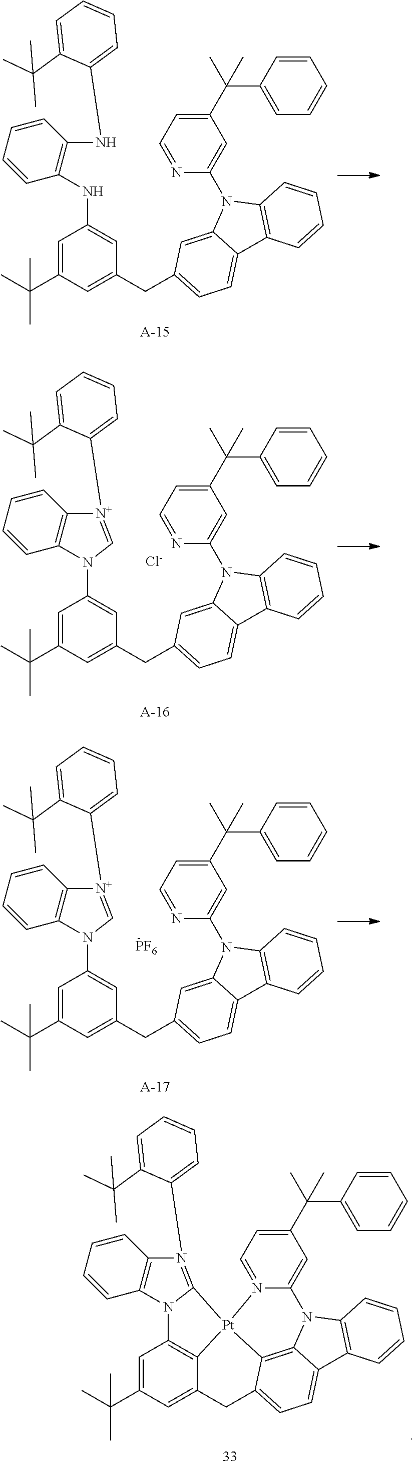

### 5-1. Synthesis of Intermediate A-12

Intermediate A-12 was obtained in substantially the same manner as to prepare Intermediate [A-2] of Synthesis Example 1, except that 2-bromo-9-(4-(2-phenylpropane)-pyridin-2-yl)-9H-carbazole was used instead of Intermediate [A-1], and 3-bromo-5-(t-butyl)benzaldehyde was used instead of 3-bromobenzaldehyde.

### 5-2. Synthesis of Intermediate A-13

Intermediate A-13 was obtained in substantially the same manner as used to prepare Intermediate [A-3] of Synthesis Example 1, except that Intermediate [A-12] was used instead of Intermediate [A-2].

### 5-3. Synthesis of Intermediate A-14

6.01 g (10 mmol) of Intermediate [A-13], 2.64 g (11 mmol) of N¹-(2-(t-butyl)phenyl)benzene-1,2-diamine, SPhos (0.75 mmol), Pd₂(dba)₃ (0.5 mmol), and sodium t-butoxide (20 mmol) were suspended in 100 mL of toluene solvent, heated to a temperature of 100° C., and stirred for 5 hours. After completion of the reaction, a solvent was removed therefrom under reduced pressure, and extracted with methylene chloride and distilled water. The extracted organic layer was washed with a saturated aqueous sodium chloride solution and dried using sodium sulfate. A residue obtained by removing the solvent therefrom was separated by column chromatography to obtain 6.24 g (8.2 mmol) of Intermediate A-14.

### 5-4. Synthesis of Intermediate A-15

Intermediate A-15 was obtained in substantially the same manner as used to prepare Intermediate [A-5] of Synthesis Example 1, except that Intermediate [A-14] was used instead of Intermediate [A-4].

### 5-5. Synthesis of Intermediate A-16

5.68 g (7.6 mmol) of Intermediate [A-15] was dissolved in 380 mmol of triethyl orthoformate, and 9.12 mmol HCl was added dropwise thereto. The reaction mixture was heated to a temperature of 100° C. and stirred for 20 hours. After completion of the reaction, a solvent was removed therefrom under reduced pressure, and extracted with methylene chloride and distilled water. The extracted organic layer was washed with a saturated aqueous sodium chloride solution and dried using sodium sulfate. A residue obtained by removing the solvent therefrom was separated by column chromatography to obtain 4.76 g (6.0 mmol) of Intermediate A-16.

### 5-6. Synthesis of Intermediate A-17

Intermediate A-17 was obtained in substantially the same manner as used to prepare Intermediate [A-7] of Synthesis Example 1, except that Intermediate [A-16] was used instead of Intermediate [A-6].

### 5-7. Synthesis of Compound 33

Compound 33 was obtained in substantially the same manner as in Synthesis Example 1, except that Intermediate [A-17] was used instead of Intermediate [A-7].

### Synthesis Example 6: Synthesis of Compound 65

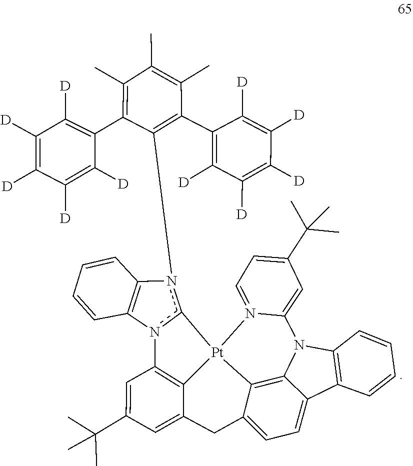

Compound 65 was obtained in substantially the same manner as in Synthesis Example 5, except that 2-bromo-9-(4-(t-butyl)pyridin-2-yl)-9H-carbazole was used instead of Intermediate [A-11], and N¹-(4′,5′,6′-trimethyl-[1,1′:3′,1″-terphen]-2′-yl-2,2″,3,3″,4,4″,5,5″,6,6″-d₁₀)benzene-1,2-diamine was used instead of N¹-(2-(t-butyl)phenyl)benzene-1,2-diamine.

### Synthesis Example 7: Synthesis of Compound 81

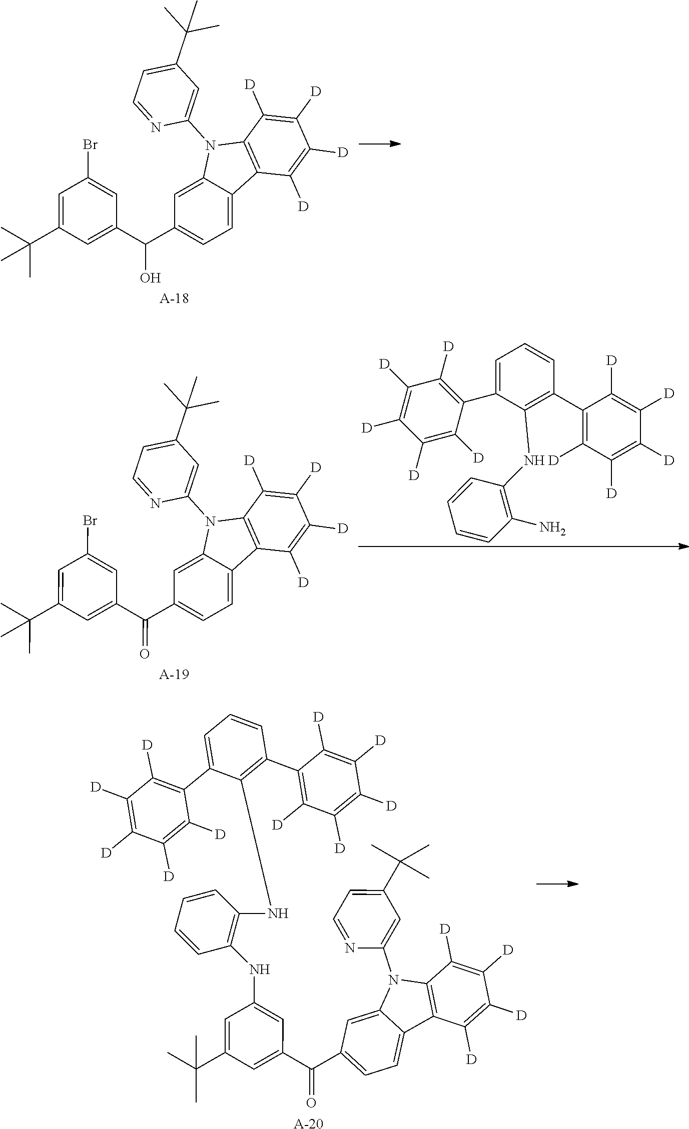

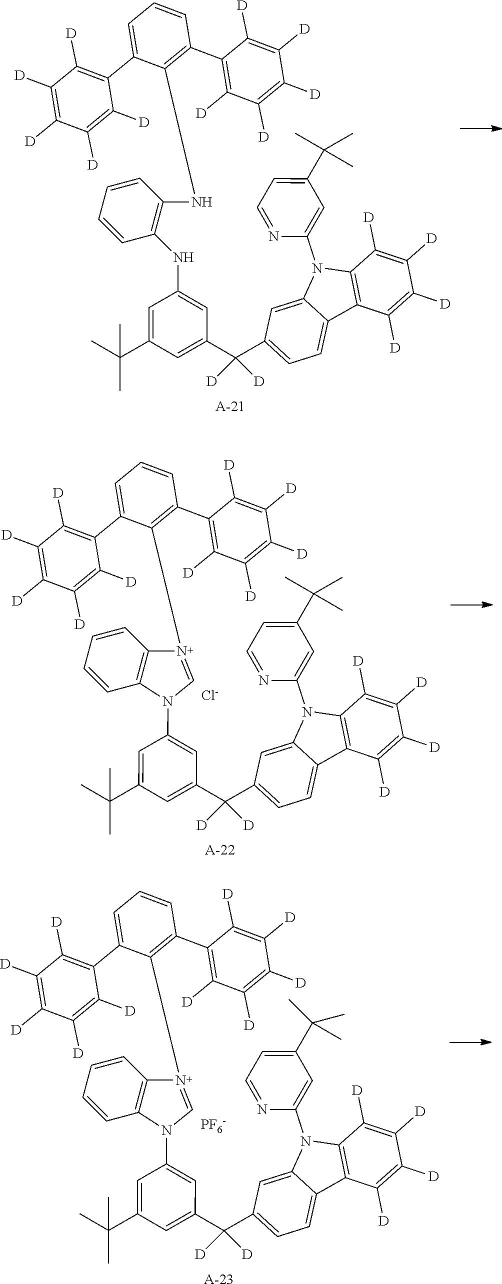

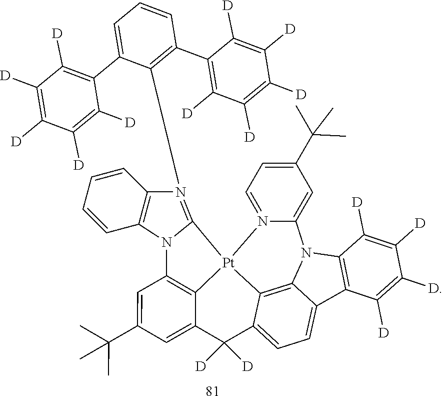

### 7-1. Synthesis of Intermediate A-18

Intermediate A-18 was obtained in substantially the same manner as used to prepare Intermediate [A-2] of Synthesis Example 1, except that 2-bromo-9-(4-(t-butyl)pyridin-2-yl)-9H-carbazole was used instead of Intermediate [A-1], and 3-bromo-5-(t-butyl)benzaldehyde was used instead of 3-bromobenzaldehyde.

### 7-2. Synthesis of Intermediate A-19

Intermediate A-19 was obtained in substantially the same manner as used to prepare Intermediate [A-3] of Synthesis Example 1, except that Intermediate [A-18] was used instead of Intermediate [A-2].

### 7-3. Synthesis of Intermediate A-20

Intermediate A-20 was obtained in substantially the same manner as used to obtain Intermediate [A-14] of Synthesis Example 5, except that Intermediate [A-19] was used instead of Intermediate [A-13], and N¹-([1,1′:3′,1″-terphen]-2′-yl-2,2″,3,3″,4,4″,5,5″,6,6″-d₁₀)benzene-1,2-diamine was used instead of N¹-(2-(t-butyl)phenyl)benzene-1,2-diamine.

### 7-4. Synthesis of Intermediate A-21

Intermediate A-21 was obtained in substantially the same manner as used to prepare Intermediate [A-9] of Synthesis Example 4, except that Intermediate [A-20] was used instead of Intermediate [A-8].

### 7-5. Synthesis of Intermediate A-22

Intermediate A-22 was obtained in substantially the same manner as used to prepare Intermediate [A-16] of Synthesis Example 5, except that Intermediate [A-21] was used instead of Intermediate [A-15].

### 7-6. Synthesis of Intermediate A-23

Intermediate A-23 was obtained in substantially the same manner as used to prepare Intermediate [A-7] of Synthesis Example 1, except that Intermediate [A-22] was used instead of Intermediate [A-6].

### 7-7. Synthesis of Compound 81

Compound 81 was obtained in substantially the same manner as in Synthesis Example 1, except that Intermediate [A-23] was used instead of Intermediate [A-7].

### Synthesis Example 8: Synthesis of Compound 88

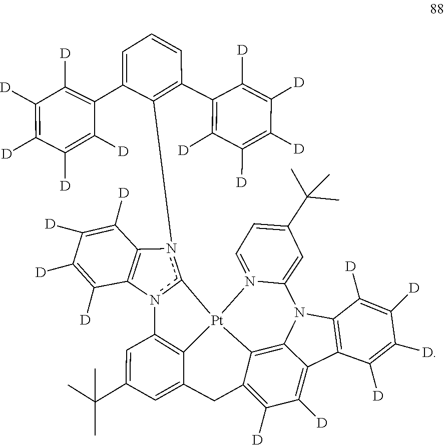

Compound 88 was obtained in substantially the same manner as in Synthesis Example 5, except that 2-bromo-9-(4-(t-butyl)pyridin-2-yl)-9H-carbazole-3,4,5,6,7,8-d₆ was used instead of Intermediate [A-11], and N¹-([1,1′:3′,1″-terphen]-2′-yl-2,2″,3,3″,4,4″,5,5″,6,6″-d₁₀)benzene-d₄-1,2-diamine was used instead of N¹-(2-(t-butyl)phenyl)benzene-1,2-diamine.

### Synthesis Example 9: Synthesis of Compound 96

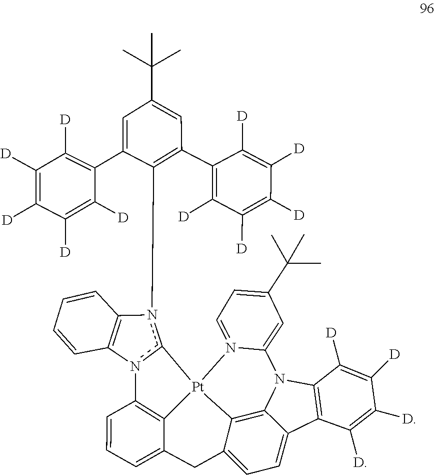

Compound 96 was obtained in substantially the same manner as in Synthesis Example 5, except that 2-bromo-9-(4-(t-butyl)pyridin-2-yl)-9H-carbazole-5,6,7,8-d₆ was used instead of Intermediate [A-11], and N¹-(5′(t-butyl)-[1,1′:3′,1″-terphen]-2′-yl-2,2″,3,3″,4,4″,5,5″,6,6″-d₁₀)benzene-d₄-1,2-diamine was used instead of N¹-(2-(t-butyl)phenyl)benzene-1,2-diamine.

### Synthesis Example 10: Synthesis of Compound 123

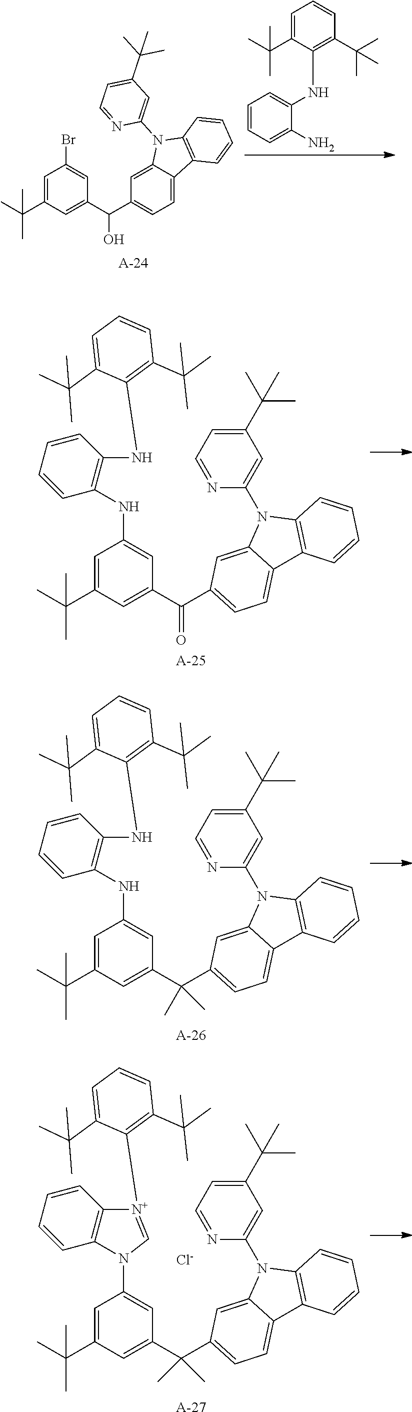

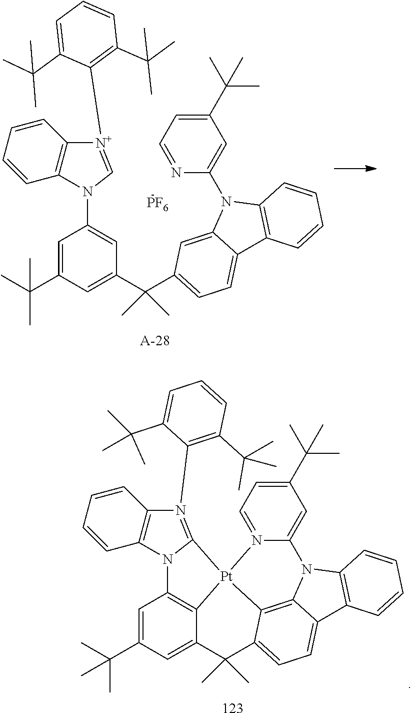

### 10-1. Synthesis of Intermediate A-25

Intermediate A-25 was obtained in substantially the same manner as to prepare Intermediate [A-14] of Synthesis Example 5, except that Intermediate [A-24] was used instead of Intermediate [A-13], and N¹-(2,6-di-t-butyl)phenyl)benzene-1,2-diamine was used instead of N¹-(2-(t-butyl)phenyl)benzene-1,2-diamine.

### 10-2. Synthesis of Intermediate A-26

Titanium tetrachloride (37.3 mL, 1 M solution, 37.3 mmol) was slowly added dropwise to 30 mL of a dichloromethane solution (−40° C.). Then, dimethylzinc (18.5 mL, 2 M solution, 37.3 mmol) was added dropwise thereto and stirred for 30 minutes. 4.5 g (6.0 mmol) of Intermediate [A-25] was added to the reaction solution, stirred for 2 hours, and stirred again at a temperature of −10° C. for 2 hours. After completion of the reaction, an extraction process was performed thereon using methylene chloride and distilled water. The extracted organic layer was washed with a saturated aqueous sodium chloride solution and dried using sodium sulfate. A residue obtained by removing the solvent therefrom was separated by column chromatography to obtain 3.69 g (4.8 mmol) of Intermediate A-26.

### 10-3. Synthesis of Intermediate A-27

Intermediate A-27 was obtained in substantially the same manner as used to prepare Intermediate [A-16] of Synthesis Example 5, except that Intermediate [A-26] was used instead of Intermediate [A-15].

### 10-4. Synthesis of Intermediate A-28

Intermediate A-28 was obtained in substantially the same manner as used to prepare Intermediate [A-7] of Synthesis Example 1, except that Intermediate [A-27] was used instead of Intermediate [A-6].

### 10-5. Synthesis of Compound 123

Compound 123 was obtained in substantially the same manner as in Synthesis Example 1, except that Intermediate [A-28] was used instead of Intermediate [A-7].

### Synthesis Example 11: Synthesis of Compound 140

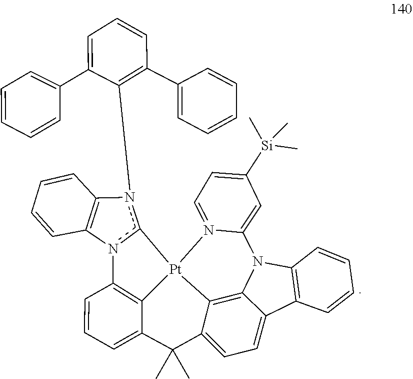

Compound 140 was obtained in substantially the same manner as in Synthesis Example 10, except that (3-bromophenyl)(9-(4-(trimethylsilyl)pyridin-2-yl)-9H-carbazol-2-yl)methanone was used instead of Intermediate [A-24], and N¹-([1,1′:3′,1″-terphen]-2′-yl)benzene-1,2-diamine was used instead of N¹-(2,6-di-t-butyl)phenyl)benzene-1,2-diamine.

### Synthesis Example 12: Synthesis of Compound 164

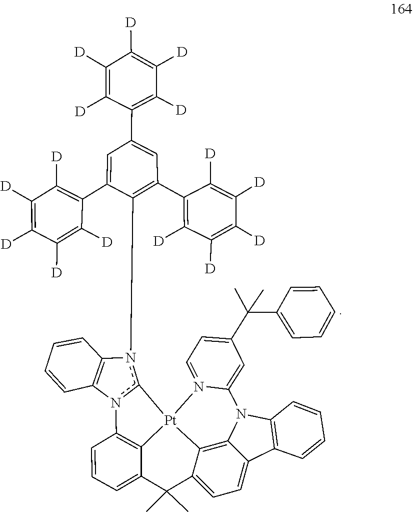

Compound 164 was obtained in substantially the same manner as in Synthesis Example 10, except that (3-bromophenyl)(9-(4-(2-phenylpropan-2-yl)pyridin-2-yl)-9H-carbazol-2-yl)methanone was used instead of Intermediate [A-24], and N¹-(5′-(phenyl-d₅)-[1,1′:3′,1″-terphen]-2′-yl-2,2″,3,3″,4,4″,5,5″,6,6″-d₁₀)benzene-1,2-diamine was instead of N¹-(2,6-di-t-butyl)phenyl)benzene-1,2-diamine.

### Synthesis Example 13: Synthesis of Compound 187

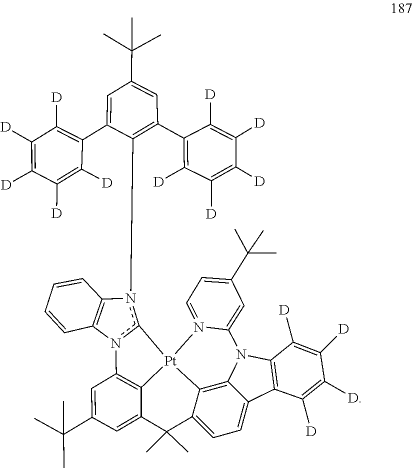

Compound 187 was obtained in substantially the same manner as in Synthesis Example 10, except that Intermediate [A-19] was used instead of Intermediate [A-24], and N¹-(5′(t-butyl)-[1,1′:3′,1″-terphen]-2′-yl-2,2″,3,3″,4,4″,5,5″,6,6″-d₁₀)benzene-1,2-diamine was used instead of N¹-(2,6-di-t-butyl)phenyl)benzene-1,2-diamine.

The compounds synthesized according to the Synthesis Examples above were identified by ¹H NMR and MS/FAB, and the results are shown in Table 1 below.

Compounds other than the compounds shown in Table 1 may be easily recognized by those skilled in the art by referring to the above synthesis routes and source materials.

TABLE 1

| Compound | | MS/FAB | |
|---|---|---|---|
| No. | ¹H NMR (CDCl₃, 400 MHz) | found | calc. |
| 1 | δ 8.73(d, 1H), 8.42(d, 1H), 8.19-8.15(m, 2H), | 719.1650 | 719.1649 |
| | 8.02(d, 1H), 7.58-7.50(m, 2H), 7.41-7.01(m, 14H), | | |
| | 6.84(d, 1H), 4.35(s, 2H) | | |
| 10 | δ 8.74(d, 1H), 8.42(d, 1H), 8.19(d, 1H), 7.58- | 831.2900 | 831.2901 |
| | 7.51(m, 2H), 7.41-7.30(m, 7H), 7.20-7.14(m, 3H), | | |
| | 7.00-6.95(m, 5H), 4.35(s, 2H), 1.41(s, 9H), 1.33(s, | | |
| | 9H) | | |
| 22 | δ 8.58(d, 1H), 8.42(d, 1H), 8.19(d, 1H), 7.58- | 886.2383 | 886.2384 |
| | 7.51(m, 2H), 7.40-7.19(m, 9H), 7.14-7.00(m, 14H), | | |
| | 6.84(d, 1H), 6.76(s, 1H), 6.65(d, 1H), 4.35(s, 2H) | | |
| 28 | δ 8.73(d, 1H), 8.42(d, 1H), 8.19-8.16(m, 2H), 8.02- | 770.2402 | 770.2400 |
| | 8.01(m, 1H), 7.58-7.50(m, 2H), 7.32-7.30(m, 2H), | | |
| | 7.20-7.08(m, 9H), 6.96-6.95(m, 2H), 6.84(d, 1H), | | |
| | 1.33(s, 9H) | | |
| 33 | δ 8.73(d, 1H), 8.42(d, 1H), 8.19-8.18(m, 1H), 7.58- | 949.3684 | 949.3683 |
| | 7.57(m, 1H), 7.51-7.50(m, 1H), 7.35-7.14(m, | | |
| | 16H), 6.96-6.95(m, 2H), 6.90(s, 1H), 4.35(s, 2H), | | |
| | 1.69(s, 6H), 1.41(s, 9H), 1.37(s, 9H) | | |
| 65 | δ 8.74(d, 1H), 8.42(d, 1H), 8.19(d, 1H), 7.58- | 1035.4625 | 1035.4624 |
| | 7.57(m, 1H), 7.51-7.50(m, 1H), 7.41-7.40(m, 2H), | | |
| | 7.31-7.30(m, 2H), 7.20-7.14(m, 3H), 6.96-6.95(m, | | |
| | 2H), 6.90(s, 1H), 4.35(s, 2H), 2.60(s, 6H), 2.18(s, | | |
| | 3H), 1.41(s, 9H), 1.32(s, 9H) | | |
| 81 | δ 8.74(d, 1H), 8.42(d, 1H), 8.20(d, 2H), 7.41- | 999.4530 | 999.4531 |
| | 7.39(m, 3H), 7.31-7.30(m, 2H), 7.15-7.14(m, 2H), | | |
| | 6.96-6.95(m, 2H), 6.90(s, 1H), 1.41(s, 9H), 1.32(s, | | |
| | 9H) | | |
| 88 | δ 8.74(d, 1H), 8.20(d, 2H), 7.41-7.39(m, 3H), 7.31- | 1003.4780 | 1003.4872 |
| | 7.30(m, 1H), 6.90(s, 1H), 4.35(s, 2H), 1.41(s, | | |
| | 9H), 1.32(s, 9H) | | |
| 96 | δ 8.74(d, 1H), 8.42(d, 1H), 7.99(s, 2H), 7.41- | 997.4406 | 997.4405 |
| | 7.40(m, 2H), 7.31(d, 1H), 7.19-7.14(m, 4H), 6.96- | | |
| | 6.95(m, 2H), 6.84(d, 1H), 4.35(s, 2H), 1.35(s, 9H), | | |
| | 1.32(s, 9H) | | |
| 123 | δ 8.74(d, 1H), 8.42(d, 1H), 8.19(d, 1H), 7.58- | 971.4465 | 971.4466 |
| | 7.57(m, 1H), 7.51-7.50(m, 1H), 7.41-7.40(m, 2H), | | |
| | 7.31-7.30(m, 2H), 7.20-7.14(m, 3H), 7.03-7.00(m, | | |
| | 3H), 6.95-6.90(m, 3H), 1.69(s, 6H), 1.41(s, 9H), | | |
| | 1.37(s, 18H), 1.32(s, 9H) | | |
| 140 | δ 8.71(d, 1H), 8.42(d, 1H), 8.20-8.19(m, 3H), | 971.2982 | 971.2983 |
| | 7.72(s, 1H), 7.58-7.30(m, 10H), 7.20-7.08(m, 10H), | | |
| | 6.96-6.95(m, 2H), 6.84(d, 1H), 1.69(s, 6H), 0.11(s, | | |
| | 9H) | | |
| 164 | δ 8.73(d, 1H), 8.42(d, 1H), 8.19(d, 1H), 8.00(s, 2H), | 1108.4623 | 1108.4625 |
| | 7.58-7.57(m, 1H), 7.51-7.50(m, 1H), 7.36-7.14(m, | | |
| | 13H), 6.96-6.95(m, 2H), 6.84(d, 1H), 1.69(s, 6H), | | |
| | 1.64(s, 6H) | | |
| 187 | δ 8.74(d, 1H), 8.42(d, 1H), 7.99(s, 2H), 7.41- | 1081.5345 | 1081.5344 |
| | 7.40(m, 2H), 7.31-7.30(m, 2H), 7.15-7.14(m, 2H), | | |
| | 6.96-6.95(m, 2H), 6.90(d, 1H), 1.69(s, 6H), 1.41(s, | | |
| | 9H), 1.36(s, 9H), 1.31(s, 9H) | | |

### Example 1

As an anode, a glass substrate with 15 Ω/cm² (1,200 Å) ITO thereon, which was manufactured by Corning Inc., was cut to a size of 50 mm×50 mm×0.7 mm, and the glass substrate was sonicated using isopropyl alcohol and pure water for 5 minutes each, and then ultraviolet (UV) light was irradiated for 30 minutes thereto and ozone was exposed thereto for cleaning. Then, the resultant glass substrate was loaded onto a vacuum deposition apparatus.

2-TNATA was vacuum-deposited on the glass substrate to form a hole injection layer having a thickness of 600 Å, and then, 4,4′-bis[N-(1-naphthyl)-N-phenylamino]biphenyl (hereinafter referred to as NPB) was vacuum-deposited on the hole injection layer to form a hole transport layer having a thickness of 300 Å.

HT29 and ETH66 (mixed hosts at a weight ratio 3:7) and Compound 1 (dopant, 10 wt %) were co-deposited on the hole transport layer to form an emission layer having a thickness of 400 Å. Subsequently, ETH2 was vacuum-deposited on the emission layer to form a hole blocking layer having a thickness of 50 Å. Then, Alq₃ was deposited on the hole blocking layer to form an electron transport layer having a thickness of 300 Å, LiF was deposited on the electron transport layer to form an electron injection layer having a thickness of 10 Å, and Al was vacuum-deposited as a cathode to a thickness of 3,000 Å to form a LiF/Al electrode, thereby completing the manufacture of a light-emitting device.

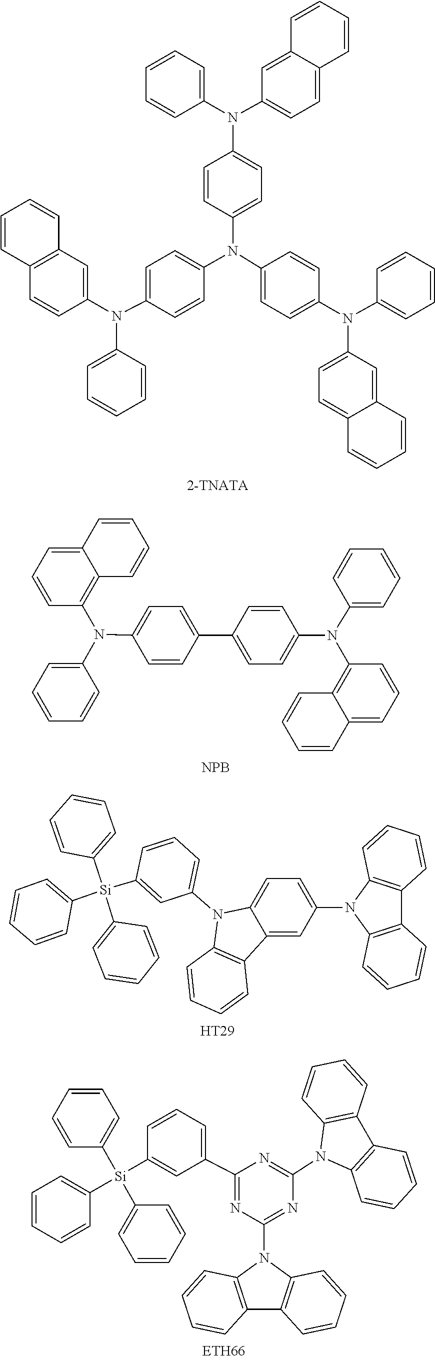

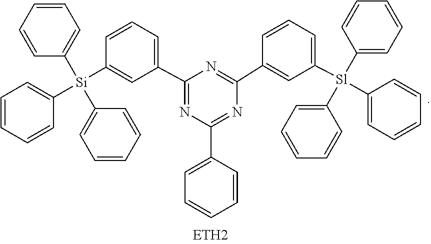

### Examples 2 to 13

Additional light-emitting devices were manufactured in substantially the same manner as in Example 1, except that the compounds shown in Table 2 were each used instead of Compound 1 as a dopant in forming an emission layer.

### Comparative Examples 1 to 4

Additional light-emitting devices were manufactured in substantially the same manner as in Example 1, except that Compounds A to D were each used instead of Compound 1 as a dopant in forming an emission layer.

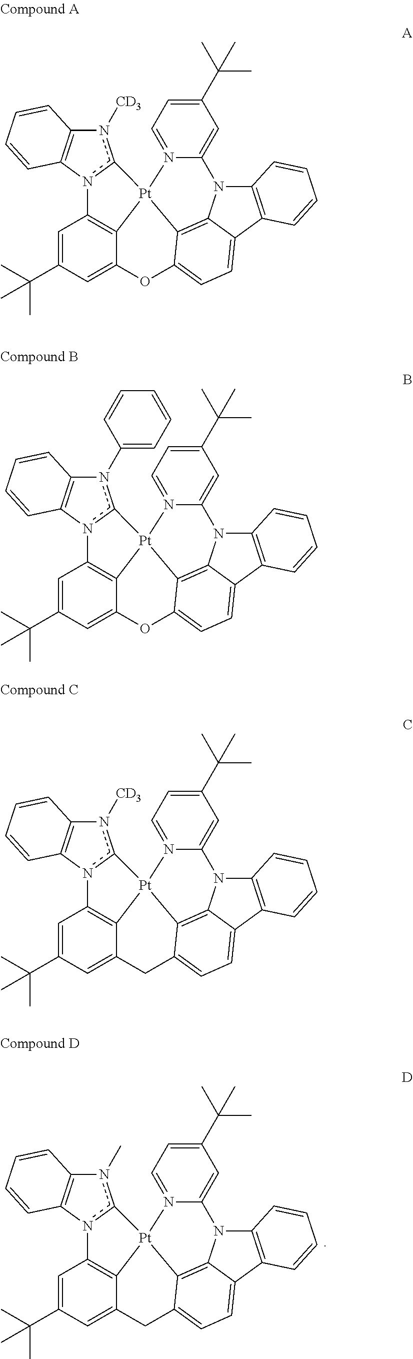

Regarding each of the light-emitting devices of Examples 1 to 13 and Comparative Examples 1 to 4, the driving voltage, luminance, luminescence efficiency, and maximum luminescence wavelength were measured using a Keithley SMU 236 and PR650 luminance meter, and the time until the initial luminance decreased by 95% (referred to as lifespan at T95) was measured. Results of the measurements are shown in Table 2:

TABLE 2

| | | | | Color | | Color | Maximum | |
|---|---|---|---|---|---|---|---|---|
| | Dopant in | | Driving | coordinate | | conversion | luminescence | |
| | emission | Luminance | voltage | CIE | Efficiency | efficiency | wavelength | Lifespan |
| | layer | (cd/m²) | (V) | (x, y) | (cd/A) | (cd/A/y) | (nm) | (T₉₅, hr) |
| Example 1 | 1 | 1000 | 4.6 | (0.14, 0.14) | 20.3 | 145 | 451 | 58 |
| Example 2 | 10 | 1000 | 4.7 | (0.14, 0.15) | 19.5 | 130 | 453 | 95 |
| Example 3 | 22 | 1000 | 5.0 | (0.14, 0.16) | 18.8 | 117.5 | 455 | 53 |
| Example 4 | 28 | 1000 | 4.7 | (0.14, 0.15) | 19.1 | 127.3 | 452 | 88 |
| Example 5 | 33 | 1000 | 4.8 | (0.14, 0.15) | 18.5 | 122.8 | 453 | 61 |
| Example 6 | 65 | 1000 | 4.3 | (0.13, 0.13) | 21.5 | 165.6 | 447 | 70 |
| Example 7 | 81 | 1000 | 4.7 | (0.14, 0.14) | 21.1 | 140.8 | 452 | 121 |
| Example 8 | 88 | 1000 | 4.6 | (0.14, 0.14) | 21.4 | 153.1 | 452 | 115 |
| Example 9 | 96 | 1000 | 4.5 | (0.14, 0.14) | 20.3 | 145 | 451 | 106 |
| Example 10 | 123 | 1000 | 4.8 | (0.14, 0.15) | 20.0 | 133.3 | 452 | 69 |
| Example 11 | 140 | 1000 | 4.9 | (0.14, 0.17) | 20.8 | 122.5 | 457 | 63 |
| Example 12 | 164 | 1000 | 4.8 | (0.14, 0.15) | 19.6 | 130.6 | 453 | 69 |
| Example 13 | 187 | 1000 | 4.7 | (0.14, 0.16) | 20.9 | 130.7 | 455 | 75 |
| Comparative | A | 1000 | 5.4 | (0.14, 0.17) | 15.2 | 88.1 | 457 | 10 |
| Example 1 | | | | | | | | |
| Comparative | B | 1000 | 5.0 | (0.14, 0.16) | 17.6 | 110 | 456 | 22 |
| Example 2 | | | | | | | | |
| Comparative | C | 1000 | 4.6 | (0.14, 0.14) | 16.5 | 117.8 | 452 | 26 |
| Example 3 | | | | | | | | |
| Comparative | D | 1000 | 4.6 | (0.14, 0.14) | 16.4 | 117.6 | 452 | 5 |
| Example 4 | | | | | | | | |

Referring to Table 2, it was confirmed that the light-emitting devices of Examples 1 to 13 using the compound according to the present disclosure as the dopant in the emission layer each showed a low or equivalent level of driving voltage, and exhibited improved (e.g., significantly improved) efficiency, color conversion efficiency, and/or lifespan, compared to the light-emitting devices of Comparative Examples 1 to 4.

For example, it was confirmed that, when the compound according to the present disclosure was used in the light-emitting device of the present disclosure, the light-emitting device had excellent characteristics in terms of driving voltage, efficiency, and/or lifespan.

According to the one or more embodiments, a light-emitting device including an organometallic compound may have a low driving voltage, high efficiency, and/or a long lifespan.

As used herein, the terms “substantially,” “about,” and similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

It should be understood that that embodiments described herein should be considered in a descriptive sense only, and not for purposes of limitation. Descriptions of features or aspects within each embodiment should typically be considered as being available for similar features or aspects in other embodiments. While one or more embodiments have been described with reference to the drawings, it will be understood by those of ordinary skill in the art that various changes in form and details may be made therein without departing from the spirit and scope as defined by the following claims and equivalents thereof.

What is claimed is:

1. A light-emitting device comprising:
a first electrode;
a second electrode facing the first electrode;
an interlayer between the first electrode and the second electrode and comprising an emission layer; and
an organometallic compound represented by Formula 1-1 or 1-2: 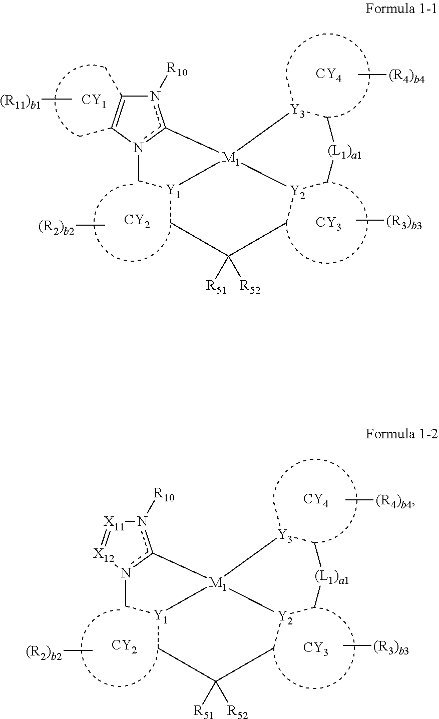
wherein, in Formulae 1-1 and 1-2,
M₁ is platinum (Pt), palladium (Pd), copper (Cu), silver (Ag), gold (Au), rhodium (Rh), iridium (Ir), ruthenium (Ru), osmium (Os), titanium (Ti), zirconium (Zr), hafnium (Hf), europium (Eu), terbium (Tb), or thulium (Tm),
Y₁ to Y₃ are each independently N or C,
CY₁ to CY₄ are each independently a C₃-C₆₀ carbocyclic group or a C₁-C₆₀ heterocyclic group,
X₁₁ is N or C(R₁₂) and X₁₂ is N or C(R₁₃),
L₁ is a single bond, *—O—*′, *—S—*′, *—Se—*′, *—S(═O)₂—*′, *—C(R₆₁)(R₆₂)—*′, *—C(R₆₁)═*′, *═C(R₆₁)—*′, *—C(R₆₁)═C(R₆₂)—*′, *—C(═O)—*′, *—C(═S)—*′, *—C≡C—*′, *—B(R₆₁)—*′, *—N(R₆₁)—*′, *—P(R₆₁)*′, *—Si(R₆₁)(R₆₂)*′, *—P(═O)(R₆₁)—*′, or *—Ge(R₆₁)(R₆₂)—*′,
a1 is an integer from 1 to 3,
R₁₀ is a C₃-C₆₀ carbocyclic group unsubstituted or substituted with at least one R₁₀ₐ or a C₁-C₆₀ heterocyclic group unsubstituted or substituted with at least one R₁₀ₐ,
R₂ to R₄, R₁₁ to R₁₃, R₅₁, R₅₂, R₆₁, and R₆₂ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b1 to b4 are each independently an integer from 0 to 10,
two or more groups selected from the b1 R₁₁(s), R₁₂, R₁₃, the b2 R₂(s), the b3 R₃(s), the b4 R₄(s), R₅₁, R₅₂, R₆₁, and R₆₂ are optionally linked together to form a C₃-C₆₀ carbocyclic group unsubstituted or substituted with at least one R₁₀ₐ or a C₁-C₆₀ heterocyclic group unsubstituted or substituted with at least one R₁₀ₐ, and
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

2. The light-emitting device of claim 1, wherein:
the first electrode is an anode,
the second electrode is a cathode,
the interlayer further comprises a hole transport region between the first electrode and the emission layer, and an electron transport region between the emission layer and the second electrode,
the hole transport region comprises a hole injection layer, a hole transport layer, an emission auxiliary layer, an electron blocking layer, or any combination thereof, and
the electron transport region comprises a buffer layer, a hole blocking layer, an electron control layer, an electron transport layer, an electron injection layer, or any combination thereof.

3. The light-emitting device of claim 1, wherein the emission layer comprises the organometallic compound.

4. The light-emitting device of claim 1, wherein:
the emission layer comprises a host and a dopant, and
the dopant comprises the organometallic compound.

5. The light-emitting device of claim 4, wherein the host comprises two different kinds of hosts.

6. The light-emitting device of claim 4, wherein the host comprises a hole transport host and an electron transport host.

7. The light-emitting device of claim 1, wherein the emission layer is to emit blue light having a maximum luminescence wavelength in a range of about 440 nm to about 475 nm.

8. The light-emitting device of claim 1, further comprising a first capping layer outside the first electrode and/or a second capping layer outside the second electrode,
wherein at least one of the first capping layer or the second capping layer has a refractive index of equal to or greater than 1.6 at a wavelength of 589 nm.

9. An electronic apparatus comprising the light-emitting device of claim 1.

10. The electronic apparatus of claim 9, further comprising a color filter, a color conversion layer, a touch screen layer, a polarizing layer, or any combination thereof.

11. An organometallic compound represented by Formula 1-1 or 1-2: 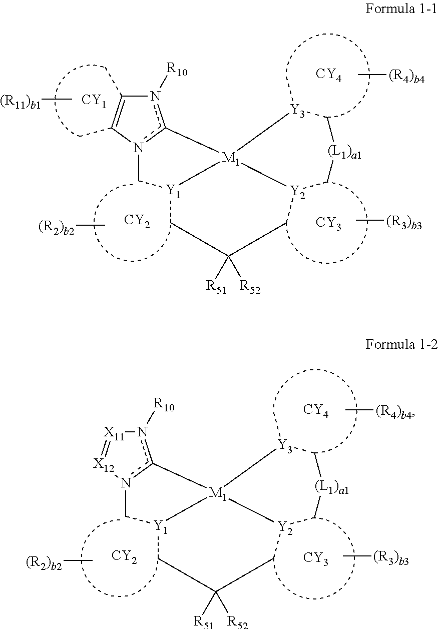
wherein, in Formulae 1-1 and 1-2,
M₁ is platinum (Pt), palladium (Pd), copper (Cu), silver (Ag), gold (Au), rhodium (Rh), iridium (Ir), ruthenium (Ru), osmium (Os), titanium (Ti), zirconium (Zr), hafnium (Hf), europium (Eu), terbium (Tb), or thulium (Tm),
Y₁ to Y₃ are each independently N or C,
CY₁ to CY₄ are each independently a C₃-C₆₀ carbocyclic group or a C₁-C₆₀ heterocyclic group,
X₁₁ is N or C(R₁₂) and X₁₂ is N or C(R₁₃),
L₁ is a single bond, *—O—*′, *—S—*′, *—Se—*′, *—S(═O)₂—*′, *—C(R₆₁)(R₆₂)—*′ *—C(R₆₁)=*′, *═C(R₆₁)—*′, *—C(R₆₁)═C(R₆₂)—*′, *—C(═O)—*′, *—C(═S)—*′, *—C≡C—*′, *—B(R₆₁)—*′, *—N(R₆₁)—*′, *—P(R₆₁)*′, *—Si(R₆₁)(R₆₂)*′, *—P(═O)(R₆₁)—*′, or *—Ge(R₆₁)(R₆₂)—*′,
a1 is an integer from 1 to 3,
R₁₀ is a C₃-C₆₀ carbocyclic group unsubstituted or substituted with at least one R₁₀ₐ or a C₁-C₆₀ heterocyclic group unsubstituted or substituted with at least one R₁₀ₐ,
R₂ to R₄, R₁₁ to R₁₃, R₅₁, R₅₂, R₆₁, and R₆₂ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
b1 to b4 are each independently an integer from 0 to 10,
two or more groups selected from the b1 R₁₁(s), R₁₂, R₁₃, the b2 R₂(s), the b3 R₃(s), the b4 R₄(s), R₅₁, R₅₂, R₆₁, and R₆₂ are optionally linked together to form a C₃-C₆₀ carbocyclic group unsubstituted or substituted with at least one R₁₀ₐ or a C₁-C₆₀ heterocyclic group unsubstituted or substituted with at least one R₁₀ₐ, and
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
wherein Q₁ to Q₃, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

12. The organometallic compound of claim 11, wherein: 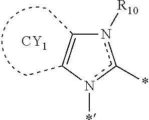
in Formula 1-1 is a group represented by Formula CY1-1;
CY₂ in Formulae 1-1 and 1-2 is a group represented by one of Formulae CY2-1 to CY2-9;
CY₃ in Formulae 1-1 and 1-2 is a group represented by one of Formulae CY3-1 to CY3-9; and/or
CY₄ in Formulae 1-1 and 1-2 is a group represented by one of Formulae CY4-1 to CY4-9: 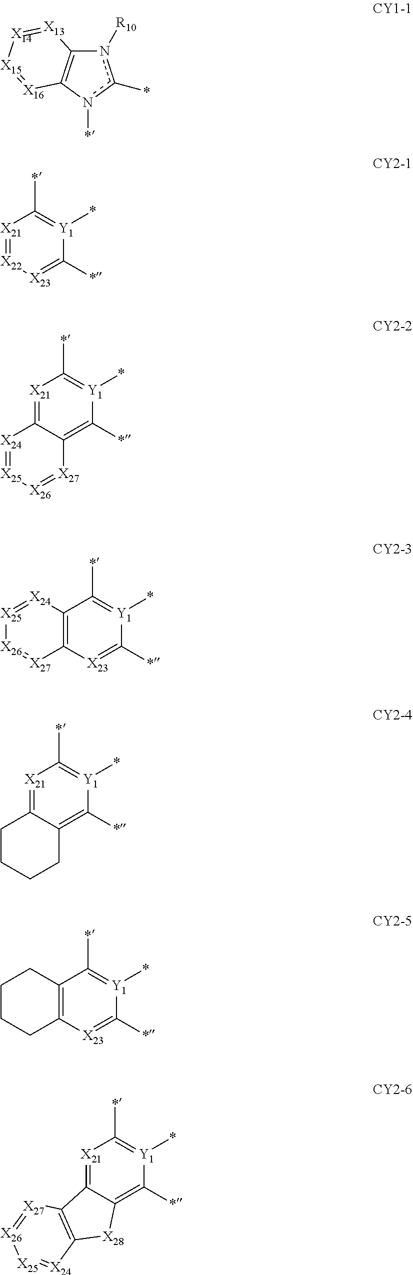 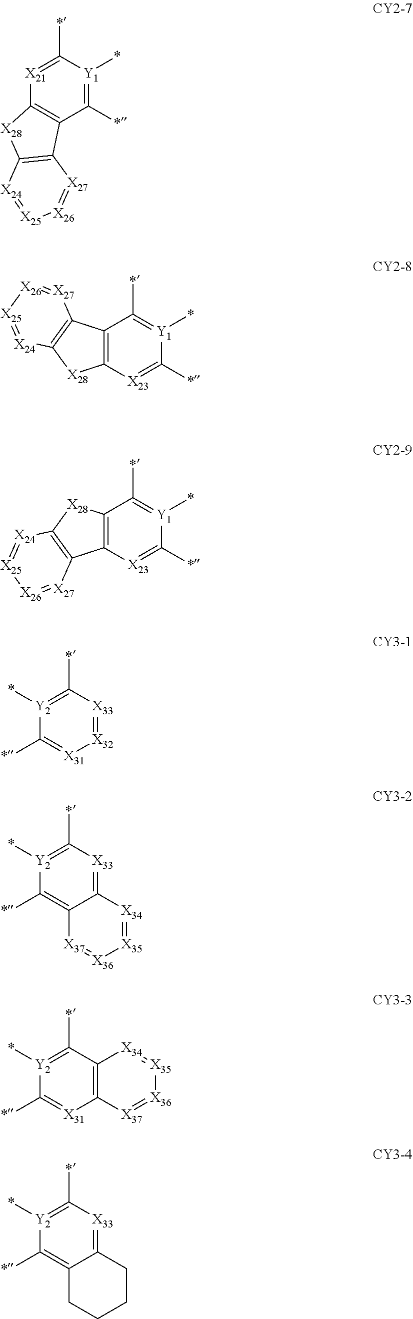 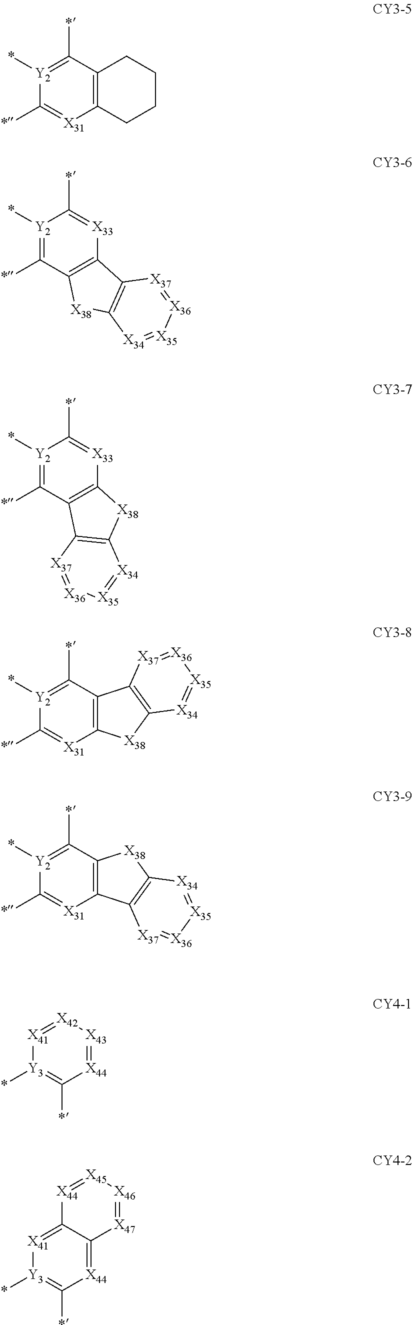 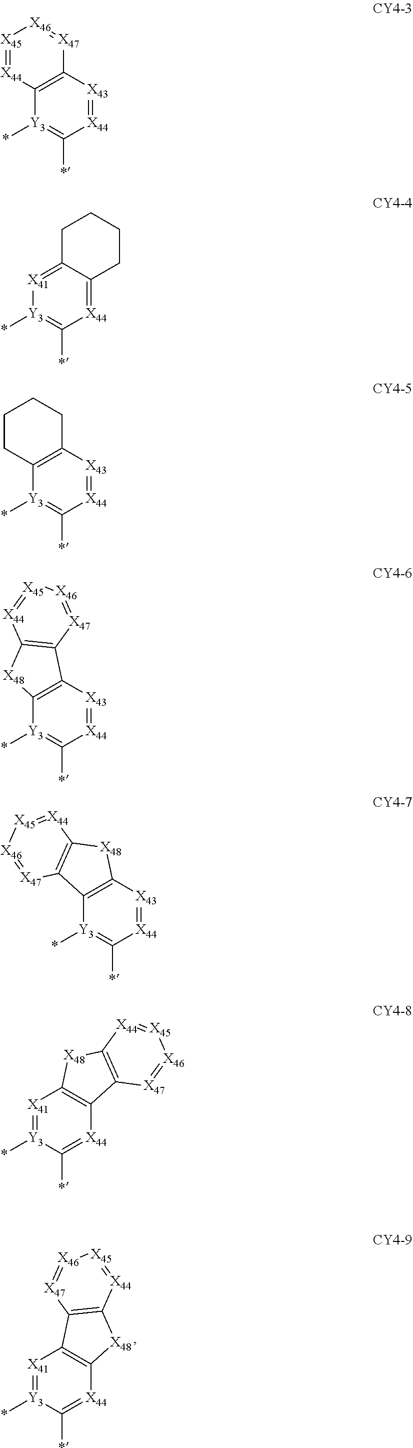
and
wherein, in Formulae CY1-1, CY2-1 to CY2-9, CY3-1 to CY3-9, and CY4-1 to CY4-9,
X₁₃ to X₁₆, X₂₁ to X₂₇, X₃₁ to X₃₇, and X₄₁ to X₄₇ are each independently N or C,
X₂₈, X₃₈, and X₄₈ are each independently O, S, N, C, or Si,
R₁₀ and Y₁ to Y₃ are each independently the same as described above,
* indicates a binding site to M, and
*′ and *″ each indicate a binding site to a neighboring atom.

13. The organometallic compound of claim 11, wherein R₁₀ is a phenyl group unsubstituted or substituted with at least one R_{10b}, and
R_{10b} is deuterium, —F, —Cl, —Br, —I, a hydroxyl group, a cyano group, a C₁-C₂₀ alkyl group, a C₁-C₂₀ alkyl group substituted with at least one deuterium, a C₁-C₂₀ alkyl group substituted with at least one phenyl group, a C₁-C₂₀ alkoxy group, a phenyl group, a biphenyl group, a naphthyl group, a fluorenyl group, a spiro-bifluorenyl group, a pyridinyl group, a pyrazinyl group, a pyrimidinyl group, a pyridazinyl group, or a triazinyl group; or
a phenyl group, a biphenyl group, a naphthyl group, a fluorenyl group, a spiro-bifluorenyl group, a pyridinyl group, a pyrazinyl group, a pyrimidinyl group, a pyridazinyl group, or a triazinyl group, each substituted with at least one deuterium.

14. The organometallic compound of claim 11, wherein R₁₀ is a group represented by one of Formulae 10-1 to 10-64: 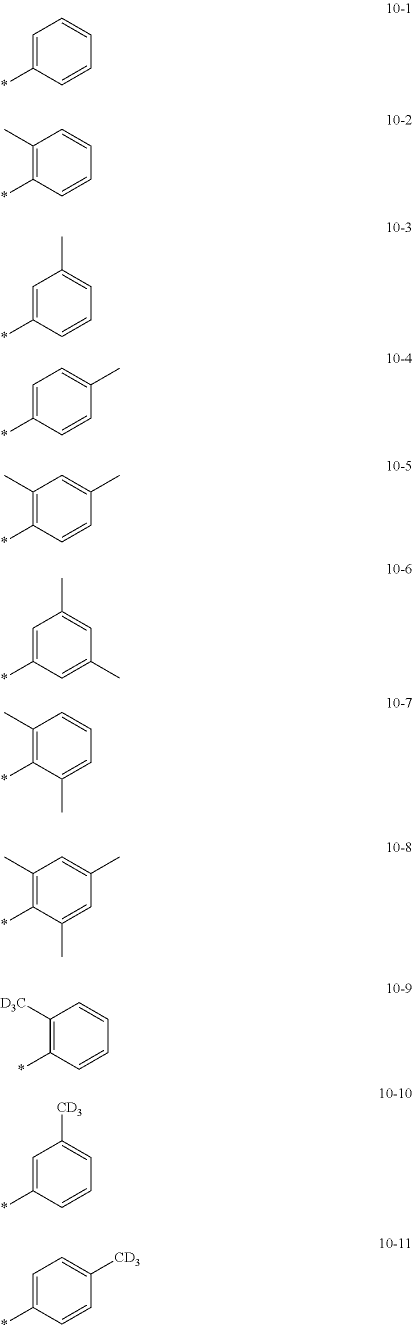 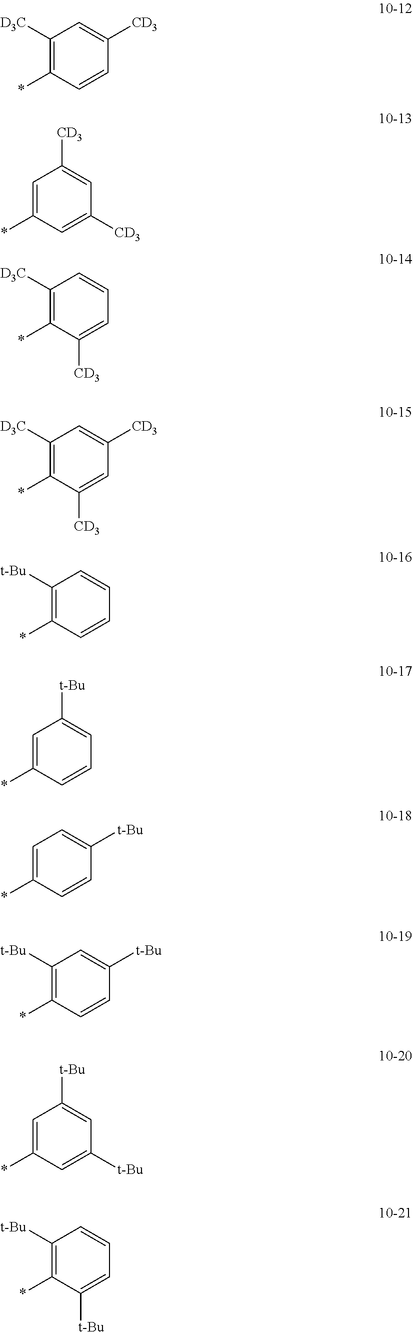 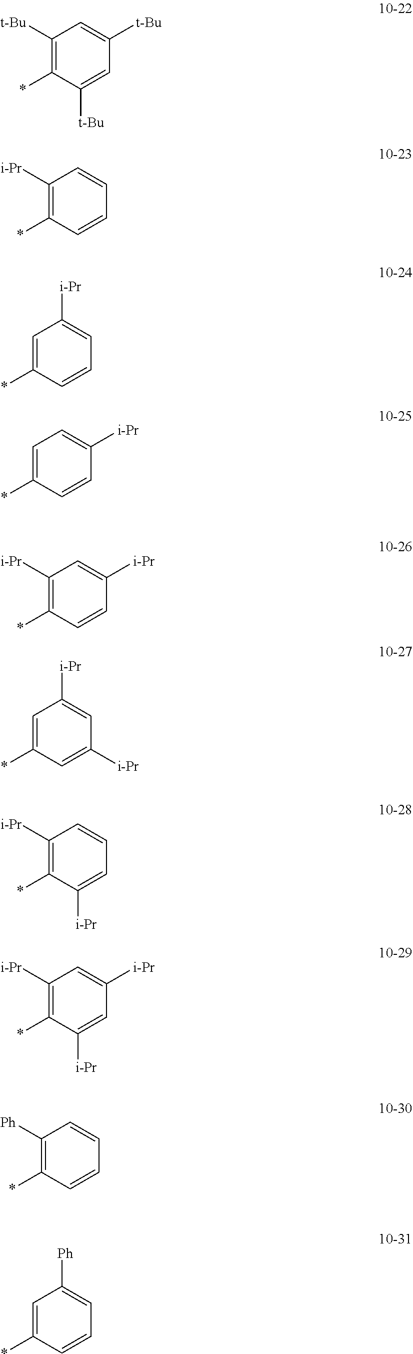 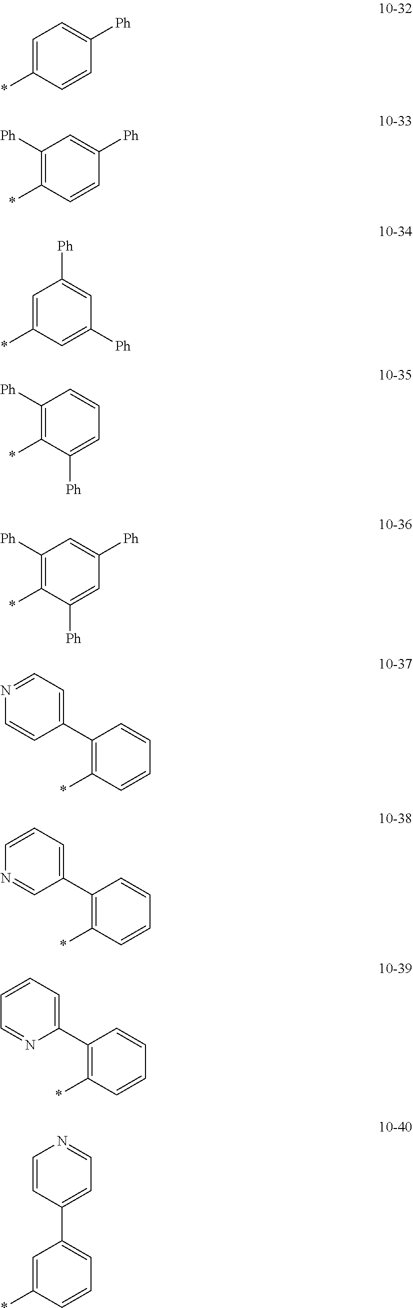 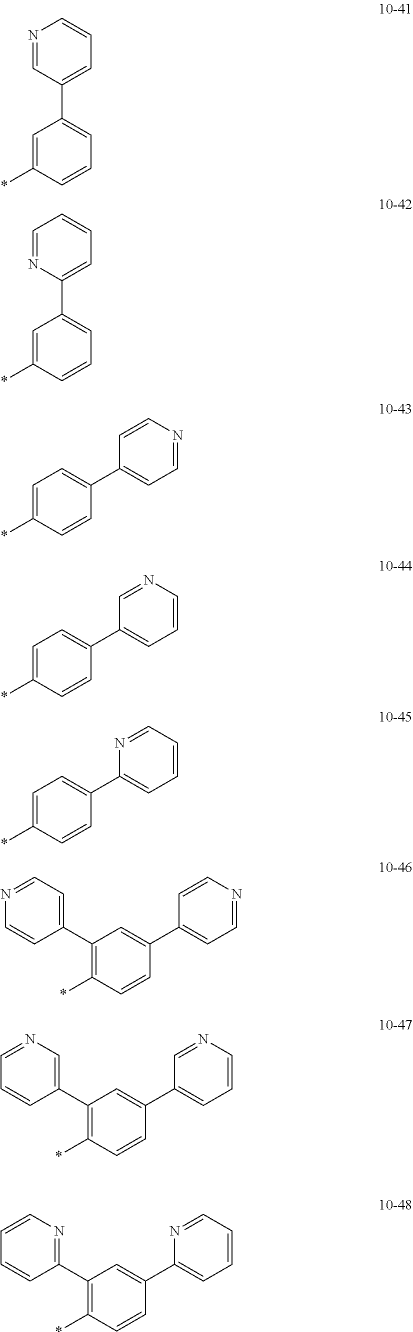 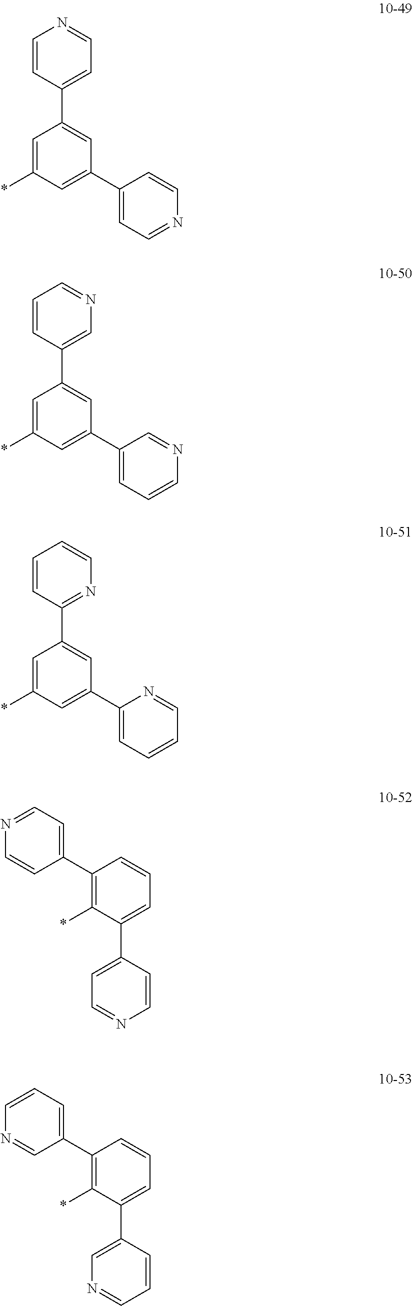 [SMILES: *c1cc(-c2ccncc2)cc(-c2ccncc2)c1 ; *c1cc(-c2cccnc2)cc(-c2cccnc2)c1 ; *c1cc(-c2ccccn2)cc(-c2ccccn2)c1 ; *c1c(-c2ccncc2)cccc1-c1ccncc1 ; *c1c(-c2cccnc2)cccc1-c1cccnc1] 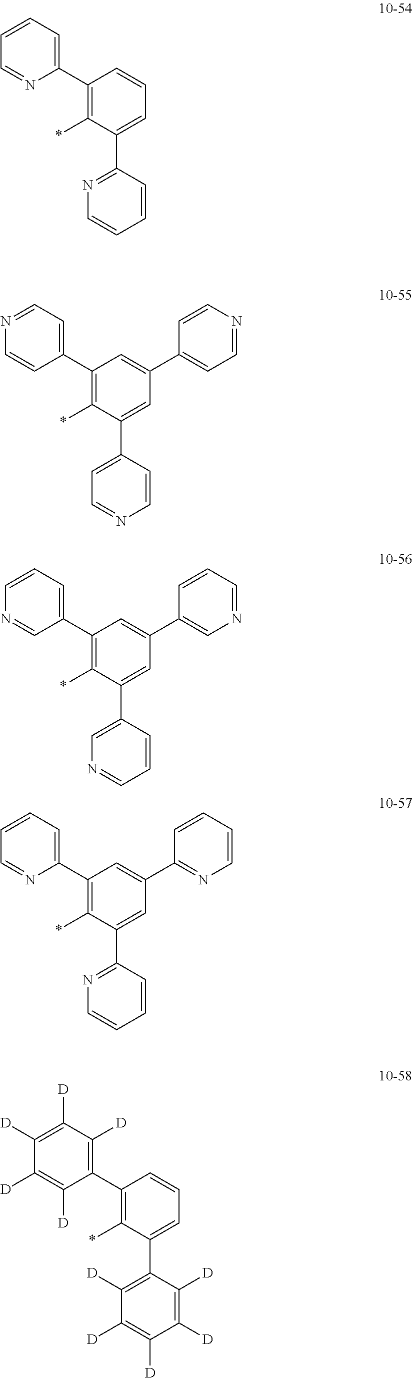 [SMILES: *c1c(-c2ccccn2)cccc1-c1ccccn1 ; *c1c(-c2ccncc2)cc(-c2ccncc2)cc1-c1ccncc1 ; *c1c(-c2cccnc2)cc(-c2cccnc2)cc1-c1cccnc1 ; *c1c(-c2ccccn2)cc(-c2ccccn2)cc1-c1ccccn1 ; *c1c(-c2c([2H])c([2H])c([2H])c([2H])c2[2H])cccc1-c1c([2H])c([2H])c([2H])c([2H])c1[2H]] 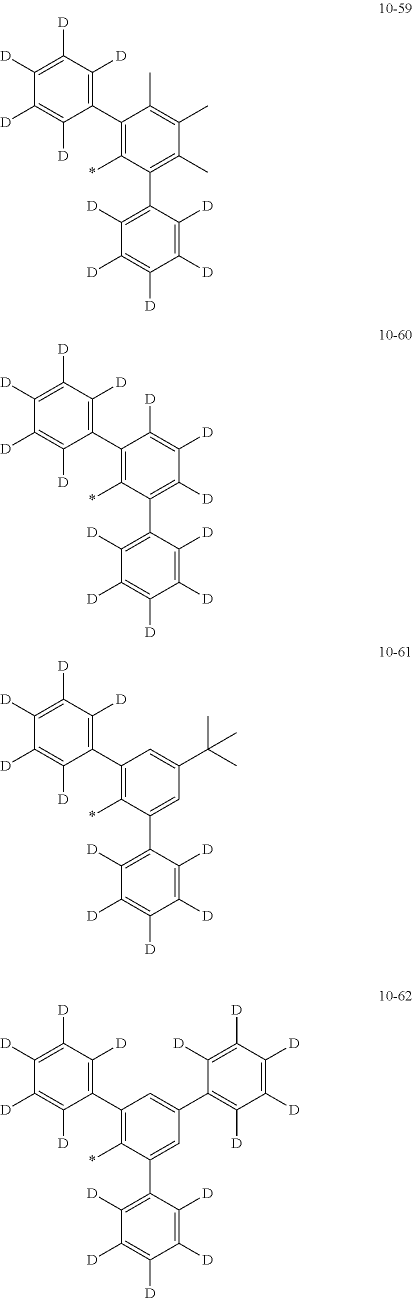 [SMILES: *c1c(-c2c([2H])c([2H])c([2H])c([2H])c2[2H])c(C)c(C)c(C)c1-c1c([2H])c([2H])c([2H])c([2H])c1[2H] ; *c1c(-c2c([2H])c([2H])c([2H])c([2H])c2[2H])c([2H])c([2H])c([2H])c1-c1c([2H])c([2H])c([2H])c([2H])c1[2H] ; *c1c(-c2c([2H])c([2H])c([2H])c([2H])c2[2H])cc(C(C)(C)C)cc1-c1c([2H])c([2H])c([2H])c([2H])c1[2H] ; *c1c(-c2c([2H])c([2H])c([2H])c([2H])c2[2H])cc(-c2c([2H])c([2H])c([2H])c([2H])c2[2H])cc1-c1c([2H])c([2H])c([2H])c([2H])c1[2H]] 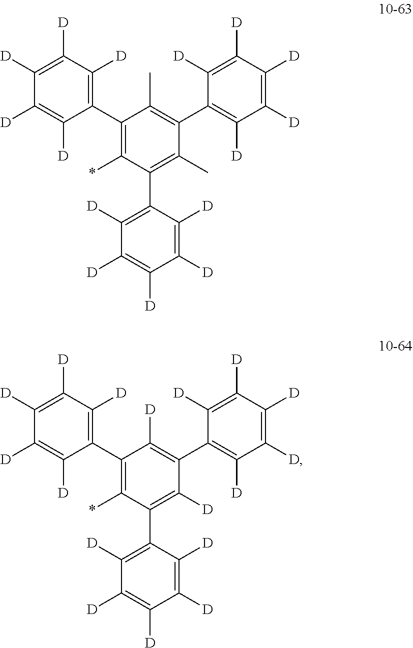
and
wherein, in Formulae 10-1 to 10-64,
t-Bu is a tert-butyl group,
i-Pr is an isopropyl group,
Ph is a phenyl group, and
* indicates a binding site to a neighboring atom.

15. The organometallic compound of claim 11, wherein:
R₂ to R₄, R₁₁ to R₁₃, R₆₁, and R₆₂ are each independently hydrogen, deuterium, —F, —Cl, —Br, —I, a hydroxyl group, a cyano group, a nitro group, —CH₃, —CD₃, —CD₂H, —CDH₂, —CF₃, —CF₂H, or —CFH₂;
a C₁-C₂₀ alkyl group and a C₁-C₂₀ alkoxy group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a naphthyl group, a pyridinyl group, a pyrimidinyl group, or any combination thereof;
a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, or an imidazopyrimidinyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantyl group, a norbornyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or
—Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and
wherein Q₁ to Q₃ are each independently hydrogen, deuterium, —F, —Cl, —Br, —I, a hydroxyl group, a cyano group, a nitro group, a C₁-C₂₀ alkyl group, a C₁-C₂₀ alkoxy group, or a C₃-C₂₀ carbocyclic group or a C₁-C₂₀ heterocyclic group, each unsubstituted or substituted with deuterium, —F, a cyano group, a C₁-C₂₀ alkyl group, a C₁-C₂₀ alkoxy group, a phenyl group, a biphenyl group, or any combination thereof.

16. The organometallic compound of claim 11, wherein R₅₁ and R₅₂ are each independently hydrogen, deuterium, or a C₁-C₁₀ alkyl group unsubstituted or substituted with deuterium, —F, —Cl, —Br, —I, or any combination thereof.

17. The organometallic compound of claim 11, wherein a moiety represented by 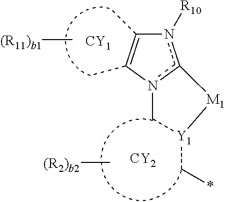
in Formula 1-1 is a group represented by Formula L-1: 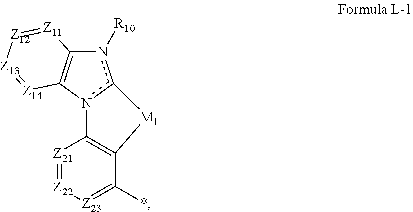
and
wherein, in Formula L-1,
Z₁₁ is N or C(R₁₄), Z₁₂ is N or C(R₁₅), Z₁₃ is N or C(R₁₆), and Z₁₄ is N or C(R₁₇),
Z₂₁ is N or C(R₂₁), Z₂₂ is N or C(R₂₂), and Z₂₃ is N or C(R₂₃),
R₁₄ to R₁₇ are each independently the same as described in connection with R₁₁,
R₂₁ to R₂₃ are each independently the same as described in connection with R₂,
M₁ and R₁₀ are each independently the same as described above, and
* indicates a binding site to a neighboring atom.

18. The organometallic compound of claim 11, wherein a moiety represented by 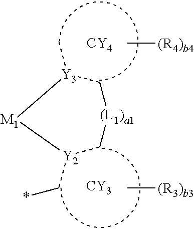
in Formulae 1-1 and 1-2 is a group represented by Formula L-2: 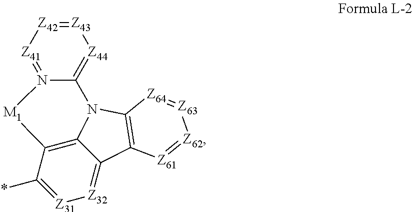
and
wherein, in Formula L-2,
Z₃₁ is N or C(R₃₁), and Z₃₂ is N or C(R₃₂),
Z₄₁ is N or C(R₄₁), Z₄₂ is N or C(R₄₂), Z₄₃ is N or C(R₄₃), and Z₄₄ is N or C(R₄₄),
Z₆₁ is N or C(R₆₁₁), Z₆₂ is N or C(R₆₁₂), Z₆₃ is N or C(R₆₁₃), and Z₆₄ is N or C(R₆₁₄),
R₃₁ and R₃₂ are each independently the same as described in connection with R₃,
R₄₁ to R₄₄ are each independently the same as described in connection with R₄, and
R₆₁₁ to R₆₁₄ are each independently the same as described in connection with R₁₀ₐ.

19. The organometallic compound of claim 11, wherein the organometallic compound is represented by Formula 1-1A: 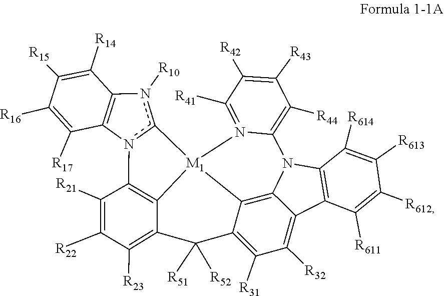
and
wherein, in Formula 1-1A,
R₁₄ to R₁₇ are each independently the same as described in connection with R₁₁,
R₂₁ to R₂₃ are each independently the same as described in connection with R₂,
R₃₁ and R₃₂ are each independently the same as described in connection with R₃,
R₄₁ to R₄₄ are each independently the same as described in connection with R₄,
R₆₁₁ to R₆₁₄ are each independently the same as described in connection with R₁₀ₐ, and
M₁, R₁₀, R₅₁, and R₅₂ are each independently the same as described above.

20. The organometallic compound of claim 11, wherein the organometallic compound is one of Compounds 1 to 188: 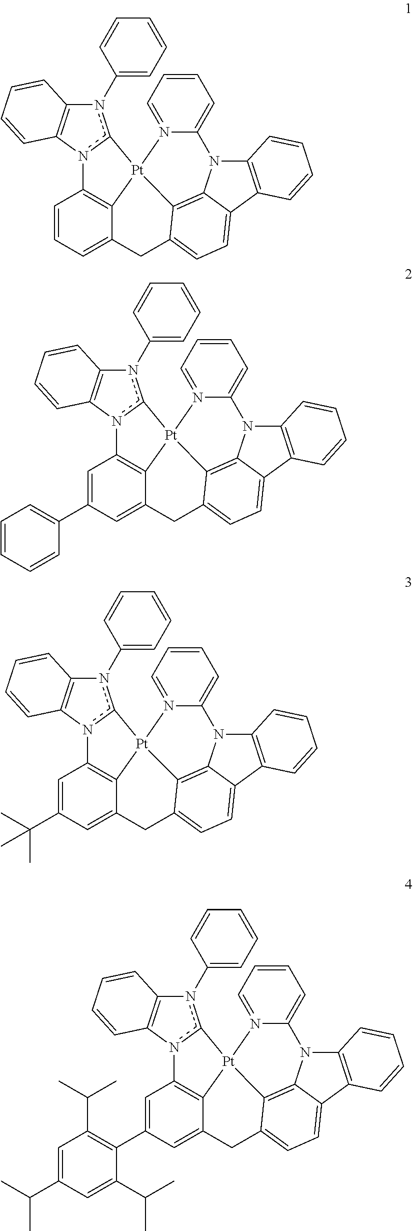 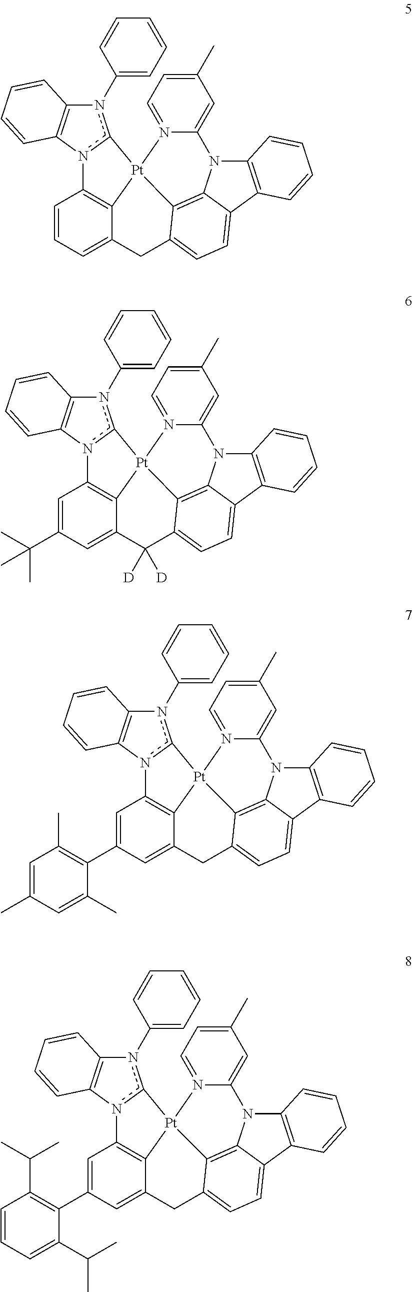 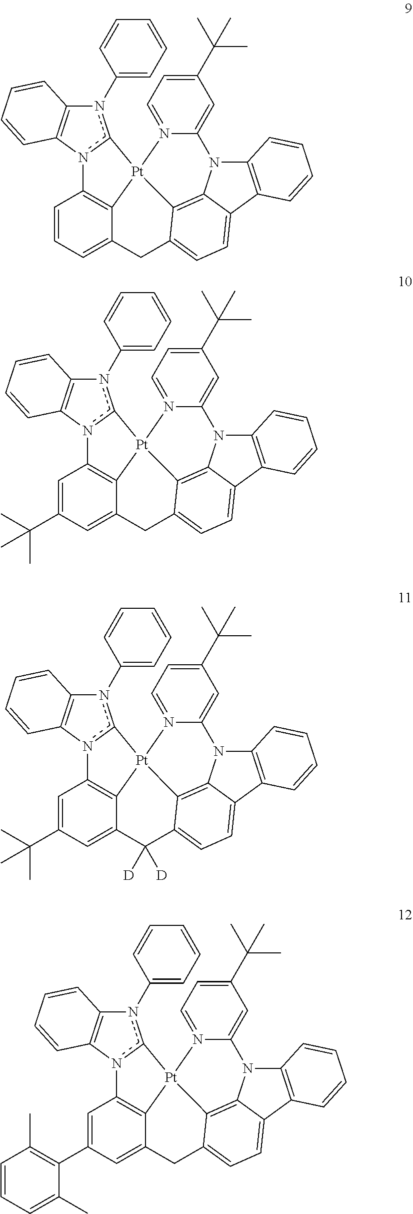 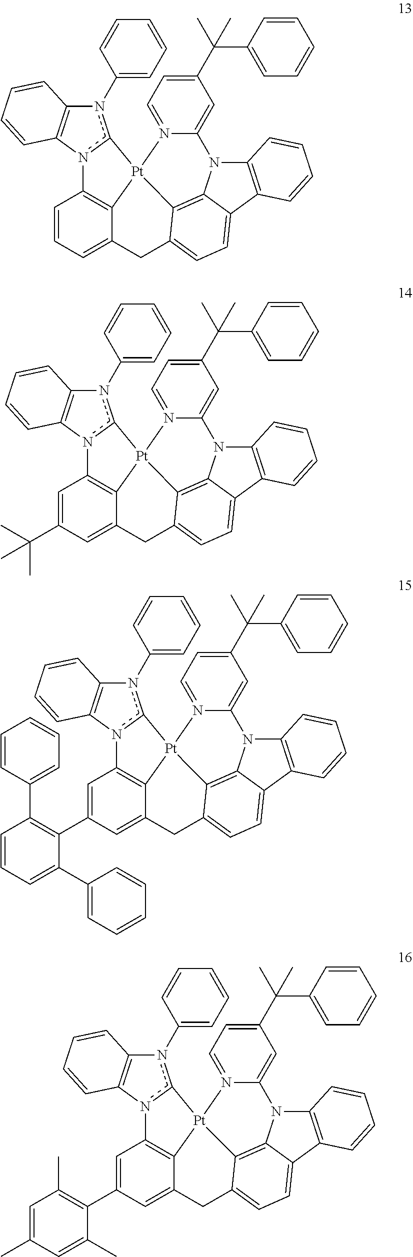 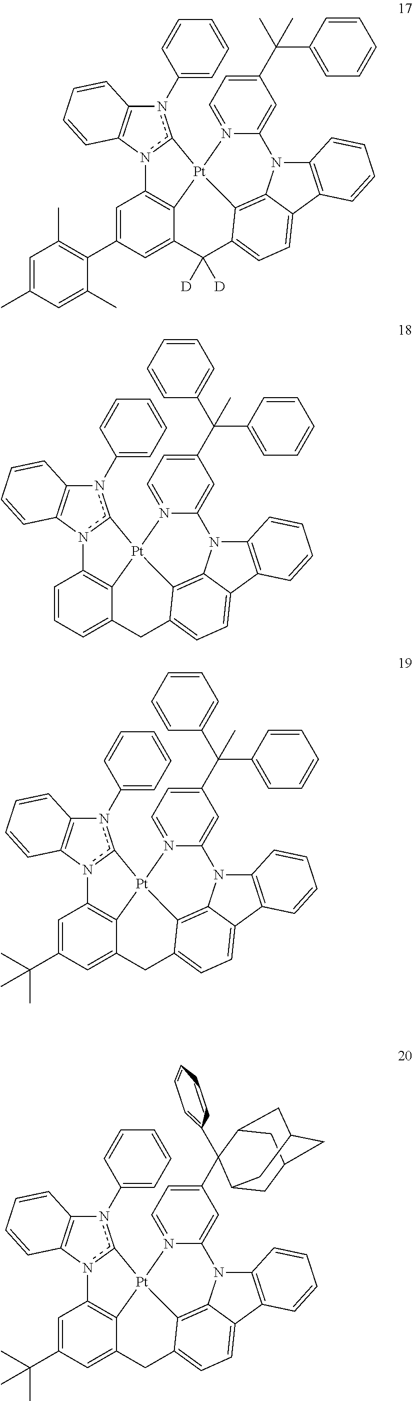 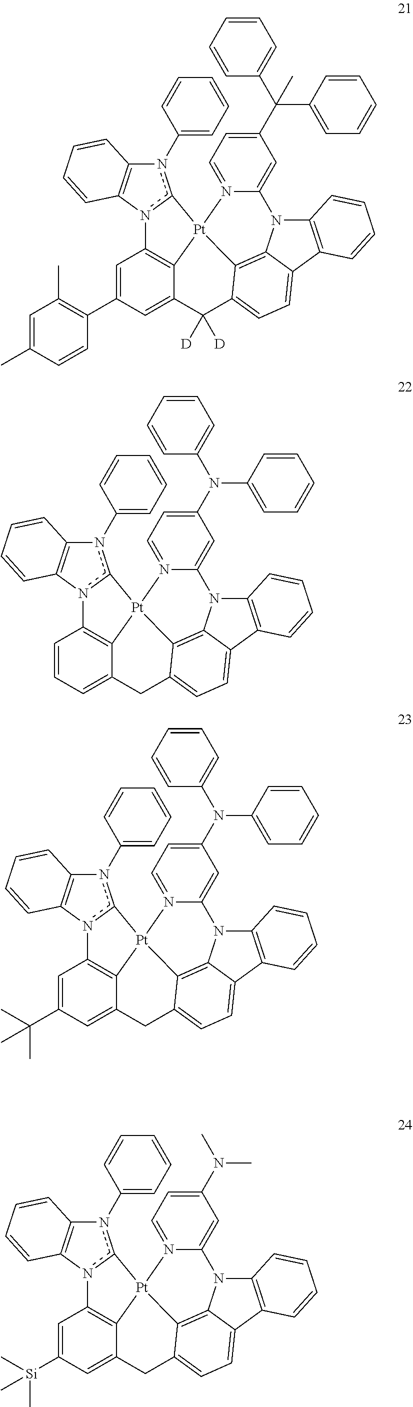 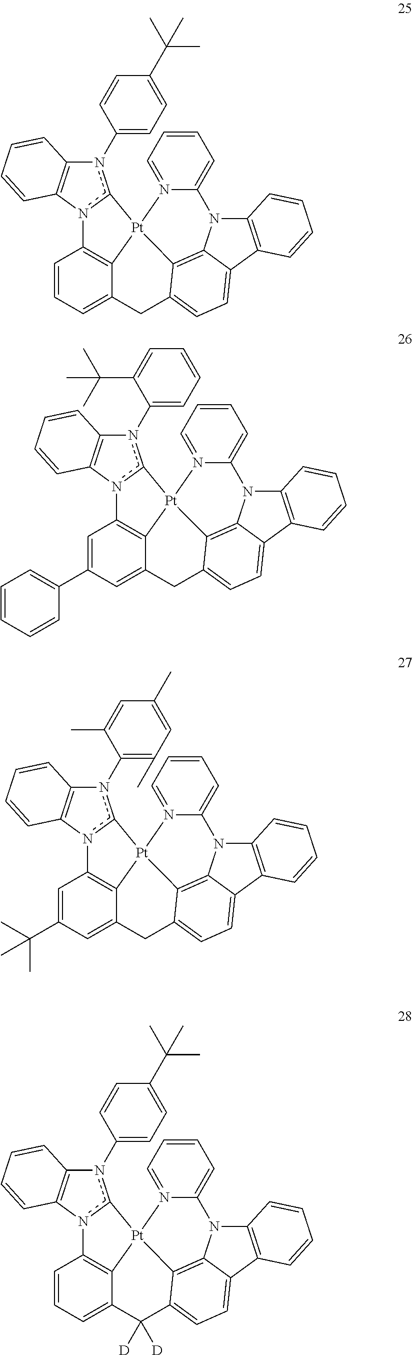 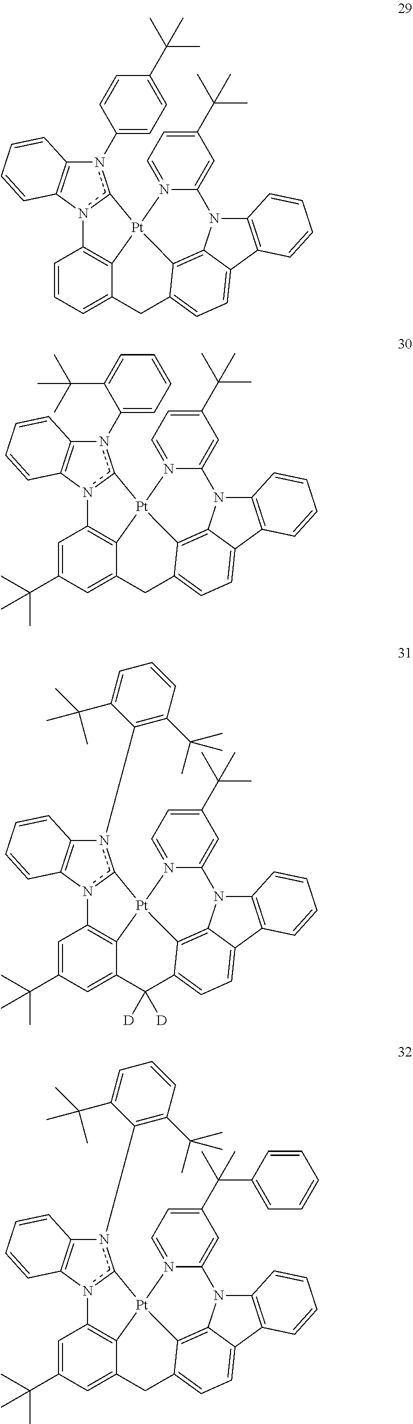 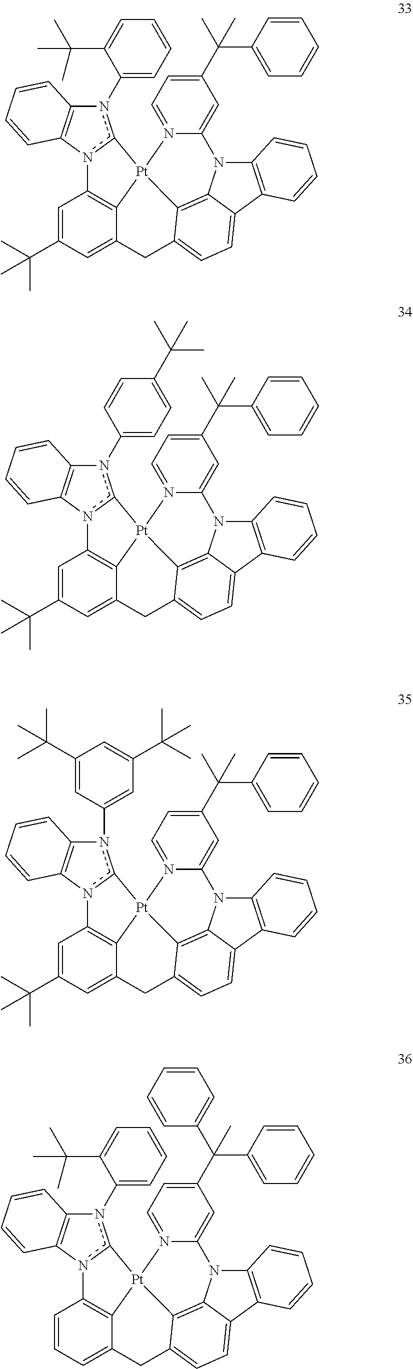 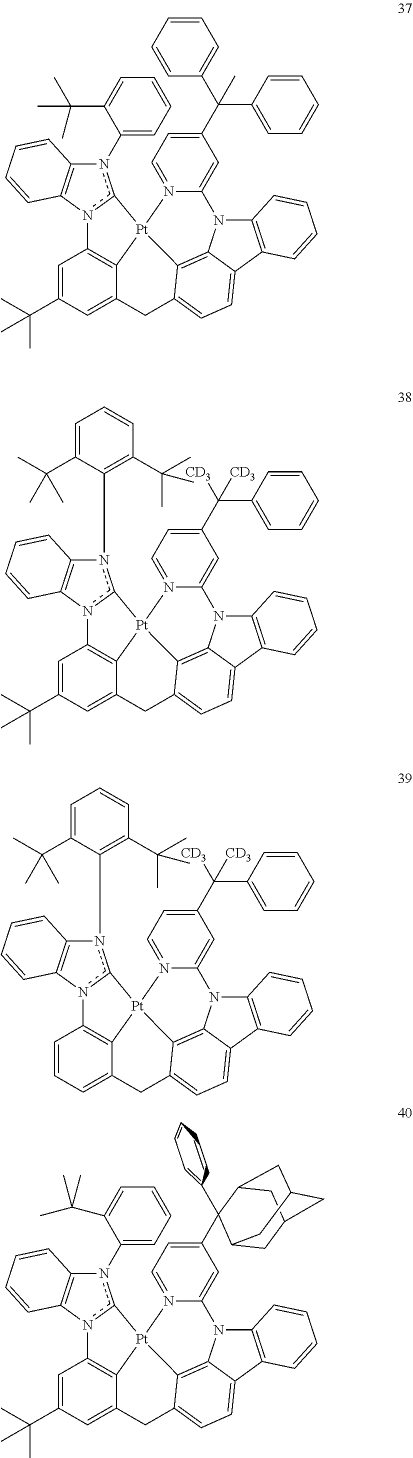 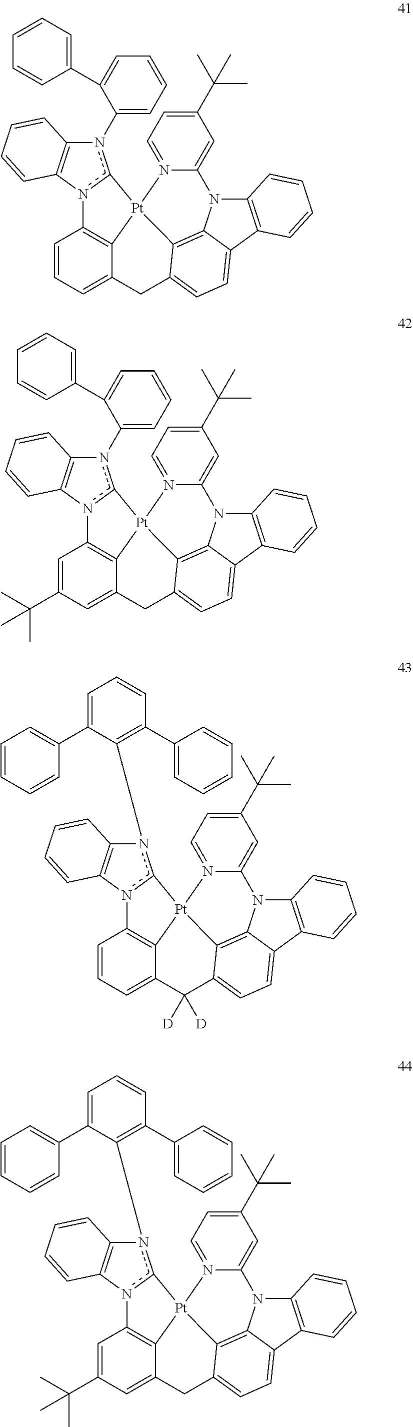 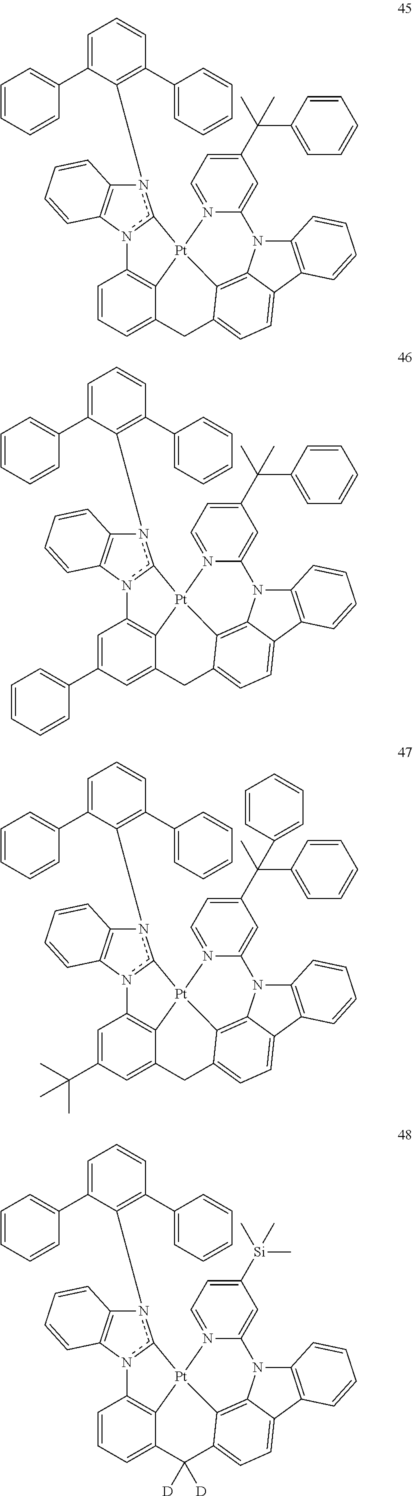 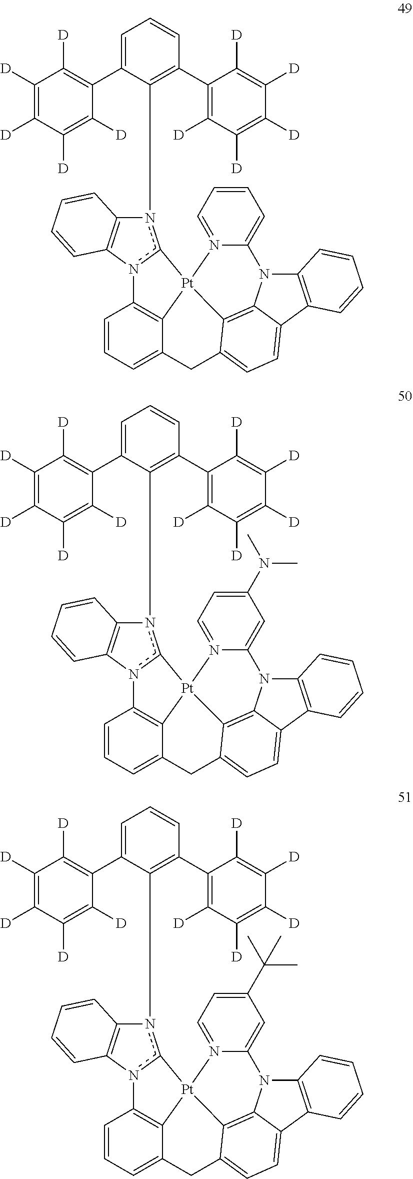 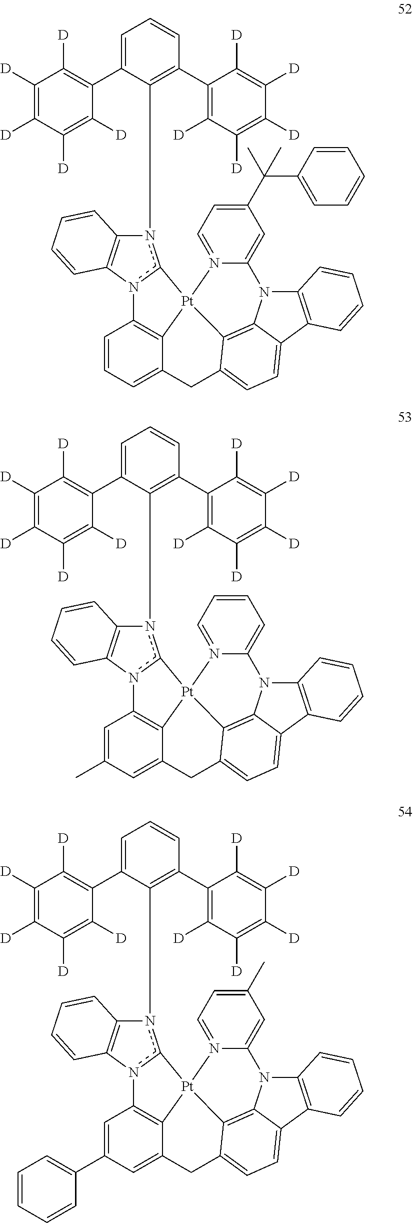 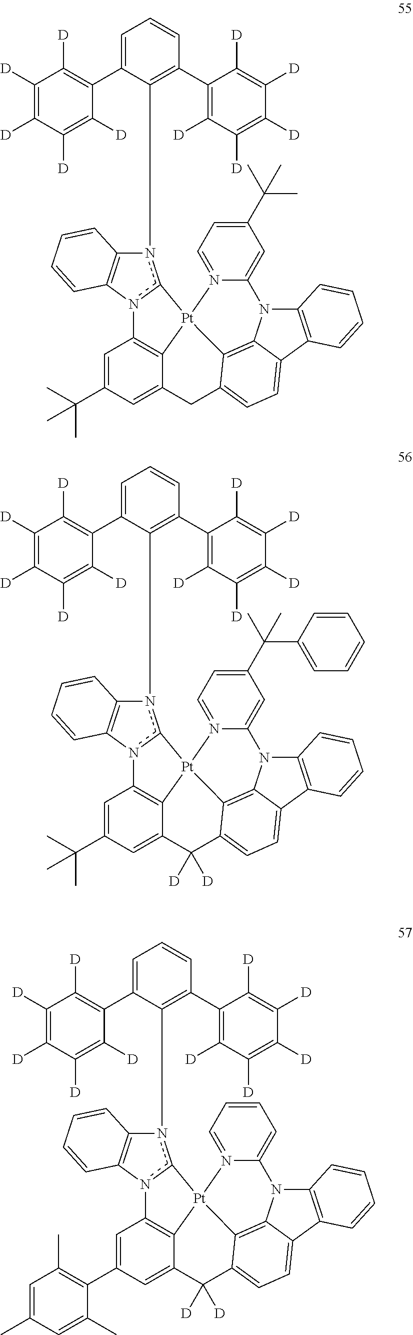 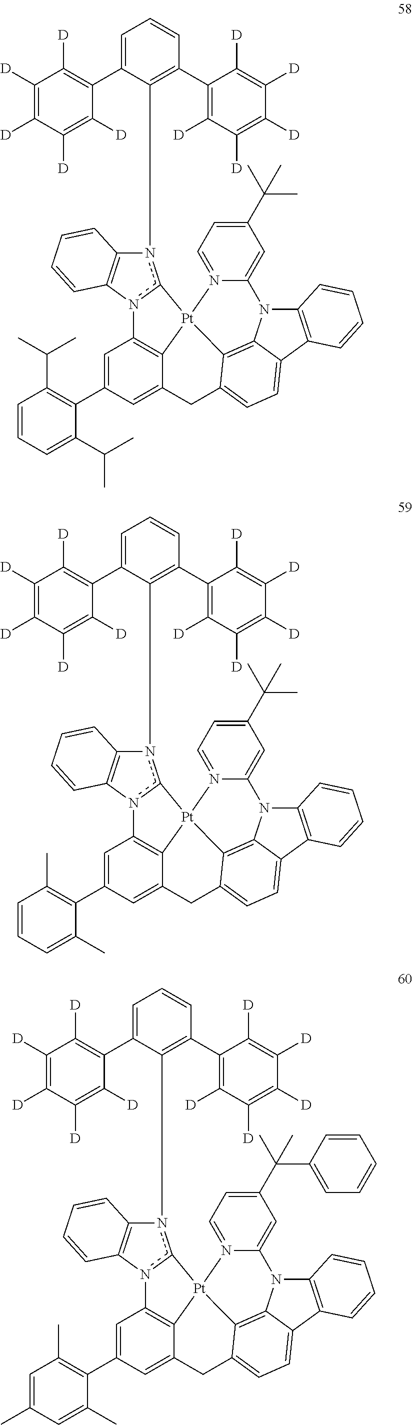 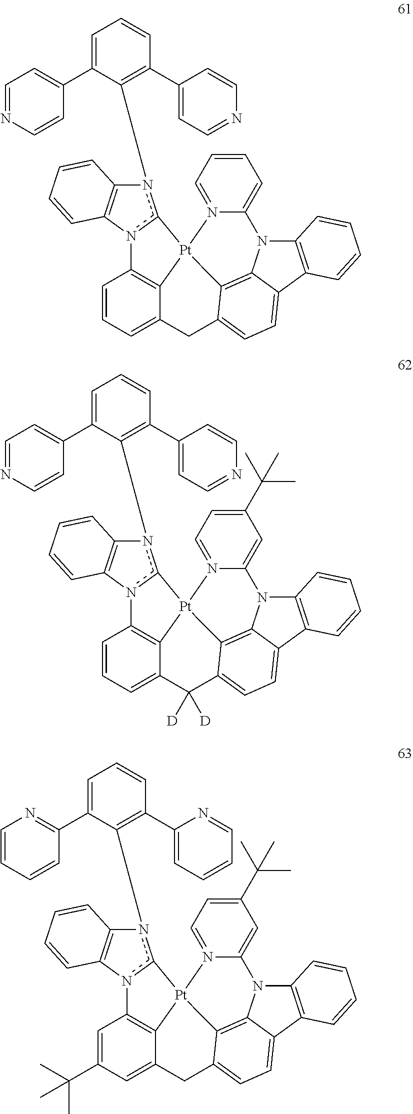 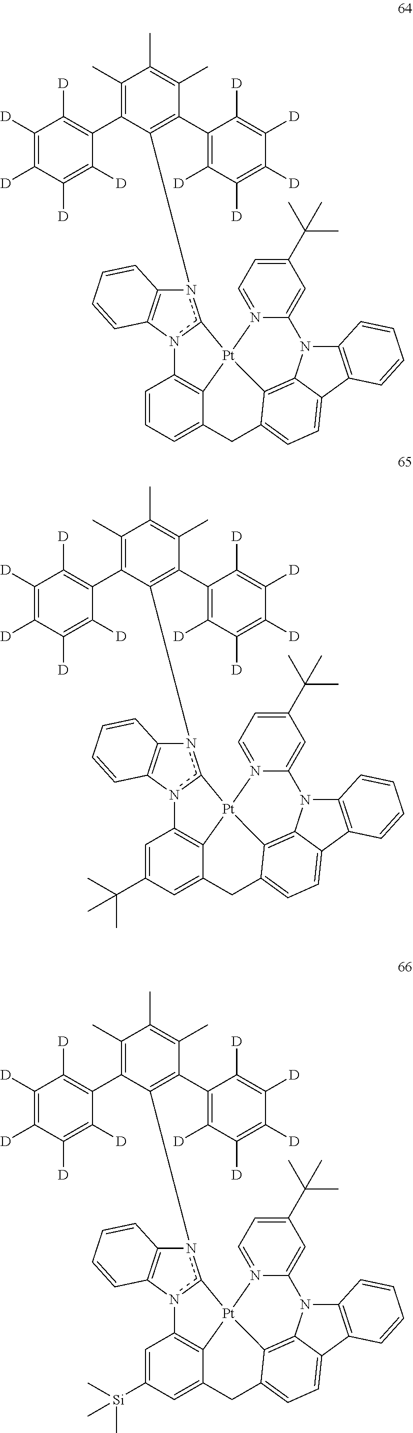 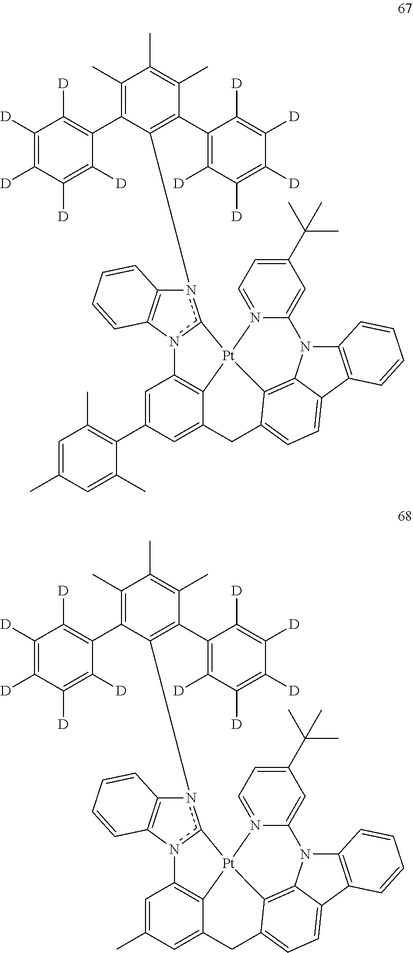 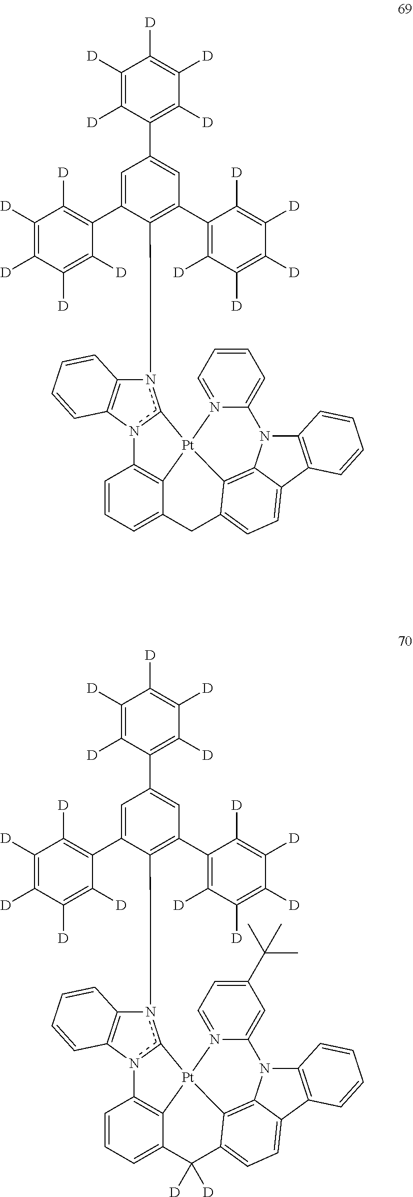 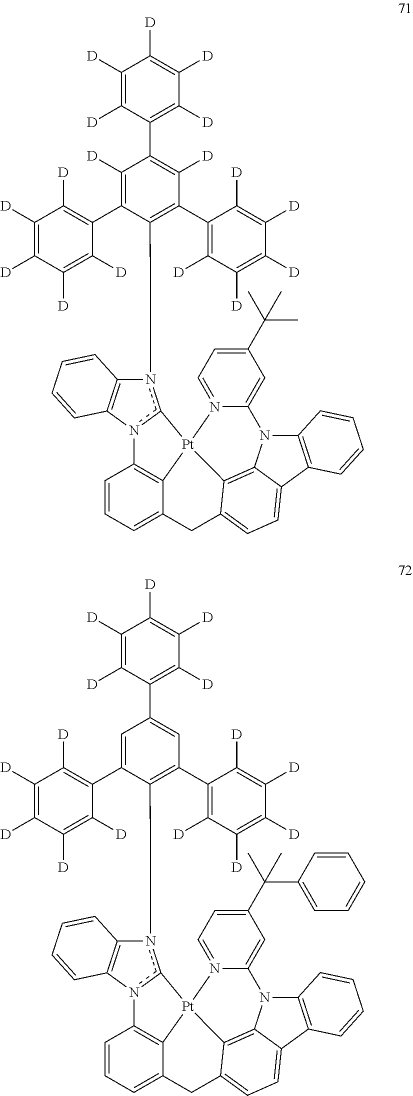 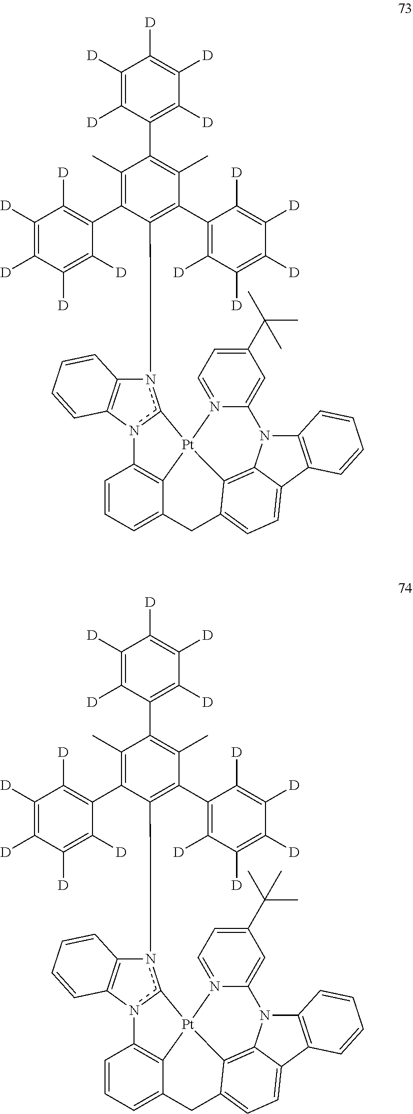 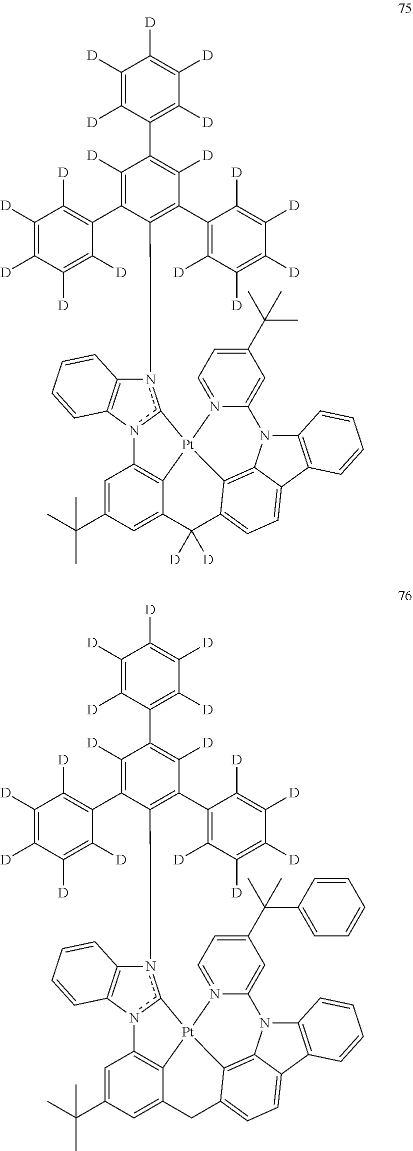 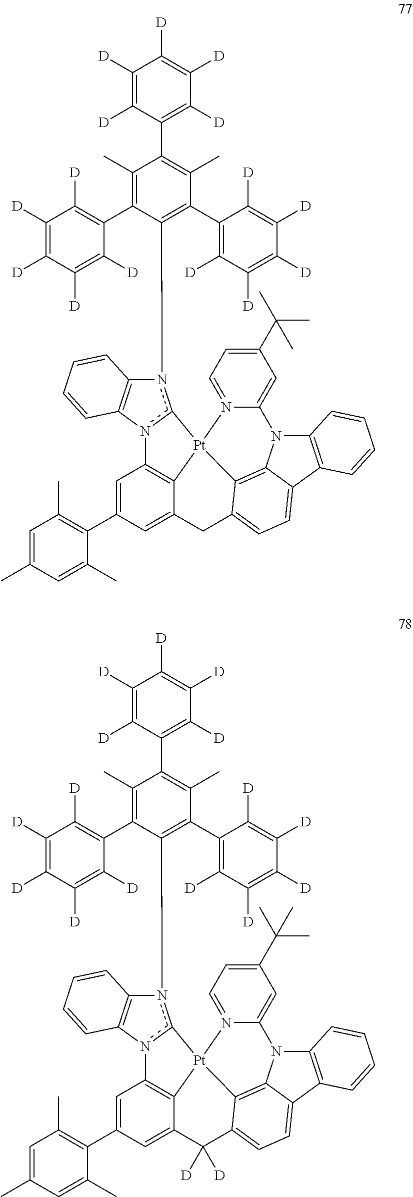 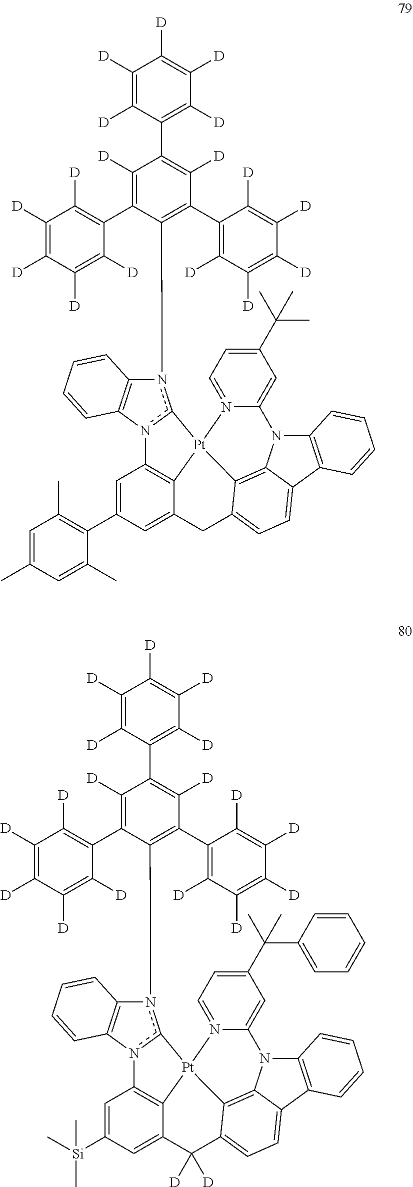 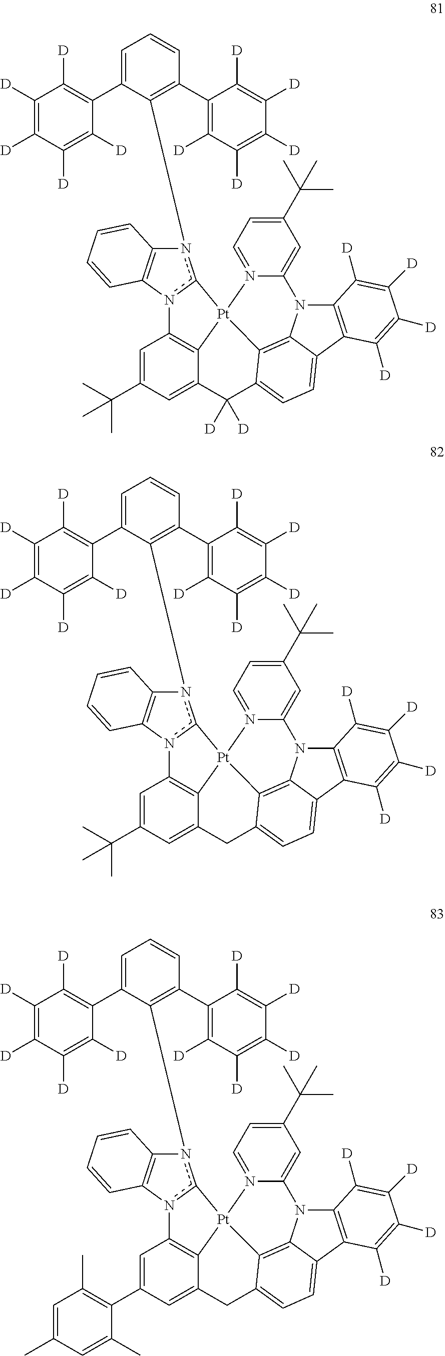 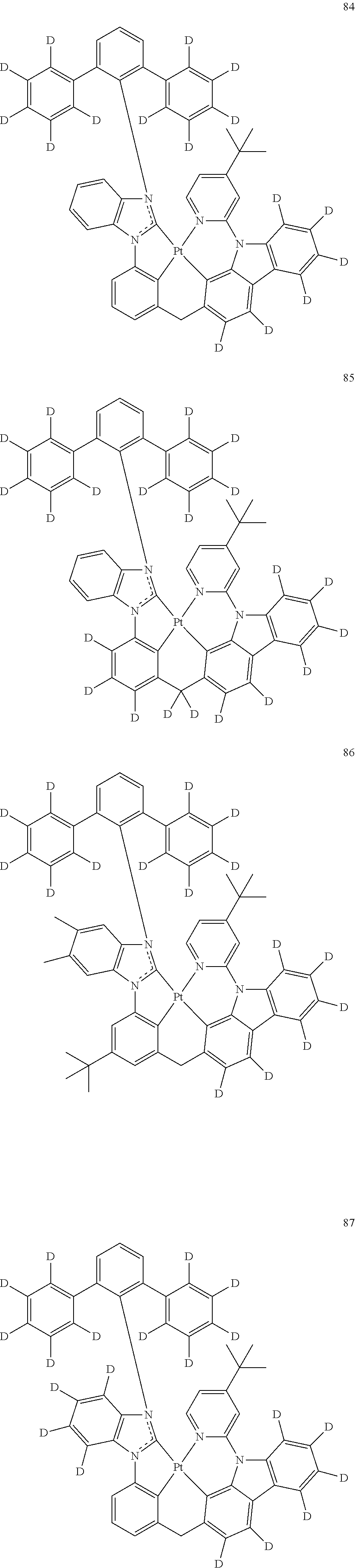 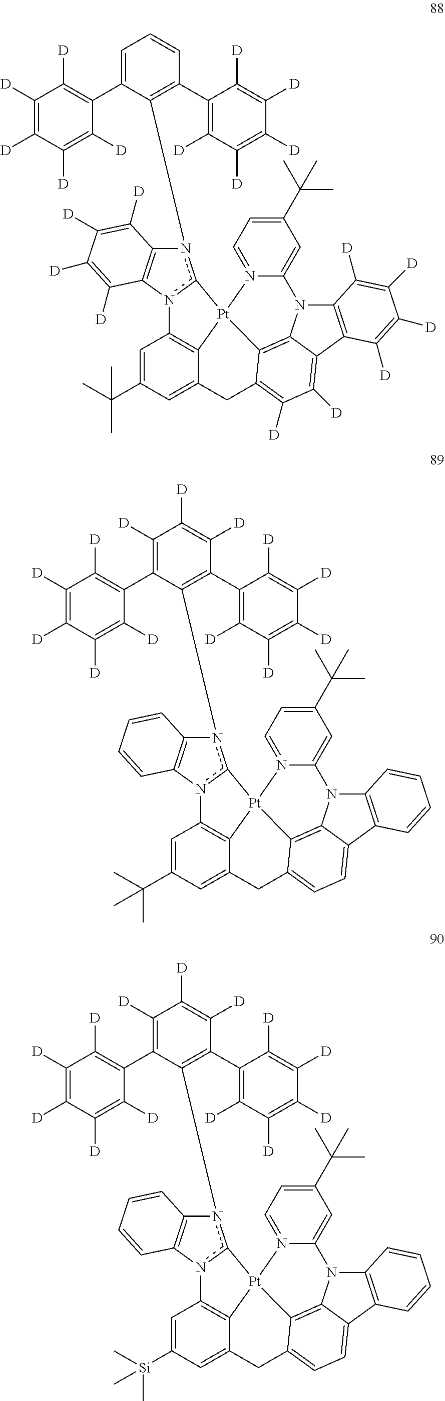 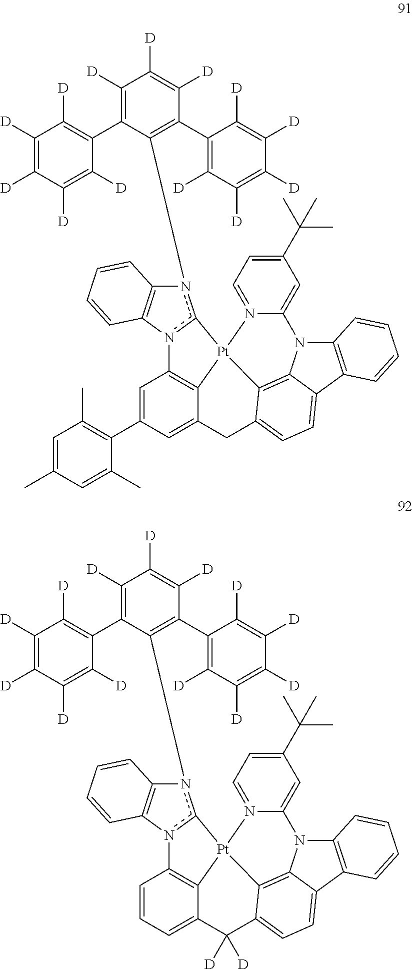 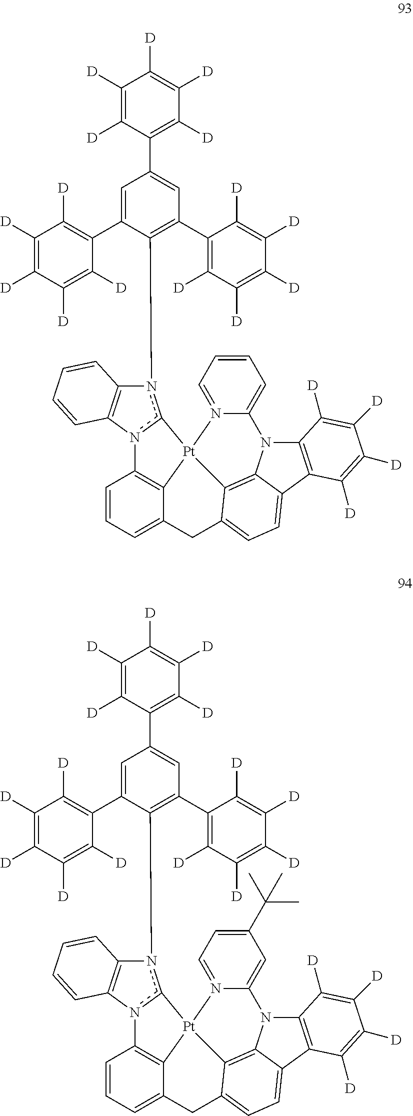 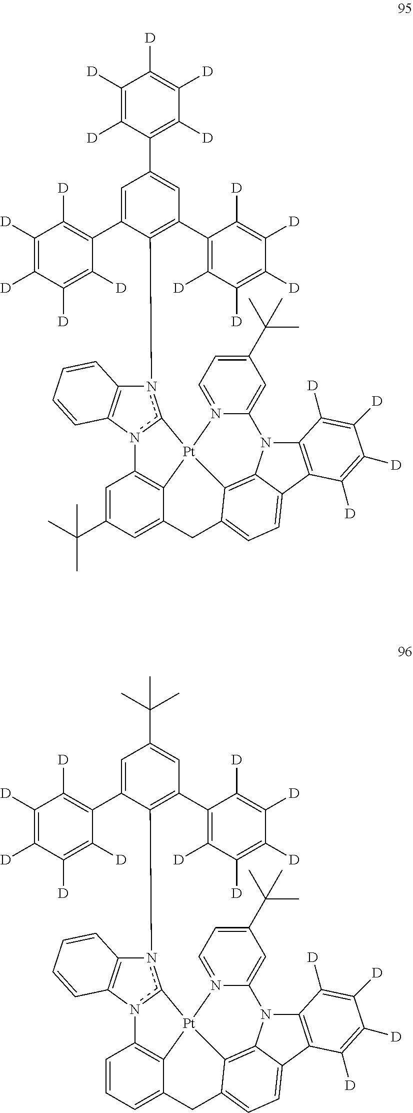 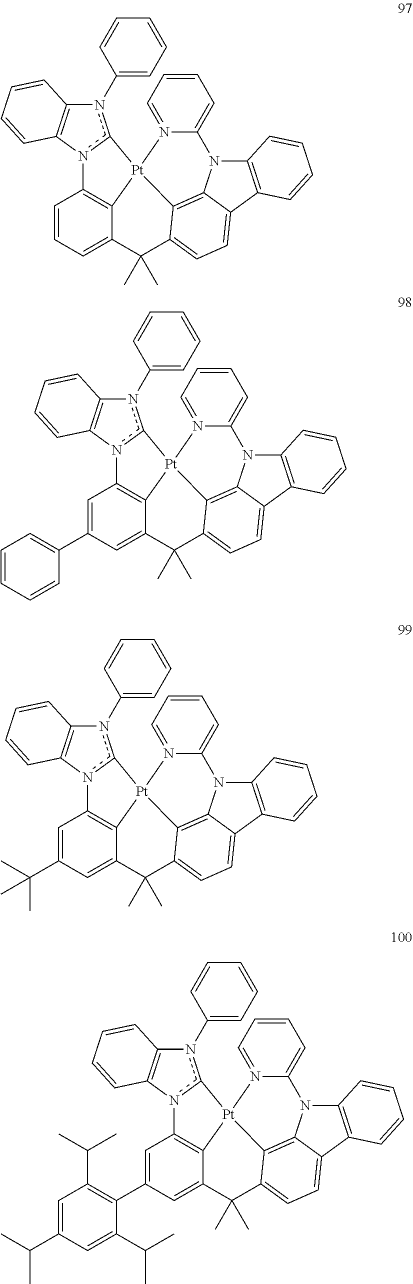 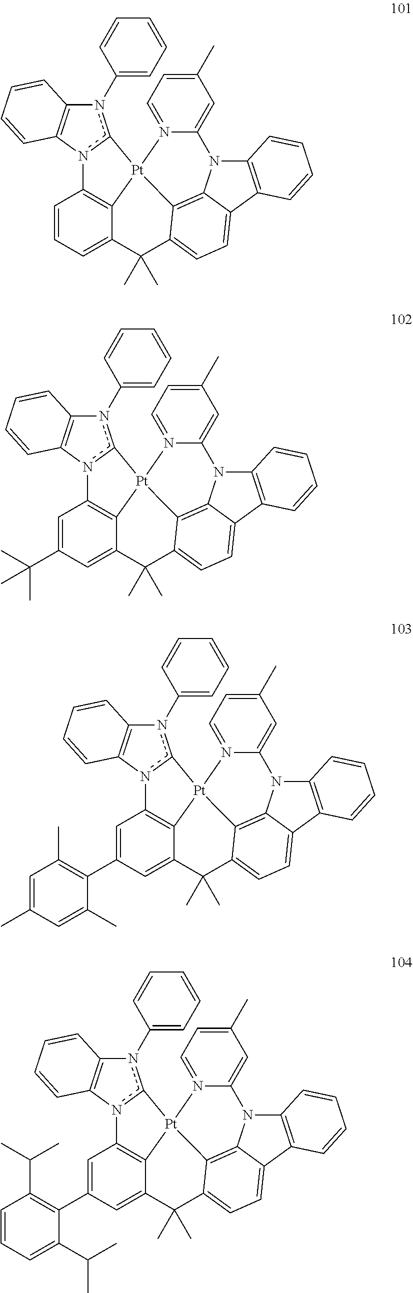 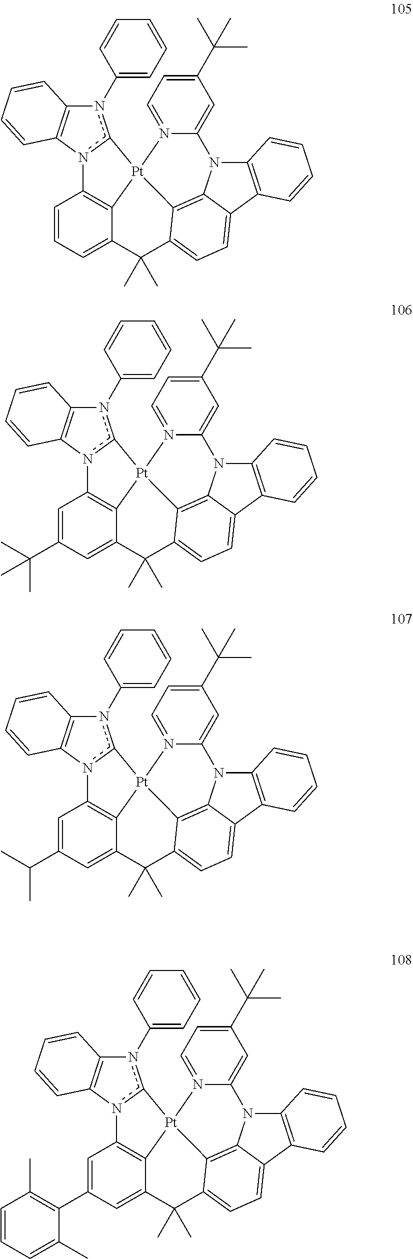 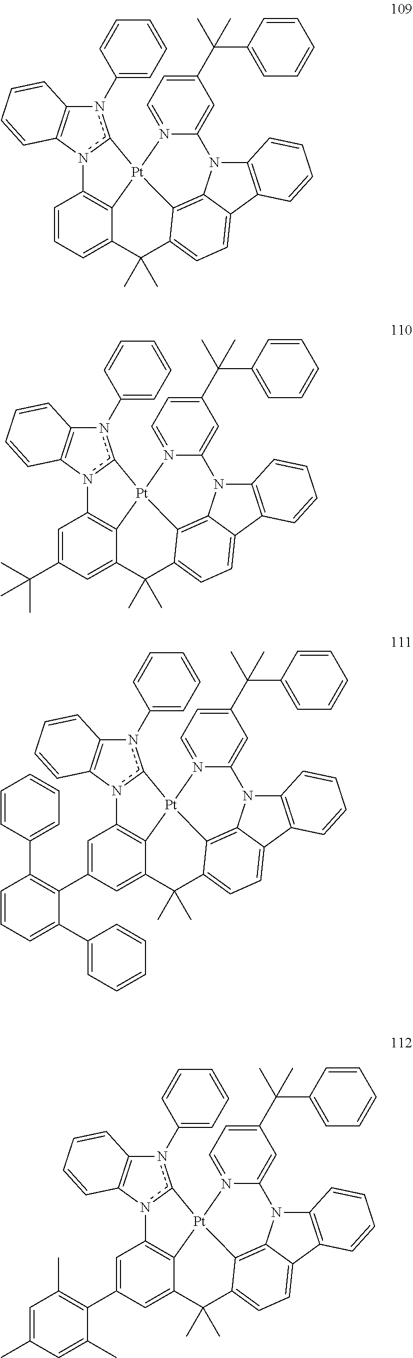 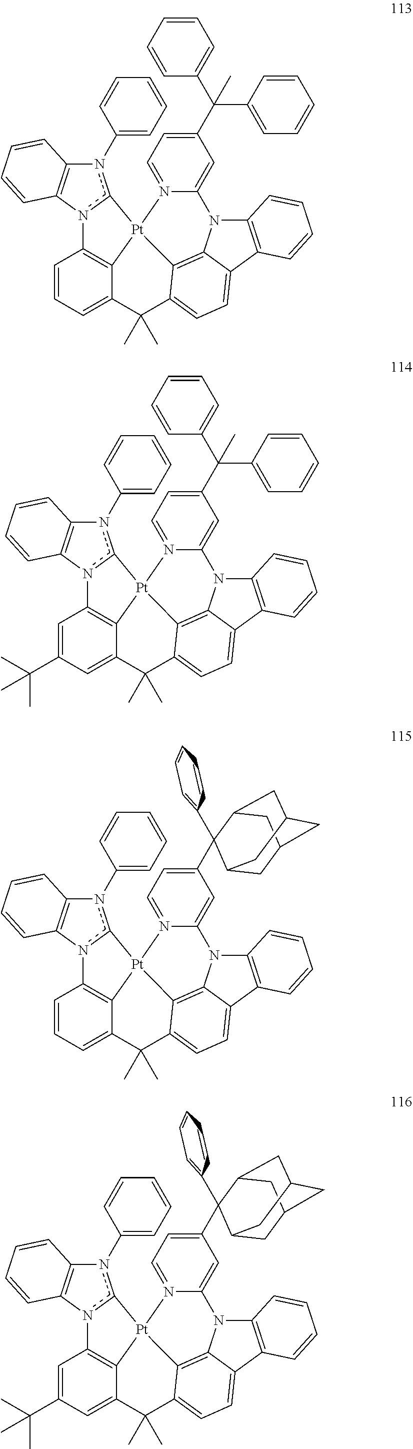 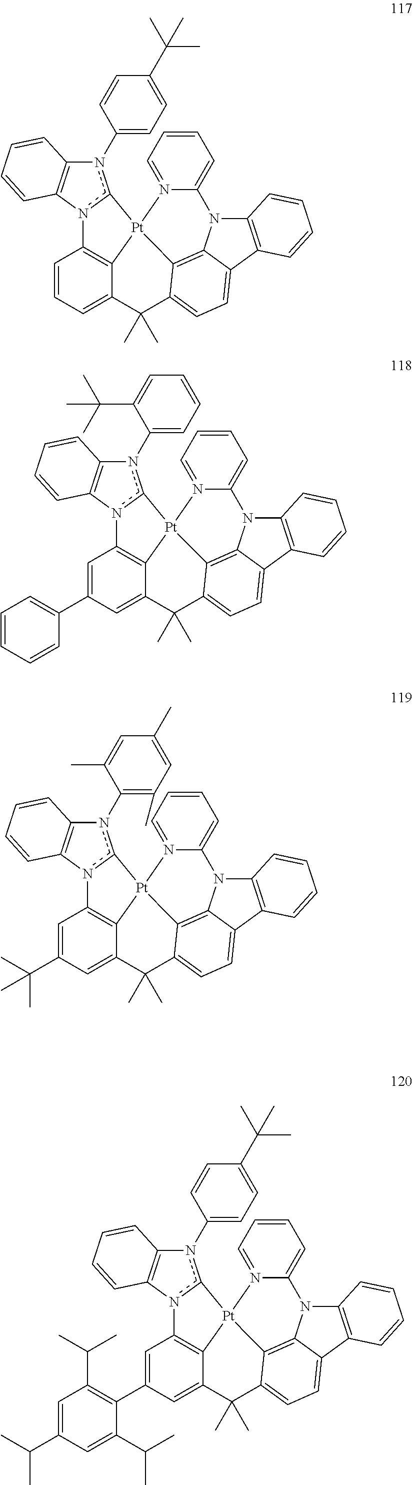 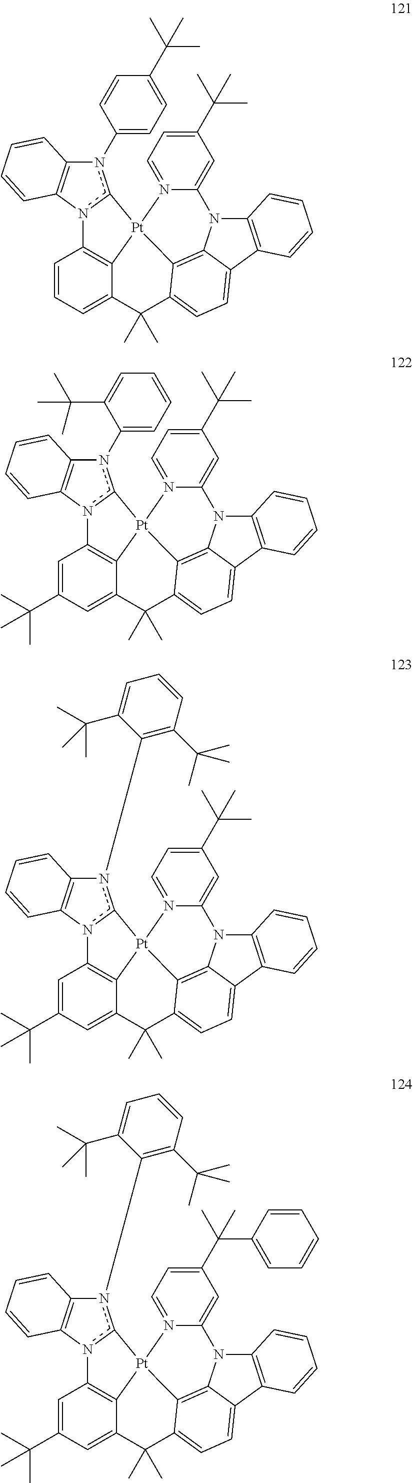 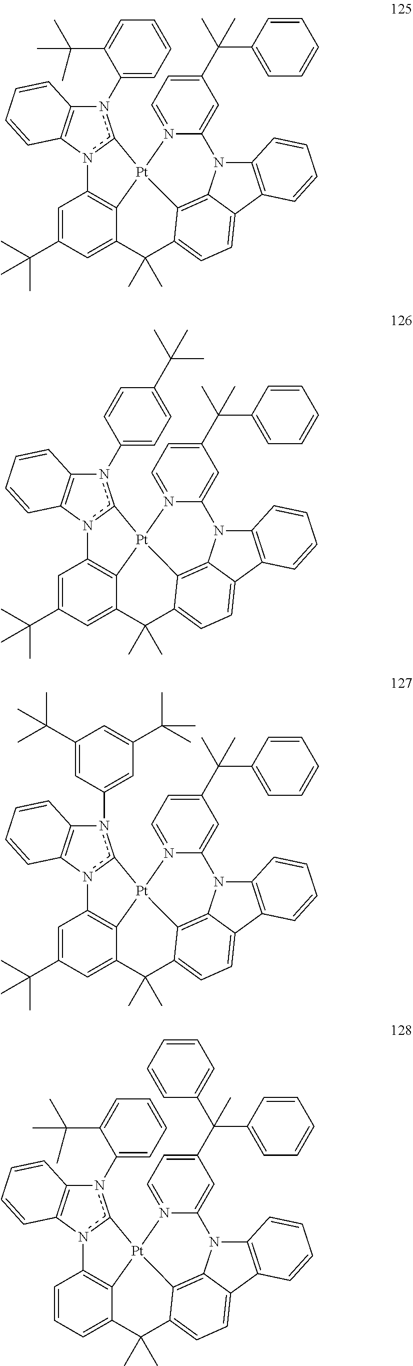 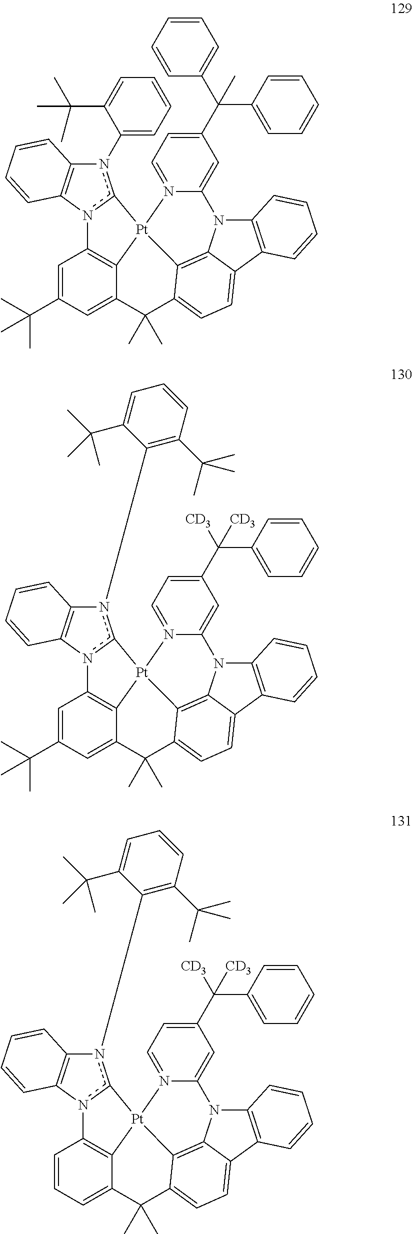 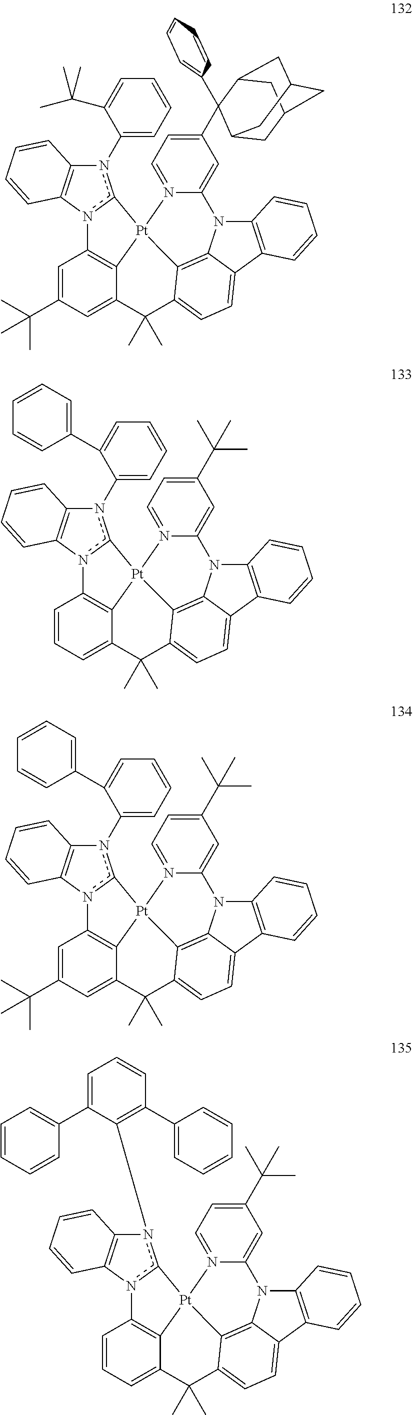 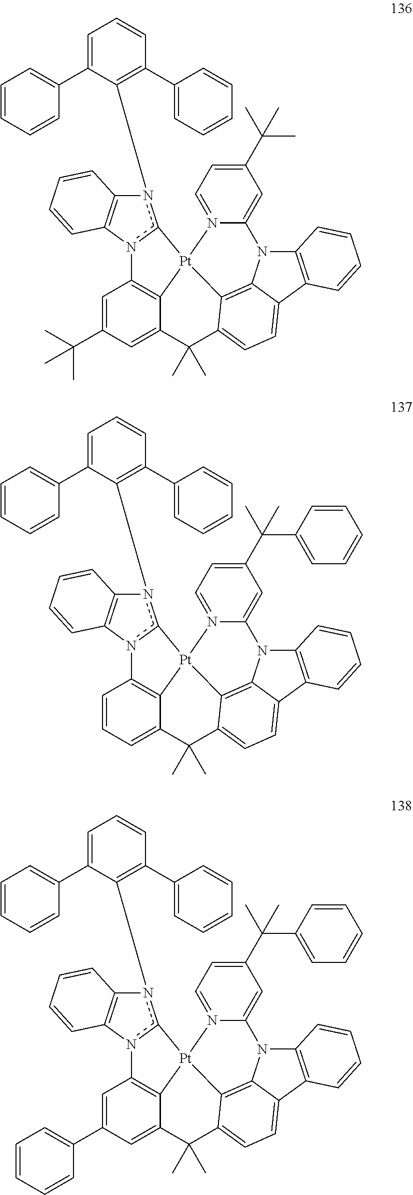 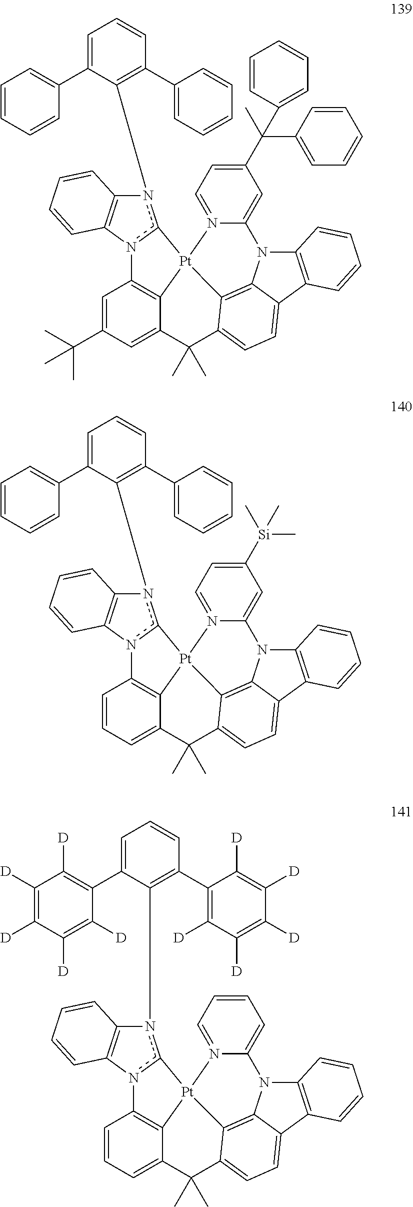 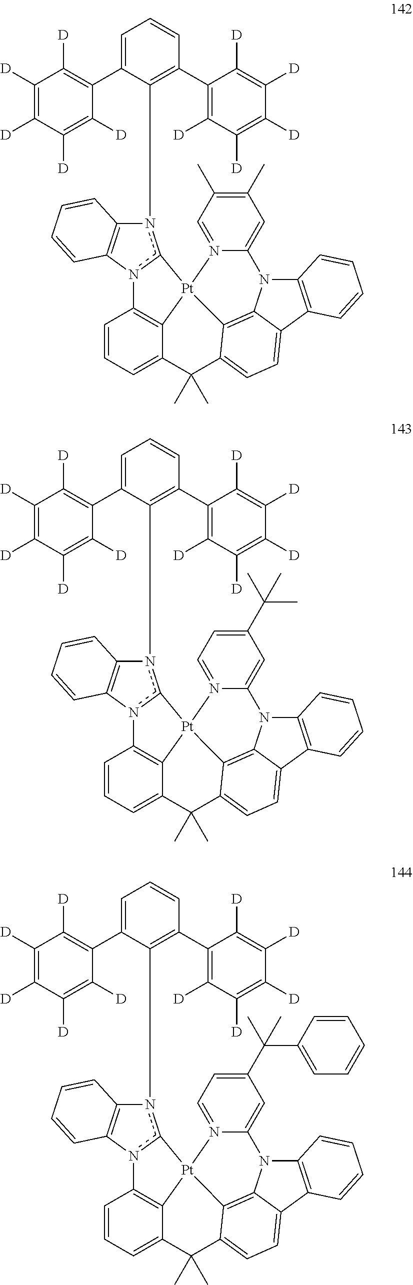 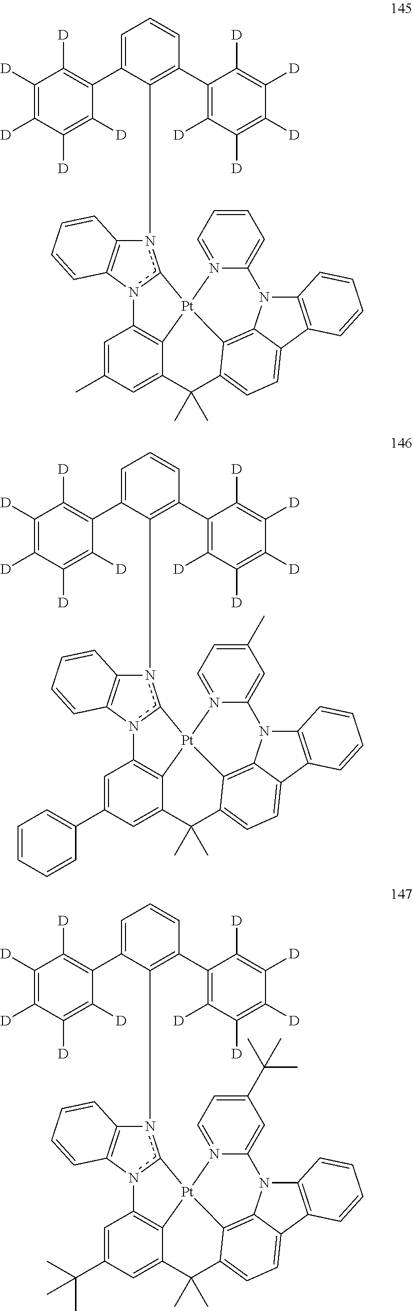 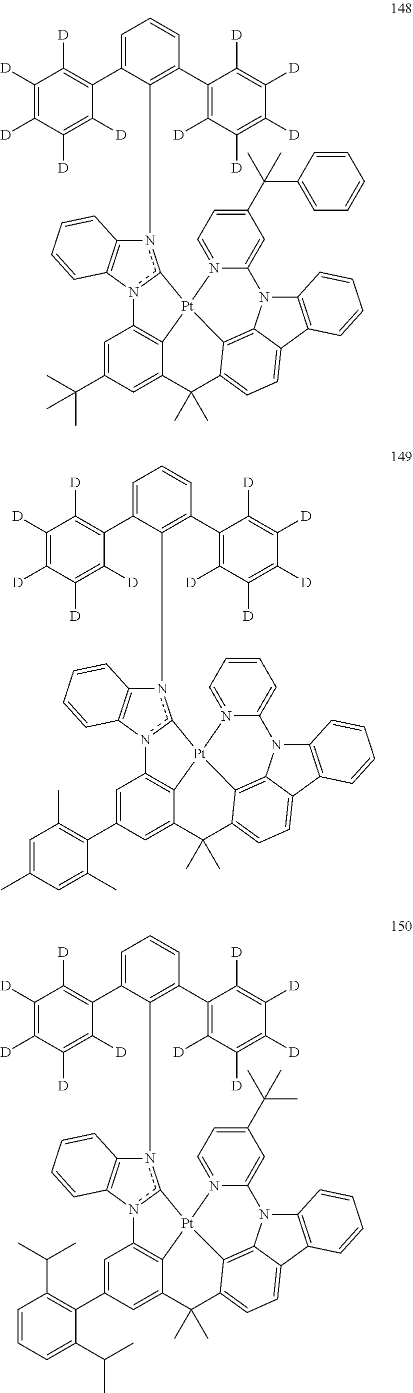 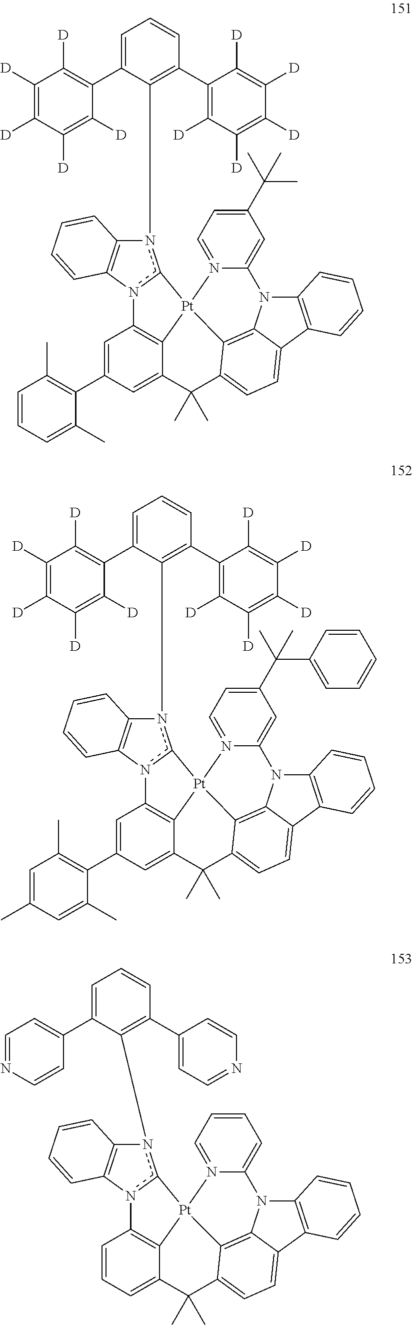 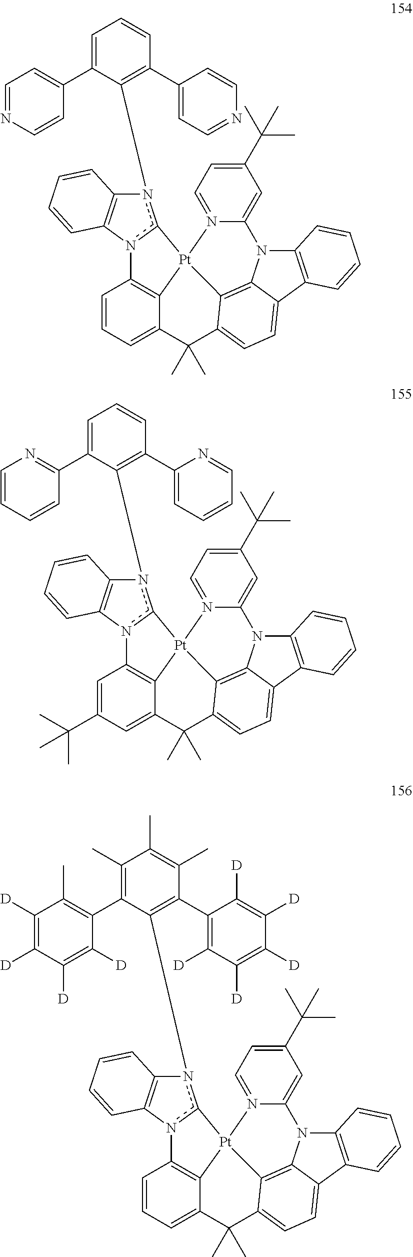 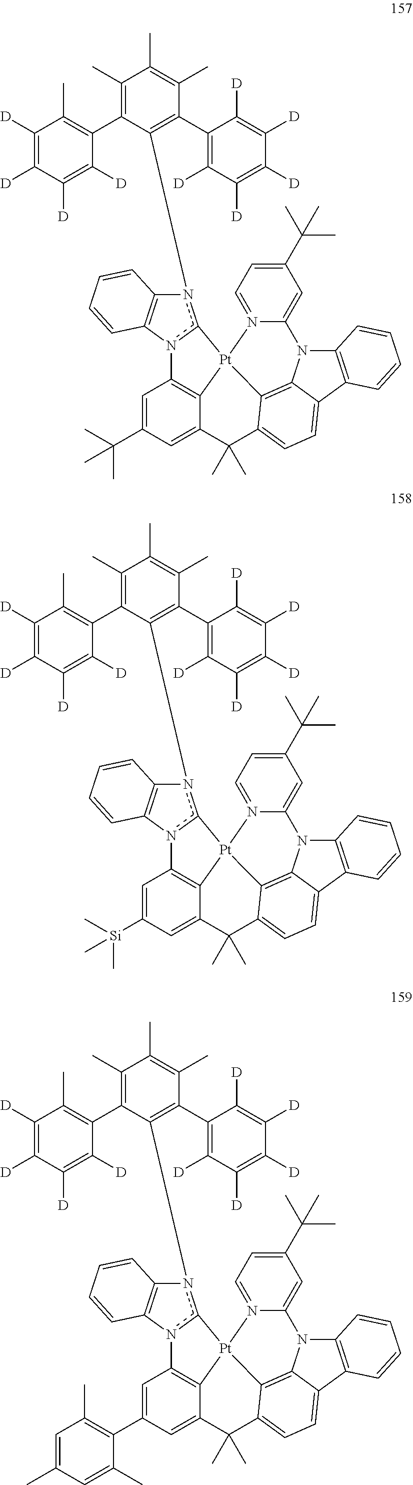 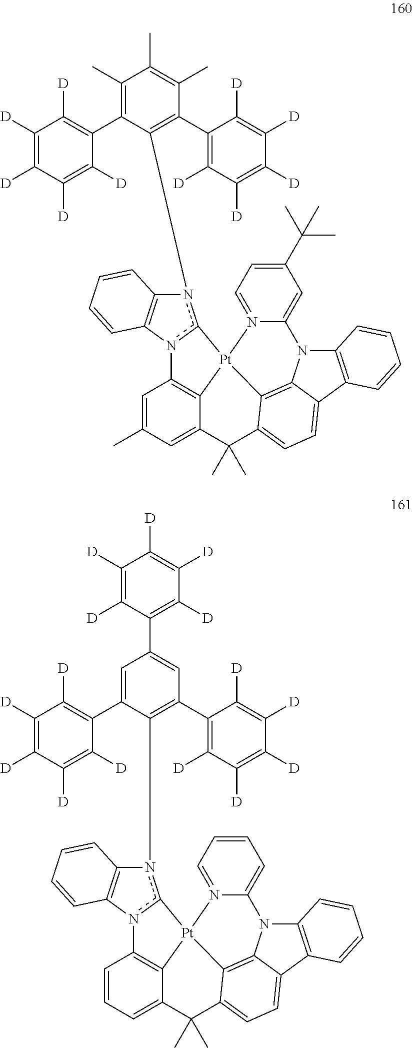 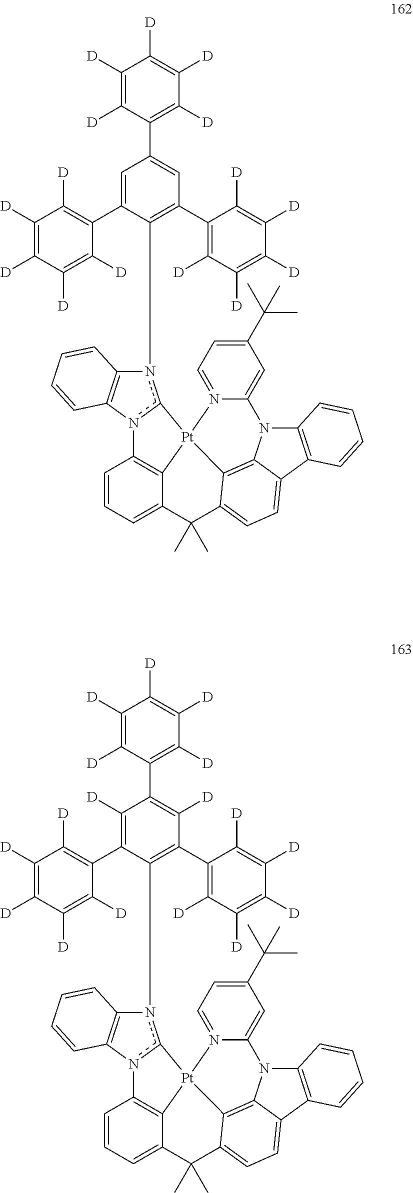 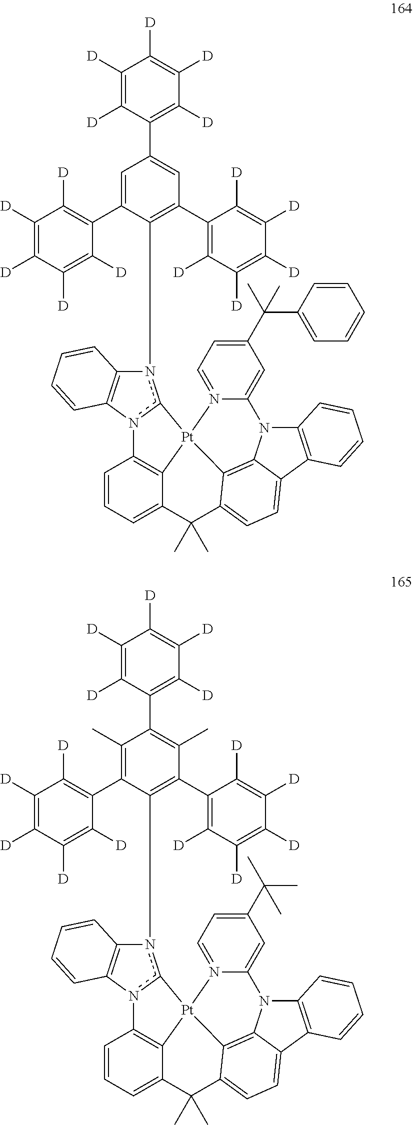 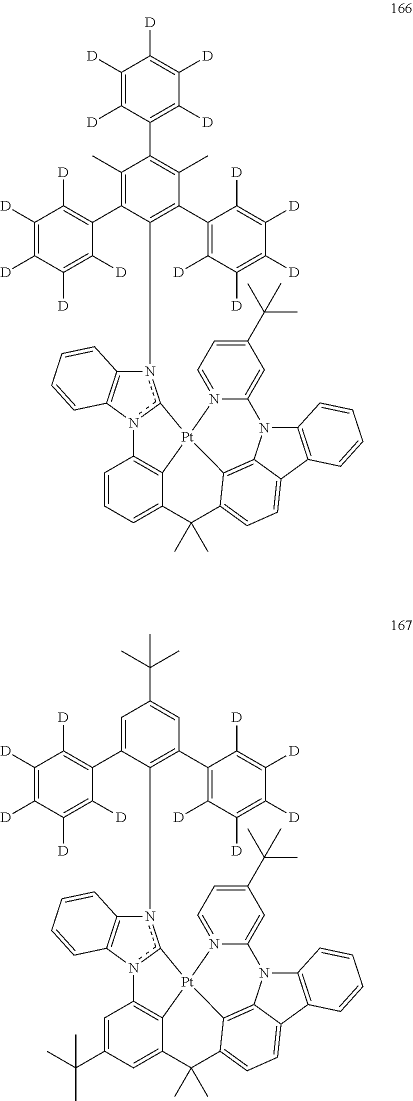 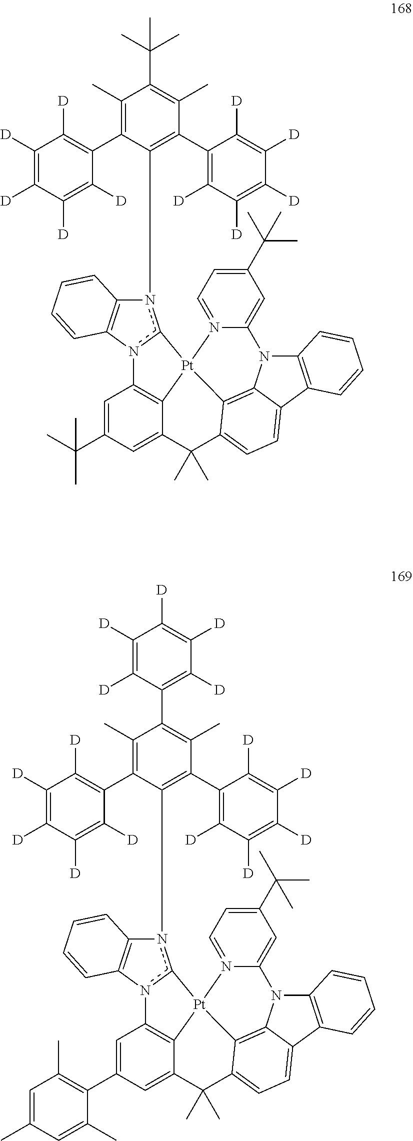 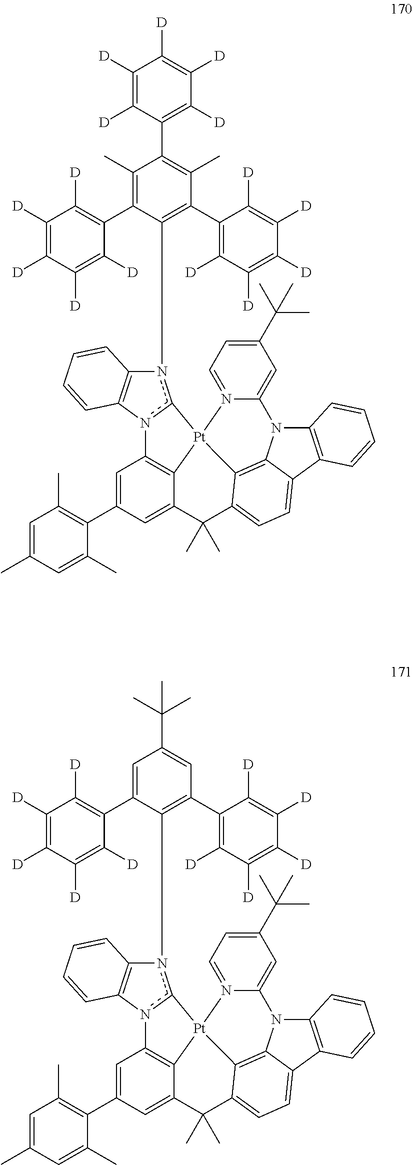 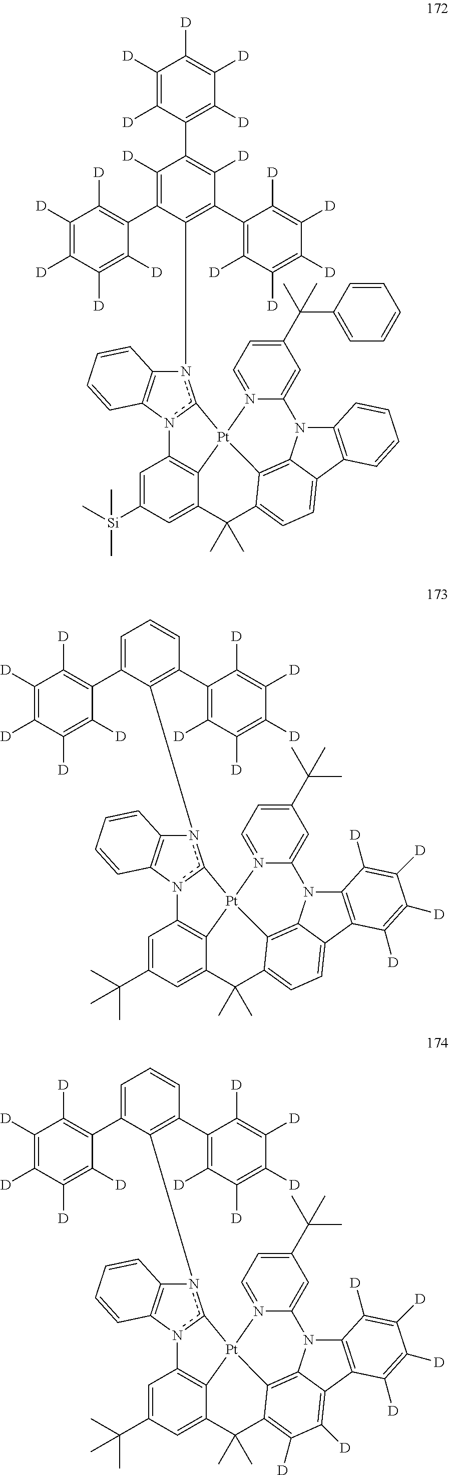 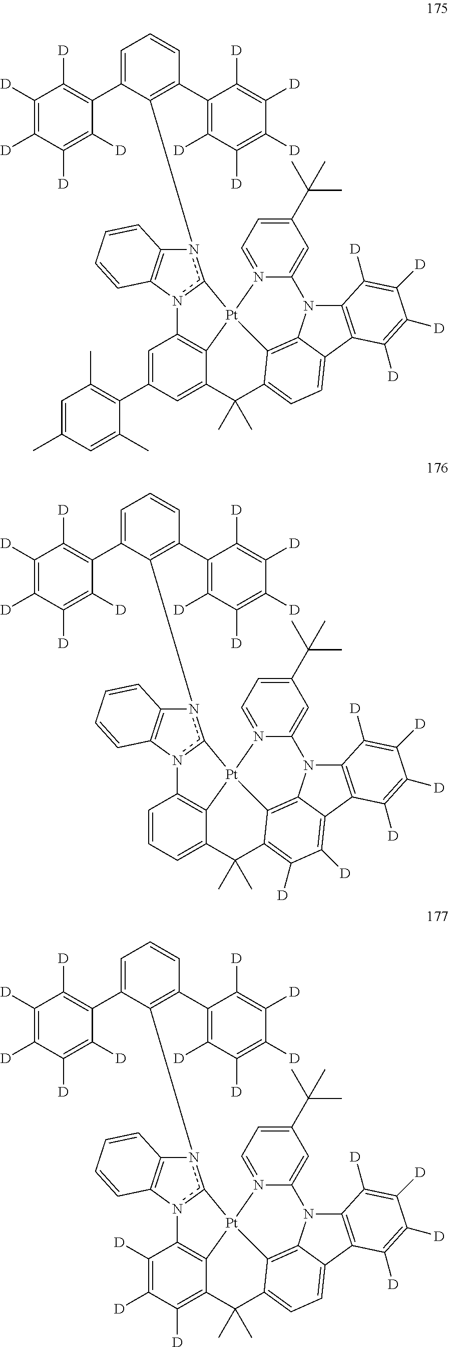 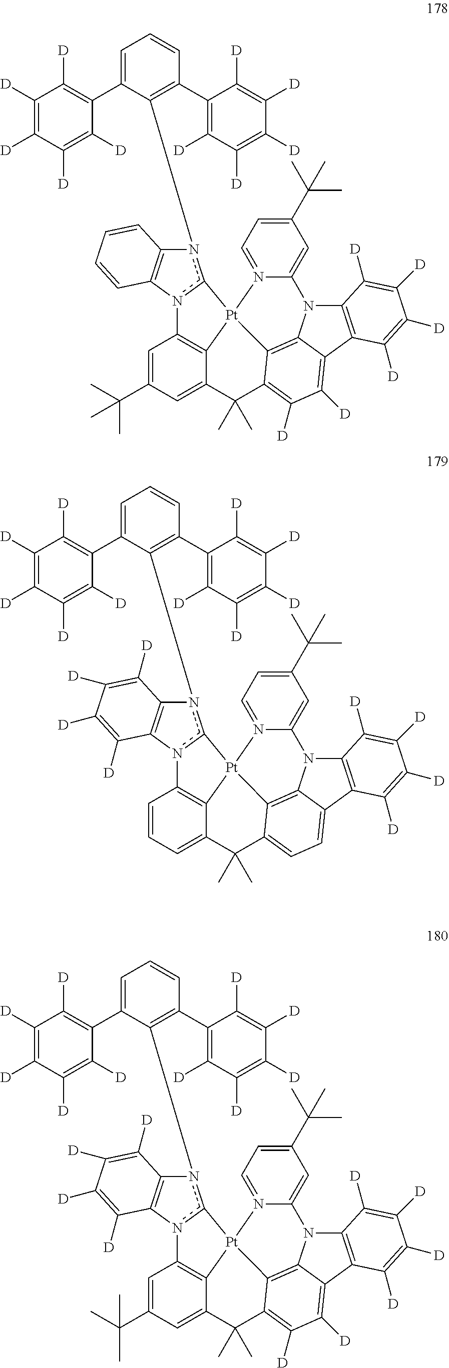 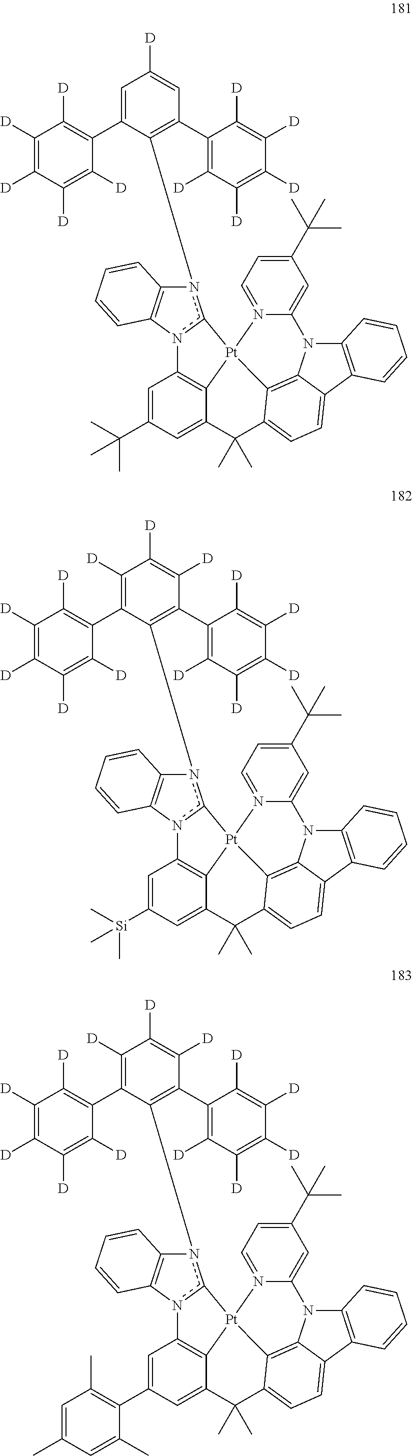 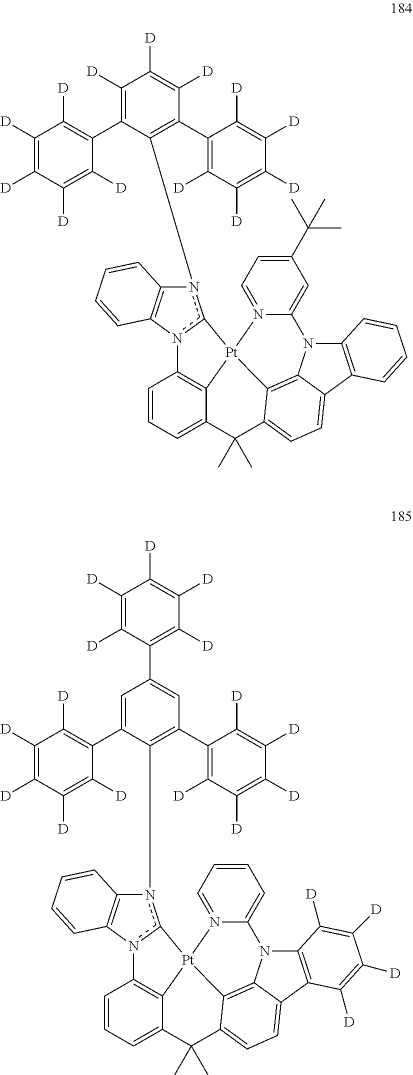 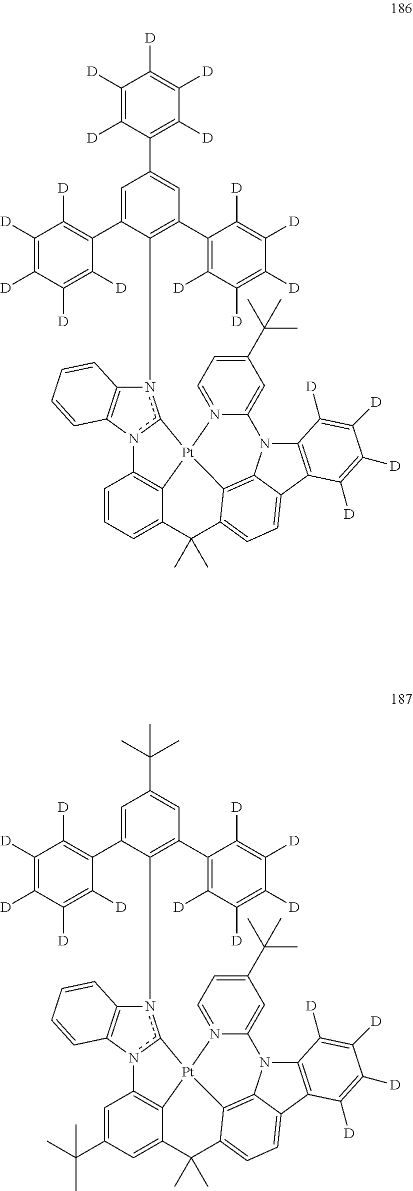 [chemical structure]
